(19) United States
(12) Patent Application Publication
(10) Pub. No.: US 2026/0271612 A1
(43) Pub. Date: Sep. 10, 2026

(54) ORGANIC ELECTROLUMINESCENT MATERIALS AND DEVICES

(71) Applicant: UNIVERSAL DISPLAY CORPORATION, Ewing, NJ (US)

(72) Inventors: Walter YEAGER, Yardley, PA (US); Wei-Chun Shih, Warrington, PA (US); Jui-Yi TSAI, Newtown, PA (US); Derek Ian Wozniak, Bensalem, PA (US); Hsiao-Fan CHEN, Princeton, NJ (US); Tyler Fleetham, Yardley, PA (US); Wystan Neil Palmer, Frenchtown, NJ (US); Robert Dyer, Media, PA (US)

(73) Assignee: UNIVERSAL DISPLAY CORPORATION, Ewing, NJ (US)

(21) Appl. No.: 19/553,614

(22) Filed: Mar. 2, 2026

Related U.S. Application Data
(60) Provisional application No. 63/765,827, filed on Mar. 3, 2025.

(51) Int. Cl. H10K 85/30; C07B 59/00; C07F 15/00; C09K 11/06; H10K 50/11

(52) U.S. Cl. CPC H10K 85/342; C07B 59/004; C07F 15/0033; C07F 15/0086; C09K 11/06; H10K 85/346; C09K 2211/185; H10K 50/11

(57) ABSTRACT

Provided are organometallic compounds comprising a central metal atom which is coordinated by an at least two-dentate ligand comprising at least one imidazole group which is fused to at least one further 5-membered to 10-membered carbocyclic or heterocyclic ring. Also provided are formulations comprising these organometallic compounds. Further provided are organic light emitting devices (OLEDs) as well as related consumer products that utilize these organometallic compounds.

### CROSS-REFERENCE TO RELATED APPLICATIONS

This application claims priority under 35 U.S.C. § 119(e) to U.S. Provisional Application No. 63/765,827, filed on Mar. 3, 2025, the entire contents of which are incorporated herein by reference.

### FIELD

The present disclosure generally relates to organic or metal coordination compounds and compositions and their various uses including as emitters, sensitizers, charge transporters, or exciton transporters in devices such as organic light emitting diodes and related electronic devices and consumer products.

### BACKGROUND

Opto-electronic devices that make use of organic materials are becoming increasingly desirable for various reasons. Many of the materials used to make such devices are relatively inexpensive, so organic opto-electronic devices have the potential for cost advantages over inorganic devices. In addition, the inherent properties of organic materials, such as their flexibility, may make them well suited for particular applications such as fabrication on a flexible substrate. Examples of organic opto-electronic devices include organic light emitting diodes/devices (OLEDs), organic phototransistors, organic photovoltaic cells, organic scintillators, and organic photodetectors. For OLEDs, the organic materials may have performance advantages over conventional materials.

OLEDs make use of thin organic films that emit light when voltage is applied across the device. OLEDs are becoming an increasingly interesting technology for use in applications such as displays, illumination, and backlighting.

One application for emissive molecules is a full color display. Industry standards for such a display call for pixels adapted to emit particular colors, referred to as “saturated” colors. In particular, these standards call for saturated red, green, and blue pixels. Alternatively, the OLED can be designed to emit white light. In conventional liquid crystal displays emission from a white backlight is filtered using absorption filters to produce red, green and blue emission. The same technique can also be used with OLEDs. The white OLED can be either a single emissive layer (EML) device or a stack structure. Color may be measured using CIE coordinates, which are well known to the art.

### SUMMARY

In one aspect, the present disclosure provides a compound having a first ligand L_{A} comprising a structure of Formula I:

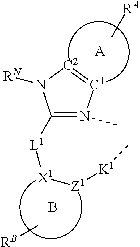

wherein C¹ and C² are carbon atoms;
wherein X¹ is C or N;
wherein Z¹ is C or N;
wherein K¹ is selected from the group consisting of a direct bond, O, S, N(R^{α}), P(R^{α}), B(R^{α}), C(R^{α})(R^{β}), and Si(R^{α})(R^{β});
wherein if K¹ is selected from the group consisting of O, S, N(R^{α}), P(R^{α}), B(R^{α}), C(R^{α})(R^{β}), and Si(R^{α})(R^{β}), then Z¹ is C;
wherein L¹ is selected from the group consisting of a direct bond, O, S, Se, NR, BR, BRR′, PR, CR, C═O, C═NR, C═CRR′, C═S, CRR′, SO, SO₂, P(O)R, SiRR′, GeRR′, alkylene, cycloalkyl, aryl, cycloalkylene, arylene, and heteroarylene;
wherein L_{A} is coordinated to a metal M;
wherein M is selected from the group consisting of Ir, Rh, Re, Ru, Os, Pt, Pd, Ag, Au, and Cu;
wherein moiety A is a fused ring system comprised of exactly one 5-membered ring and one 6-membered ring, and the 5-membered ring comprises C¹ and C²;
wherein moiety B is a monocyclic ring or a polycyclic fused ring system, wherein the monocyclic ring or each ring of the polycyclic fused ring system is independently a 5-membered to 10-membered carbocyclic or heterocyclic ring with the proviso that when M is Ir, moiety B is a polycyclic fused ring system;
wherein R^{A} and R^{B} each independently represent mono to the maximum allowable substitution, or no substitution;
wherein each of R^{N}, R, R′, R^{α}, R^{β}, R^{A}, and R^{B} is independently hydrogen or a substituent selected from the group consisting of deuterium, halogen, alkyl, cycloalkyl, heteroalkyl, heterocycloalkyl, arylalkyl, alkoxy, carboxylic acid, ether, ester, nitrile, isonitrile, sulfanyl, sulfinyl, sulfonyl, phosphino, and combinations thereof;
wherein L_{A} may be joined with other ligands to comprise a tridentate, tetradentate, pentadentate, or hexadentate ligand; and
wherein any two of R^{N}, R, R′, R^{α}, R^{β}, R^{A}, and R^{B} may be joined or fused to form a ring, with the proviso that when M is Ir, two R^{A} substituents do not join to form a ring.

In another aspect, the present disclosure provides a formulation of the compound as described herein.

In yet another aspect, the present disclosure provides an OLED having an organic layer comprising the compound as described herein.

In yet another aspect, the present disclosure provides a consumer product comprising an OLED with an organic layer comprising the compound as described herein.

### BRIEF DESCRIPTION OF THE DRAWINGS

FIG. 1 shows an organic light emitting device.

FIG. 2 shows an inverted organic light emitting device that does not have a separate electron transport layer.

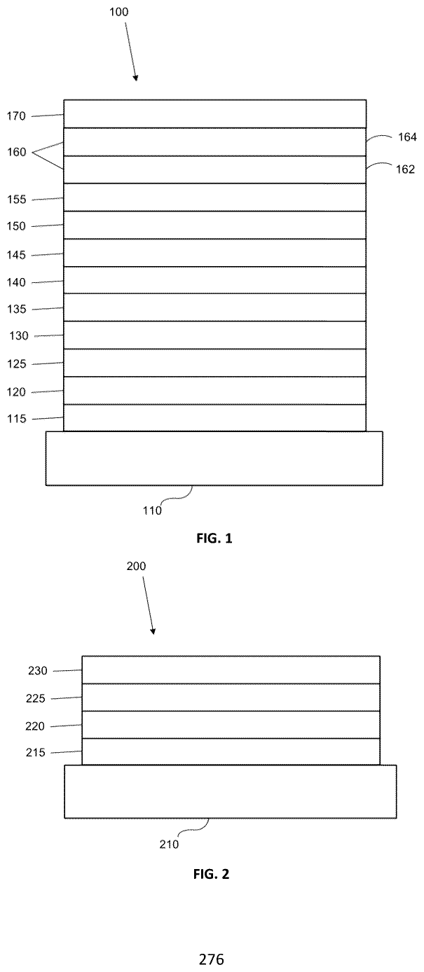

### DETAILED DESCRIPTION

### A. Terminology

Unless otherwise specified, the below terms used herein are defined as follows:

As used herein, “top” means furthest away from the substrate, while “bottom” means closest to the substrate. Where a first layer is described as “disposed over” a second layer, the first layer is disposed further away from substrate. There may be other layers between the first and second layer, unless it is specified that the first layer is “in contact with” the second layer. For example, a cathode may be described as “disposed over” an anode, even though there are various organic layers in between.

As used herein, “solution processable” means capable of being dissolved, dispersed, or transported in and/or deposited from a liquid medium, either in solution or suspension form.

As used herein, and as would be generally understood by one skilled in the art, a first “Highest Occupied Molecular Orbital” (HOMO) or “Lowest Unoccupied Molecular Orbital” (LUMO) energy level is “greater than” or “higher than” a second HOMO or LUMO energy level if the first energy level is closer to the vacuum energy level. Since ionization potentials (IP) are measured as a negative energy relative to a vacuum level, a higher HOMO energy level corresponds to an IP having a smaller absolute value (an IP that is less negative). Similarly, a higher LUMO energy level corresponds to an electron affinity (EA) having a smaller absolute value (an EA that is less negative). On a conventional energy level diagram, with the vacuum level at the top, the LUMO energy level of a material is higher than the HOMO energy level of the same material. A “higher” HOMO or LUMO energy level appears closer to the top of such a diagram than a “lower” HOMO or LUMO energy level.

As used herein, and as would be generally understood by one skilled in the art, a first work function is “greater than” or “higher than” a second work function if the first work function has a higher absolute value. Because work functions are generally measured as negative numbers relative to vacuum level, this means that a “higher” work function is more negative. On a conventional energy level diagram, with the vacuum level at the top, a “higher” work function is illustrated as further away from the vacuum level in the downward direction. Thus, the definitions of HOMO and LUMO energy levels follow a different convention than work functions.

Layers, materials, regions, and devices may be described herein in reference to the color of light they emit. In general, as used herein, an emissive region that is described as producing a specific color of light may include one or more emissive layers disposed over each other in a stack.

As used herein, a “NIR”, “red”, “green”, “blue”, “yellow” layer, material, region, or device refers to a layer, a material, a region, or a device that emits light in the wavelength range of about 700-1500 nm, 580-700 nm, 500-600 nm, 400-500 nm, 540-600 nm, respectively, or a layer, a material, a region, or a device that has a highest peak in its emission spectrum in the respective wavelength region. In some arrangements, separate regions, layers, materials, or devices may provide separate “deep blue” and “light blue” emissions. As used herein, the “deep blue” emission component refers to an emission having a peak emission wavelength that is at least about 4 nm less than the peak emission wavelength of the “light blue” emission component. Typically, a “light blue” emission component has a peak emission wavelength in the range of about 465-500 nm, and a “deep blue” emission component has a peak emission wavelength in the range of about 400-470 nm, though these ranges may vary for some configurations.

In some arrangements, a color altering layer that converts, modifies, or shifts the color of the light emitted by another layer to an emission having a different wavelength is provided. Such a color altering layer can be formulated to shift wavelength of the light emitted by the other layer by a defined amount, as measured by the difference in the wavelength of the emitted light and the wavelength of the resulting light. In general, there are two classes of color altering layers: color filters that modify a spectrum by removing light of unwanted wavelengths, and color changing layers that convert photons of higher energy to lower energy. For example, a “red” color filter can be present in order to filter an input light to remove light having a wavelength outside the range of about 580-700 nm. A component “of a color” refers to a component that, when activated or used, produces or otherwise emits light having a particular color as previously described. For example, a “first emissive region of a first color” and a “second emissive region of a second color different than the first color” describes two emissive regions that, when activated within a device, emit two different colors as previously described.

As used herein, emissive materials, layers, and regions may be distinguished from one another and from other structures based upon light initially generated by the material, layer or region, as opposed to light eventually emitted by the same or a different structure. The initial light generation typically is the result of an energy level change resulting in emission of a photon. For example, an organic emissive material may initially generate blue light, which may be converted by a color filter, quantum dot or other structure to red or green light, such that a complete emissive stack or sub-pixel emits the red or green light. In this case the initial emissive material, region, or layer may be referred to as a “blue” component, even though the sub-pixel is a “red” or “green” component.

In some cases, it may be preferable to describe the color of a component such as an emissive region, sub-pixel, color altering layer, or the like, in terms of 1931 CIE coordinates. For example, a yellow emissive material may have multiple peak emission wavelengths, one in or near an edge of the “green” region, and one within or near an edge of the “red” region as previously described. Accordingly, as used herein, each color term also corresponds to a shape in the 1931 CIE coordinate color space. The shape in 1931 CIE color space is constructed by following the locus between two color points and any additional interior points. For example, interior shape parameters for red, green, blue, and yellow may be defined as shown below:

| Color | CIE Shape Parameters |
|---|---|
| Central Red | Locus: [0.6270, 0.3725]; [0.7347, 0.2653]; |
| | Interior: [0.5086, 0.2657] |
| Central Green | Locus: [0.0326, 0.3530]; [0.3731, 0.6245]; |
| | Interior: [0.2268, 0.3321 |
| Central Blue | Locus: [0.1746, 0.0052]; [0.0326, 0.3530]; |
| | Interior: [0.2268, 0.3321] |
| Central Yellow | Locus: [0.373l, 0.6245]; [0.6270, 0.3725]; |
| | Interior: [0.3700, 0.4087]; [0.2886, 0.4572] |

The terms “halo,” “halogen,” and “halide” are used interchangeably and refer to fluorine, chlorine, bromine, and iodine.

The term “acyl” refers to a substituted carbonyl group (—C(O)—Rₛ).

The term “ester” refers to a substituted oxycarbonyl (—O—C(O)—Rₛ or —C(O)—O—Rₛ) group.

The term “ether” refers to an —ORₛ group.

The terms “sulfanyl” or “thio-ether” are used interchangeably and refer to a —SRs group.

The term “selenyl” refers to a —SeRₛ group.

The term “sulfinyl” refers to a —S(O)—Rₛ group.

The term “sulfonyl” refers to a —SO₂—Rₛ group.

The term “phosphino” refers to a group containing at least one phosphorus atom bonded to the relevant structure. Common examples of phosphino groups include, but are not limited to, groups such as a —P(Rₛ)₂ group or a —PO(Rₛ)₂ group, wherein each Rₛ can be same or different.

The term “silyl” refers to a group containing at least one silicon atom bonded to the relevant structure. Common examples of silyl groups include, but are not limited to, groups such as a —Si(Rₛ)₃ group, wherein each Rₛ can be same or different.

The term “germyl” refers to a group containing at least one germanium atom bonded to the relevant structure. Common examples of germyl groups include, but are not limited to, groups such as a —Ge(Rₛ)₃ group, wherein each Rₛ can be same or different.

The term “boryl” refers to a group containing at least one boron atom bonded to the relevant structure. Common examples of boryl groups include, but are not limited to, groups such as a —B(Rₛ)₂ group or its Lewis adduct —B(Rₛ)₃ group, wherein Rₛ can be same or different.

In each of the above, Rₛ can be hydrogen, or a substituent selected from the group consisting of the General Substituents as defined in this application. Preferred Rₛ is selected from the group consisting of deuterium, halogen, alkyl, cycloalkyl, heteroalkyl, heterocycloalkyl, arylalkyl, alkoxy, aryloxy, amino, silyl, alkenyl, cycloalkenyl, heteroalkenyl, alkynyl, aryl, heteroaryl, and combination thereof. More preferably Rₛ is selected from the group consisting of alkyl, cycloalkyl, aryl, heteroaryl, and combination thereof.

The term “alkyl” refers to and includes both straight and branched chain alkyl groups having an alkyl carbon atom bonded to the relevant structure. Preferred alkyl groups are those containing from one to fifteen carbon atoms, preferably one to nine carbon atoms, and the preferred alkyl groups include methyl, ethyl, n-propyl, iso-propyl, n-butyl, sec-butyl, iso-butyl, tert-butyl, n-pentyl, 2-methylbutyl, 3-methylbutyl, 2,2-dimethylpropyl, 1,3-dimethylpropyl, 1,1-dimethylpropyl, 2-ethylpropyl, 1,2-dimethylpropyl, n-hexyl, 2-methylpentyl, 3-methylpentyl, 2,2-dimethylbutyl, 2,3-dimethylbutyl, n-heptyl, 2-methylhexyl, 3-methylhexyl, 2,2-dimethylpentyl, 2,3-dimethylpentyl, 2,4-dimethylpentyl, 3,3-dimethylpentyl, 3-ethylpentyl, 2,2,3-trimethylbutyl, and the like. Additionally, the alkyl group can be further substituted.

The term “cycloalkyl” refers to and includes monocyclic, polycyclic, and spiro alkyl groups having a ring alkyl carbon atom bonded to the relevant structure. Preferred cycloalkyl groups are those containing 3 to 12 ring carbon atoms and includes cyclopropyl, cyclopentyl, cyclohexyl, bicyclo[3.1.1]heptyl, spiro[4.5]decyl, spiro[5.5]undecyl, adamantyl, and the like. Additionally, the cycloalkyl group can be further substituted.

The terms “heteroalkyl” or “heterocycloalkyl” refer to an alkyl or a cycloalkyl group, respectively, having at least one carbon atom replaced by a heteroatom. Optionally the at least one heteroatom is selected from O, S, N, P, B, Si, Ge and Se, preferably, O, S or N. Additionally, the heteroalkyl or heterocycloalkyl group can be further substituted.

The term “alkenyl” refers to and includes both straight and branched chain alkene groups. Alkenyl groups are essentially alkyl groups that include at least one carbon-carbon double bond in the alkyl chain with one carbon atom from the carbon-carbon double bond that is bonded to the relevant structure. Cycloalkenyl groups are essentially cycloalkyl groups that include at least one carbon-carbon double bond in the cycloalkyl ring. The term “heteroalkenyl” as used herein refers to an alkenyl group having at least one carbon atom replaced by a heteroatom. Optionally the at least one heteroatom is selected from O, S, N, P, B, Si, Ge, and Se, preferably, O, S, or N. Preferred alkenyl, cycloalkenyl, or heteroalkenyl groups are those containing two to fifteen carbon atoms. Additionally, the alkenyl, cycloalkenyl, or heteroalkenyl group can be further substituted.

The term “alkynyl” refers to and includes both straight and branched chain alkyne groups. Alkynyl groups are essentially alkyl groups that include at least one carbon-carbon triple bond in the alkyl chain with one carbon atom from the carbon-carbon triple bond that is bonded to the relevant structure. Preferred alkynyl groups are those containing two to fifteen carbon atoms. Additionally, the alkynyl group can be further substituted.

The terms “aralkyl” or “arylalkyl” are used interchangeably and refer to an aryl-substituted alkyl group having an alkyl carbon atom bonded to the relevant structure. Additionally, the aralkyl group can be further substituted.

The term “heterocyclic group” refers to and includes aromatic and non-aromatic cyclic groups containing at least one heteroatom. Optionally the at least one heteroatom is selected from O, S, Se, N, P, B, Si, Ge, and Se, preferably, O, S, N, or B. Hetero-aromatic cyclic groups may be used interchangeably with heteroaryl. Preferred hetero-non-aromatic cyclic groups are those containing 3 to 10 ring atoms, preferably those containing 3 to 7 ring atoms, which includes at least one hetero atom, and includes cyclic amines such as morpholino, piperidino, pyrrolidino, and the like, and cyclic ethers/thio-ethers, such as tetrahydrofuran, tetrahydropyran, tetrahydrothiophene, and the like. Additionally, the heterocyclic group can be further substituted or fused.

The term “aryl” refers to and includes both single-ring and polycyclic aromatic hydrocarbyl groups. The polycyclic rings may have two or more rings in which two carbons are common to two adjoining rings (the rings are “fused”). Preferred aryl groups are those containing six to thirty carbon atoms, preferably six to twenty-four carbon atoms, six to eighteen carbon atoms, and more preferably six to twelve carbon atoms. Especially preferred is an aryl group having six carbons, ten carbons, twelve carbons, fourteen carbons, or eighteen carbons. Suitable aryl groups include phenyl, biphenyl, triphenyl, triphenylene, tetraphenylene, naphthalene, anthracene, phenalene, phenanthrene, pyrene, chrysene, perylene, and azulene, preferably phenyl, biphenyl, triphenyl, triphenylene, and naphthalene. Additionally, the aryl group can be further substituted or fused, such as, without limitation, fluorene.

The term “heteroaryl” refers to and includes both single-ring aromatic groups and polycyclic aromatic ring systems that include at least one heteroatom. The heteroatoms include, but are not limited to O, S, Se, N, P, B, Si, Ge, and Se. In many instances, O, S, N, or B are the preferred heteroatoms. Hetero-single ring aromatic systems are preferably single rings with 5 or 6 ring atoms, and the ring can have from one to six heteroatoms. The hetero-polycyclic ring systems can have two or more aromatic rings in which two atoms are common to two adjoining rings (the rings are “fused”) wherein at least one of the rings is a heteroaryl. The hetero-polycyclic aromatic ring systems can have from one to six heteroatoms per ring of the polycyclic aromatic ring system. Preferred heteroaryl groups are those containing three to thirty carbon atoms, preferably three to twenty-four carbon atoms, three to eighteen carbon atoms, and more preferably three to twelve carbon atoms. Suitable heteroaryl groups include dibenzothiophene, dibenzofuran, dibenzoselenophene, furan, thiophene, benzofuran, benzothiophene, benzoselenophene, carbazole, indolocarbazole, pyridylindole, pyrrolodipyridine, pyrazole, imidazole, triazole, oxazole, thiazole, oxadiazole, oxatriazole, dioxazole, thiadiazole, pyridine, pyridazine, pyrimidine, pyrazine, triazine, oxazine, oxathiazine, oxadiazine, indole, benzimidazole, indazole, indoxazine, benzoxazole, benzisoxazole, benzothiazole, quinoline, isoquinoline, cinnoline, quinazoline, quinoxaline, naphthyridine, phthalazine, pteridine, xanthene, acridine, phenazine, phenothiazine, phenoxazine, benzofuropyridine, furodipyridine, benzothienopyridine, thienodipyridine, benzoselenophenopyridine, selenophenodipyridine, azaborine, borazine, 5λ²,9λ²-diaza-13b-boranaphtho[2,3,4-de]anthracene, 5\2-benzo[d]benzo[4,5]imidazo[3,2-a]imidazole, and 5,9-dioxa-13b-boranaphtho[3,2,1-de]anthracene; preferably dibenzothiophene, dibenzofuran, dibenzoselenophene, carbazole, indolocarbazole, imidazole, pyridine, triazine, benzimidazole, 5λ²,9λ²-diaza-13b-boranaphtho[2,3,4-de]anthracene, 5λ²-benzo[d]benzo[4,5]imidazo[3,2-a]imidazole, and 5,9-dioxa-13b-boranaphtho[3,2,1-de]anthracene. Additionally, the heteroaryl group can be further substituted or fused.

Of the aryl and heteroaryl groups listed above, the groups of triphenylene, naphthalene, anthracene, dibenzothiophene, dibenzofuran, dibenzoselenophene, carbazole, indolocarbazole, imidazole, pyridine, pyrazine, pyrimidine, triazine, benzimidazole, 5λ²,9λ²-diaza-13b-boranaphtho[2,3,4-de]anthracene, 5λ²-benzo[d]benzo[4,5]imidazo[3,2-a]imidazole, 5,9-dioxa-13b-boranaphtho[3,2,1-de]anthracene, and the respective aza-analogs of each thereof are of particular interest.

In many instances, the General Substituents are selected from the group consisting of deuterium, halogen, alkyl, cycloalkyl, heteroalkyl, heterocycloalkyl, arylalkyl, alkoxy, aryloxy, amino, silyl, germyl, boryl, alkenyl, cycloalkenyl, heteroalkenyl, alkynyl, aryl, heteroaryl, acyl, carboxylic acid, ether, ester, nitrile, isonitrile, sulfanyl, selenyl, sulfinyl, sulfonyl, phosphino, and combinations thereof.

In some instances, the Preferred General Substituents are selected from the group consisting of deuterium, fluorine, alkyl, cycloalkyl, heteroalkyl, alkoxy, aryloxy, amino, silyl, germyl, boryl, alkenyl, cycloalkenyl, heteroalkenyl, aryl, heteroaryl, nitrile, isonitrile, sulfanyl, and combinations thereof.

In some instances, the More Preferred General Substituents are selected from the group consisting of deuterium, fluorine, alkyl, cycloalkyl, alkoxy, aryloxy, amino, silyl, germyl, boryl, aryl, heteroaryl, nitrile, sulfanyl, and combinations thereof.

In some instances, the Even More Preferred General Substituents are selected from the group consisting of deuterium, fluorine, alkyl, cycloalkyl, silyl, aryl, heteroaryl, nitrile, and combinations thereof.

In yet other instances, the Most Preferred General Substituents are selected from the group consisting of deuterium, alkyl, cycloalkyl, aryl, heteroaryl, and combinations thereof.

In the event one or more substituents (e.g., R, R′, R″, R^{A}, R_{A}, R¹, R₁, etc.) is not specifically defined, each of the one or more substituents shall be understood to independently represent hydrogen or a substituent selected from the group consisting of the General Substituents defined herein. Similarly, each of the one or more substituents can optionally be joined or fused with another substituent to form a ring. It shall also be understood that any substituent that can be selected from the General Substituents defined herein can also be selected from the Preferred General Substituents defined herein, the More Preferred General Substituents defined herein, the Even More Preferred General Substituents defined herein, or the Most Preferred General Substituents defined herein.

The terms “substituted” and “substitution” refer to a substituent other than H that is bonded to the relevant position, e.g., a carbon or nitrogen. For example, when R¹ represents mono-substitution, then one R¹ must be other than H (i.e., a substitution). Similarly, when R¹ represents di-substitution, then two of R¹ must be other than H. Similarly, when R¹ represents zero or no substitution, R¹, for example, can be a hydrogen for all available valencies of ring atoms, as in carbon atoms for benzene and the nitrogen atom in pyrrole, or simply represents nothing for ring atoms with fully filled valencies, e.g., the nitrogen atom in pyridine. The maximum number of substitutions possible in a ring structure will depend on the total number of available valencies in the ring atoms.

As used herein, “combinations thereof” indicates that one or more members of the applicable list are combined to form a known or chemically stable arrangement that one of ordinary skill in the art can envision from the applicable list. For example, an alkyl and deuterium can be combined to form a partial or fully deuterated alkyl group; a halogen and alkyl can be combined to form a halogenated alkyl substituent; and a halogen, alkyl, and aryl can be combined to form a halogenated arylalkyl. In one instance, the term substitution includes a combination of two to four of the listed groups. In another instance, the term substitution includes a combination of two to three groups. In yet another instance, the term substitution includes a combination of two groups. Preferred combinations of substituent groups are those that contain up to fifty atoms that are not hydrogen or deuterium, or those which include up to forty atoms that are not hydrogen or deuterium, or those that include up to thirty atoms that are not hydrogen or deuterium. In many instances, a preferred combination of substituent groups will include up to twenty atoms that are not hydrogen or deuterium.

The “aza” designation in the fragments described herein, i.e. aza-dibenzofuran, aza-dibenzothiophene, etc. means that one or more of the C—H groups in the respective aromatic ring can be replaced by a nitrogen atom, for example, and without any limitation, azatriphenylene encompasses both dibenzo[f,h]quinoxaline and dibenzo[f,h]quinoline. One of ordinary skill in the art can readily envision other nitrogen analogs of the aza-derivatives described above, and all such analogs are intended to be encompassed by the terms as set forth herein.

The present disclosure includes all acceptable isotopically-labelled compounds of the present disclosure wherein one or more atoms are replaced by atoms having the same atomic number, but an atomic mass or mass number different from the atomic mass or mass number usually found in nature.

Examples of isotopes suitable for inclusion in the compounds of the present disclosure include isotopes of hydrogen, such as ²H and ³H, carbon, such as ¹¹C, ¹³C and ¹⁴C, chlorine, such as ³⁶Cl, fluorine, such as ¹⁸F, iodine, such as ¹²³I, ¹²⁴I and ¹²⁵I, nitrogen, such as ¹³N and ¹⁵N, oxygen, such as ¹⁵O, ¹⁷O and ¹⁸O, phosphorus, such as ³²P, and sulphur, such as ³⁵S.

Certain isotopically-labelled compounds of the present disclosure, for example, those incorporating a radioactive isotope, are useful in diagnostic and other studies. The radioactive isotopes tritium, i.e. ₃H, and carbon-14, i.e. ₁₄C, are particularly useful for this purpose in view of their ease of incorporation and ready means of detection.

Substitution with heavier isotopes such as deuterium, i.e. 2H, may afford certain advantages resulting from greater stability, and hence may be preferred in some circumstances.

Isotopically-labelled compounds of the invention can generally be prepared by conventional techniques known to those skilled in the art or by processes analogous to those described in the accompanying Examples and Preparations using an appropriate isotopically-labelled reagent in place of the non-labelled reagent previously employed.

For example, deuterated compounds can be readily prepared using methods known in the art. For example, U.S. Pat. No. 8,557,400, Patent Pub. No. WO 2006/095951, and U.S. Pat. Application Pub. No. US 2011/0037057, which are hereby incorporated by reference in their entireties, describe the making of deuterium-substituted organometallic complexes. Further reference is made to Ming Yan, et al., Tetrahedron 2015, 71, 1425-30 and Atzrodt et al., Angew. Chem. Int. Ed. (Reviews) 2007, 46, 7744-65, which are incorporated by reference in their entireties, describe the deuteration of the methylene hydrogens in benzyl amines and efficient pathways to replace aromatic ring hydrogens with deuterium, respectively.

As used herein, any specifically listed substituent, such as, without limitation, methyl, phenyl, pyridyl, etc. includes undeuterated, partially deuterated, and fully deuterated versions thereof. Similarly, classes of substituents such as, without limitation, alkyl, aryl, cycloalkyl, heteroaryl, etc. also include undeuterated, partially deuterated, and fully deuterated versions thereof. Unless otherwise specified, atoms in chemical structures without valences fully filled by H or D should be considered to include undeuterated, partially deuterated, and fully deuterated versions thereof. For example, the chemical structure of

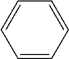

implies to include C₆H₆, C₆D₆, C₆H₃D₃, and any other partially deuterated variants thereof. Some common basic partially or fully deuterated groups include, without limitation, CD₃, CD₂C(CH₃)₃, C(CD₃)₃, and C₆D₅. Similarly, where partially or fully defined atomic structures show a particular position may be or is deuterium, the same atomic structures with one, two, or up to all deuterium atoms replaced by hydrogen are also envisioned.

It is to be understood that when a molecular fragment is described as being a substituent or otherwise attached to another moiety, its name may be written as if it were a fragment (e.g. phenyl, phenylene, naphthyl, dibenzofuryl) or as if it were the whole molecule (e.g. benzene, naphthalene, dibenzofuran). As used herein, these different ways of designating a substituent or attached fragment are considered to be equivalent.

In some instances, a pair of substituents in the molecule can be joined or fused into a ring. The preferred ring is a five to nine-membered carbocyclic or heterocyclic ring, including both instances where the portion of the ring formed by the pair of substituents is saturated and where the portion of the ring formed by the pair of substituents is unsaturated. In yet other instances, a pair of adjacent substituents can be joined or fused into a ring. As used herein, “adjacent” means that the two substituents involved can be on the same ring next to each other, or on two neighboring rings having the two closest available substitutable positions, such as 2, 2′ positions in a biphenyl, or 1, 8 position in a naphthalene.

### B. The Compounds of the Present Disclosure

In one aspect, the present disclosure provides a compound having a first ligand L_{A} comprising a structure of Formula I:

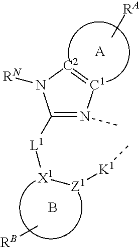

wherein C¹ and C² are carbon atoms;
wherein X¹ is C or N;
wherein Z¹ is C or N;
wherein K¹ is selected from the group consisting of a direct bond, O, S, N(R^{α}), P(R^{α}), B(R^{α}), C(R^{α})(R^{β}), and Si(R^{α})(R^{β});
wherein if K¹ is selected from the group consisting of O, S, N(R^{α}), P(R^{α}), B(R^{α}), C(R^{α})(R^{β}), and Si(R^{α})(R^{β}), then Z¹ is C;
wherein L¹ is selected from the group consisting of a direct bond, O, S, Se, NR, BR, BRR′, PR, CR, C═O, C═NR, C═CRR′, C═S, CRR′, SO, SO₂, P(O)R, SiRR′, GeRR′, alkylene, cycloalkyl, aryl, cycloalkylene, arylene, and heteroarylene;
wherein L_{A} is coordinated to a metal M;
wherein M is selected from the group consisting of Ir, Rh, Re, Ru, Os, Pt, Pd, Ag, Au, and Cu;
wherein moiety A is a fused ring system comprised of exactly one 5-membered ring and one 6-membered ring, and the 5-membered ring comprises C¹ and C²;
wherein moiety B is a monocyclic ring or a polycyclic fused ring system, wherein the monocyclic ring or each ring of the polycyclic fused ring system is independently a 5-membered to 10-membered carbocyclic or heterocyclic ring with the proviso that when M is Ir, moiety B is a polycyclic fused ring system; wherein R^{A} and R^{B} each independently represent mono to the maximum allowable substitution, or no substitution;
wherein each of R^{N}, R, R′, R^{α}, R^{β}, R^{A}, and R^{B} is independently hydrogen or a substituent selected from the group consisting of deuterium, halogen, alkyl, cycloalkyl, heteroalkyl, heterocycloalkyl, arylalkyl, alkoxy, carboxylic acid, ether, ester, nitrile, isonitrile, sulfanyl, sulfinyl, sulfonyl, phosphino, and combinations thereof;
wherein L_{A} may be joined with other ligands to comprise a tridentate, tetradentate, pentadentate, or hexadentate ligand; and
wherein any two of R^{N}, R, R′, R^{α}, R^{β}, R^{A}, and R^{B} may be joined or fused to form a ring, with the proviso that when M is Ir, two R^{A} substituents do not join to form a ring.

Although Formula I depicts Z¹ and X¹ are connected by a single line, depending on the structure of the associated ring of moiety B, Z¹ and X¹ can be joined by any appropriate bond (e.g., a single bond, a double bond, etc.) in a Lewis structure. It will be understood that, absent an indication to the contrary, the same rule applies to the bonds between atoms of other generalized rings disclosed herein.

In some embodiments, the first ligand L_{A} consists essentially of Formula I.

In some embodiments, the first ligand L_{A} has a structure of Formula I.

In some embodiments, any two substituents may be joined or fused to form a ring. In some embodiments, at least two of R^{N}, R, R′, R^{α}, R^{β}, R^{A}, and R^{B} are alkyl and joined to form into a ring, which can be further substituted. In some embodiments, at least two adjacent R are joined to form into a ring. In some embodiments, at least two adjacent R′ are joined to form into a ring. In some embodiments, at least two R^{A} are joined to form into a ring. In some embodiments, at least two R^{B} are joined to form into a ring. In some embodiments, at least one R with an adjacent R′ are joined to form into a ring. In some embodiments, at least one R with an adjacent R^{A} are joined to form into a ring. In some embodiments, at least one R with an adjacent R^{B} are joined to form into a ring. In some embodiments, at least one R with an adjacent R^{N} are joined to form into a ring. In some embodiments, at least one R′ with an adjacent R^{A} are joined to form into a ring. In some embodiments, at least one R′ with an adjacent R^{B} are joined to form into a ring. In some embodiments, at least one R′ with an adjacent R^{N} are joined to form into a ring. In some embodiments, at least one R^{α} with an adjacent R^{B} are joined to form into a ring. In some embodiments, at least one R with an adjacent R^{β} are joined to form into a ring. In some embodiments, at least one R^{A} with one R^{B} are joined to form into a ring. In some of the above embodiments, the ring formed by the two substituents can be an aromatic ring or a non-aromatic ring. In some of such embodiments, the non-aromatic ring can be formed by two alkyl substituents.

In some embodiments, the first ligand L_{A} has the structure of Formula I, at least one R^{N}, R, R′, R^{α}, R^{β}, R^{A}, and R^{B} is partially or fully deuterated. In some embodiments, the first ligand L_{A} has the structure of Formula I, at least one R^{N}, R, R′, R^{α}, R^{β}, R^{A}, and R^{B} is selected from the group consisting of the General Substituents defined herein. In some embodiments, the first ligand L_{A} has the structure of Formula I, at least one R^{N}, R, R′, R^{α}, R^{β}, R^{A}, and R^{B} is selected from the group consisting of the Preferred General Substituents defined herein.

In some embodiments, the first ligand L_{A} comprises an electron-withdrawn group selected from the group consisting of the structures of the following EWG1 LIST: F, CF₃, CN, COCH₃, CHO, COCF₃, COOMe, COOCF₃, NO₂, SF₃, SiF₃, PF₄, SF₅, OCF₃, SCF₃, SeCF₃, SOCF₃, SeOCF₃, SO₂F, SO₂CF₃, SeO₂CF₃, OSeO₂CF₃, OCN, SCN, SeCN, NC, ⁺N(R^{k2})₃, (R^{k2})₂CCN, (R^{k2})₂CCF₃, CNC(CF₃)₂, BR^{k3}R^{k2}, substituted or unsubstituted dibenzoborole, 1-substituted carbazole, 1,9-substituted carbazole, substituted or unsubstituted carbazole, substituted or unsubstituted pyridine, substituted or unsubstituted pyrimidine, substituted or unsubstituted pyrazine, substituted or unsubstituted pyridoxine, substituted or unsubstituted triazine, substituted or unsubstituted oxazole, substituted or unsubstituted benzoxazole, substituted or unsubstituted thiazole, substituted or unsubstituted benzothiazole, substituted or unsubstituted imidazole, substituted or unsubstituted benzimidazole, ketone, carboxylic acid, ester, nitrile, isonitrile, sulfinyl, sulfonyl, partially and fully fluorinated alkyl, partially and fully fluorinated aryl, partially and fully fluorinated heteroaryl, cyano-containing alkyl, cyano-containing aryl, cyano-containing heteroaryl, isocyanate,

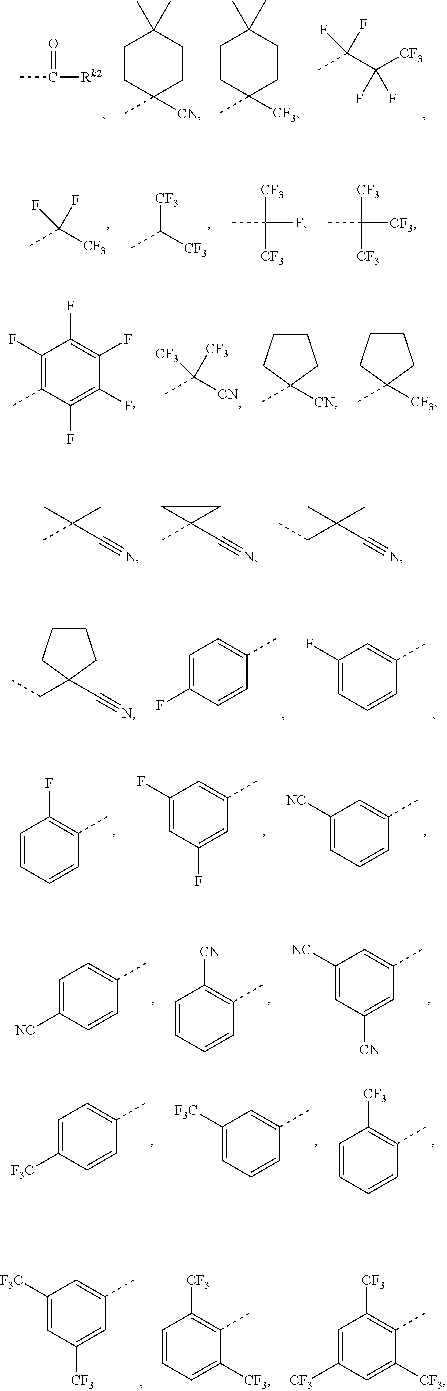

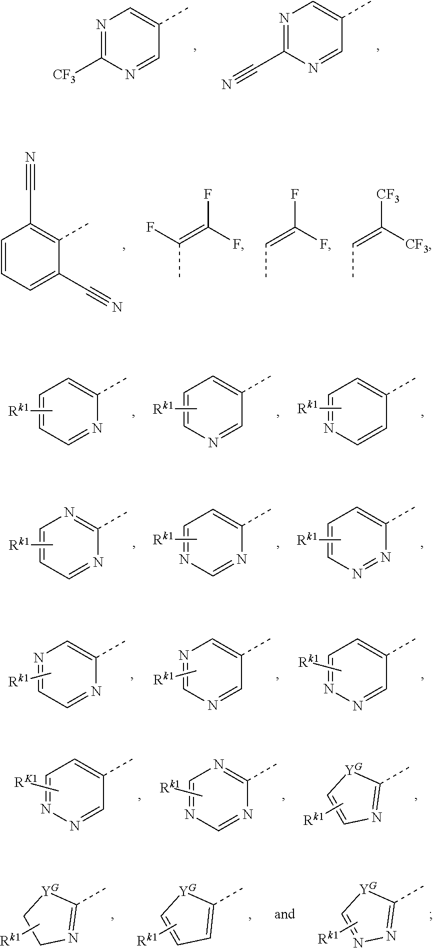

wherein each R^{k1} represents mono to the maximum allowable substitution, or no substitutions;
wherein Y^{G} is selected from the group consisting of BRₑ, NRₑ, PRₑ, O, S, Se, C═O, S═O, SO₂, CRₑR_{f}, SiRₑR_{f}, and GeRₑR_{f}; and
wherein each of R^{k1}, R^{k2}, R^{k3}, Rₑ, and R_{f} is independently a hydrogen, or a substituent selected from the group consisting of the General Substituents defined herein.

In some embodiments, the first ligand L_{A} comprises an electron-withdrawing group selected from the group consisting of the structures of the following EWG2 List:

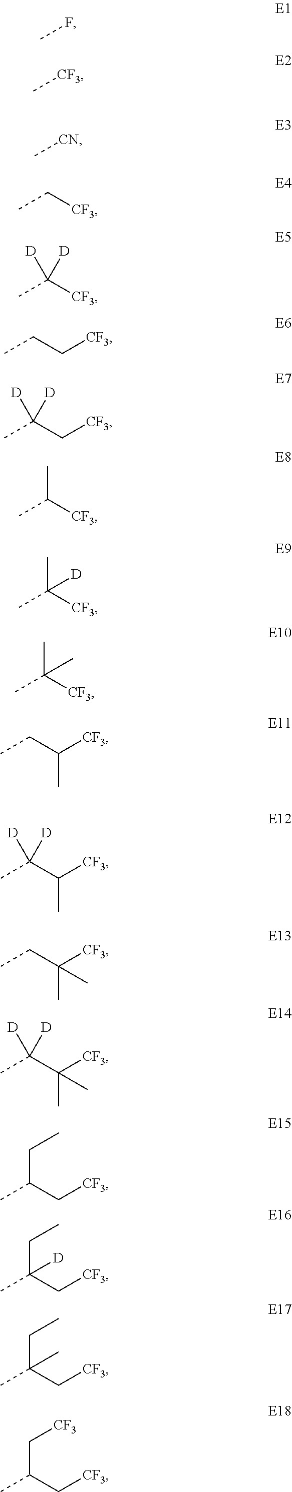

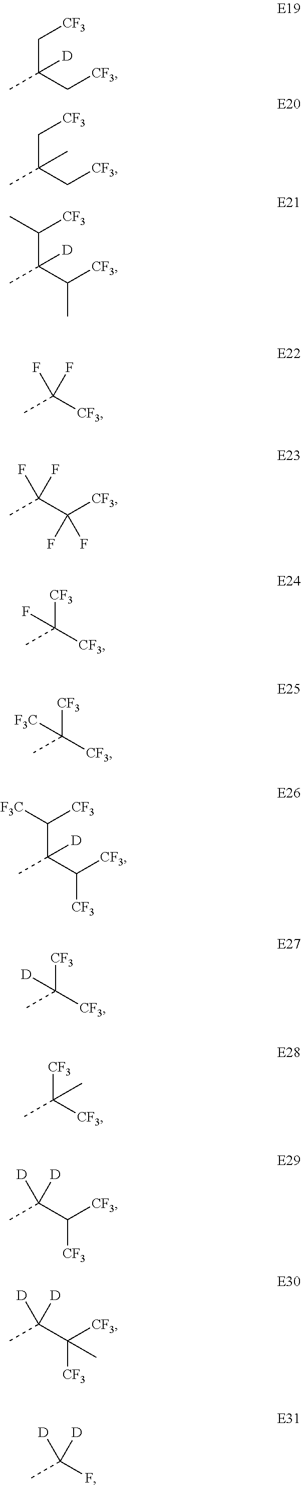

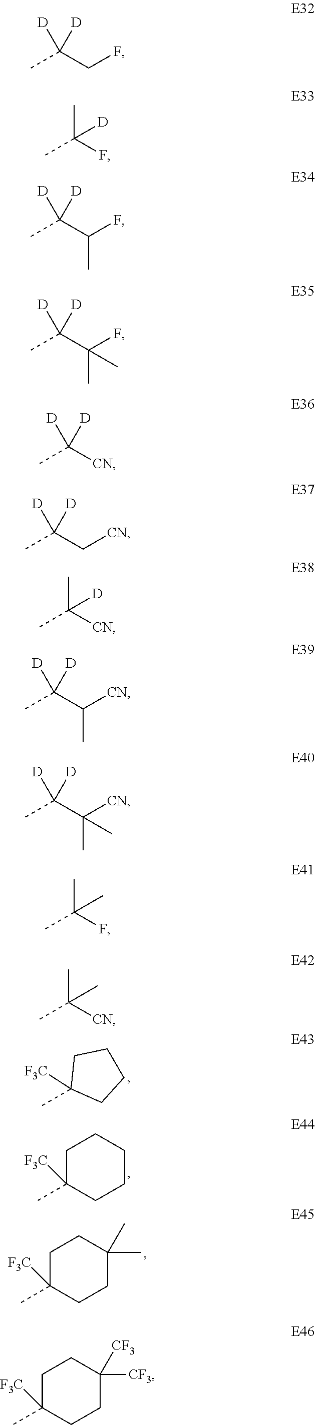

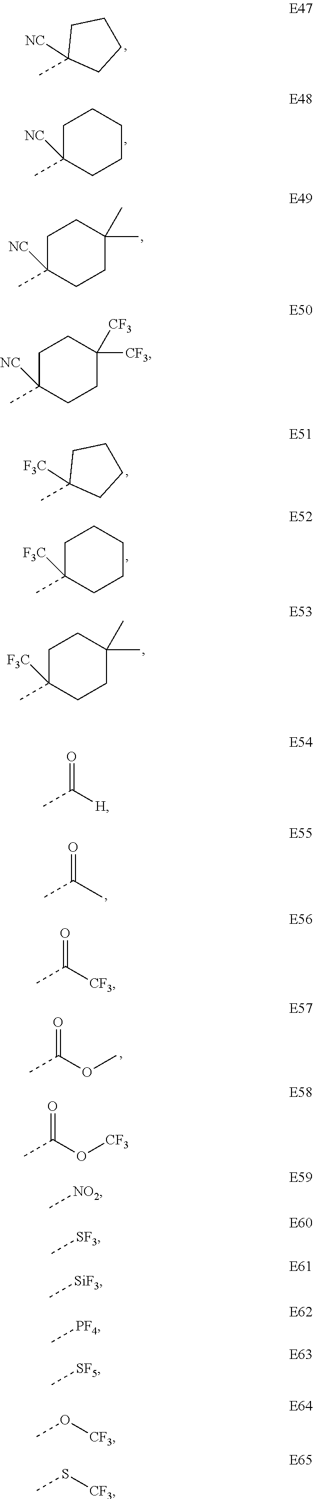

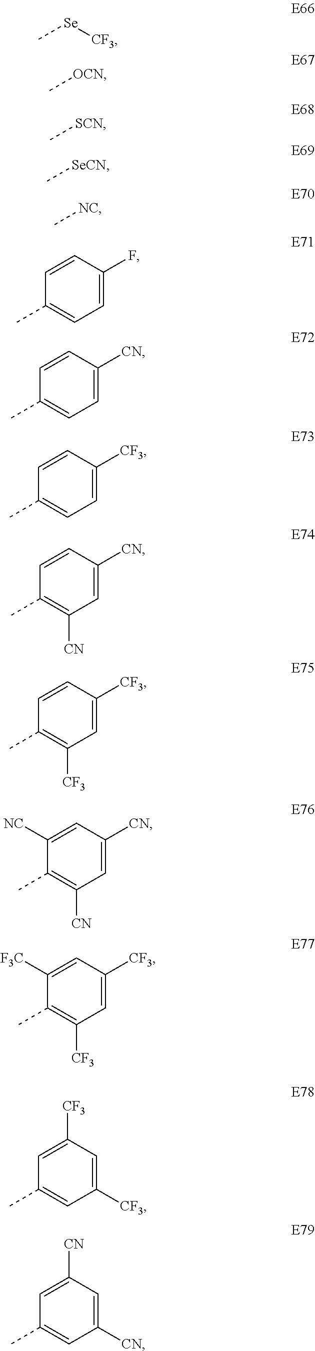

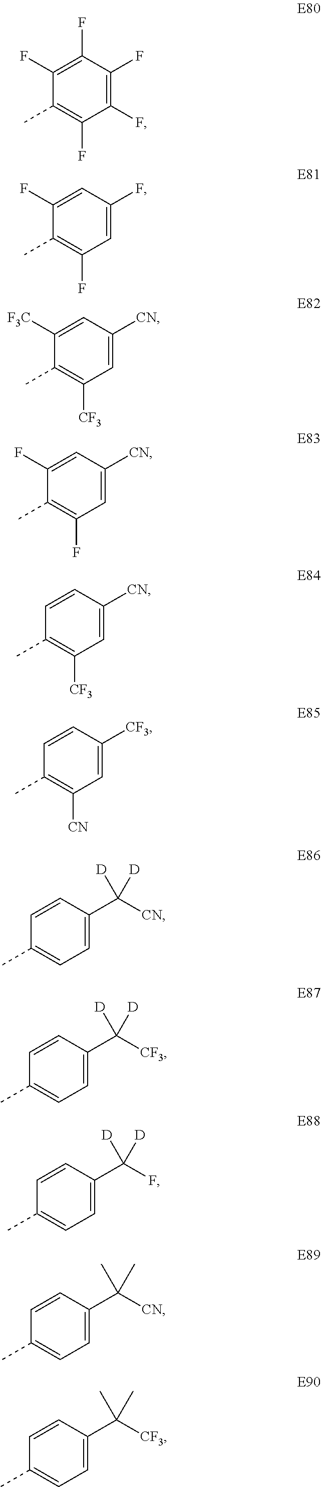

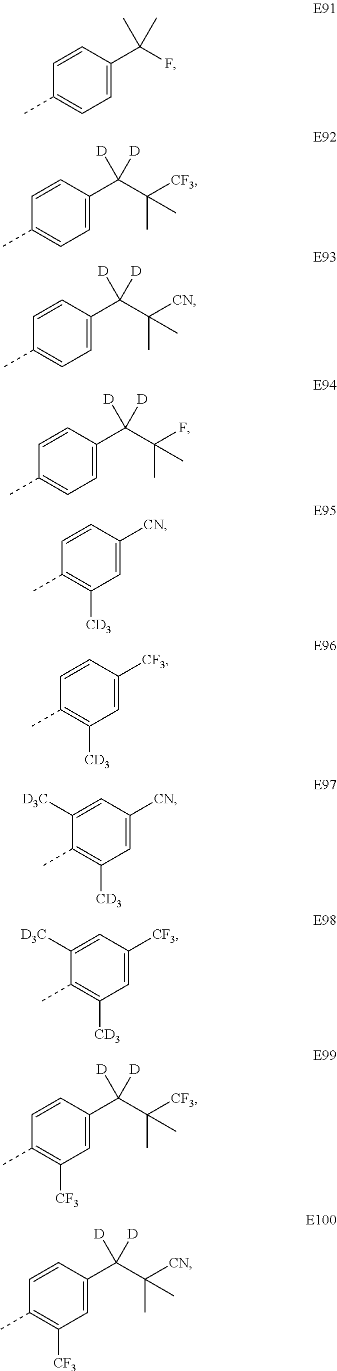

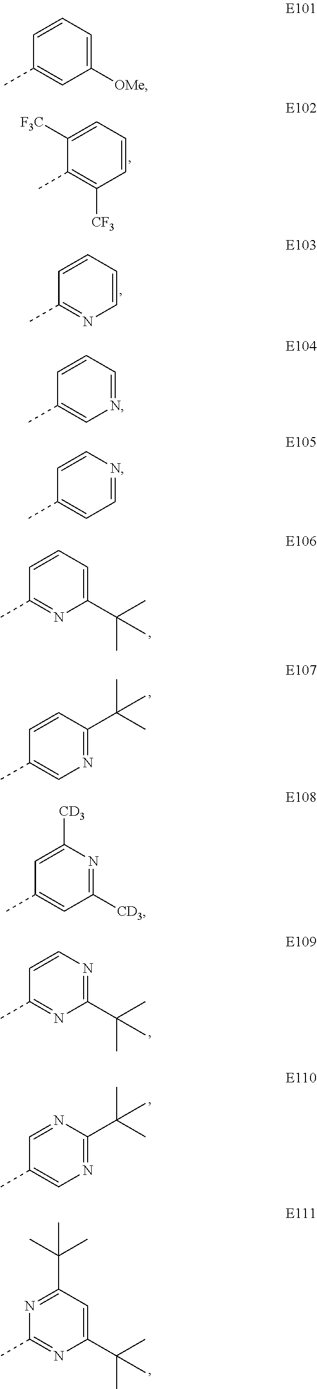

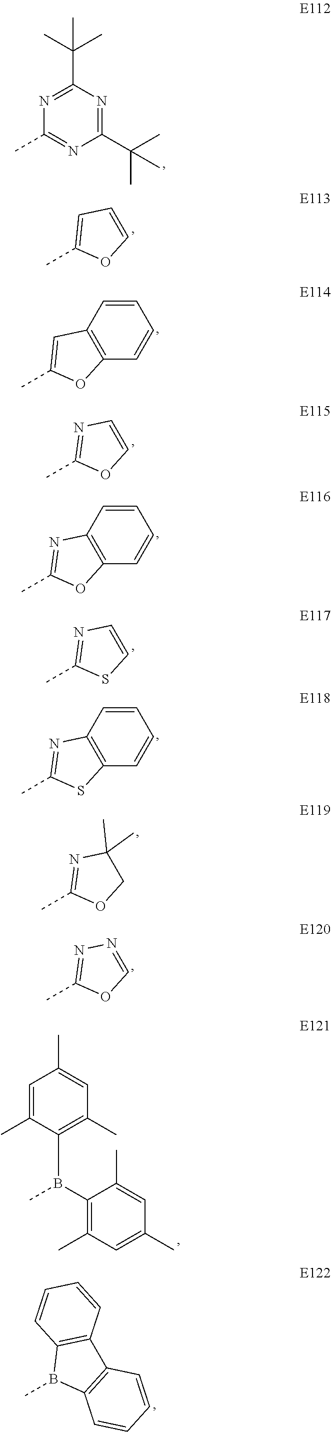

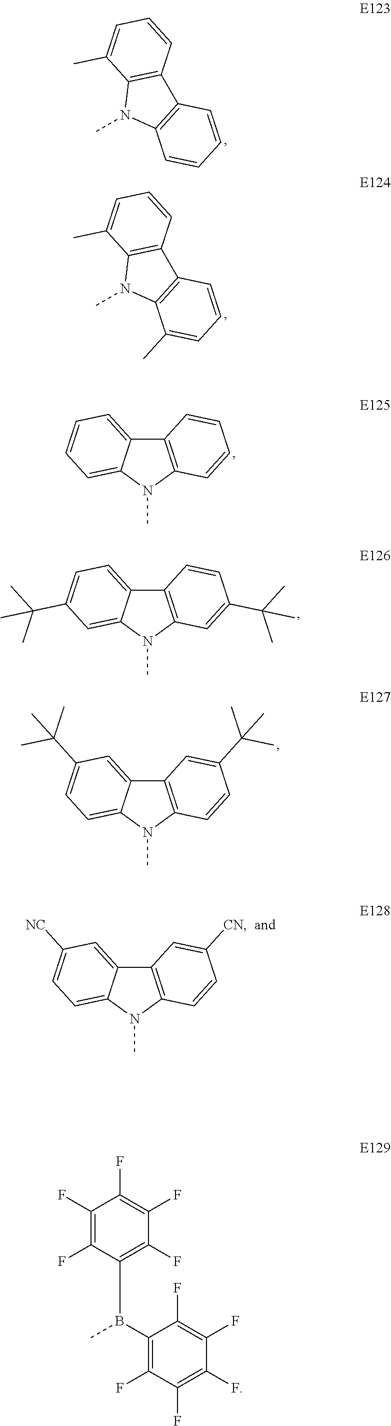

In some embodiments, the first ligand L_{A} comprises an electron-withdrawing group selected from the group consisting of the structures of the following EWG3 LIST:

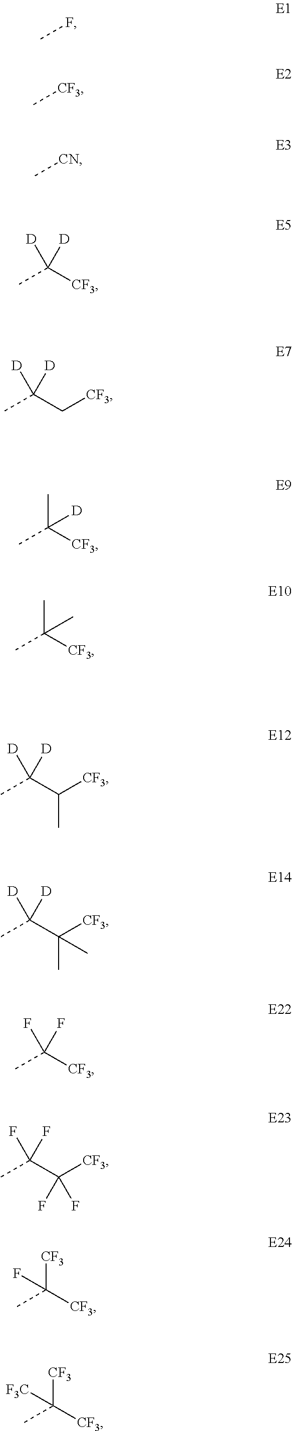

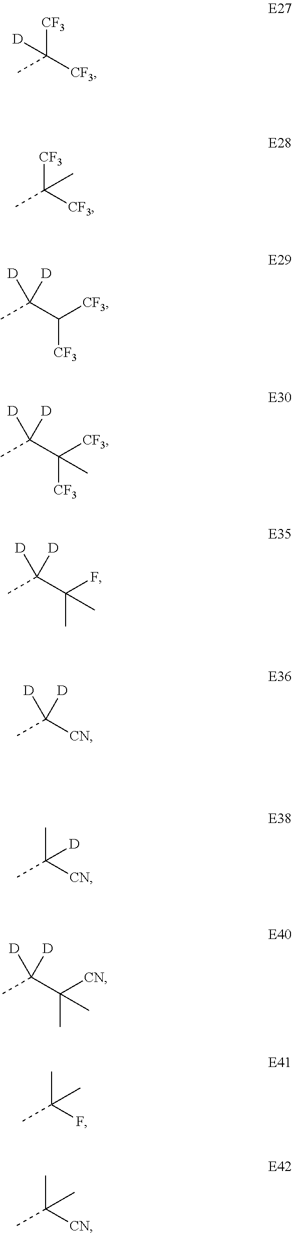

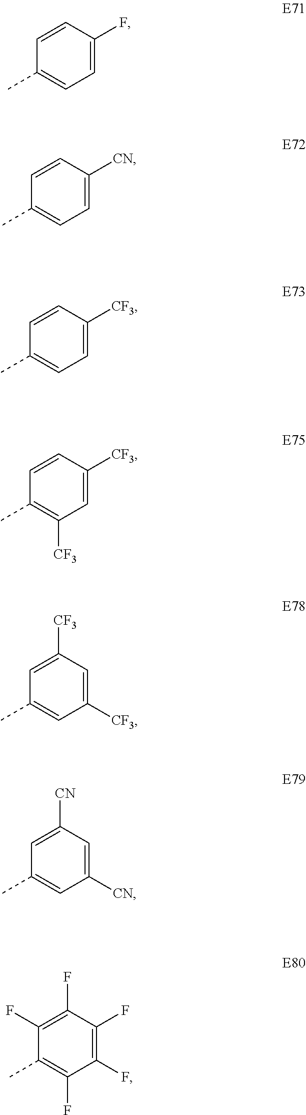

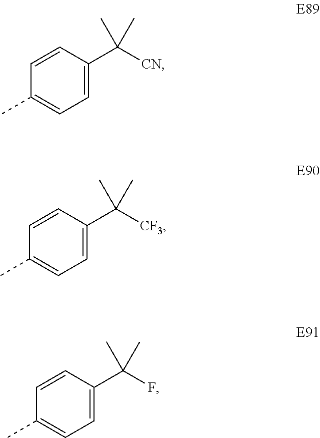

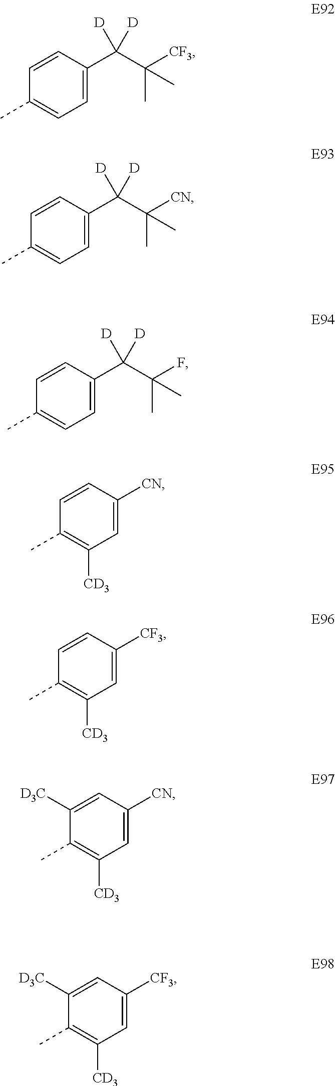

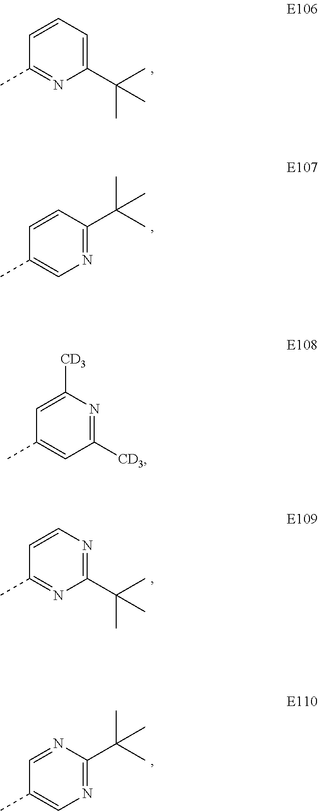

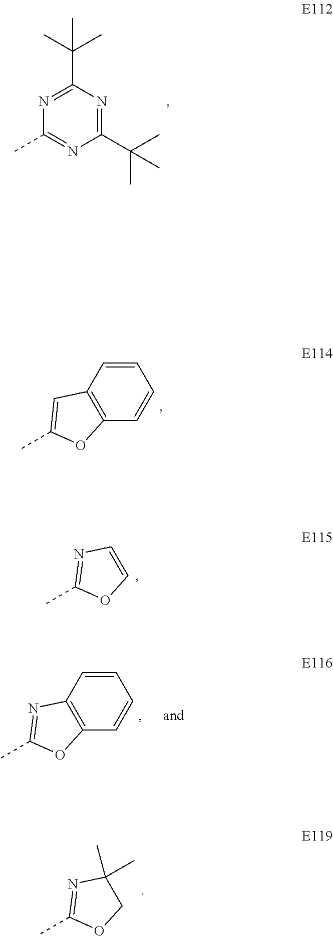

In some embodiments, the first ligand L_{A} comprises an electron-withdrawing group selected from the group consisting of the structures of the following EWG4 LIST:

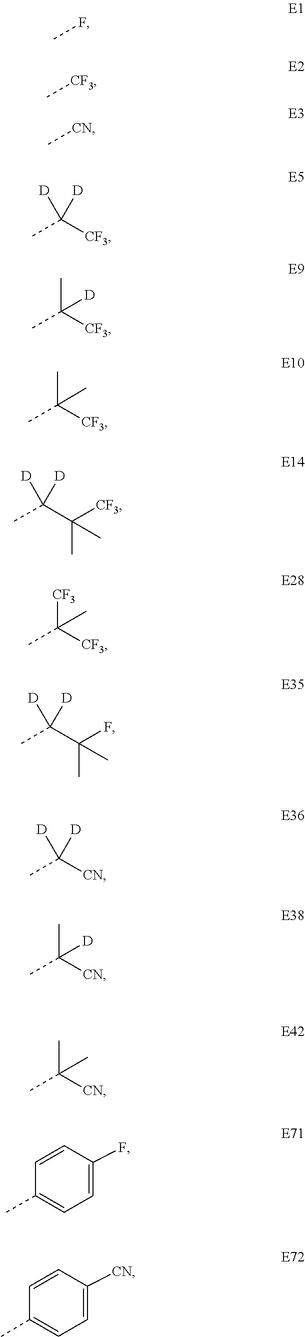

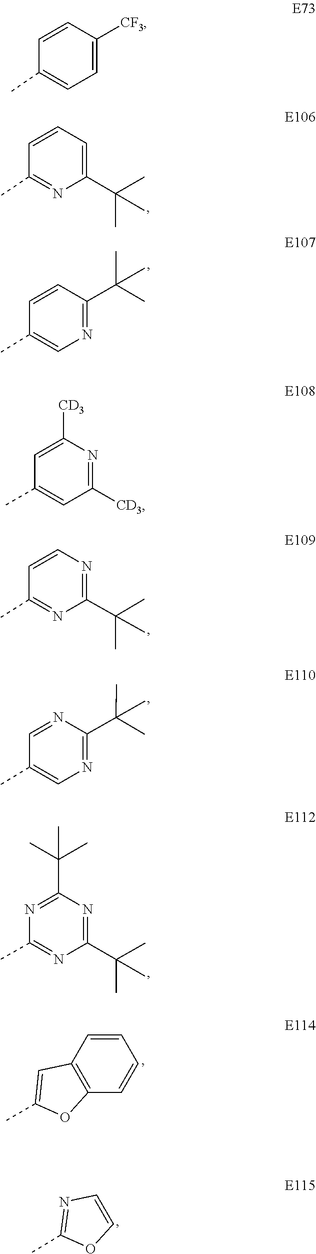

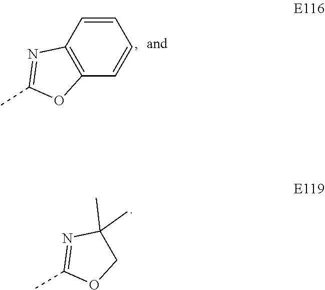

In some embodiments, the first ligand L_{A} comprises a π-electron deficient electron-withdrawing group selected from the group consisting of the structures of the following Pi-EWG LIST: CN, COCH₃, CHO, COCF₃, COOMe, COOCF₃, NO₂, SF₃, SiF₃, PF₄, SF₅, OCF₃, SCF₃, SeCF₃, SOCF₃, SeOCF₃, SO₂F, SO₂CF₃, SeO₂CF₃, OSeO₂CF₃, OCN, SCN, SeCN, NC, +N(R^{k2})₃, BR^{k2}R^{k3}, substituted or unsubstituted dibenzoborole, 1-substituted carbazole, 1,9-substituted carbazole, substituted or unsubstituted carbazole, substituted or unsubstituted pyridine, substituted or unsubstituted pyrimidine, substituted or unsubstituted pyrazine, substituted or unsubstituted pyridazine, substituted or unsubstituted triazine, substituted or unsubstituted oxazole, substituted or unsubstituted benzoxazole, substituted or unsubstituted thiazole, substituted or unsubstituted benzothiazole, substituted or unsubstituted imidazole, substituted or unsubstituted benzimidazole, ketone, carboxylic acid, ester, nitrile, isonitrile, sulfinyl, sulfonyl, partially and fully fluorinated aryl, partially and fully fluorinated heteroaryl, cyano-containing aryl, cyano-containing heteroaryl, isocyanate,

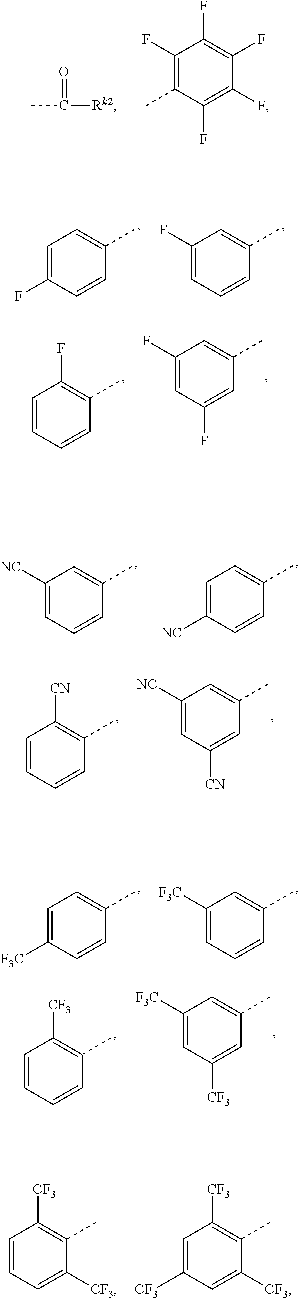

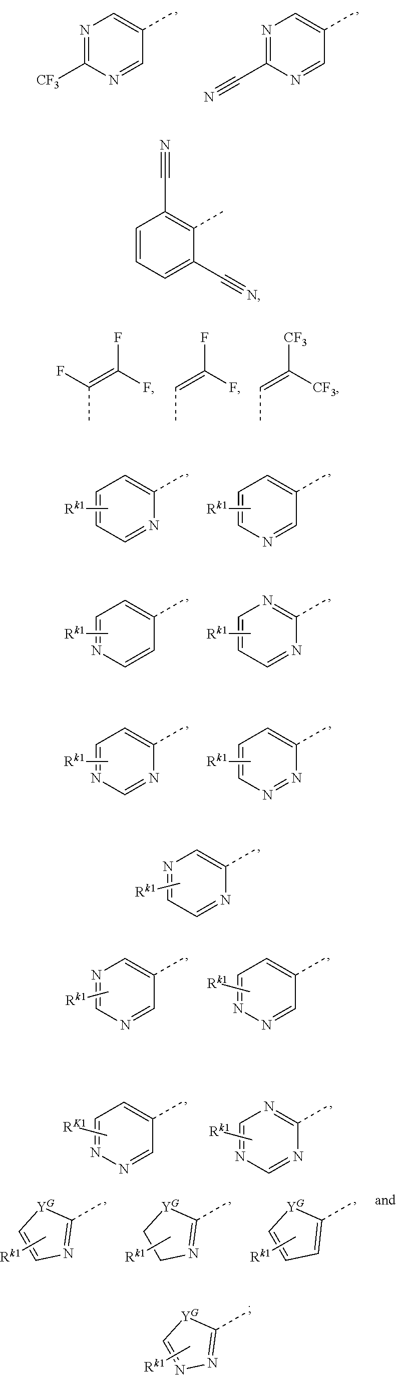

wherein the variables are the same as previously defined.

In some embodiments, the first ligand L_{A} has the structure of Formula I, at least one R^{A} is or comprises an electron-withdrawing group from the EWG1 LIST as defined herein. In some embodiments, at least one R^{A} is or comprises an electron-withdrawing group from the EWG2 LIST as defined herein. In some embodiments, at least one R^{A} is or comprises an electron-withdrawing group from the EWG3 LIST as defined herein. In some embodiments, at least one R^{A} is or comprises an electron-withdrawing group from the EWG4 LIST as defined herein. In some embodiments, at least one R^{A} is or comprises an electron-withdrawing group from the Pi-EWG LIST as defined herein.

In some embodiments, the first ligand L_{A} has the structure of Formula I, at least one R^{B} is or comprises an electron-withdrawing group from the EWG1 LIST as defined herein. In some embodiments, at least one R^{B} is or comprises an electron-withdrawing group from the EWG2 LIST as defined herein. In some embodiments, at least one R^{B} is or comprises an electron-withdrawing group from the EWG3 LIST as defined herein. In some embodiments, at least one R^{B} is or comprises an electron-withdrawing group from the EWG4 LIST as defined herein. In some embodiments, at least one R^{B} is or comprises an electron-withdrawing group from the Pi-EWG LIST as defined herein.

In some embodiments, the first ligand L_{A} has the structure of Formula I, at least one R^{N} is or comprises an electron-withdrawing group from the EWG1 LIST as defined herein. In some embodiments, at least one R^{N} is or comprises an electron-withdrawing group from the EWG2 LIST as defined herein. In some embodiments, at least one R^{N} is or comprises an electron-withdrawing group from the EWG3 LIST as defined herein. In some embodiments, at least one R^{N} is or comprises an electron-withdrawing group from the EWG4 LIST as defined herein. In some embodiments, at least one R^{N} is or comprises an electron-withdrawing group from the Pi-EWG LIST as defined herein.

In some embodiments, the first ligand L_{A} has the structure of Formula I, at least one R^{N}, R, R′, R^{α}, or R^{β} is or comprises an electron-withdrawing group from the EWG1 LIST as defined herein. In some embodiments, at least one R^{N}, R, R′, R^{α}, or R^{β} is or comprises an electron-withdrawing group from the EWG2 LIST as defined herein. In some embodiments, at least one R^{N}, R, R′, R^{α}, or R^{β} is or comprises an electron-withdrawing group from the EWG3 LIST as defined herein. In some embodiments, at least one R^{N}, R, R′, R^{α}, or R^{β} is or comprises an electron-withdrawing group from the EWG4 LIST as defined herein. In some embodiments, at least one R^{N}, R, R′, R^{α}, or R^{β} is or comprises an electron-withdrawing group from the Pi-EWG LIST as defined herein.

In some embodiments, each of R^{N}, R, R′, R^{α}, R^{β}, R^{A}, and R^{B} is independently a hydrogen or a substituent selected from the group consisting of deuterium, fluorine, alkyl, cycloalkyl, heteroalkyl, alkoxy, aryloxy, amino, silyl, germyl, boryl, alkenyl, cycloalkenyl, heteroalkenyl, aryl, heteroaryl, nitrile, isonitrile, sulfanyl, and combinations thereof.

In some embodiments, M is Ir.

In some embodiments, M is Pt.

In some embodiments, M is Pd.

In some embodiments, X¹ is C.

In some embodiments, Z¹ is C.

In some embodiments, one of X¹ and Z¹ is N and the other of X¹ and Z¹ is C.

In some embodiments, K¹ is a direct bond.

In some embodiments, K¹ is selected from the group consisting of O, S, N(R^{α}), P(R^{α}), B(R^{α}), C(R^{α})(R^{β}), and Si(R^{α})(R^{β}).

In some embodiments, R^{N} is a substituent selected from the group consisting of fluorine, alkyl, cycloalkyl, heteroalkyl, alkoxy, aryloxy, amino, silyl, germyl, boryl, alkenyl, cycloalkenyl, heteroalkenyl, aryl, heteroaryl, nitrile, isonitrile, sulfanyl, and combinations thereof.

In some embodiments, R^{N} comprises at least one aryl group.

In some embodiments, R^{N} comprises at least one alkyl group.

In some embodiments, R^{N} comprises a structure of Formula II,

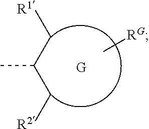

Ring G is a 5-membered to 10-membered carbocyclic or heterocyclic ring; wherein R^{G} represents mono to tri-substitutions, or no substitutions; wherein each R^{1′}, R^{2′}, and R^{G} is independently hydrogen or a substituent selected from the group consisting of deuterium, halogen, alkyl, cycloalkyl, heteroalkyl, heterocycloalkyl, arylalkyl, alkoxy, aryloxy, amino, silyl, germyl, boryl, alkenyl, cycloalkenyl, heteroalkenyl, alkynyl, aryl, heteroaryl, acyl, carboxylic acid, ether, ester, nitrile, isonitrile, sulfanyl, sulfinyl, sulfonyl, phosphino, selenyl, and combinations thereof; and wherein at least one of R^{1′} or R^{2′} is not hydrogen or deuterium.

In some embodiments, Ring G is a 5-membered or 6-membered carbocyclic or heterocyclic ring. Ring G is a 5-membered or 6-membered aryl or heteroaryl ring. In some embodiments, neither R^{1′} nor R^{2′} is hydrogen or deuterium. In some embodiments, each of R^{1′} and R^{2′} is independently selected from the group consisting of alkyl, cycloalkyl, aryl, heteroaryl, silyl, germyl, and combinations thereof. In some embodiments, R^{1′} and R^{2′} are the same; R^{1′} and R^{2′} are different. In some embodiments, each of R^{1′} and R^{2′} comprises at least 1 carbon atom. In some embodiments, each of R^{1′} and R^{2′} comprises at least 2 carbon atoms. In some embodiments, each of R^{1′} and R^{2′} comprises at least 3 carbon atoms. In some embodiments, each of R^{1′} and R^{2′} comprises at least 4 carbon atoms. In some embodiments, each of R^{1′} and R^{2′} comprises at least 5 carbon atoms.

In some embodiments, at least one R^{G} is not hydrogen or deuterium. In some embodiments, at least one R^{G} is selected from the group consisting of alkyl, cycloalkyl, aryl, heteroaryl, silyl, germyl, and combinations thereof.

In some embodiments, ring G is selected from the group consisting of benzene, pyridine, pyrimidine, pyridazine, pyrazine, triazine, imidazole, imidazole-derived carbene, pyrazole, pyrrole, oxazole, furan, thiophene, thiazole, and triazole.

In some embodiments, at least one RN comprises a structure of Formula IIA,

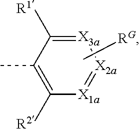

wherein each of X₁ₐ, X₂ₐ, and X₃ₐ is independently C or N.

In some embodiments, the R^{G} bonded to X₁ₐ is selected from the group consisting of alkyl, cycloalkyl, aryl, heteroaryl, silyl, germyl, and combinations thereof. In some embodiments, the RG bonded to X₁ₐ is selected from the group consisting of alkyl, aryl, heteroaryl, silyl, and germyl. In some embodiments, the RG bonded to X₂ₐ is selected from the group consisting of alkyl, cycloalkyl, aryl, heteroaryl, silyl, germyl, and combinations thereof. In some embodiments, the RG bonded to X₂ₐ is selected from the group consisting of alkyl, aryl, heteroaryl, silyl, and germyl.

In some embodiments, the RG bonded to X₃ₐ is selected from the group consisting of alkyl, cycloalkyl, aryl, heteroaryl, silyl, germyl, and combinations thereof. In some embodiments, the RG bonded to X₃ₐ is selected from the group consisting of alkyl, aryl, heteroaryl, silyl, and germyl. In some embodiments, each of X₁ₐ, X₂ₐ, and X₃ₐ is C.

In some embodiments, all R^{A} are hydrogen.

In some embodiments, at least one R^{A} is not hydrogen.

In some embodiments, all R^{B} are hydrogen.

In some embodiments, at least one R^{B} is not hydrogen.

In some embodiments, L¹ is a direct bond.

In some embodiments, L¹ is NR.

In some embodiments, the 5-membered ring of moiety A is a heterocyclic ring.

In some embodiments, the 5-membered ring of moiety A is a heterocyclic aromatic ring.

In some embodiments, the 5-membered ring of moiety A is a heterocyclic ring and the heteroatom of the heterocyclic ring is directly bond to C².

In some embodiments, the 6-membered ring of moiety A is a carbocyclic ring.

In some embodiments, the 6-membered ring of moiety A is a carbocyclic aromatic ring.

In some embodiments, moiety A is selected from the group consisting of benzofuran, aza-benzofuran, benzothiophene, aza-benzothiophene, benzothiazole, aza-benzothiazole, indene, aza-indene, indole, and aza-indole.

In some embodiments, moiety A is benzofuran or aza-benzofuran.

In some embodiments, moiety A is indole or aza-indole.

In some embodiments, moiety B comprises exactly one 5-membered ring, and M is selected from the group consisting of Rh, Re, Ru, Os, Pt, Pd, Ag, Au, and Cu.

In some embodiments, moiety B comprises exactly one 5-membered heterocyclic ring, and M is selected from the group consisting of Rh, Re, Ru, Os, Pt, Pd, Ag, Au, and Cu.

In some embodiments, moiety B comprises exactly one 6-membered ring, and M is selected from the group consisting of Rh, Re, Ru, Os, Pt, Pd, Ag, Au, and Cu.

In some embodiments, moiety B comprises exactly one 6-membered carbocyclic ring, and M is selected from the group consisting of Rh, Re, Ru, Os, Pt, Pd, Ag, Au, and Cu.

In some embodiments, moiety B is selected from the group consisting of benzene, pyridine, pyrimidine, pyridazine, pyrazine, triazine, imidazole, pyrazole, pyrrole, oxazole, furan, thiophene, thiazole, and triazole, and M is selected from the group consisting of Rh, Re, Ru, Os, Pt, Pd, Ag, Au, and Cu.

In some embodiments, moiety B comprises at least two 5-membered rings.

In some embodiments, moiety B comprises at least two 5-membered heterocyclic rings.

In some embodiments, moiety B comprises at least two 6-membered rings.

In some embodiments, moiety B comprises at least two 6-membered carbocyclic rings.

In some embodiments, moiety B comprises at least three 5-membered to 10-membered carbocyclic or heterocyclic rings which are fused together.

In some embodiments, moiety B comprises at least four 5-membered to 10-membered carbocyclic or heterocyclic rings which are fused together.

In some embodiments, moiety B comprises at least five 5-membered to 10-membered carbocyclic or heterocyclic rings which are fused together.

In some embodiments, moiety B is selected from the group consisting of naphthalene, quinoline, isoquinoline, quinazoline, benzofuran, phenanthro[3,2-b]benzofuran, aza-benzofuran, benzoxazole, aza-benzoxazole, benzothiophene, aza-benzothiophene, benzothiazole, aza-benzothiazole, benzoselenophene, aza-benzoselenophene, indene, aza-indene, indole, aza-indole, benzimidazole, benzimidazole-derived carbene, aza-benzimidazole-derived carbene, aza-benzimidazole, benzobenzimidazole, aza-benzobenzimidazolecarbazole, aza-carbazole, dibenzofuran, aza-dibenzofuran, dibenzothiophene, aza-dibenzothiophene, quinoxaline, phthalazine, phenanthrene, aza-phenanthrene, anthracene, aza-anthracene, phenanthridine, fluorene, and aza-fluorene.

In some embodiments, moiety B is selected from the group consisting of naphthalene, quinoline, isoquinoline, quinazoline, benzofuran, aza-benzofuran, benzoxazole, aza-benzoxazole, benzothiophene, aza-benzothiophene, benzothiazole, aza-benzothiazole, benzoselenophene, aza-benzoselenophene, indene, aza-indene, indole, aza-indole, benzimidazole, benzimidazole-derived carbene, aza-benzimidazole, benzobenzimidazole, aza-benzobenzimidazole, carbazole, aza-carbazole, dibenzofuran, aza-dibenzofuran, dibenzothiophene, aza-dibenzothiophene, quinoxaline, phthalazine, phenanthrene, aza-phenanthrene, anthracene, aza-anthracene, phenanthridine, fluorene, and aza-fluorene.

In some embodiments, moiety B is benzimidazole.

In some embodiments, moiety B comprises dibenzofuran or aza-dibenzofuran.

In some embodiments, moiety B a polycyclic fused ring structure comprising at least two fused rings.

In some embodiments, the polycyclic fused ring structure comprising at least two fused rings has one 6-membered ring and one 5-membered ring. In some such embodiments, either the 5-membered ring or the 6-membered ring can coordinate to the metal. In some embodiments, the polycyclic fused ring structure has two 6-membered rings.

In some embodiments, moiety B is selected from the group consisting of benzofuran, benzothiophene, benzoselenophene, naphthalene, and aza-variants thereof.

In some embodiments, moiety B is a polycyclic fused ring structure comprising at least three fused rings.

In some embodiments, the polycyclic fused ring structure comprising at least three fused rings has two 6-membered rings and one 5-membered ring. In some such embodiments, the 5-membered ring is fused to the ring coordinated to metal M and the second 6-membered ring is fused to the 5-membered ring.

In some embodiments, moiety B is selected from the group consisting of dibenzofuran, dibenzothiophene, dibenzoselenophene, and aza-variants thereof.

In some embodiments, moiety B can be further substituted at the ortho- or meta-position of the O, S, or Se atom by a substituent selected from the group consisting of deuterium, fluorine, nitrile, alkyl, cycloalkyl, aryl, heteroaryl, and combinations thereof. In some such embodiments, the aza-variants contain exactly one N atom at the 6-position (ortho to the O, S, or Se) with a substituent at the 7-position (meta to the O, S, or Se).

In some embodiments, moiety B is a polycyclic fused ring structure comprising at least four fused rings.

In some embodiments, the polycyclic fused ring structure comprising at least four fused rings comprises three 6-membered rings and one 5-membered ring. In some such embodiments, the 5-membered ring is fused to the ring coordinated to metal M, the second 6-membered ring is fused to the 5-membered ring, and the third 6-membered ring is fused to the second 6-membered ring. In some such embodiments, the third 6-membered ring is further substituted by a substituent selected from the group consisting of deuterium, fluorine, nitrile, alkyl, cycloalkyl, aryl, heteroaryl, and combinations thereof.

In some embodiments, moiety B is a polycyclic fused ring structure comprising at least five fused rings.

In some embodiments, the polycyclic fused ring structure comprising at least five fused rings comprises four 6-membered rings and one 5-membered ring or three 6-membered rings and two 5-membered rings. In some embodiments comprising two 5-membered rings, the 5-membered rings are fused together. In some embodiments comprising two 5-membered rings, the 5-membered rings are separated by at least one 6-membered ring. In some embodiments with one 5-membered ring, the 5-membered ring is fused to the ring coordinated to metal M, the second 6-membered ring is fused to the 5-membered ring, the third 6-membered ring is fused to the second 6-membered ring, and the fourth 6-membered ring is fused to the third 6-membered ring.

In some embodiments, moiety B can be an aza version of the polycyclic fused rings described above. In some such embodiments, moiety B can contain exactly one aza N atom. In some such embodiments, moiety B contains exactly two aza N atoms, which can be in one ring, or in two different rings. In some such embodiments, the ring having aza N atom is separated by at least two other rings from the metal M atom. In some such embodiments, the ring having aza N atom is separated by at least three other rings from the metal M atom. In some such embodiments, each of the ortho position of the aza N atom is substituted.

In some embodiments, the ligand L_{A} is selected from the group consisting of the following structures (LIST 1):

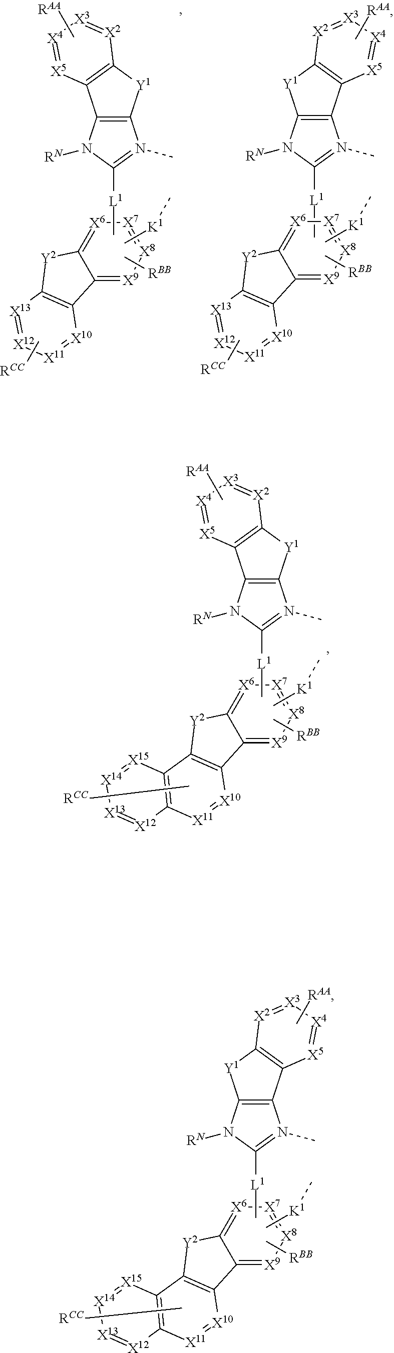

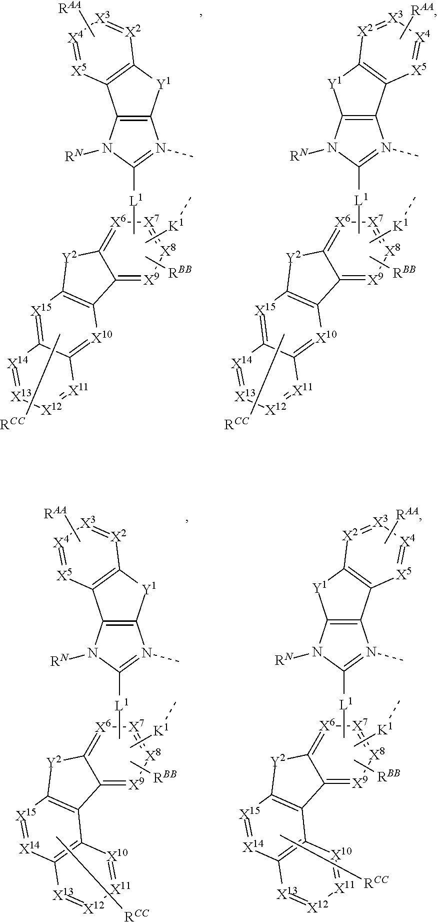

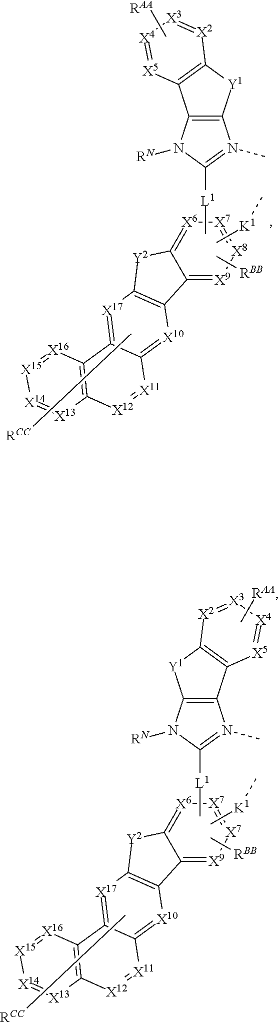

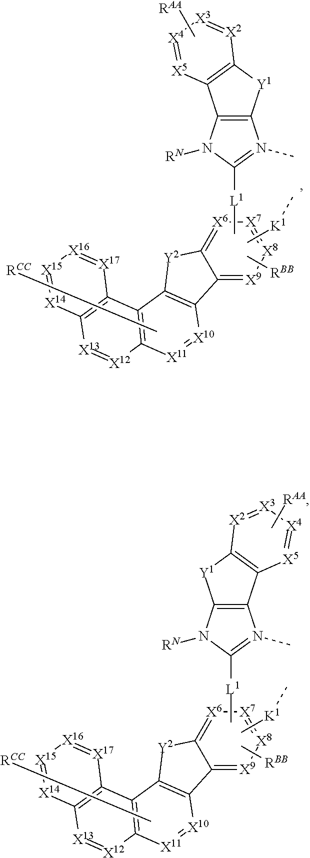

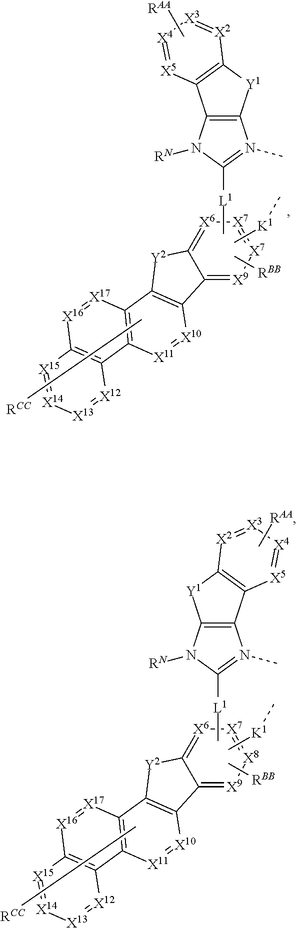

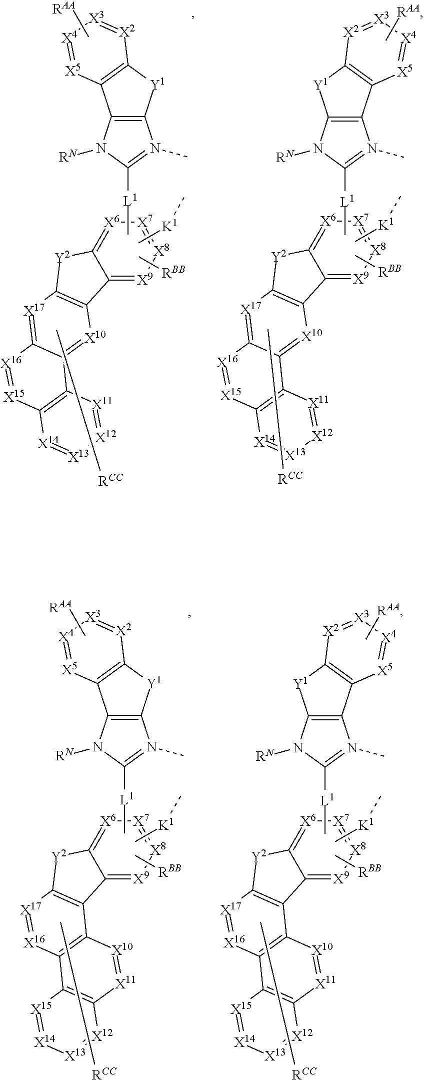

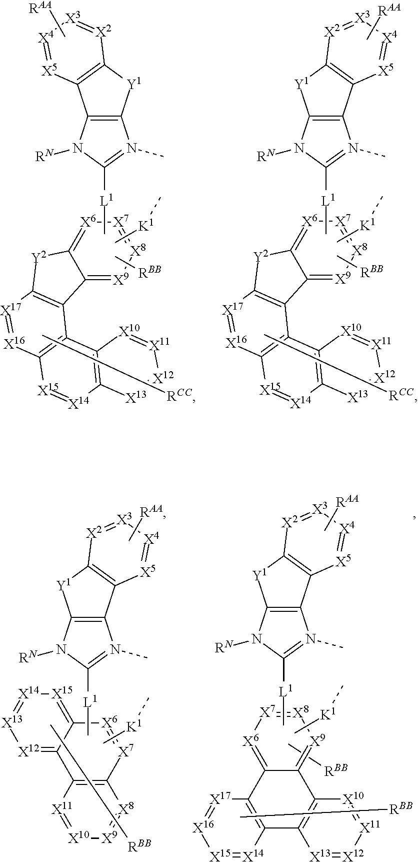

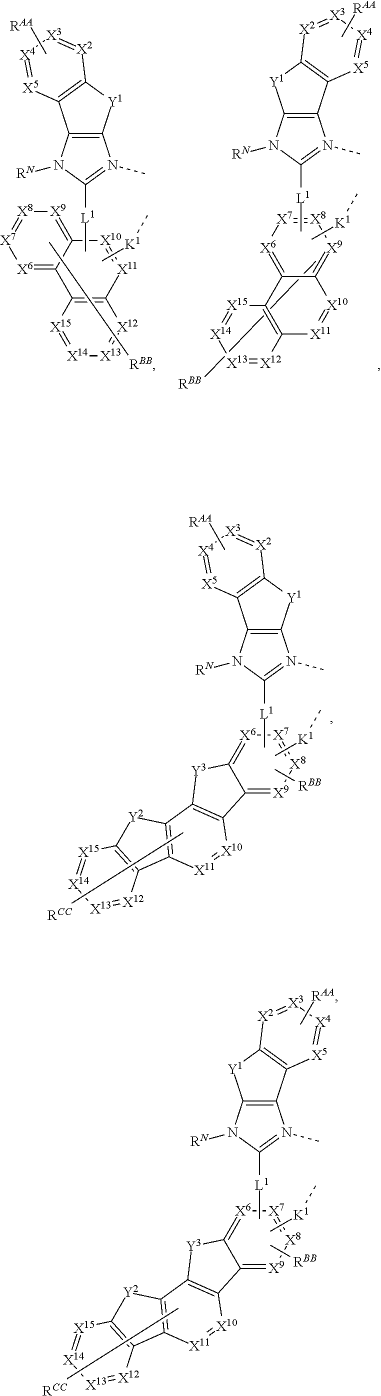

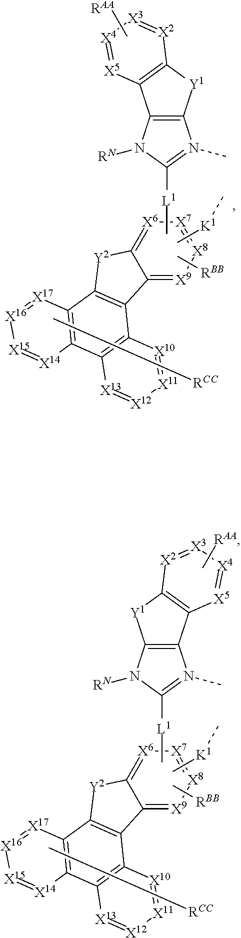

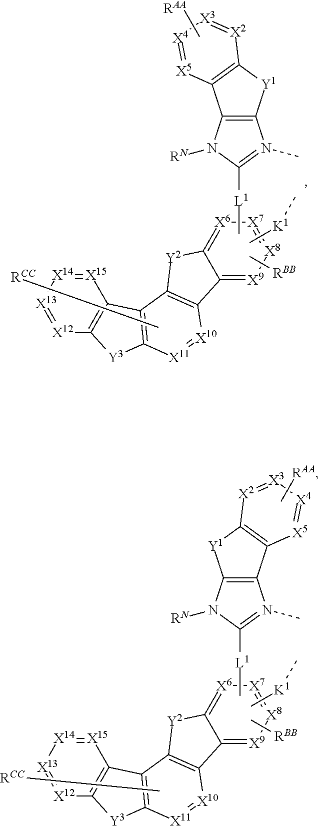

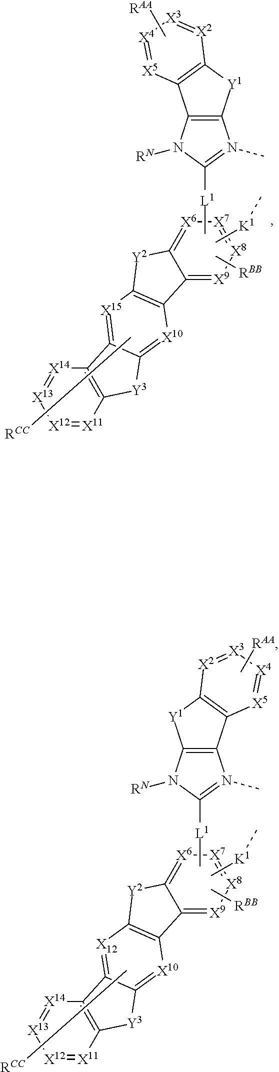

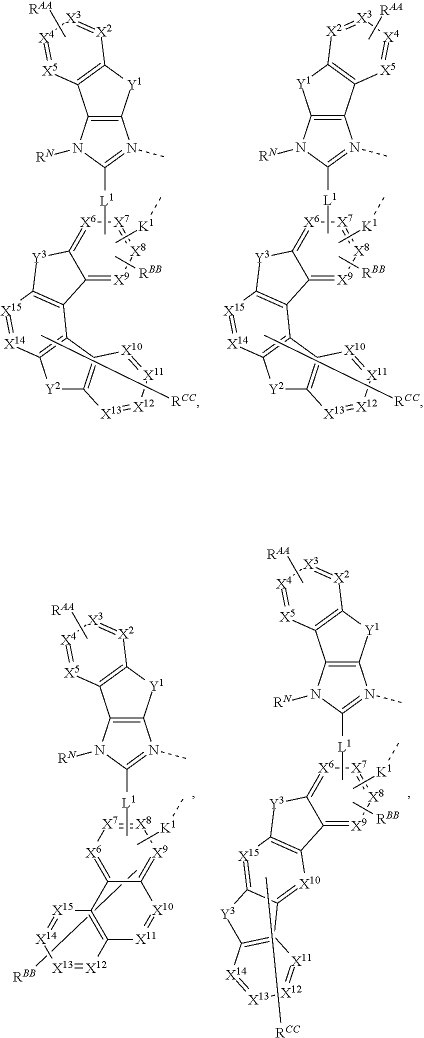

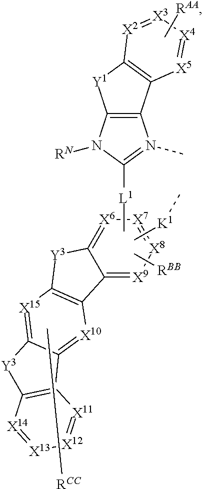

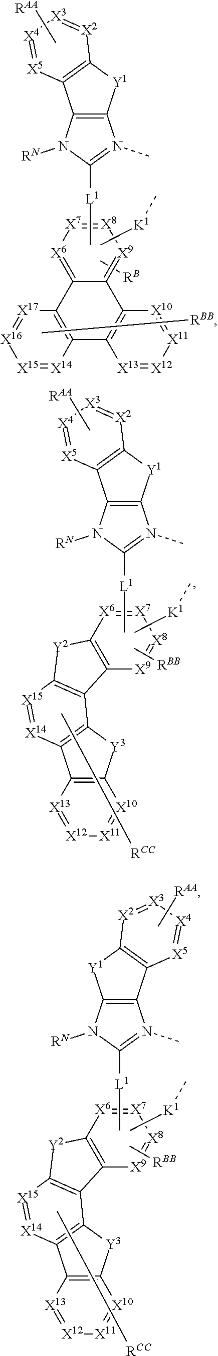

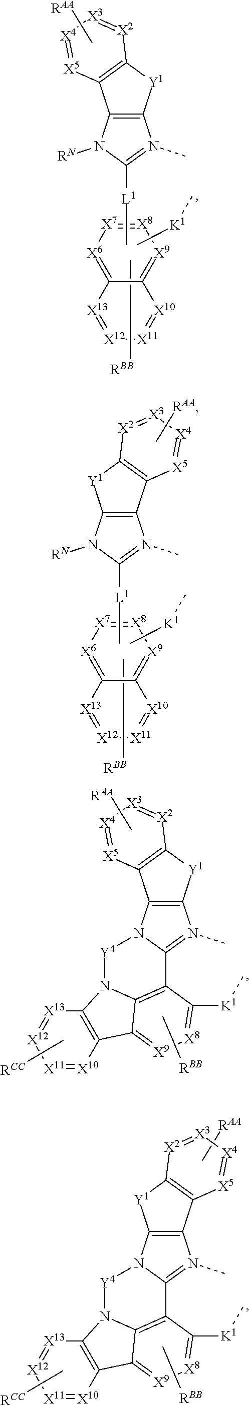

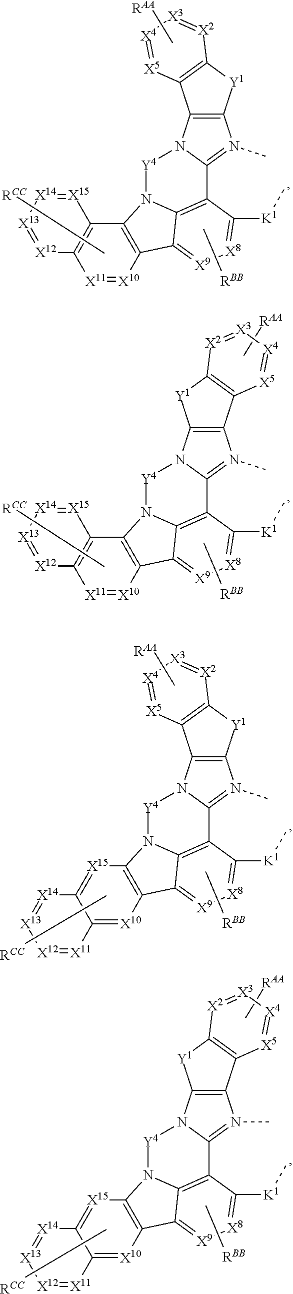

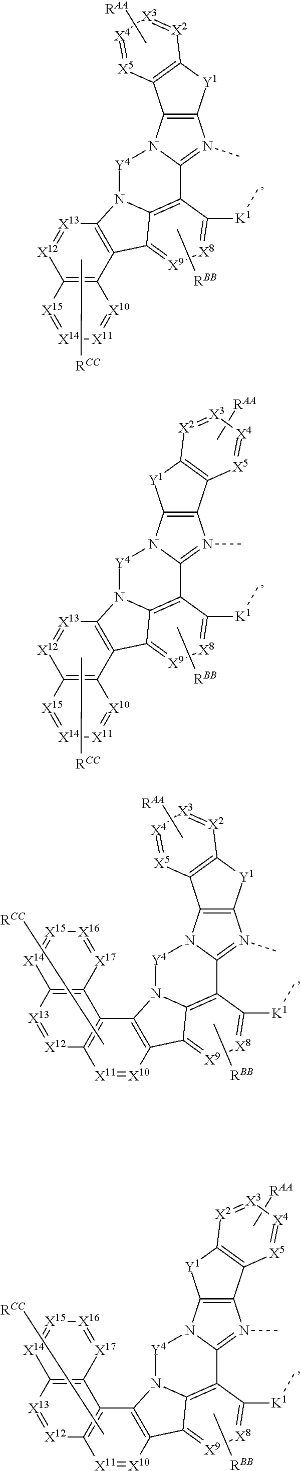

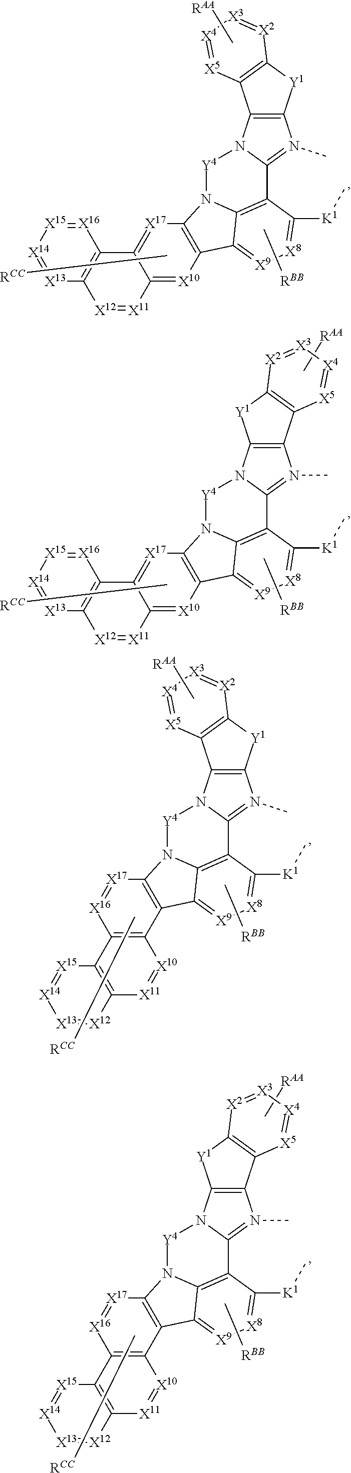

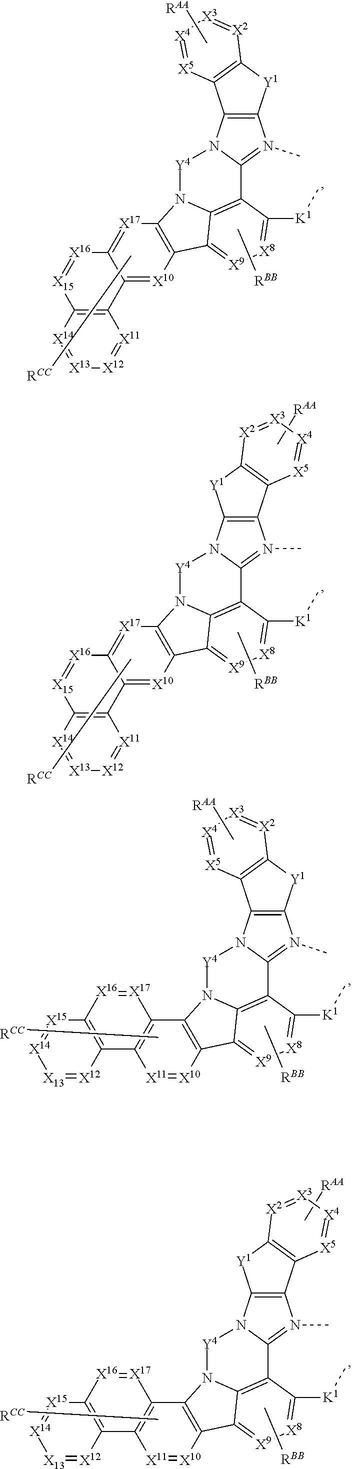

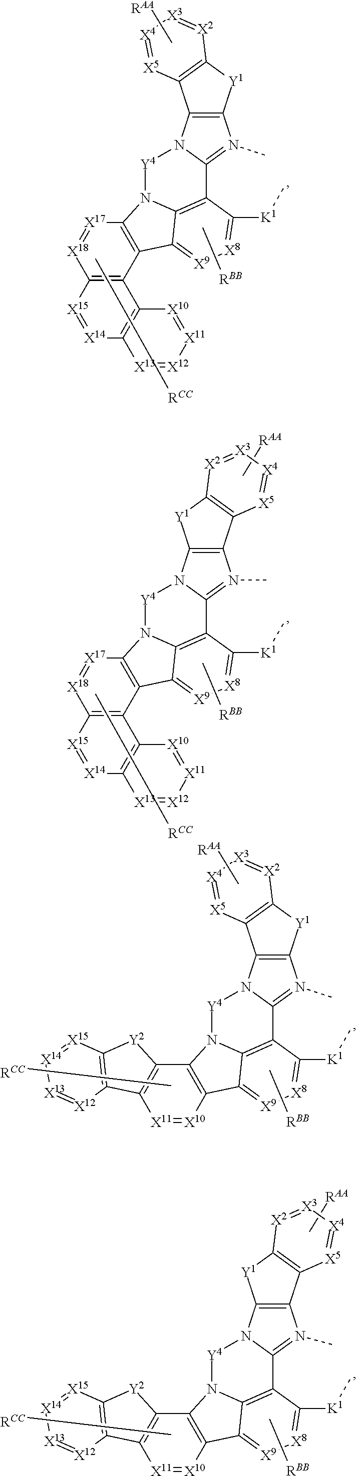

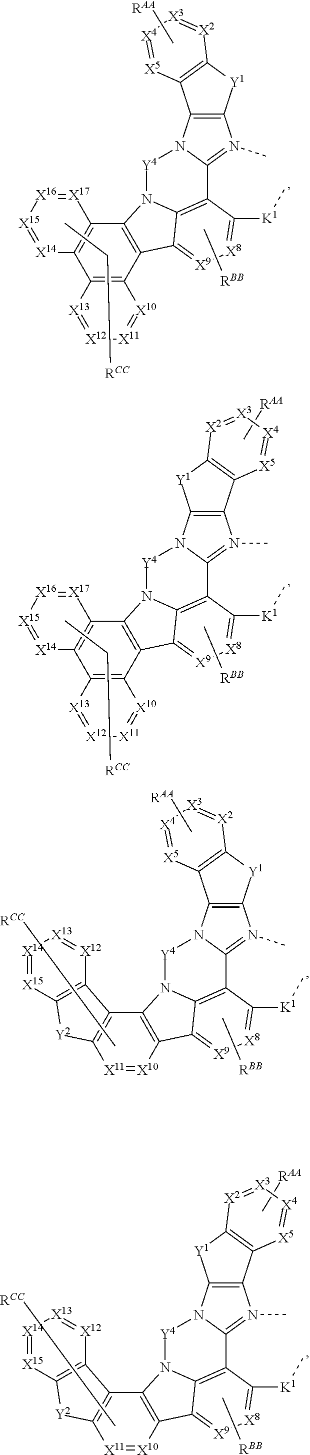

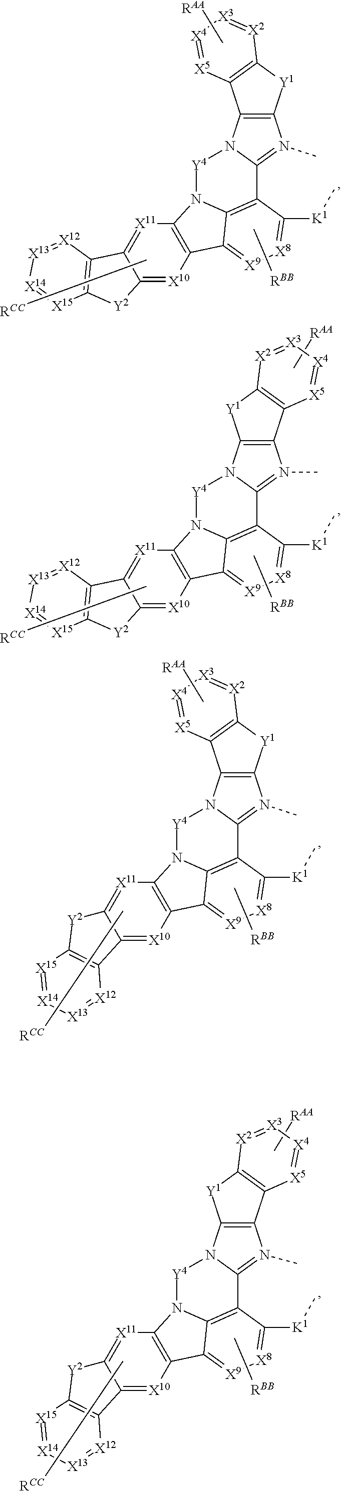

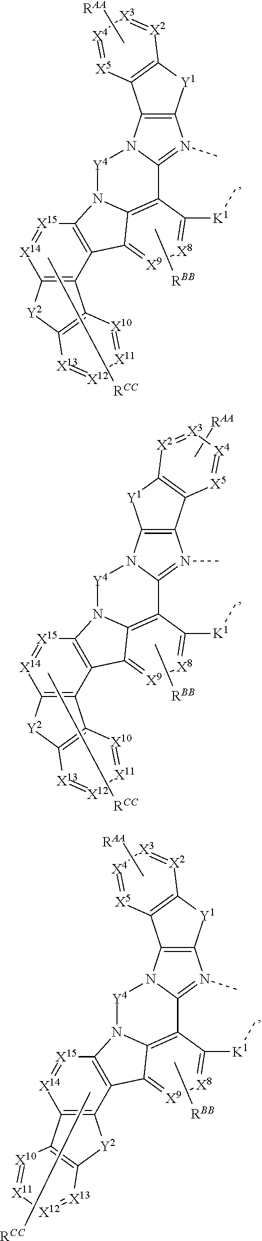

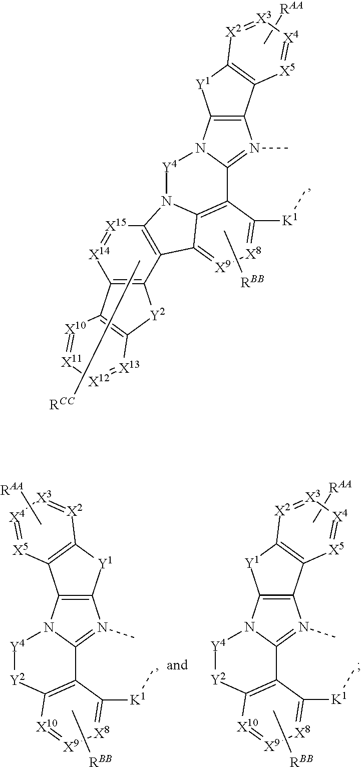

wherein X² to X¹⁷ is C or N;
wherein R^{AA}, R^{BB}, and R^{CC} is independently hydrogen or a substituent selected from the group consisting of deuterium, halogen, alkyl, cycloalkyl, heteroalkyl, heterocycloalkyl, arylalkyl, alkoxy, aryloxy, amino, silyl, germyl, boryl, alkenyl, cycloalkenyl, heteroalkenyl, alkynyl, aryl, heteroaryl, acyl, carboxylic acid, ether, ester, nitrile, isonitrile, sulfanyl, sulfinyl, sulfonyl, phosphino, and combinations thereof;
wherein Y¹, Y², and Y³ are each independently selected from the group consisting of O, S, NR, CRR′, and SiRR; and
wherein Y⁴ is selected from the group consisting of C═O, C═S, C═Se, BR, GaR, SiRR′, and GeRR′.

In some embodiments, the first ligand L_{A} has the structure of Formula I selected from LIST 1, all X² to X¹⁷ are C. In some embodiments, the first ligand L_{A} has the structure of Formula I selected from LIST 1, at least one of X² to X¹⁷ is N. In some embodiments, the first ligand L_{A} has the structure of Formula I selected from LIST 1, at least two of X² to X¹⁷ is N. In some embodiments, the first ligand L_{A} has the structure of Formula I selected from LIST 1, at least three of X² to X¹⁷ is N. In some embodiments, the first ligand L_{A} has the structure of Formula I selected from LIST 1, Y¹ is O. In some embodiments, the first ligand L_{A} has the structure of Formula I selected from LIST 1, Y² is O. In some embodiments, the first ligand L_{A} has the structure of Formula I selected from LIST 1, Y³ is O.

In some embodiments, the first ligand L_{A} has the structure of Formula I selected from LIST 1, X⁶ is C and L¹ is connected to X⁶. In some embodiments, the first ligand L_{A} has the structure of Formula I selected from LIST 1, X⁷ is C and L¹ is connected to X⁷. In some embodiments, the first ligand L_{A} has the structure of Formula I selected from LIST 1, X⁸ is C and L¹ is connected to X⁸. In some embodiments, the first ligand L_{A} has the structure of Formula I selected from LIST 1, X⁹ is C and L¹ is connected to X⁹. In some embodiments, the first ligand L_{A} has the structure of Formula I selected from LIST 1, X¹⁰ is C and L¹ is connected to X¹⁰. In some embodiments, the first ligand L_{A} has the structure of Formula I selected from LIST 1, X¹¹ is C and L¹ is connected to X¹¹.

In some embodiments, the first ligand L_{A} has the structure of Formula I selected from LIST 1, L¹ is a direct bond. In some embodiments, the first ligand L_{A} has the structure of Formula I selected from LIST 1, Y¹ is O. In some embodiments, the first ligand L_{A} has the structure of Formula I selected from LIST 1, Y² is O. In some embodiments, the first ligand L_{A} has the structure of Formula I selected from LIST 1, Y³ is O. In some embodiments, the first ligand L_{A} has the structure of Formula I selected from LIST 1, Y¹ is NR. In some embodiments, the first ligand L_{A} has the structure of Formula I selected from LIST 1, Y² is NR. In some embodiments, the first ligand L_{A} has the structure of Formula I selected from LIST 1, Y³ is NR.

In some embodiments, the first ligand L_{A} has the structure of Formula I selected from LIST 1, at least one R^{N}, R, R′, R^{α}, R^{β}, R^{AA}, R^{BB}, and R^{CC} is partially or fully deuterated. In some embodiments, the first ligand L_{A} has the structure of Formula I selected from LIST 1, at least one R^{N}, R, R′, R^{α}, R^{β}, R^{AA}, R^{BB}, and R^{CC} is selected from the group consisting of the General Substituents defined herein. In some embodiments, the first ligand L_{A} has the structure of Formula I selected from LIST 1, at least one R^{N}, R, R′, R^{α}, R^{β}, R^{AA}, R^{BB}, and R^{CC} is selected from the group consisting of the Preferred General Substituents defined herein.

In some embodiments, the first ligand L_{A} has the structure of Formula I selected from LIST 1, at least one RAA is or comprises an electron-withdrawing group from the EWG1 LIST as defined herein. In some embodiments, at least one RAA is or comprises an electron-withdrawing group from the EWG2 LIST as defined herein. In some embodiments, at least one RAA is or comprises an electron-withdrawing group from the EWG3 LIST as defined herein. In some embodiments, at least one RAA is or comprises an electron-withdrawing group from the EWG4 LIST as defined herein. In some embodiments, at least one RAA is or comprises an electron-withdrawing group from the Pi-EWG LIST as defined herein.

In some embodiments, the first ligand L_{A} has the structure of Formula I selected from LIST 1, at least one R^{BB} is or comprises an electron-withdrawing group from the EWG1 LIST as defined herein. In some embodiments, at least one R^{BB} is or comprises an electron-withdrawing group from the EWG2 LIST as defined herein. In some embodiments, at least one R^{BB} is or comprises an electron-withdrawing group from the EWG3 LIST as defined herein. In some embodiments, at least one R^{BB} is or comprises an electron-withdrawing group from the EWG4 LIST as defined herein. In some embodiments, at least one R^{BB} is or comprises an electron-withdrawing group from the Pi-EWG LIST as defined herein.

In some embodiments, the first ligand L_{A} has the structure of Formula I selected from LIST 1, at least one R^{CC} is or comprises an electron-withdrawing group from the EWG1 LIST as defined herein. In some embodiments, at least one R^{CC} is or comprises an electron-withdrawing group from the EWG2 LIST as defined herein. In some embodiments, at least one R^{CC} is or comprises an electron-withdrawing group from the EWG3 LIST as defined herein. In some embodiments, at least one R^{CC} is or comprises an electron-withdrawing group from the EWG4 LIST as defined herein. In some embodiments, at least one R^{CC} is or comprises an electron-withdrawing group from the Pi-EWG LIST as defined herein.

In some embodiments, the first ligand L_{A} has the structure of Formula I selected from LIST 1, at least one R^{N}, R, R′, R^{α}, or R^{β} is or comprises an electron-withdrawing group from the EWG1 LIST as defined herein. In some embodiments, at least one R^{N}, R, R′, R^{α}, or R^{β} is or comprises an electron-withdrawing group from the EWG2 LIST as defined herein. In some embodiments, at least one R^{N}, R, R′, R^{α}, or R^{β} is or comprises an electron-withdrawing group from the EWG3 LIST as defined herein. In some embodiments, at least one R^{N}, R, R′, R^{α}, or R^{β} is or comprises an electron-withdrawing group from the EWG4 LIST as defined herein. In some embodiments, at least one R^{N}, R, R′, R^{α}, or R^{β} is or comprises an electron-withdrawing group from the Pi-EWG LIST as defined herein.

In some embodiments, the ligand L_{A} is selected from the group consisting of the following structures (LIST 2):

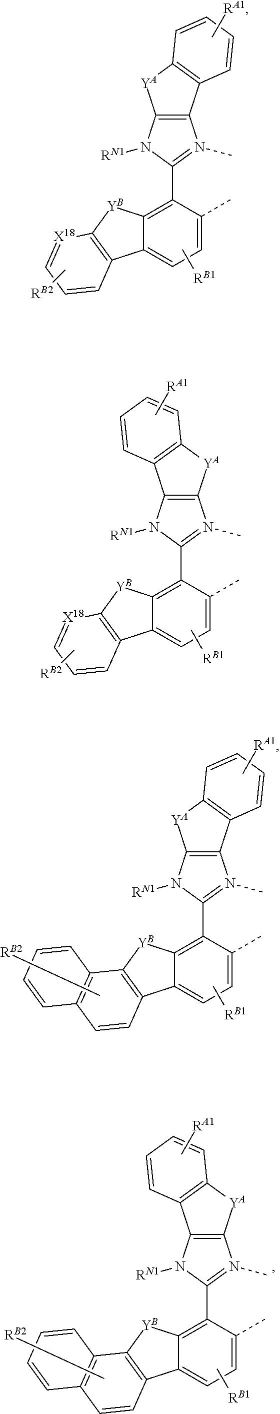

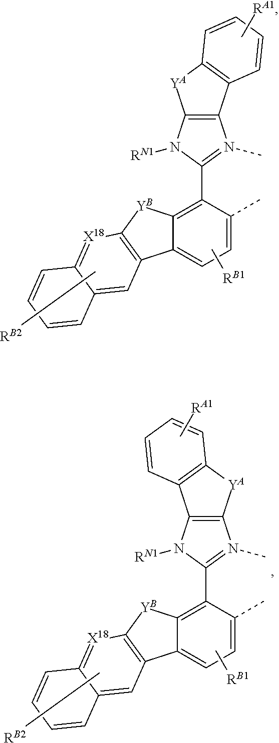

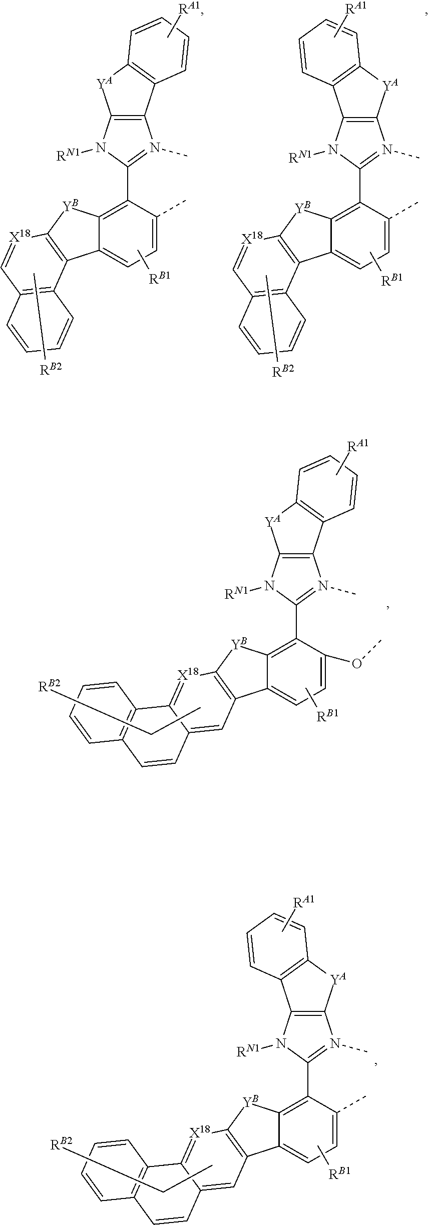

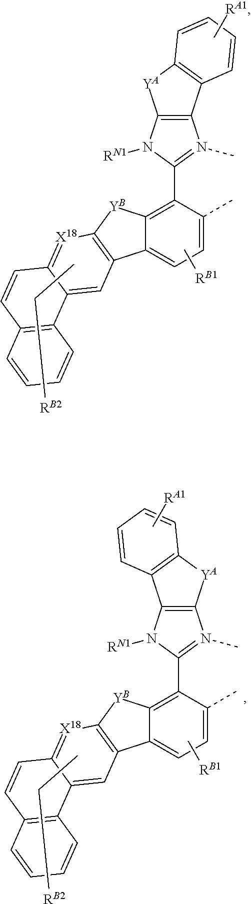

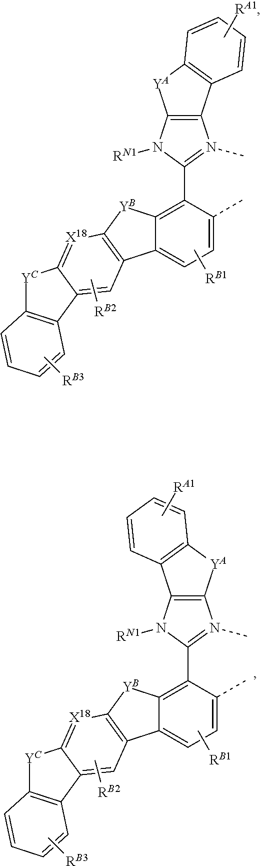

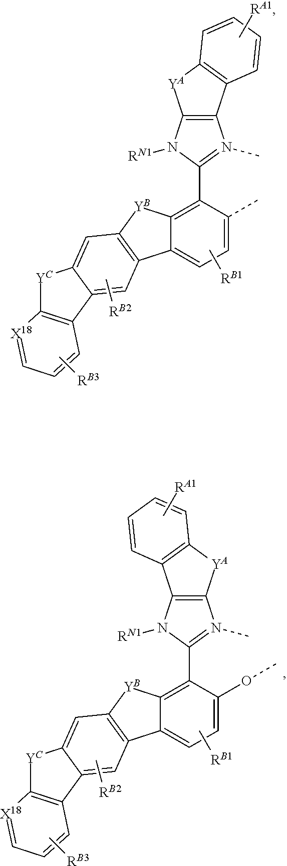

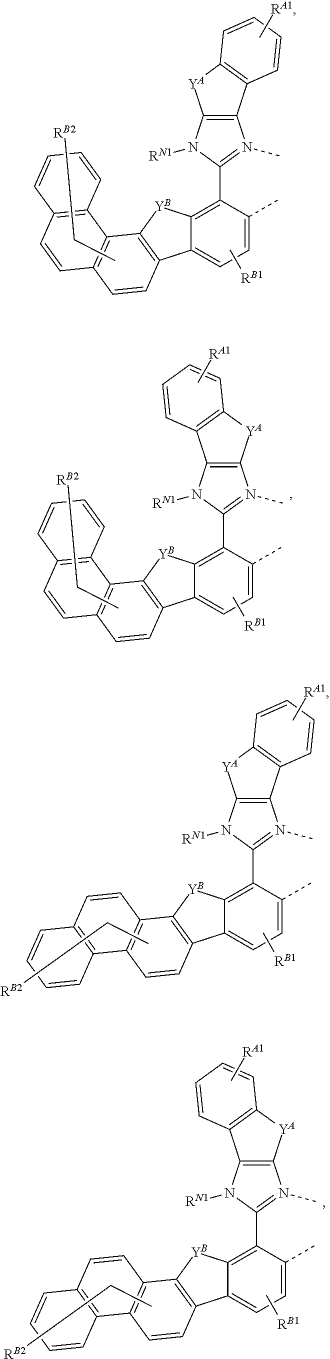

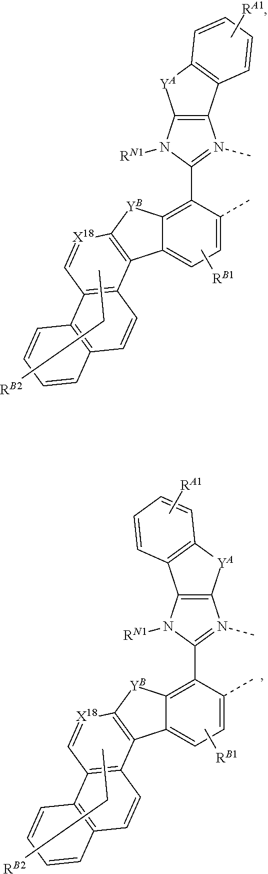

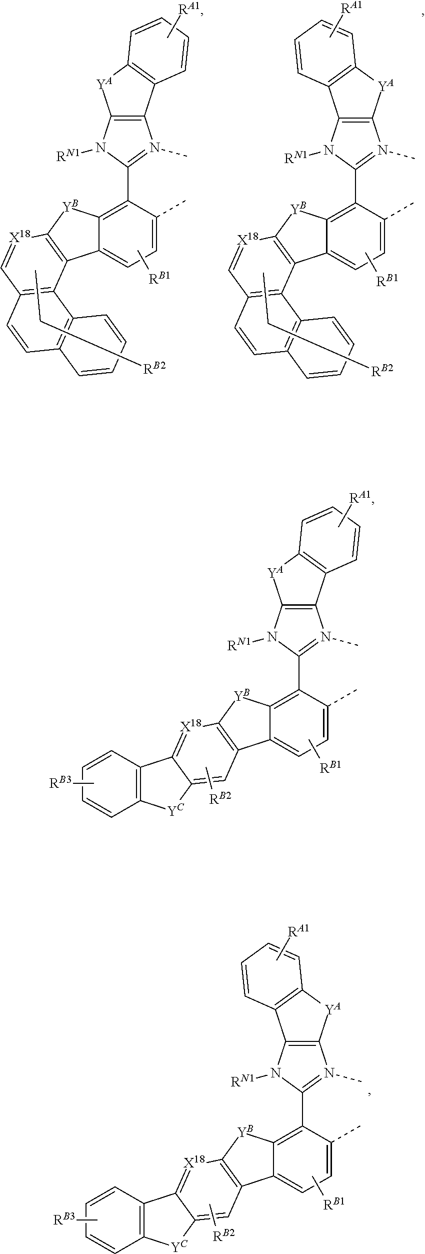

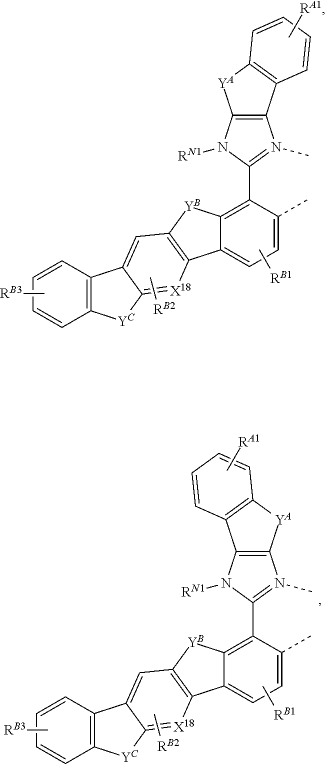

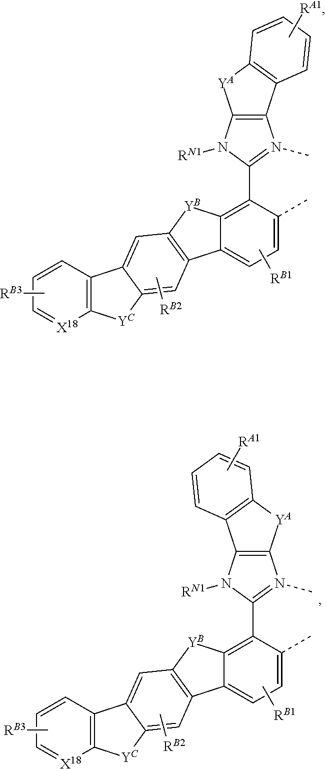

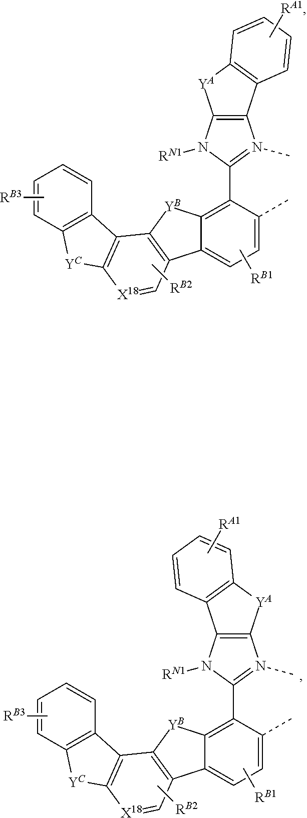

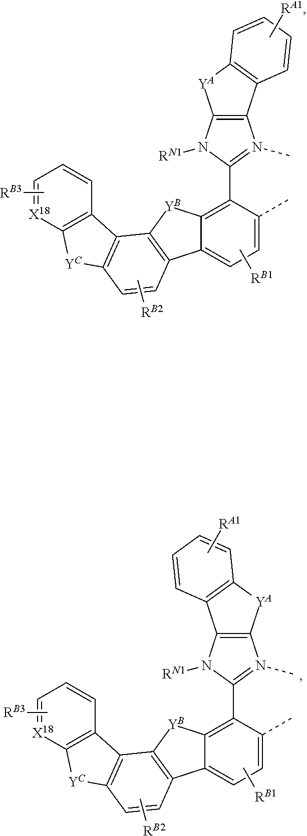

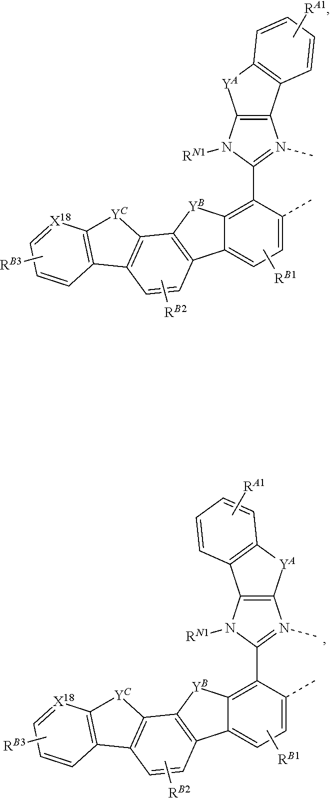

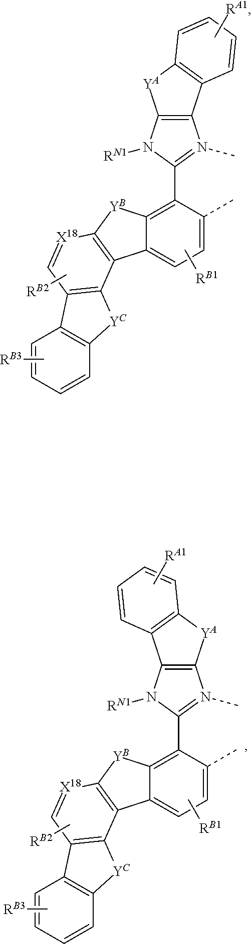

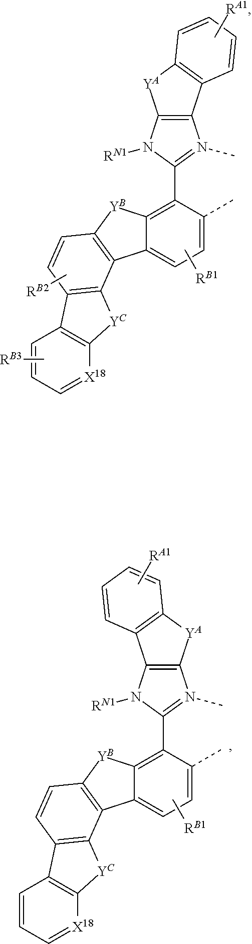

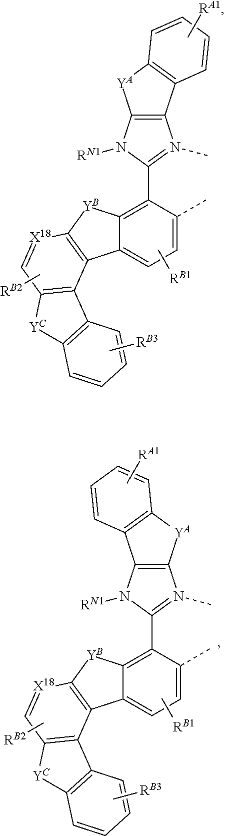

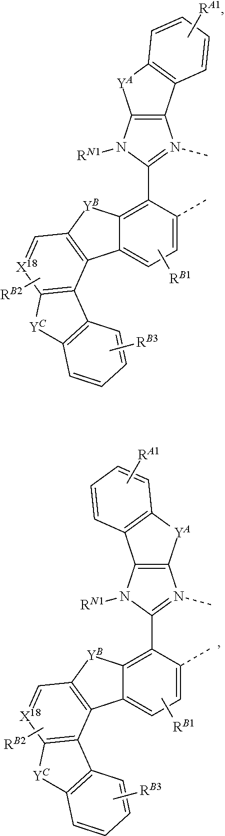

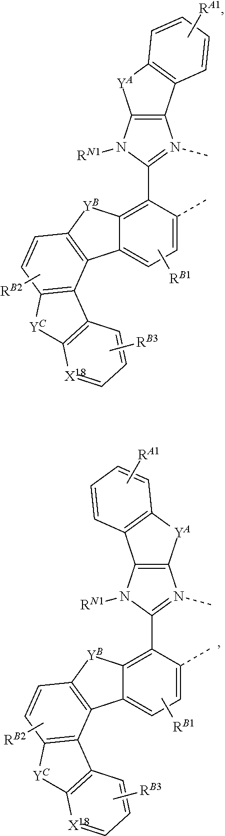

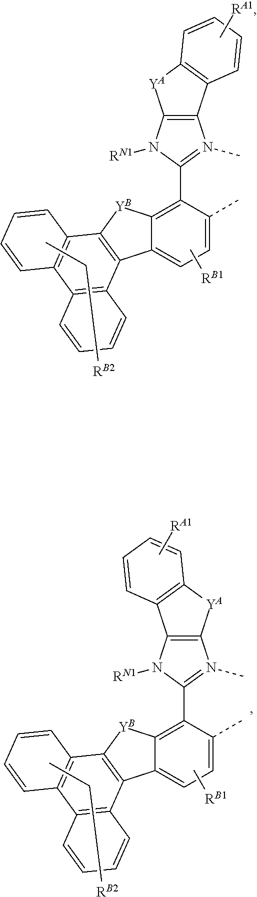

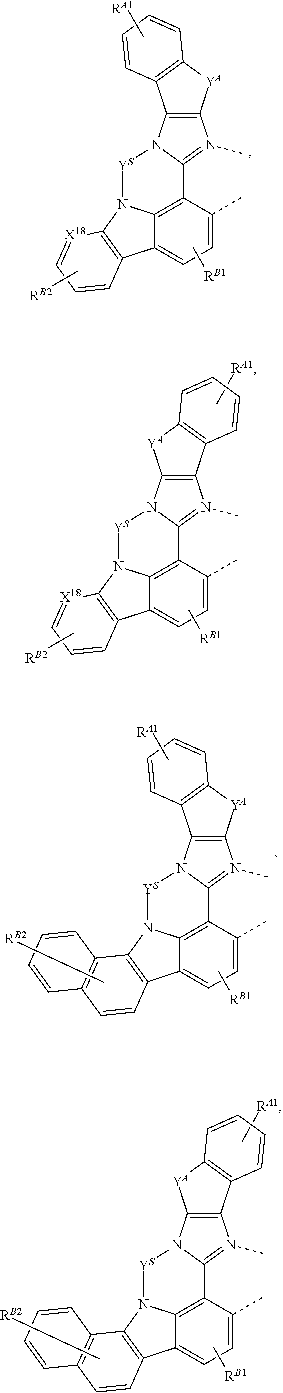

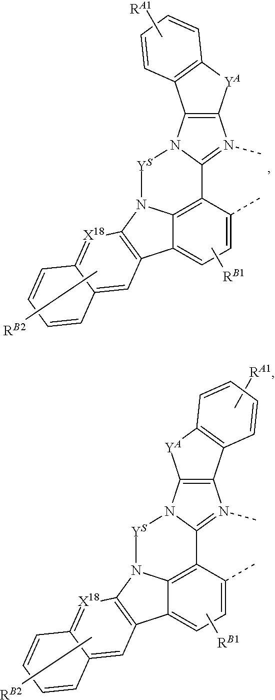

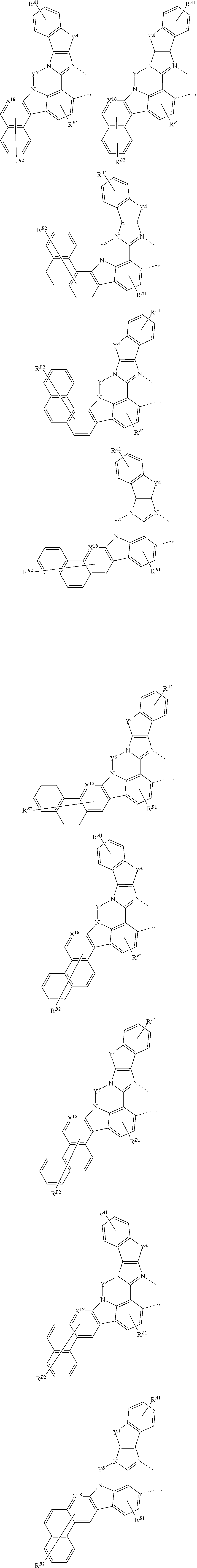

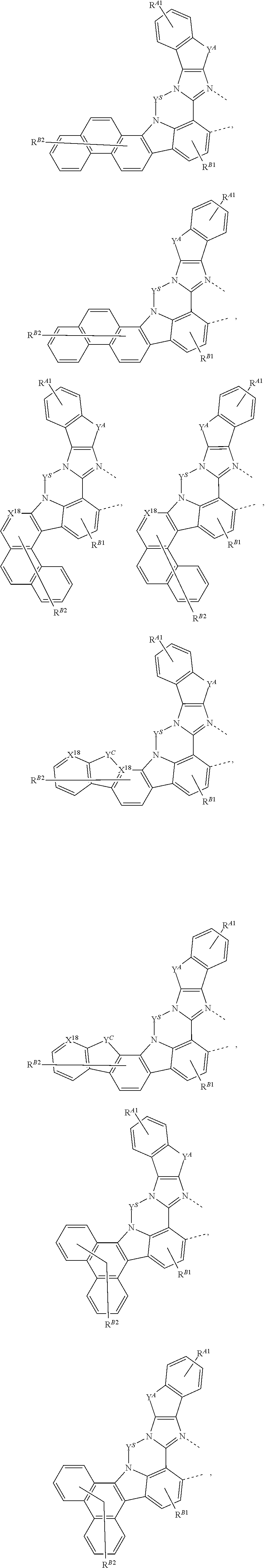

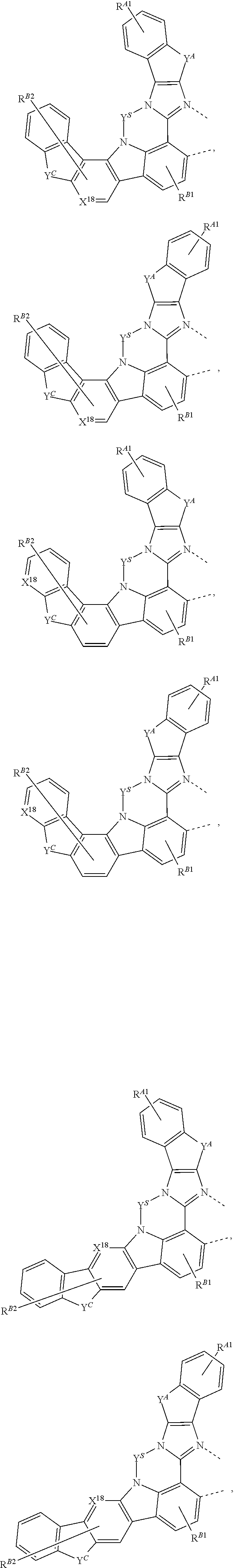

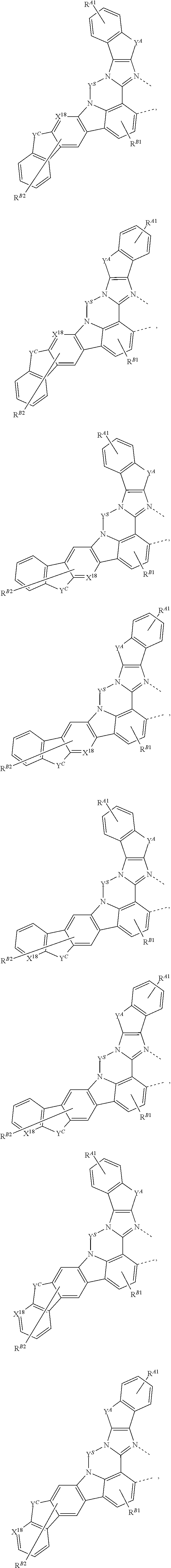

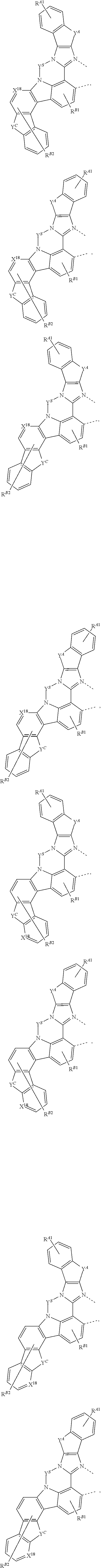

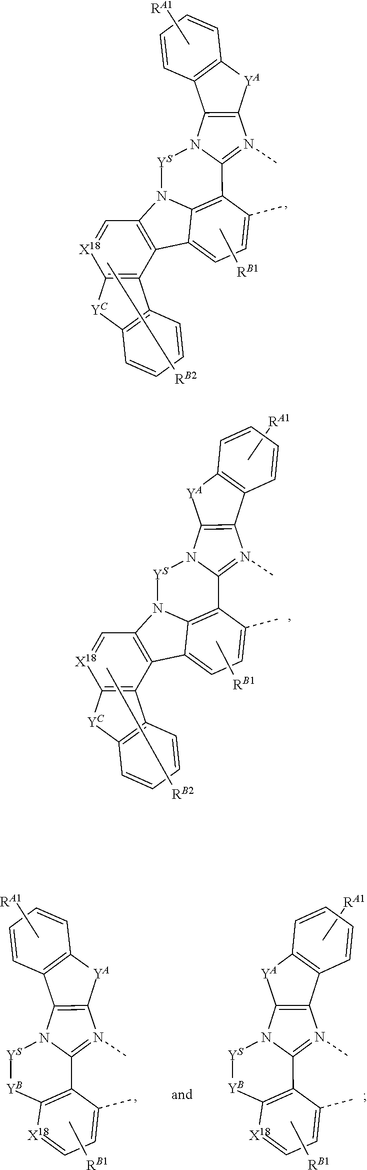

wherein X¹⁸ is C or N;
wherein R^{N1}, R^{A1}, R^{B1}, R^{B2}, and R^{B3} is each independently hydrogen or a substituent selected from the group consisting of deuterium, halogen, alkyl, cycloalkyl, heteroalkyl, heterocycloalkyl, arylalkyl, alkoxy, aryloxy, amino, silyl, germyl, boryl, alkenyl, cycloalkenyl, heteroalkenyl, alkynyl, aryl, heteroaryl, acyl, carboxylic acid, ether, ester, nitrile, isonitrile, sulfanyl, sulfinyl, sulfonyl, phosphino, and combinations thereof;
wherein Y^{A}, Y^{B}, and Y^{C} are each independently selected from the group consisting of O, S, NR, CRR′, and SiRR;
and
wherein Y^{S} is selected from the group consisting of C═O, C═S, C═Se, BR, GaR, SiRR′, and GeRR′.

In some embodiments, the first ligand L_{A} has the structure of Formula I selected from LIST 2, Y^{A} is O. In some embodiments, the first ligand L_{A} has the structure of Formula I selected from LIST 2, Y^{B} is O. In some embodiments, the first ligand L_{A} has the structure of Formula I selected from LIST 2, Y^{C} is O. In some embodiments, the first ligand L_{A} has the structure of Formula I selected from LIST 2, Y^{A} is NR. In some embodiments, the first ligand L_{A} has the structure of Formula I selected from LIST 2, Y^{B} is NR. In some embodiments, the first ligand L_{A} has the structure of Formula I selected from LIST 2, Y^{C} is NR. In some embodiments, the first ligand L_{A} has the structure of Formula I selected from LIST 2, X¹⁸ is C. In some embodiments, the first ligand L_{A} has the structure of Formula I selected from LIST 2, X¹⁸ is N.

In some embodiments, the first ligand L_{A} has the structure of Formula I selected from LIST 2, at least one R^{N1}, R^{A1}, R^{B1}, R^{B2}, R^{B3}, R, R′, R^{α}, and R^{B} is partially or fully deuterated. In some embodiments, the first ligand L_{A} has the structure of Formula I selected from LIST 2, at least one R^{N1}, R^{A1}, R^{B1}, R^{B2}, R^{B3}, R, R′, R^{α}, and R^{β} is selected from the group consisting of the General Substituents defined herein. In some embodiments, the first ligand L_{A} has the structure of Formula I selected from LIST 2, at least one R^{N1}, R^{A1}, R^{B1}, R^{B2}, R^{B3}, R, R′, R^{α}, and R^{β} is selected from the group consisting of the Preferred General Substituents defined herein.

In some embodiments, the first ligand L_{A} has the structure of Formula I selected from LIST 2, at least one R^{A1} is or comprises an electron-withdrawing group from the EWG1 LIST as defined herein. In some embodiments, at least one R^{A1} is or comprises an electron-withdrawing group from the EWG2 LIST as defined herein. In some embodiments, at least one R^{A1} is or comprises an electron-withdrawing group from the EWG3 LIST as defined herein. In some embodiments, at least one R^{A1} is or comprises an electron-withdrawing group from the EWG4 LIST as defined herein. In some embodiments, at least one R^{A1} is or comprises an electron-withdrawing group from the Pi-EWG LIST as defined herein.

In some embodiments, the first ligand L_{A} has the structure of Formula I selected from LIST 2, at least one R^{B1}, R^{B2}, or R^{B3} is or comprises an electron-withdrawing group from the EWG1 LIST as defined herein. In some embodiments, at least one R^{B1}, R^{B2}, or R^{B3} is or comprises an electron-withdrawing group from the EWG2 LIST as defined herein. In some embodiments, at least one R^{B1}, R^{B2}, or R^{B3} is or comprises an electron-withdrawing group from the EWG3 LIST as defined herein. In some embodiments, at least one R^{B1}, R^{B2}, or R^{B3} is or comprises an electron-withdrawing group from the EWG4 LIST as defined herein. In some embodiments, at least one R^{B1}, R^{B2}, or R^{B3} is or comprises an electron-withdrawing group from the Pi-EWG LIST as defined herein.

In some embodiments, the first ligand L_{A} has the structure of Formula I selected from LIST 2, at least one R^{N1}, R, R′, R^{α}, or R^{β} is or comprises an electron-withdrawing group from the EWG1 LIST as defined herein. In some embodiments, at least one R^{N1}, R, R′, R^{α}, or R^{β} is or comprises an electron-withdrawing group from the EWG2 LIST as defined herein. In some embodiments, at least one R^{N1}, R, R′, R^{α}, or R^{β} is or comprises an electron-withdrawing group from the EWG3 LIST as defined herein. In some embodiments, at least one R^{N1}, R, R′, R^{α}, or R^{β} is or comprises an electron-withdrawing group from the EWG4 LIST as defined herein. In some embodiments, at least one R^{N1}, R, R′, R^{α}, or R^{β} is or comprises an electron-withdrawing group from the Pi-EWG LIST as defined herein.

In some embodiments, R^{N1} comprises a structure of Formula II,

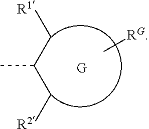

In some embodiments, at least one R^{N1} comprises a structure of Formula IIA,

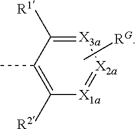

In some embodiments, the ligand L_{A} is selected from L_{Ai1}(R^{H})(R^{I})(R^{J})(Y^{D})(Y^{E}), L_{Ai2}(R^{H})(R^{I})(R^{J})(Y^{D})(Y^{F}), L_{Ai3}(R^{H})(R^{I})(R^{J})(Y^{D}), and L_{Ai4}(R^{I})(R^{J})(Y^{D})(Y^{F}), wherein i1 is an integer of from 1 to 56, i2 is an integer of from 57 to 90, and 135 to 184, i3 is an integer of from 91 to 134, i4 is an integer of from 185 to 192, H, I and J are each independent an integer of from 1 to 263, each of D, E and F is an integer of from 1 to 31, each of R^{H}, R^{I}, and R^{J} are independently selected from V1 to V263, each of Y^{D}, Y^{E} and Y^{F} is independently selected from G1 to G31, wherein L_{A1}(V1)(V1)(V1)(G1)(G1) to L_{A56}(V263)(V263)(V263)(G31)(G31), L_{A57}(V1)(V1)(V1)(G1)(G1) to L_{A90}(V263)(V263)(V263)(G31)(G31), L_{A91}-(V1)(V1)(V1)(G1) to L_{A134}-(V263)(V263)(V263)(G31), L_{A135}(V1)(V1)(V1)(G1)(G1) to L_{A184}(V263)(V263)(V263)(G31)(G31), L_{A185}-(V1)(V1)(G1)(G1) to L_{A192}-(V263)(V263)(G31)(G31) are defined in the table below (LIST 3):

| L_{A} | Structure of L_{A} |
|---|---|
| L_{A1}(R^{H})(R^{I})(R^{J})(Y^{D})(Y^{E}), wherein L_{A1}(V1)(V1)(V1) (G1)(G1) to L_{A1}(V263)(V263)(V263) (G31)(G31), have the structure | 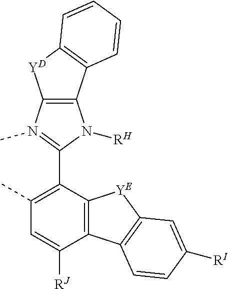 |
| L_{A2}(R^{H})(R^{I})(R^{J})(Y^{D})(Y^{E}), wherein L_{A2}(V1)(V1)(V1) (G1)(G1) to L_{A2}(V263)(V263)(V263) (G31)(G31), have the structure | 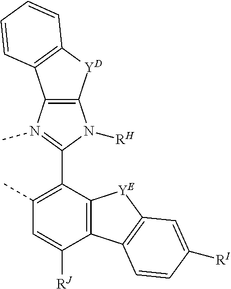 |
| L_{A3}(R^{H})(R^{I})(R^{J})(Y^{D})(Y^{E}), wherein L_{A3}(V1)(V1)(V1) (G1)(G1) to L_{A3}(V263)(V263)(V263) (G31)(G31), have the structure | 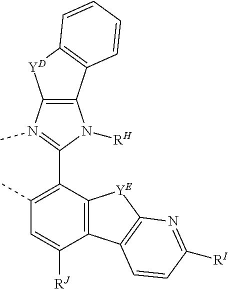 |
| L_{A4}(R^{H})(R^{I})(R^{J})(Y^{D})(Y^{E}), wherein L_{A4}(V1)(V1)(V1) (G1)(G1) to L_{A4}(V263)(V263)(V263) (G31)(G31), have the structure | 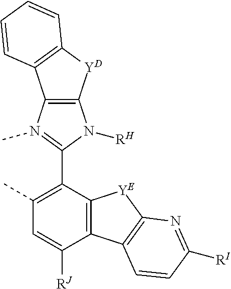 |
| L_{A5}(R^{H})(R^{I})(R^{J})(Y^{D})(Y^{E}), wherein L_{A5}(V1)(V1)(V1) (G1)(G1) to L_{A5}(V263)(V263)(V263) (G31)(G31), have the structure | 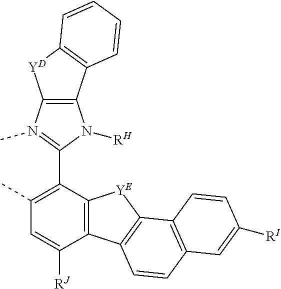 |
| L_{A6}(R^{H})(R^{I})(R^{J})(Y^{D})(Y^{E}), wherein L_{A6}(V1)(V1)(V1) (G1)(G1) to L_{A6}(V263)(V263)(V263) (G31)(G31), have the structure | 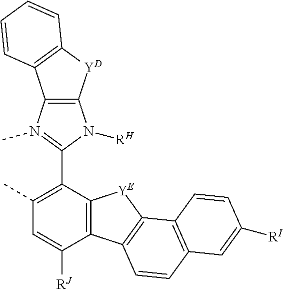 |
| L_{A7}(R^{H})(R^{I})(R^{J})(Y^{D})(Y^{E}), wherein L_{A7}(V1)(V1)(V1) (G1)(G1) to L_{A7}(V263)(V263)(V263) G31)(G31), have the structure | 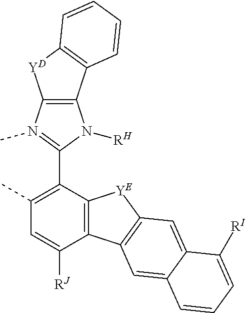 |
| L_{A8}(R^{H})(R^{I})(R^{J})(Y^{D})(Y^{E}), wherein L_{A8}(V1)(V1)(V1) (G1)(G1) to L_{A8}(V263)(V263)(V263) (G31)(G31), have the structure | 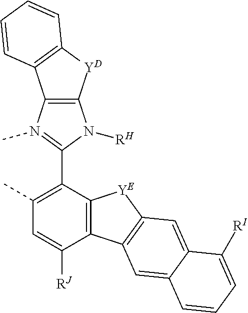 |
| L_{A9}(R^{H})(R^{I})(R^{J})(Y^{D})(Y^{E}), wherein L_{A9}(V1)(V1)(V1) (G1)(G1) to L_{A9}(V263)(V263)(V263) (G31)(G31), have the structure | 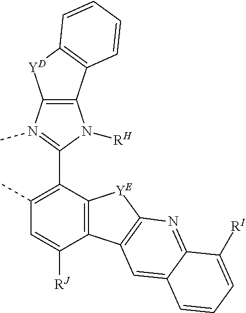 |
| L_{A10}(R^{H})(R^{I})(R^{J})(Y^{D})(Y^{E}), wherein L_{A10}(V1)(V1)(V1) (G1)(G1) to L_{A10}(V263)(V263)(V263) (G31)(G31), have the structure | 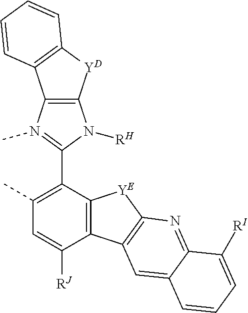 |
| L_{A11}(R^{H})(R^{I})(R^{J})(Y^{D})(Y^{E}), wherein L_{A11}(V1)(V1)(V1) (G1)(G1) to L_{A11}(V263)(V263)(V263) (G31)(G31), have the structure | 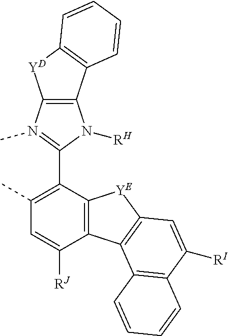 |
| L_{A12}(R^{H})(R^{I})(R^{J})(Y^{D})(Y^{E}), wherein L_{A12}(V1)(V1)(V1) (G1)(G1) to L_{A12}(V263)(V263)(V263) (G31)(G31), have the structure | 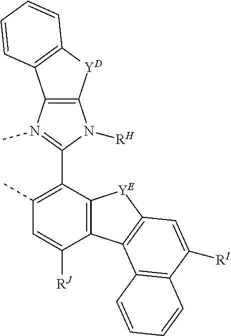 |
| L_{A13}(R^{H})(R^{I})(R^{J})(Y^{D})(Y^{E}), wherein L_{A13}(V1)(V1)(V1) (G1)(G1) to L_{A13}(V263)(V263)(V263) (G31)(G31), have the structure | 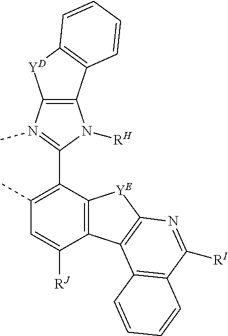 |
| L_{A14}(R^{H})(R^{I})(R^{J})(Y^{D})(Y^{E}), wherein L_{A14}(V1)(V1)(V1) (G1)(G1) to L_{A14}(V263)(V263)(V263) (G31)(G31), have the structure | 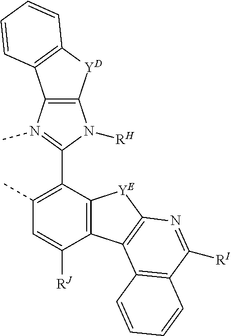 |
| L_{A15}(R^{H})(R^{I})(R^{J})(Y^{D})(Y^{E}), wherein L_{A15}(V1)(V1)(V1) (G1)(G1) to L_{A15}(V263)(V263)(V263) (G31)(G31), have the structure | 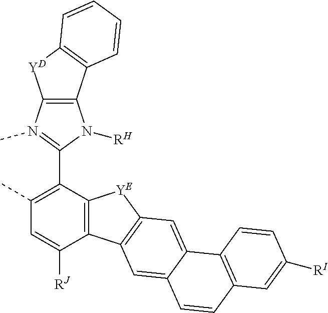 |
| L_{A16}(R^{H})(R^{I})(R^{J})(Y^{D})(Y^{E}), wherein L_{A16}(V1)(V1)(V1) (G1)(G1) to L_{A16}(V263)(V263)(V263) (G31)(G31), have the structure | 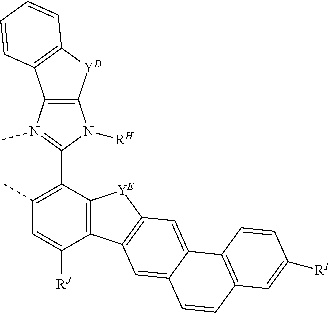 |
| L_{A17}(R^{H})(R^{I})(R^{J})(Y^{D})(Y^{E}), wherein L_{A17}(V1)(V1)(V1) (G1)(G1) to L_{A17}(V263)(V263)(V263) (G31)(G31), have the structure | 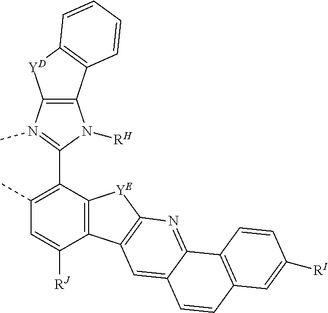 |
| L_{A18}(R^{H})(R^{I})(R^{J})(Y^{D})(Y^{E}), wherein L_{A18}(V1)(V1)(V1) (G1)(G1) to L_{A18}(V263)(V263)(V263) (G31)(G31), have the structure | 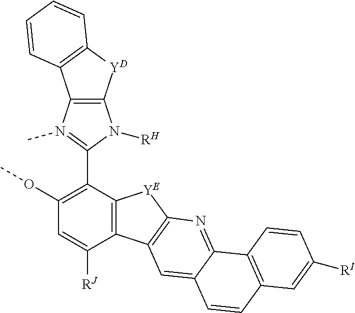 |
| L_{A19}(R^{H})(R^{I})(R^{J})(Y^{D})(Y^{E}), wherein L_{A19}(V1)(V1)(V1) (G1)(G1) to L_{A19}(V263)(V263)(V263) (G31)(G31), have the structure | 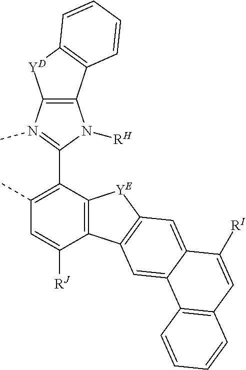 |
| L_{A20}(R^{H})(R^{I})(R^{J})(Y^{D})(Y^{E}), wherein L_{A20}(V1)(V1)(V1) (G1)(G1) to L_{A20}(V263)(V263)(V263) (G31)(G31), have the structure | 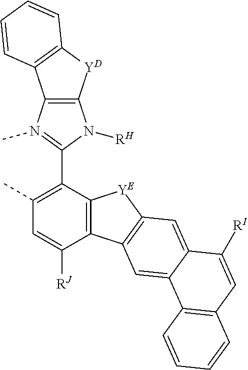 |
| L_{A21}(R^{H})(R^{I})(R^{J})(Y^{D})(Y^{E}), wherein L_{A21}(V1)(V1)(V1) (G1)(G1) to L_{A21}(V263)(V263)(V263) (G31)(G31), have the structure | 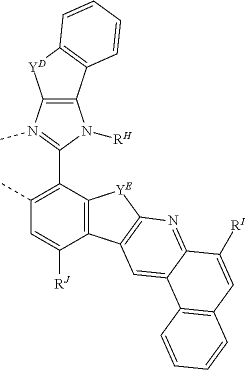 |
| L_{A22}(R^{H})(R^{I})(R^{J})(Y^{D})(Y^{E}), wherein L_{A22}(V1)(V1)(V1) (G1)(G1) to L_{A22}(V263)(V263)(V263) (G31)(G31), have the structure | 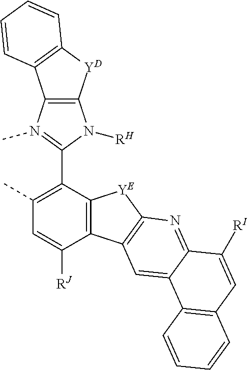 |
| L_{A23}(R^{H})(R^{I})(R^{J})(Y^{D})(Y^{E}), wherein L_{A23}(V1)(V1)(V1) (G1)(G1) to L_{A23}(V263)(V263)(V263) (G31)(G31), have the structure | 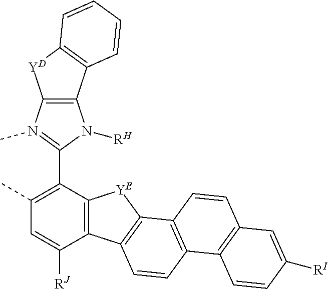 |
| L_{A24}(R^{H})(R^{I})(R^{J})(Y^{D})(Y^{E}), wherein L_{A24}(V1)(V1)(V1) (G1)(G1) to L_{A24}(V263)(V263)(V263) (G31)(G31), have the structure | 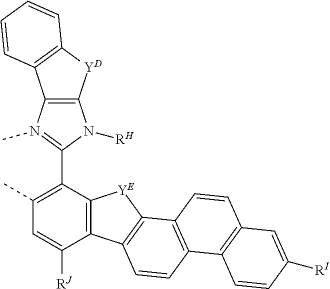 |
| L_{A25}(R^{H})(R^{I})(R^{J})(Y^{D})(Y^{E}), wherein L_{A25}(V1)(V1)(V1) (G1)(G1) to L_{A25}(V263)(V263)(V263) (G31)(G31), have the structure | 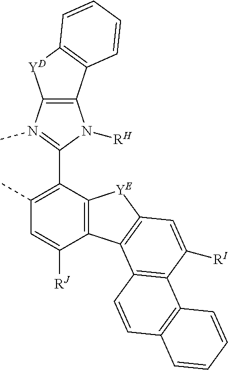 |
| L_{A26}(R^{H})(R^{I})(R^{J})(Y^{D})(Y^{E}), wherein L_{A26}(V1)(V1)(V1) (G1)(G1) to L_{A26}(V263)(V263)(V263) (G31)(G31), have the structure | 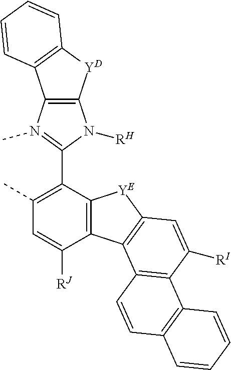 |
| L_{A27}(R^{H})(R^{I})(R^{J})(Y^{D})(Y^{E}), wherein L_{A27}(V1)(V1)(V1) (G1)(G1) to L_{A27}(V263)(V263)(V263) (G31)(G31), have the structure | 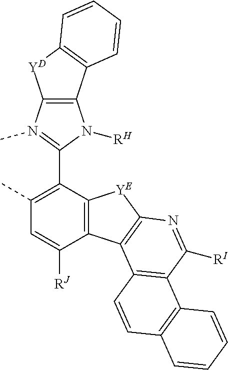 |
| L_{A28}(R^{H})(R^{I})(R^{J})(Y^{D})(Y^{E}), wherein L_{A28}(V1)(V1)(V1) (G1)(G1) to L_{A28}(V263)(V263)(V263) (G31)(G31), have the structure | 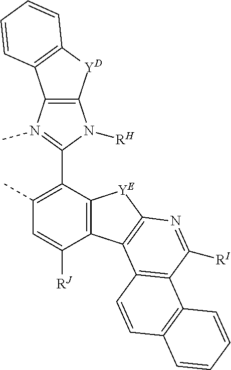 |
| L_{A29}(R^{H})(R^{I})(R^{J})(Y^{D})(Y^{E}), wherein L_{A29}(V1)(V1)(V1) (G1)(G1) to L_{A29}(V263)(V263)(V263) (G31)(G31), have the structure | 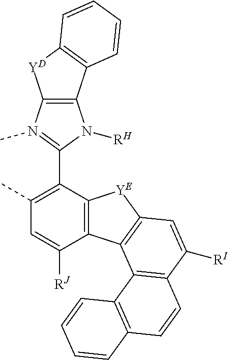 |
| L_{A30}(R^{H})(R^{I})(R^{J})(Y^{D})(Y^{E}), wherein L_{A30}(V1)(V1)(V1) (G1)(G1) to L_{A30}(V263)(V263)(V263) (G31)(G31), have the structure | 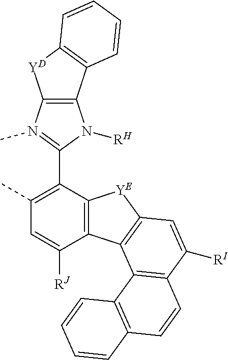 |
| L_{A31}(R^{H})(R^{I})(R^{J})(Y^{D})(Y^{E}), wherein L_{A31}(V1)(V1)(V1) (G1)(G1) to L_{A31}(V263)(V263)(V263) (G31)(G31), have the structure | 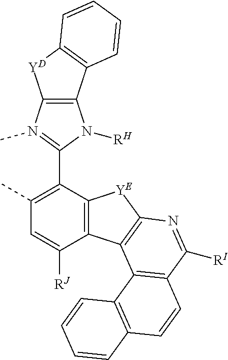 |
| L_{A32}(R^{H})(R^{I})(R^{J})(Y^{D})(Y^{E}), wherein L_{A32}(V1)(V1)(V1) (G1)(G1) to L_{A32}(V263)(V263)(V263) (G31)(G31), have the structure | 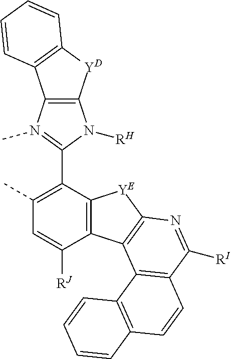 |
| L_{A33}(R^{H})(R^{I})(R^{J})(Y^{D})(Y^{E}), wherein L_{A33}(V1)(V1)(V1) (G1)(G1) to L_{A33}(V263)(V263)(V263) (G31)(G31), have the structure | 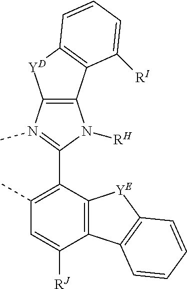 |
| L_{A34}(R^{H})(R^{I})(R^{J})(Y^{D})(Y^{E}), wherein L_{A34}(V1)(V1)(V1) (G1)(G1) to L_{A34}(V263)(V263)(V263) (G31)(G31), have the structure | 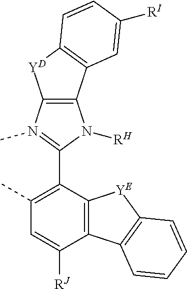 |
| L_{A35}(R^{H})(R^{I})(R^{J})(Y^{D})(Y^{E}), wherein L_{A35}(V1)(V1)(V1) (G1)(G1) to L_{A35}(V263)(V263)(V263) (G31)(G31), have the structure | 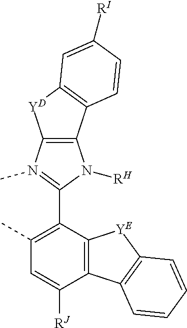 |
| L_{A36}(R^{H})(R^{I})(R^{J})(Y^{D})(Y^{E}), wherein L_{A36}(V1)(V1)(V1) (G1)(G1) to L_{A36}(V263)(V263)(V263) (G31)(G31), have the structure | 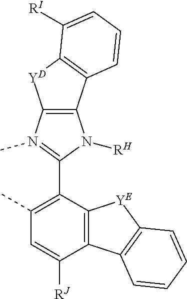 |
| L_{A37}(R^{H})(R^{I})(R^{J})(Y^{D})(Y^{E}), wherein L_{A37}(V1)(V1)(V1) (G1)(G1) to L_{A37}(V263)(V263)(V263) (G31)(G31), have the structure | 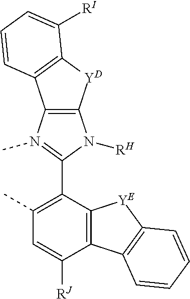 |
| L_{A38}(R^{H})(R^{I})(R^{J})(Y^{D})(Y^{E}), wherein L_{A38}(V1)(V1)(V1) (G1)(G1) to L_{A38}(V263)(V263)(V263) (G31)(G31), have the structure | 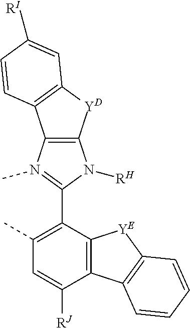 |
| L_{A39}(R^{H})(R^{I})(R^{J})(Y^{D})(Y^{E}), wherein L_{A39}(V1)(V1)(V1) (G1)(G1) to L_{A39}(V263)(V263)(V263) (G31)(G31), have the structure | 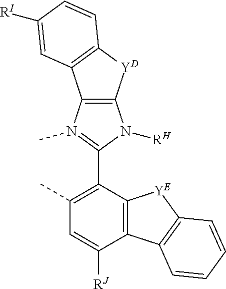 |
| L_{A40}(R^{H})(R^{I})(R^{J})(Y^{D})(Y^{E}), wherein L_{A40}(V1)(V1)(V1) (G1)(G1) to L_{A40}(V263)(V263)(V263) (G31)(G31), have the structure | 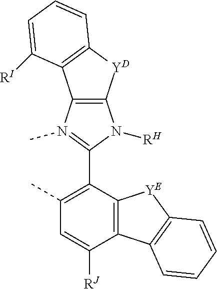 |
| L_{A41}(R^{H})(R^{I})(R^{J})(Y^{D})(Y^{E}), wherein L_{A41}(V1)(V1)(V1) (G1)(G1) to L_{A41}(V263)(V263)(V263) (G31)(G31), have the structure | 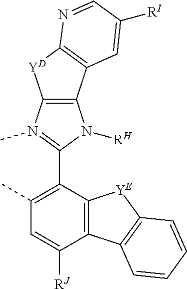 |
| L_{A42}(R^{H})(R^{I})(R^{J})(Y^{D})(Y^{E}), wherein L_{A42}(V1)(V1)(V1) (G1)(G1) to L_{A42}(V263)(V263)(V263) (G31)(G31), have the structure | 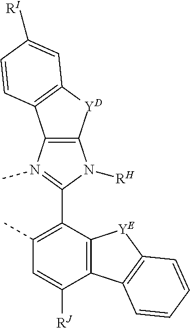 |
| L_{A43}(R^{H})(R^{I})(R^{J})(Y^{D})(Y^{E}), wherein L_{A43}(V1)(V1)(V1) (G1)(G1) to L_{A43}(V263)(V263)(V263) (G31)(G31), have the structure | 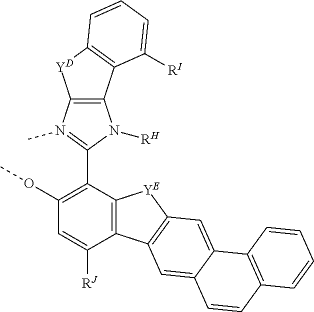 |
| L_{A44}(R^{H})(R^{I})(R^{J})(Y^{D})(Y^{E}), wherein L_{A44}(V1)(V1)(V1) (G1)(G1) to L_{A44}(V263)(V263)(V263) (G31)(G31), have the structure | 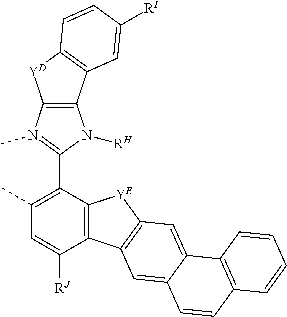 |
| L_{A45}(R^{H})(R^{I})(R^{J})(Y^{D})(Y^{E}), wherein L_{A45}(V1)(V1)(V1) (G1)(G1) to L_{A45}(V263)(V263)(V263) (G31)(G31), have the structure | 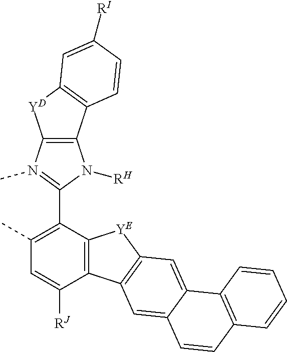 |
| L_{A46}(R^{H})(R^{I})(R^{J})(Y^{D})(Y^{E}), wherein L_{A46}(V1)(V1)(V1) (G1)(G1) to L_{A46}(V263)(V263)(V263) (G31)(G31), have the structure | 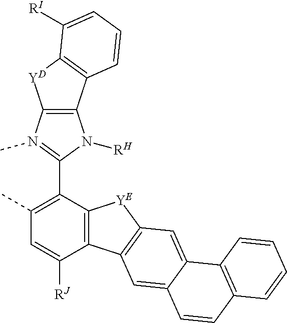 |
| L_{A47}(R^{H})(R^{I})(R^{J})(Y^{D})(Y^{E}), wherein L_{A47}(V1)(V1)(V1) (G1)(G1) to L_{A47}(V263)(V263)(V263) (G31)(G31), have the structure | 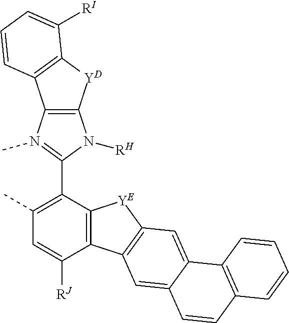 |
| L_{A48}(R^{H})(R^{I})(R^{J})(Y^{D})(Y^{E}), wherein L_{A48}(V1)(V1)(V1) (G1)(G1) to L_{A48}(V263)(V263)(V263) (G31)(G31), have the structure | 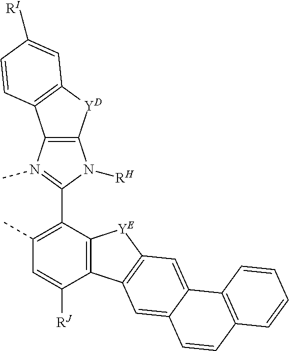 |
| L_{A49}(R^{H})(R^{I})(R^{J})(Y^{D})(Y^{E}), wherein L_{A49}(V1)(V1)(V1) (G1)(G1) to L_{A49}(V263)(V263)(V263) (G31)(G31), have the structure | 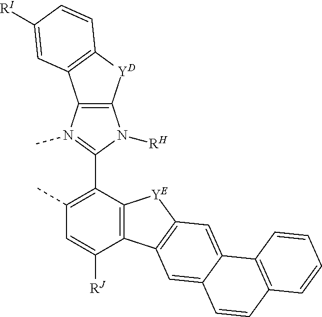 |
| L_{A50}(R^{H})(R^{I})(R^{J})(Y^{D})(Y^{E}), wherein L_{A50}(V1)(V1)(V1) (G1)(G1) to L_{A50}(V263)(V263)(V263) (G31)(G31), have the structure | 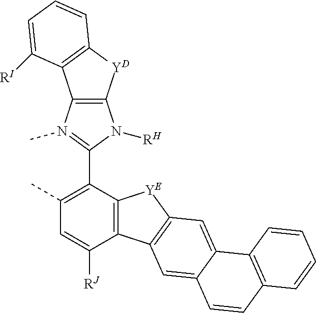 |
| L_{A51}(R^{H})(R^{I})(R^{J})(Y^{D})(Y^{E}), wherein L_{A51}(V1)(V1)(V1) (G1)(G1) to L_{A51}(V263)(V263)(V263) (G31)(G31), have the structure | 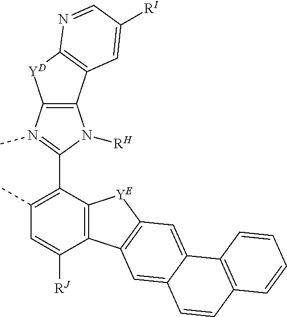 |
| L_{A52}(R^{H})(R^{I})(R^{J})(Y^{D})(Y^{E}), wherein L_{A52}(V1)(V1)(V1) (G1)(G1) to L_{A52}(V263)(V263)(V263) (G31)(G31), have the structure | 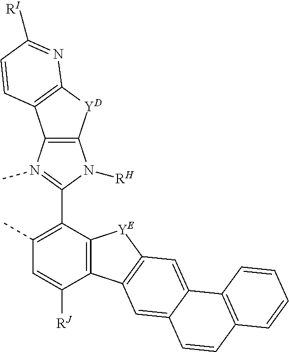 |
| L_{A53}(R^{H})(R^{I})(R^{J})(Y^{D})(Y^{E}), wherein L_{A53}(V1)(V1)(V1) (G1)(G1) to L_{A53}(V263)(V263)(V263) (G31)(G31), have the structure | 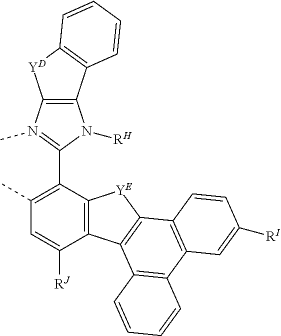 |
| L_{A54}(R^{H})(R^{I})(R^{J})(Y^{D})(Y^{E}), wherein L_{A54}(V1)(V1)(V1) (G1)(G1) to L_{A54}(V263)(V263)(V263) (G31)(G31), have the structure | 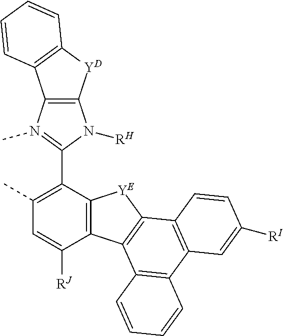 |
| L_{A55}(R^{H})(R^{I})(R^{J})(Y^{D})(Y^{E}), wherein L_{A55}(V1)(V1)(V1) (G1)(G1) to L_{A55}(V263)(V263)(V263) (G31)(G31), have the structure | 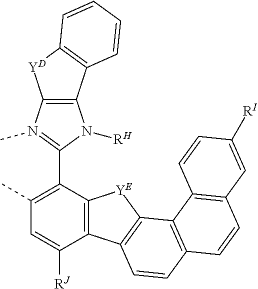 |
| L_{A56}(R^{H})(R^{I})(R^{J})(Y^{D})(Y^{E}), wherein L_{A56}(V1)(V1)(V1) (G1)(G1) to L_{A56}(V263)(V263)(V263) (G31)(G31), have the structure | 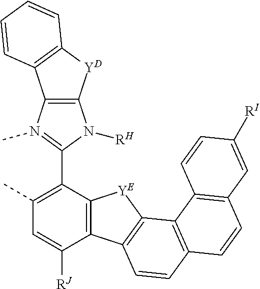 |
| L_{A57}(R^{H})(R^{I})(R^{J})(Y^{D})(Y^{F}), wherein L_{A57}(V1)(V1)(V1) (G1)(G1) to L_{A57}(V263)(V263)(V263) (G31)(G31), have the structure | 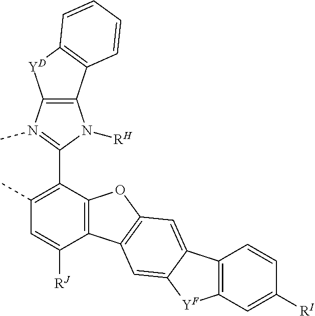 |
| L_{A57}(R^{H})(R^{I})(R^{J})(Y^{D})(Y^{F}), wherein L_{A58}(V1)(V1)(V1) (G1)(G1) to L_{A58}(V263)(V263)(V263) (G31)(G31), have the structure | 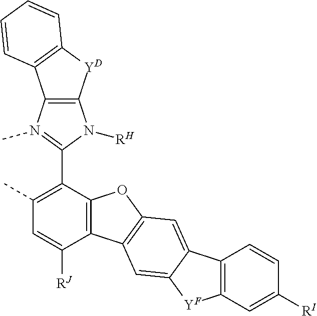 |
| L_{A59}(R^{H})(R^{I})(R^{J})(Y^{D})(Y^{F}), wherein L_{A59}(V1)(V1)(V1) (G1)(G1) to L_{A59}(V263)(V263)(V263) (G31)(G31), have the structure | 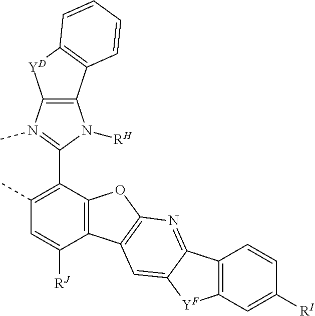 |
| L_{A60}(R^{H})(R^{I})(R^{J})(Y^{D})(Y^{F}), wherein L_{A60}(V1)(V1)(V1) (G1)(G1) to L_{A60}(V263)(V263)(V263) (G31)(G31), have the structure | 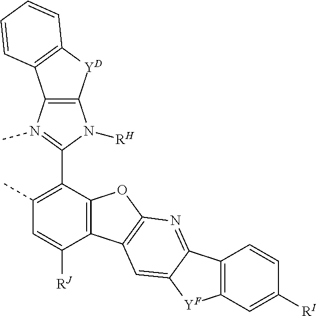 |
| L_{A61}(R^{H})(R^{I})(R^{J})(Y^{D})(Y^{F}), wherein L_{A61}(V1)(V1)(V1) (G1)(G1) to L_{A61}(V263)(V263)(V263) (G31)(G31), have the structure | 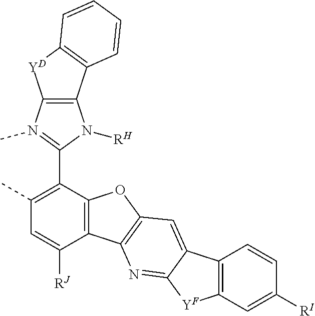 |
| L_{A62}(R^{H})(R^{I})(R^{J})(Y^{D})(Y^{F}), wherein L_{A62}(V1)(V1)(V1) (G1)(G1) to L_{A62}(V263)(V263)(V263) (G31)(G31), have the structure | 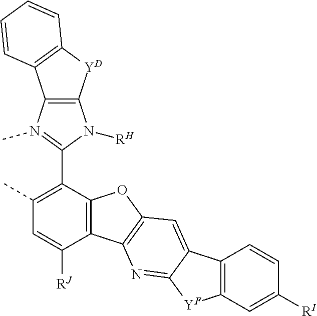 |
| L_{A63}(R^{H})(R^{I})(R^{J})(Y^{D})(Y^{F}), wherein L_{A63}(V1)(V1)(V1) (G1)(G1) to L_{A63}(V263)(V263)(V263) (G31)(G31), have the structure | 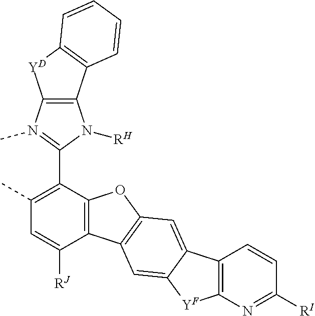 |
| L_{A64}(R^{H})(R^{I})(R^{J})(Y^{D})(Y^{F}), wherein L_{A64}(V1)(V1)(V1) (G1)(G1) to L_{A64}(V263)(V263)(V263) (G31)(G31), have the structure | 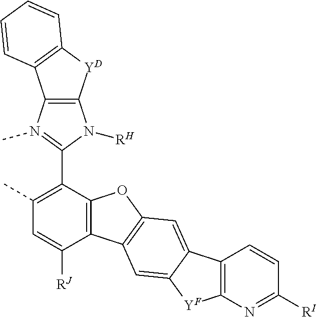 |
| L_{A65}(R^{H})(R^{I})(R^{J})(Y^{D})(Y^{F}), wherein L_{A65}(V1)(V1)(V1) (G1)(G1) to L_{A65}(V263)(V263)(V263) (G31)(G31), have the structure | 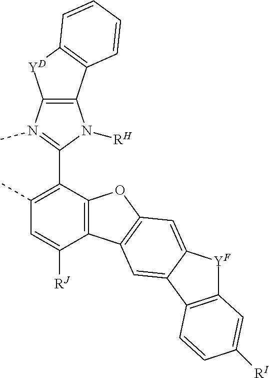 |
| L_{A66}(R^{H})(R^{I})(R)(Y)(Y^{F}), wherein L_{A66}(V1)(V1)(V1) (G1)(G1) to L_{A66}(V263)(V263)(V263) (G31)(G31), have the structure | 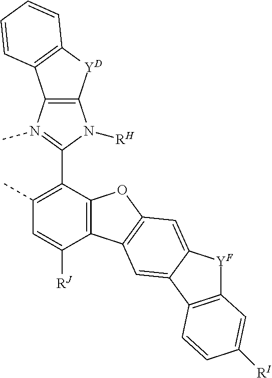 |
| L_{A67}(R^{H})(R^{I})(R)(Y)(Y^{F}), wherein L_{A67}(V1)(V1)(V1) (G1)(G1) to L_{A67}(V263)(V263)(V263) (G31)(G31), have the structure | 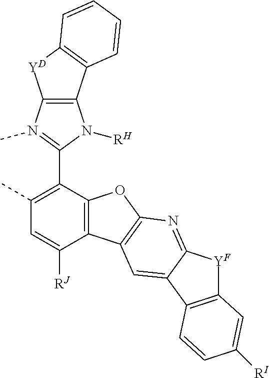 |
| L_{A68}(R^{H})(R^{I})(R^{J})(Y^{D})(Y^{F}), wherein L_{A68}(V1)(V1)(V1) (G1)(G1) to L_{A68}(V263)(V263)(V263) (G31)(G31), have the structure | 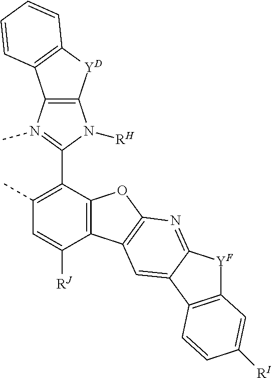 |
| L_{A69}(R^{H})(R^{I})(R^{J})(Y^{D})(Y^{F}), wherein L_{A69}(V1)(V1)(V1) (G1)(G1) to L_{A69}(V263)(V263)(V263) (G31)(G31), have the structure | 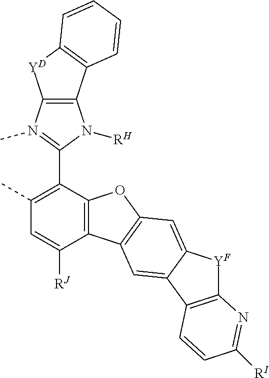 |
| L_{A70}(R^{H})(R^{I})(R^{J})(Y^{D})(Y^{F}), wherein L_{A70}(V1)(V1)(V1) (G1)(G1) to L_{A70}(V263)(V263)(V263) (G31)(G31), have the structure | 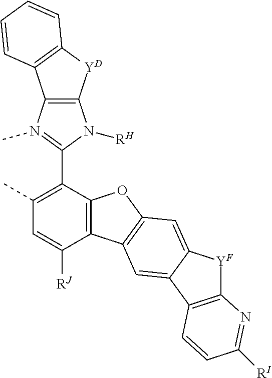 |
| L_{A71}(R^{H})(R^{I})(R^{J})(Y^{D})(Y^{F}), wherein L_{A71}(V1)(V1)(V1) (G1)(G1) to L_{A71}(V263)(V263)(V263) (G31)(G31), have the structure | 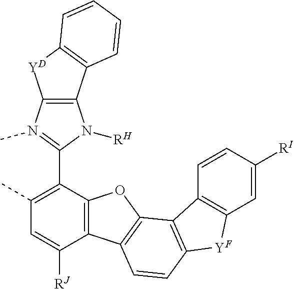 |
| L_{A72}(R^{H})(R^{I})(R^{J})(Y^{D})(Y^{F}), wherein L_{A72}(V1)(V1)(V1) (G1)(G1) to L_{A72}(V263)(V263)(V263) (G31)(G31), have the structure | 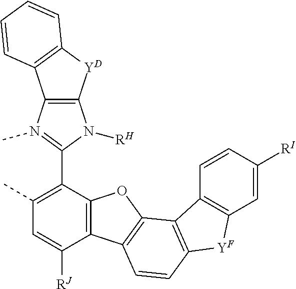 |
| L_{A73}(R^{H})(R^{I})(R^{J})(Y^{D})(Y^{F}), wherein L_{A73}(V1)(V1)(V1) (G1)(G1) to L_{A73}(V263)(V263)(V263) (G31)(G31), have the structure | 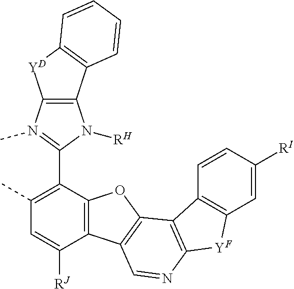 |
| L_{A74}(R^{H})(R^{I})(R^{J})(Y^{D})(Y^{F}), wherein L_{A74}(V1)(V1)(V1) (G1)(G1) to L_{A74}(V263)(V263)(V263) (G31)(G31), have the structure | 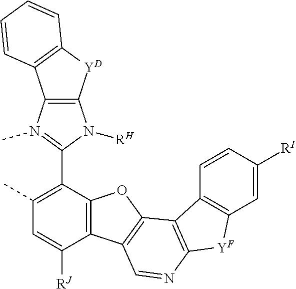 |
| L_{A75}(R^{H})(R^{I})(R^{J})(Y^{D})(Y^{F}), wherein L_{A75}(V1)(V1)(V1) (G1)(G1) to L_{A75}(V263)(V263)(V263) (G31)(G31), have the structure | 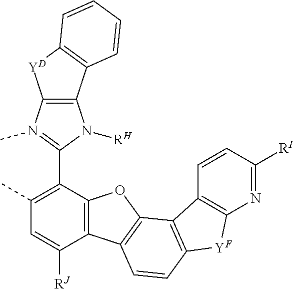 |
| L_{A76}(R^{H})(R^{I})(R^{J})(Y^{D})(Y^{F}), wherein L_{A76}(V1)(V1)(V1) (G1)(G1) to L_{A76}(V263)(V263)(V263) (G31)(G31), have the structure | 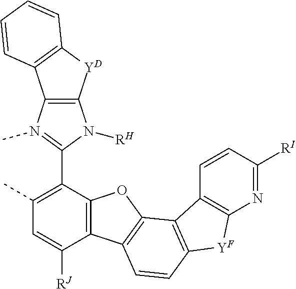 |
| L_{A77}(R^{H})(R^{I})(R^{J})(Y^{D})(Y^{F}), wherein L_{A77}(V1)(V1)(V1) (G1)(G1) to L_{A77}(V263)(V263)(V263) (G31)(G31), have the structure | 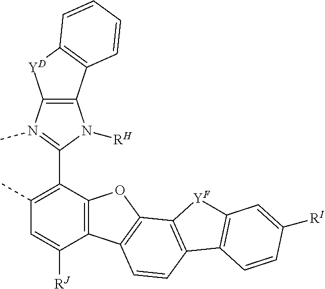 |
| L_{A78}(R^{H})(R^{I})(R^{J})(Y^{D})(Y^{F}), wherein L_{A78}(V1)(V1)(V1) (G1)(G1) to L_{A78}(V263)(V263)(V263) (G31)(G31), have the structure | 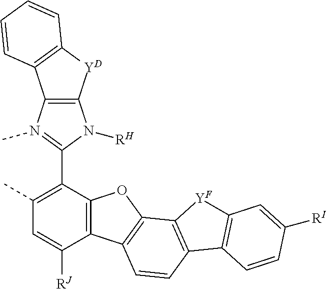 |
| L_{A79}(R^{H})(R^{I})(R^{J})(Y^{D})(Y^{F}), wherein L_{A79}(V1)(V1)(V1) (G1)(G1) to L_{A79}(V263)(V263)(V263) (G31)(G31), have the structure | 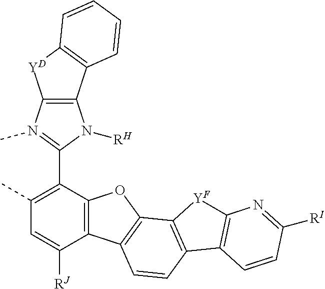 |
| L_{A80}(R^{H})(R^{I})(R^{J})(Y^{D})(Y^{F}), wherein L_{A80}(V1)(V1)(V1) (G1)(G1) to L_{A80}(V263)(V263)(V263) (G31)(G31), have the structure | 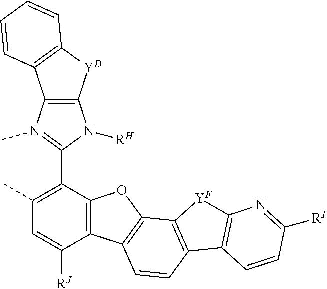 |
| L_{A81}(R^{H})(R^{I})(R^{J})(Y^{D})(Y^{F}), wherein L_{A81}(V1)(V1)(V1) (G1)(G1) to L_{A81}(V263)(V263)(V263) (G31)(G31), have the structure | 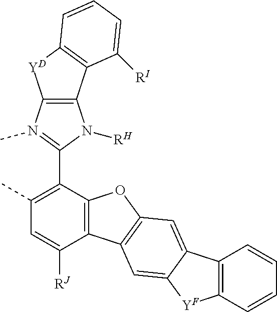 |
| L_{A82}(R^{H})(R^{I})(R^{J})(Y^{D})(Y^{F}), wherein L_{A82}(V1)(V1)(V1) (G1)(G1) to L_{A82}(V263)(V263)(V263) (G31)(G31), have the structure | 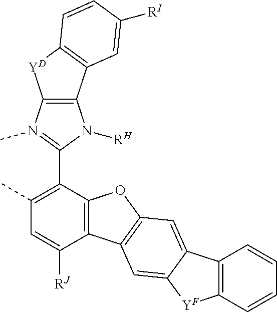 |
| L_{A83}(R^{H})(R^{I})(R^{J})(Y^{D})(Y^{F}), wherein L_{A83}(V1)(V1)(V1) (G1)(G1) to L_{A83}(V263)(V263)(V263) (G31)(G31), have the structure | 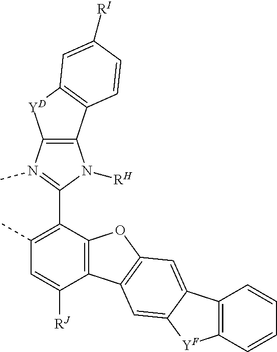 |
| L_{A84}(R^{H})(R^{I})(R^{J})(Y^{D})(Y^{F}), wherein L_{A84}(V1)(V1)(V1) (G1)(G1) to L_{A84}(V263)(V263)(V263) (G31)(G31), have the structure | 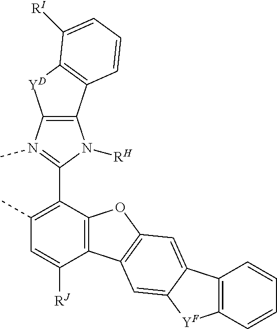 |
| L_{A85}(R^{H})(R^{I})(R^{J})(Y^{D})(Y^{F}), wherein L_{A85}(V1)(V1)(V1) (G1)(G1) to L_{A85}(V263)(V263)(V263) (G31)(G31), have the structure | 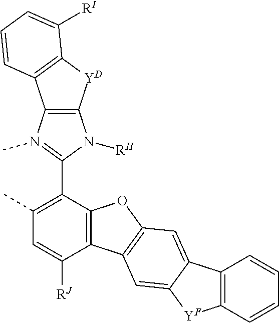 |
| L_{A86}(R^{H})(R^{I})(R^{J})(Y^{D}) (Y^{F}), wherein L_{A86}(V1)(V1)(V1) (G1)(G1) to L_{A86}(V263)(V263)(V263) (G31)(G31), have the structure | 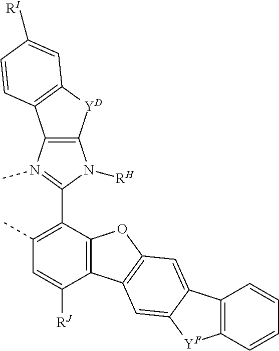 |
| L_{A87}(R^{H})(R^{I})(R^{J})(Y^{D})(Y^{F}), wherein L_{A87}(V1)(V1)(V1) (G1)(G1) to L_{A87}(V263)(V263)(V263) (G31)(G31), have the structure | 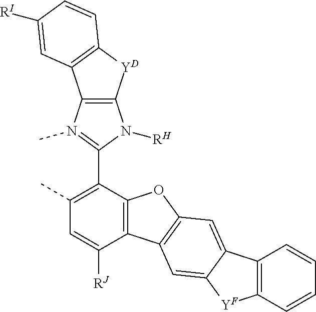 |
| L_{A88}(R^{H})(R^{I})(R^{J})(Y^{D})(Y^{F}), wherein L_{A88}(V1)(V1)(V1) (G1)(G1) to L_{A88}(V263)(V263)(V263) (G31)(G31), have the structure | 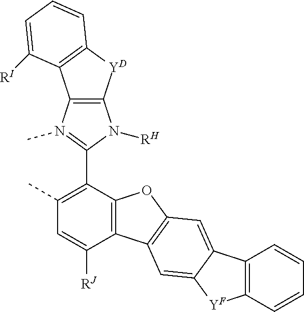 |
| L_{A89}(R^{H})(R^{I})(R^{J})(Y^{D})(Y^{F}), wherein L_{A89}(V1)(V1)(V1) (G1)(G1) to L_{A89}(V263)(V263)(V263) (G31)(G31), have the structure | 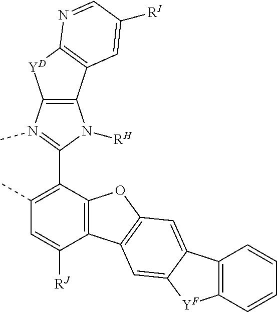 |
| L_{A90}(R^{H})(R^{I})(R^{J})(Y^{D})(Y^{F}), wherein L_{A90}(V1)(V1)(V1) (G1)(G1) to L_{A90}(V263)(V263)(V263) (G31)(G31), have the structure | 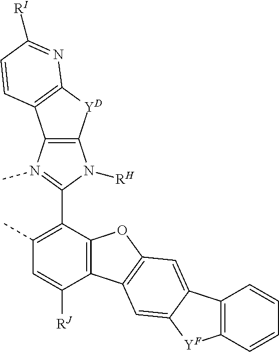 |
| L_{A91}-(R^{H})(R^{I})(R^{J})(Y^{D}), wherein L_{A91}- (V1)(V1)(V1)(G1) to L_{A91}- (V263)(V263)(V263)(G31), have the structure | 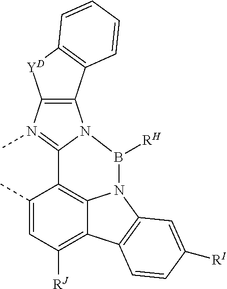 |
| L_{A92}-(R^{H})(R^{I})(R^{J})(Y^{D}), wherein L_{A92}- (V1)(V1)(V1)(G1) to L_{A92}- (V263)(V263)(V263)(G31), have the structure | 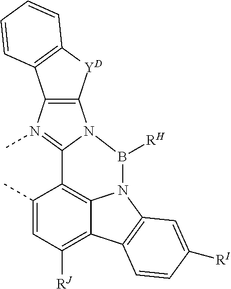 |
| L_{A93}-(R^{H})(R^{I})(R^{J})(Y^{D}), wherein L_{A93}- (V1)(V1)(V1)(G1) to L_{A93}- (V263)(V263)(V263)(G31), have the structure | 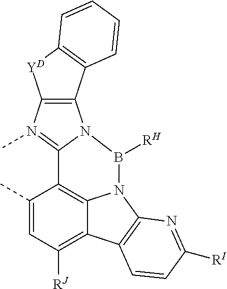 |
| L_{A94}-(R^{H})(R^{I})(R^{J})(Y^{D}), wherein L_{A94}- (V1)(V1)(V1)(G1) to L_{A94}- (V263)(V263)(V263)(G31), have the structure | 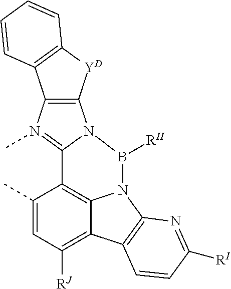 |
| L_{A95}-(R^{H})(R^{I})(R^{J})(Y^{D}), wherein L_{A95}- (V1)(V1)(V1)(G1) to L_{A95}- (V263)(V263)(V263)(G31), have the structure | 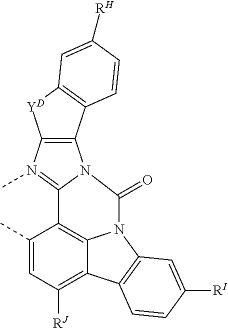 |
| L_{A96}-(R^{H})(R^{I})(R^{J})(Y^{D}), wherein L_{A96}- (V1)(V1)(V1)(G1) to L_{A96}- (V263)(V263)(V263)(G31), have the structure | 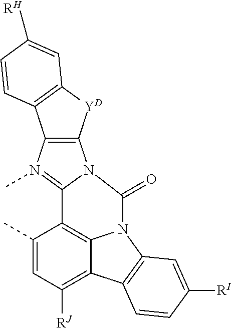 |
| L_{A97}-(R^{H})(R^{I})(R^{J})(Y^{D}), wherein L_{A97}- (V1)(V1)(V1)(G1) to L_{A97}- (V263)(V263)(V263)(G31), have the structure | 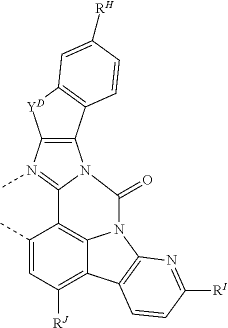 |
| L_{A98}-(R^{H})(R^{I})(R^{J})(Y^{D}), wherein L_{A98}- (V1)(V1)(V1)(G1) to L_{A98}- (V263)(V263)(V263)(G31), have the structure | 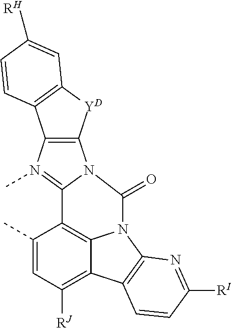 |
| L_{A99}-(R^{H})(R^{I})(R^{J})(Y^{D}), wherein L_{A99}- (V1)(V1)(V1)(G1) to L_{A99}- (V263)(V263)(V263)(G31), have the structure | 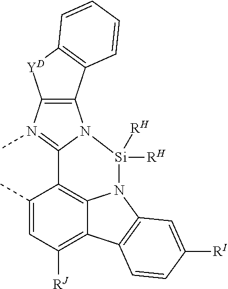 |
| L_{A100}-(R^{H})(R^{I})(R^{J})(Y^{D}), wherein L_{A100}- (V1)(V1)(V1)(G1) to L_{A100}- (V263)(V263)(V263)(G31), have the structure | 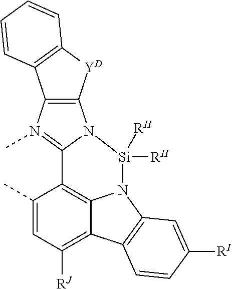 |
| L_{A101}-(R^{H})(R^{I})(R^{J})(Y^{D}), wherein L_{A101}- (V1)(V1)(V1)(G1) to L_{A101}- (V263)(V263)(V263)(G31), have the structure | 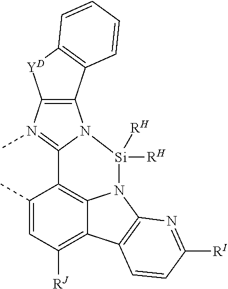 |
| L_{A102}-(R^{H})(R^{I})(R^{J})(Y^{D}), wherein L_{A102}- (V1)(V1)(V1)(G1) to L_{A102}- (V263)(V263)(V263)(G31), have the structure | 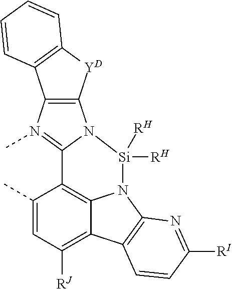 |
| L_{A103}-(R^{H})(R^{I})(R^{J})(Y^{D}), wherein L_{A103}- (V1)(V1)(V1)(G1) to L_{A103}- (V263)(V263)(V263)(G31), have the structure | 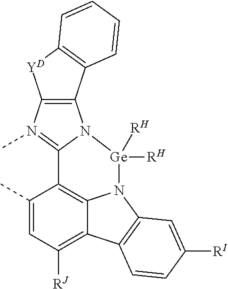 |
| L_{A104}-(R^{H})(R^{I})(R^{J})(Y^{D}), wherein L_{A104}- (V1)(V1)(V1)(G1) to L_{A104}- (V263)(V263)(V263)(G31), have the structure | 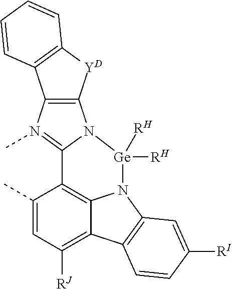 |
| L_{A105}-(R^{H})(R^{I})(R^{J})(Y^{D}), wherein L_{A105}- (V1)(V1)(V1)(G1) to L_{A105}- (V263)(V263)(V263)(G31), have the structure | 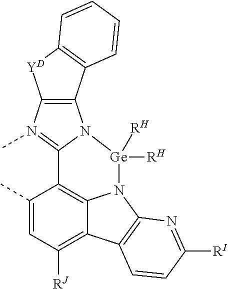 |
| L_{A106}-(R^{H})(R^{I})(R^{J})(Y^{D}), wherein L_{A106}- (V1)(V1)(V1)(G1) to L_{A106}- (V263)(V263)(V263)(G31), have the structure | 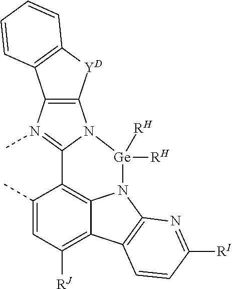 |
| L_{A107}-(R^{H})(R^{I})(R^{J})(Y^{D}), wherein L_{A107}- (V1)(V1)(V1)(G1) to L_{A107}- (V263)(V263)(V263)(G31), have the structure | 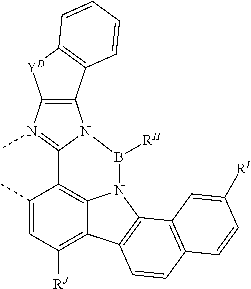 |
| L_{A108}-(R^{H})(R^{I})(R^{J})(Y^{D}), wherein L_{A108}- (V1)(V1)(V1)(G1) to L_{A108}- (V263)(V263)(V263)(G31), have the structure | 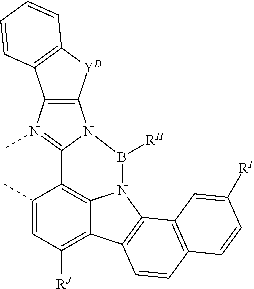 |
| L_{A109}-(R^{H})(R^{I})(R^{J})(Y^{D}), wherein L_{A109}- (V1)(V1)(V1)(G1) to L_{A109}- (V263)(V263)(V263)(G31), have the structure | 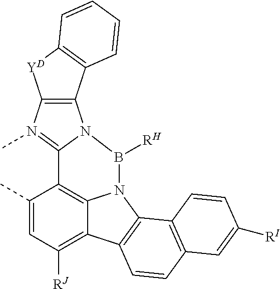 |
| L_{A110}-(R^{H})(R^{I})(R^{J})(Y^{D}), wherein L_{A110}- (V1)(V1)(V1)(G1) to L_{A110}- (V263)(V263)(V263)(G31), have the structure | 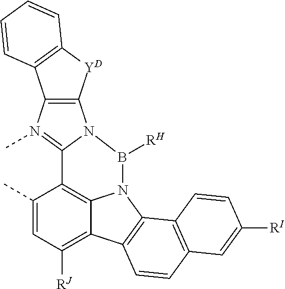 |
| L_{A111}-(R^{H})(R^{I})(R^{J})(Y^{D}), wherein L_{A111}- (V1)(V1)(V1)(G1) to L_{A111}- (V263)(V263)(V263)(G31), have the structure | 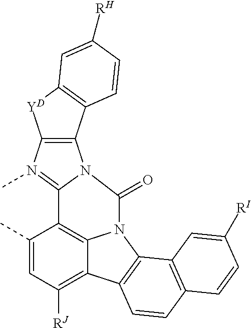 |
| L_{A112}-(R^{H})(R^{I})(R^{J})(Y^{D}), wherein L_{A112}- (V1)(V1)(V1)(G1) to L_{A112}- (V263)(V263)(V263)(G31), have the structure | 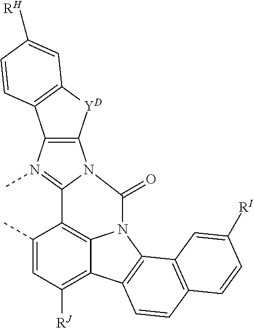 |
| L_{A113}-(R^{H})(R^{I})(R^{J})(Y^{D}), wherein L_{A113}- (V1)(V1)(V1)(G1) to L_{A113}- (V263)(V263)(V263)(G31), have the structure | 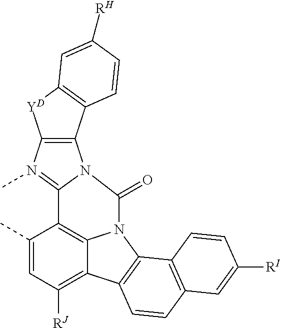 |
| L_{A114}-(R^{H})(R^{I})(R)(Y), wherein L_{A114}- (V1)(V1)(V1)(G1) to L_{A114}- (V263)(V263)(V263)(G31), have the structure | 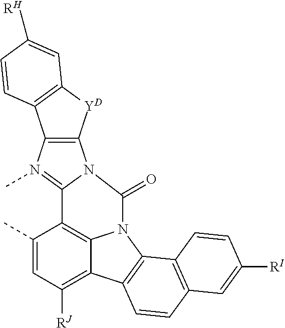 |
| L_{A115}-(R^{H})(R^{I})(R^{J})(Y^{D}), wherein L_{A115}- (V1)(V1)(V1)(G1) to L_{A115}- (V263)(V263)(V263)(G31), have the structure | 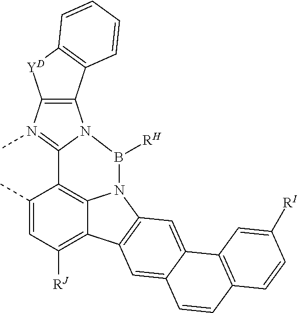 |
| L_{A116}-(R^{H})(R^{I})(R^{J})(Y^{D}), wherein L_{A116}- (V1)(V1)(V1)(G1) to L_{A116}- (V263)(V263)(V263)(G31), have the structure | 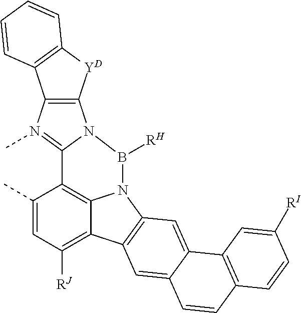 |
| L_{A117}-(R^{H})(R^{I})(R^{J})(Y^{D}), wherein L_{A117}- (V1)(V1)(V1)(G1) to L_{A117}- (V263)(V263)(V263)(G31), have the structure | 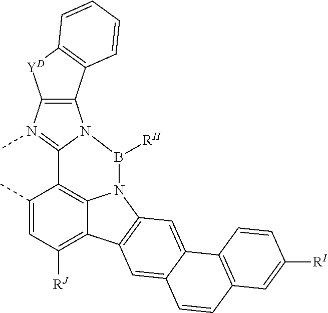 |
| L_{A118}-(R^{H})(R^{I})(R^{J})(Y^{D}), wherein L_{A118}- (V1)(V1)(V1)(G1) to L_{A118}- (V263)(V263)(V263)(G31), have the structure | 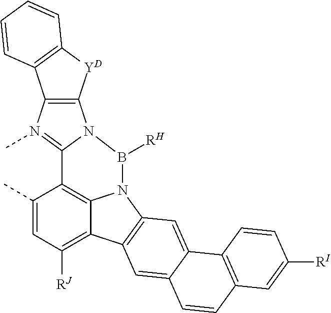 |
| L_{A119}-(R^{H})(R^{I})(R^{J})(Y^{D}), wherein L_{A119}- (V1)(V1)(V1)(G1) to L_{A119}- (V263)(V263)(V263)(G31), have the structure | 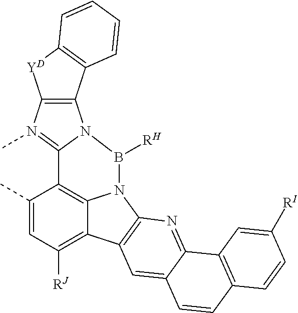 |
| L_{A120}-(R^{H})(R^{I})(R^{J})(Y^{D}), wherein L_{A120}- (V1)(V1)(V1)(G1) to L_{A120}- (V263)(V263)(V263)(G31), have the structure | 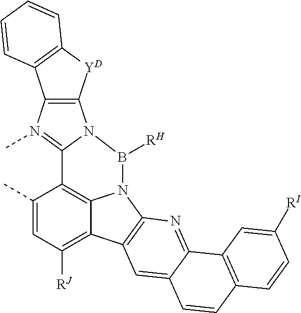 |
| L_{A121}-(R^{H})(R^{I})(R^{J})(Y^{D}), wherein L_{A121}- (V1)(V1)(V1)(G1) to L_{A121}- (V263)(V263)(V263)(G31), have the structure | 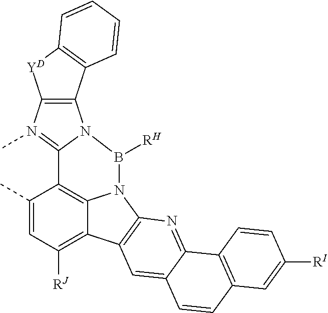 |
| L_{A122}-(R^{H})(R^{I})(R^{J})(Y^{D}), wherein L_{A122}- (V1)(V1)(V1)(G1) to L_{A122}- (V263)(V263)(V263)(G31), have the structure | 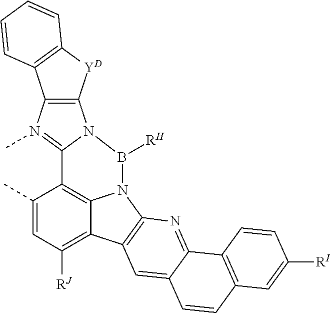 |
| L_{A123}-(R^{H})(R^{I})(R^{J})(Y^{D}), wherein L_{A123}- (V1)(V1)(V1)(G1) to L_{A123}- (V263)(V263)(V263)(G31), have the structure | 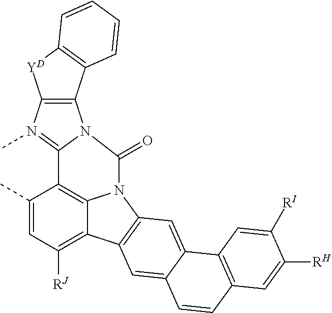 |
| L_{A124}-(R^{H})(R^{I})(R^{J})(Y^{D}), wherein L_{A124}- (V1)(V1)(V1)(G1) to L_{A124}- (V263)(V263)(V263)(G31), have the structure | 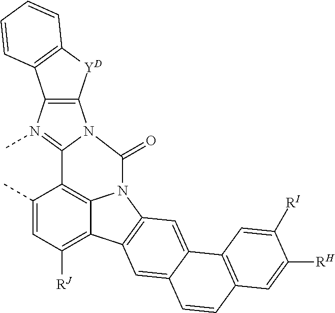 |
| L_{A125}-(R^{H})(R^{I})(R^{J})(Y^{D}), wherein L_{A125}- (V1)(V1)(V1)(G1) to L_{A125}- (V263)(V263)(V263)(G31), have the structure | 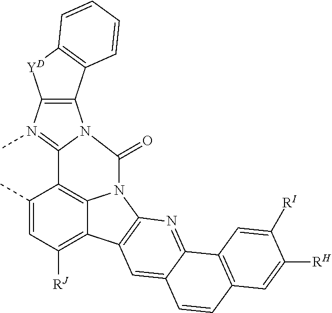 |
| L_{A126}-(R^{H})(R^{I})(R^{J})(Y^{D}), wherein L_{A126}- (V1)(V1)(V1)(G1) to L_{A126}- (V263)(V263)(V263)(G31), have the structure | 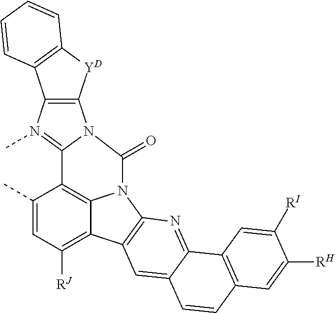 |
| L_{A127}-(R^{H})(R^{I})(R^{J})(Y^{D}), wherein L_{A127}- (V1)(V1)(V1)(G1) to L_{A127}- (V263)(V263)(V263)(G31), have the structure | 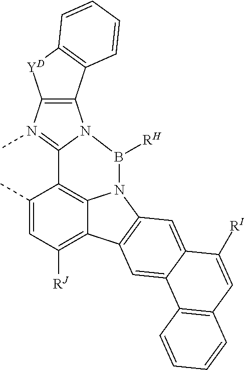 |
| L_{A128}-(R^{H})(R^{I})(R^{J})(Y^{D}), wherein L_{A128}- (V1)(V1)(V1)(G1) to L_{A128}- (V263)(V263)(V263)(G31), have the structure | 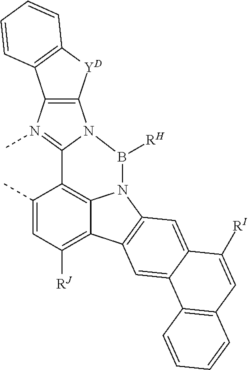 |
| L_{A129}-(R^{H})(R^{I})(R^{J})(Y^{D}), wherein L_{A129}- (V1)(V1)(V1)(G1) to L_{A129}- (V263)(V263)(V263)(G31), have the structure | 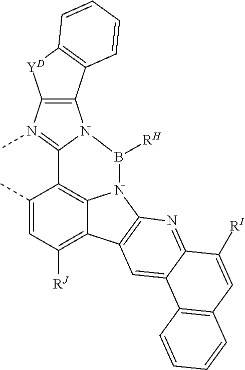 |
| L_{A130}-(R^{H})(R^{I})(R^{J})(Y^{D}), wherein L_{A130}- (V1)(V1)(V1)(G1) to L_{A130}- (V263)(V263)(V263)(G31), have the structure | 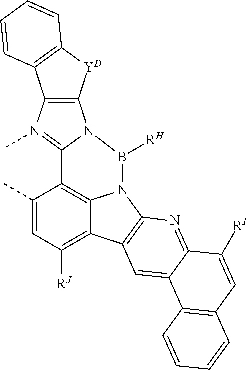 |
| L_{A131}-(R^{H})(R^{I})(R^{J})(Y^{D}), wherein L_{A131}- (V1)(V1)(V1)(G1) to L_{A131}- (V263)(V263)(V263)(G31), have the structure | 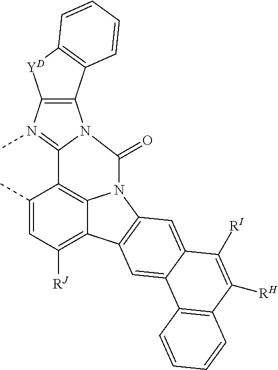 |
| L_{A132}-(R^{H})(R^{I})(R^{J})(Y^{D}), wherein L_{A132}- (V1)(V1)(V1)(G1) to L_{A132}- (V263)(V263)(V263)(G31), have the structure | 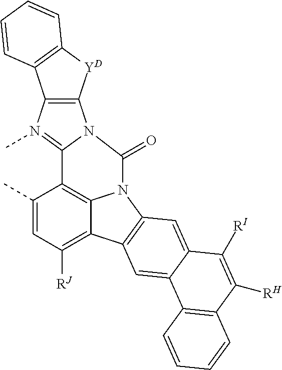 |
| L_{A133}-(R^{H})(R^{I})(R^{J})(Y^{D}), wherein L_{A133}- (V1)(V1)(V1)(G1) to L_{A133}- (V263)(V263)(V263)(G31), have the structure | 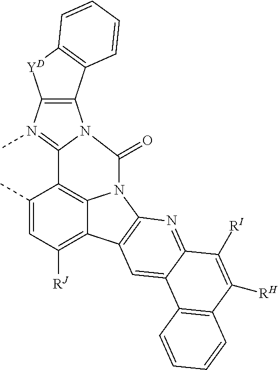 |
| L_{A134}-(R^{H})(R^{I})(R^{J})(Y^{D}), wherein L_{A134}- (V1)(V1)(V1)(G1) to L_{A134}- (V263)(V263)(V263)(G31), have the structure | 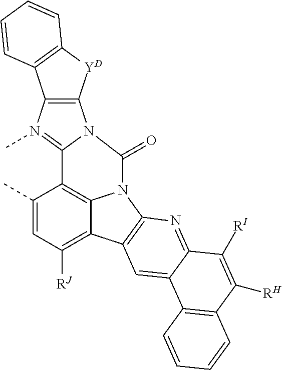 |
| L_{A135}-(R^{H})(R^{I})(R^{J})(Y^{D})(Y^{F}), wherein L_{A135}- (V1)(V1)(V1) (G1)(G1)to L_{A135}- (V263)(V263)(V263)(G31) (G31), have the structure | 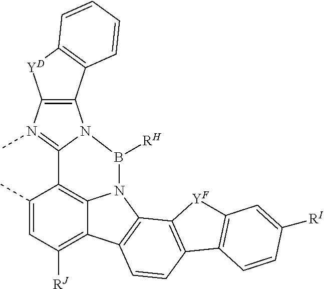 |
| L_{A136}-(R^{H})(R^{I})(R^{J})(Y^{D})(Y^{F}), wherein L_{A136}- (V1)(V1)(V1) (G1)(G1)to L_{A136}- (V263)(V263)(V263)(G31) (G31), have the structure | 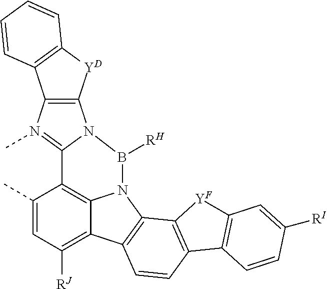 |
| L_{A137}-(R^{H})(R^{I})(R^{J})(Y^{D})(Y^{F}), wherein L_{A137}- (V1)(V1)(V1) (G1)(G1)to L_{A137}- (V263)(V263)(V263)(G31) (G31), have the structure | 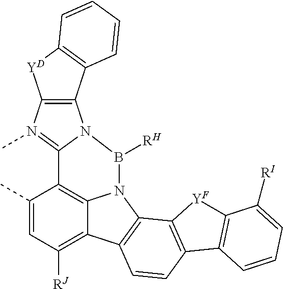 |
| L_{A138}-(R^{H})(R^{I})(R^{J})(Y^{D})(Y^{F}), wherein L_{A138}- (V1)(V1)(V1) (G1)(G1)to L_{A138}- (V263)(V263)(V263)(G31) (G31), have the structure | 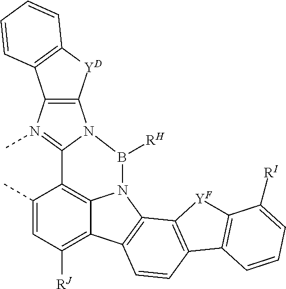 |
| L_{A139}-(R^{H})(R^{I})(R^{J})(Y^{D})(Y^{F}), wherein L_{A139}- (V1)(V1)(V1) (G1)(G1)to L_{A139}- (V263)(V263)(V263)(G31) (G31), have the structure | 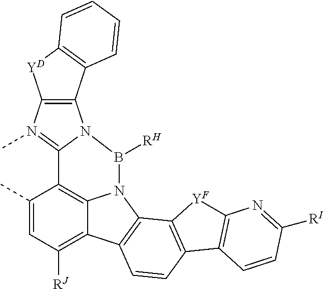 |
| L_{A140}-(R^{H})(R^{I})(R^{J})(Y^{D})(Y^{F}), wherein L_{A140}- (V1)(V1)(V1) (G1)(G1)to L_{A140}- (V263)(V263)(V263)(G31) (G31), have the structure | 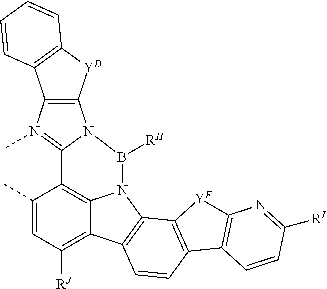 |
| L_{A141}-(R^{H})(R^{I})(R^{J})(Y^{D})(Y^{F}), wherein L_{A141}- (V1)(V1)(V1) (G1)(G1)to L_{A141}- (V263)(V263)(V263)(G31) (G31), have the structure | 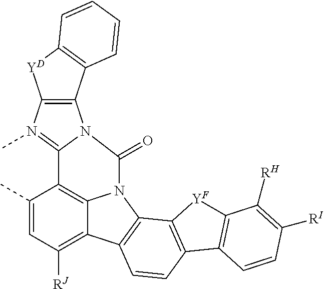 |
| L_{A142}-(R^{H})(R^{I})(R^{J})(Y^{D})(Y^{F}), wherein L_{A142}- (V1)(V1)(V1) (G1)(G1)to L_{A142}- (V263)(V263)(V263)(G31) (G31), have the structure | 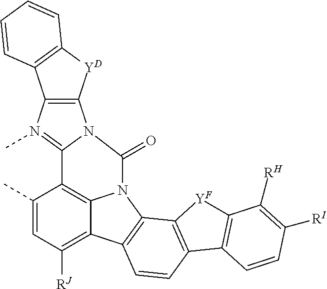 |
| L_{A143}-(R^{H})(R^{I})(R^{J})(Y^{D})(Y^{F}), wherein L_{A143}- (V1)(V1)(V1) (G1)(G1)to L_{A143}- (V263)(V263)(V263)(G31) (G31), have the structure | 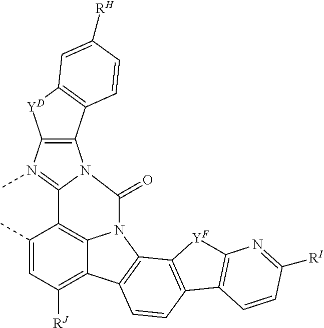 |
| L_{A144}-(R^{H})(R^{I})(R^{J})(Y^{D})(Y^{F}), wherein L_{A144}- (V1)(V1)(V1) (G1)(G1)to L_{A144}- (V263)(V263)(V263)(G31) (G31), have the structure | 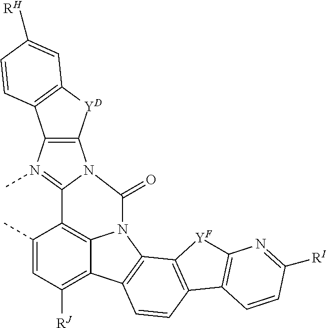 |
| L_{A145}-(R^{H})(R^{I})(R^{J})(Y^{D})(Y^{F}), wherein L_{A145}- (V1)(V1)(V1) (G1)(G1)to L_{A145}- (V263)(V263)(V263)(G31) (G31), have the structure | 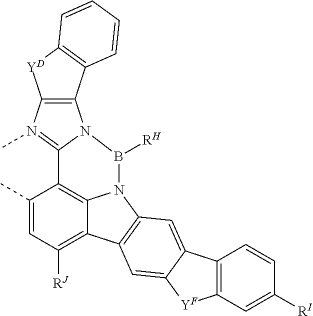 |
| L_{A146}-(R^{H})(R^{I})(R^{J})(Y^{D})(Y^{D}), wherein L_{A146}- (V1)(V1)(V1) (G1)(G1)to L_{A146}- (V263)(V263)(V263)(G31) (G31), have the structure | 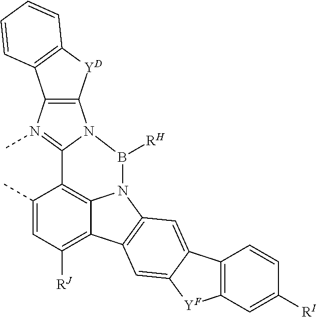 |
| L_{A147}-(R^{H})(R^{I})(R^{J})(Y^{D})(Y^{F}), wherein L_{A147}- (V1)(V1)(V1) (G1)(G1)to L_{A147}- (V263)(V263)(V263)(G31) (G31), have the structure | 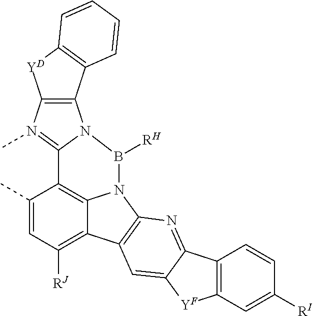 |
| L_{A148}-(R^{H})(R^{I})(R^{J})(Y^{D})(Y^{D}), wherein L_{A148}- (V1)(V1)(V1) (G1)(G1)to L_{A148}- (V263)(V263)(V263)(G31) (G31), have the structure | 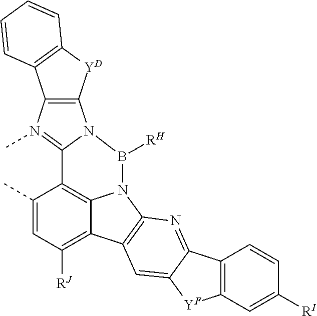 |
| L_{A149}-(R^{H})(R^{I})(R^{J})(Y^{D})(Y^{F}), wherein L_{A149}- (V1)(V1)(V1) (G1)(G1)to L_{A149}- (V263)(V263)(V263)(G31) (G31), have the structure | 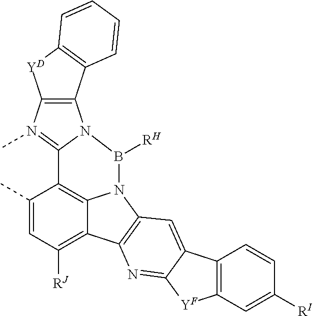 |
| L_{A150}-(R^{H})(R^{I})(R^{J})(Y^{D})(Y^{F}), wherein L_{A150}- (V1)(V1)(V1) (G1)(G1)to L_{A150}- (V263)(V263)(V263)(G31) (G31), have the structure | 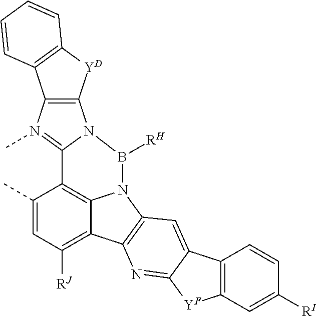 |
| L_{A151}-(R^{H})(R^{I})(R^{J})(Y^{D})(Y^{F}), wherein L_{A151}- (V1)(V1)(V1) (G1)(G1)to L_{A151}- (V263)(V263)(V263)(G31) (G31), have the structure | 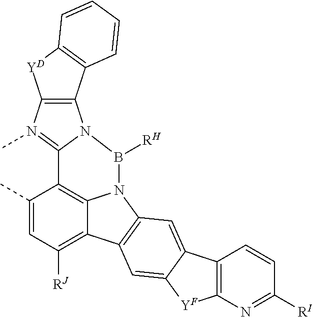 |
| L_{A152}-(R^{H})(R^{I})(R^{J})(Y^{D})(Y^{F}), wherein L_{A152}- (V1)(V1)(V1) (G1)(G1)to L_{A152}- (V263)(V263)(V263)(G31) (G31), have the structure | 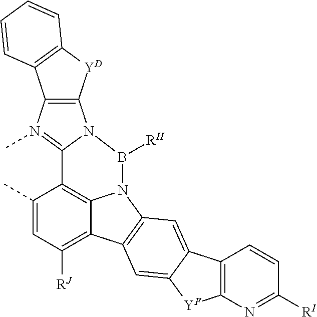 |
| L_{A153}-(R^{H})(R^{I})(R^{J})(Y^{D})(Y^{F}), wherein L_{A153}- (V1)(V1)(V1) (G1)(G1)to L_{A153}- (V263)(V263)(V263)(G31) (G31), have the structure | 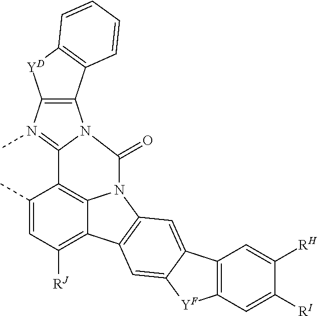 |
| L_{A154}-(R^{H})(R^{I})(R^{J})(Y^{D})(Y^{F}), wherein L_{A154}- (V1)(V1)(V1) (G1)(G1)to L_{A154}- (V263)(V263)(V263)(G31) (G31), have the structure | 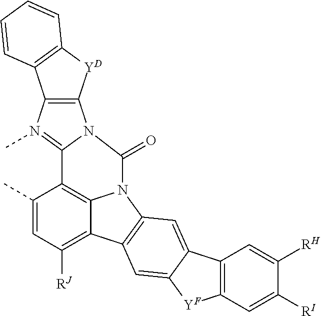 |
| L_{A155}-(R^{H})(R^{I})(R^{J})(Y^{D})(Y^{F}), wherein L_{A155}- (V1)(V1)(V1) (G1)(G1)to L_{A155}- (V263)(V263)(V263)(G31) (G31), have the structure | 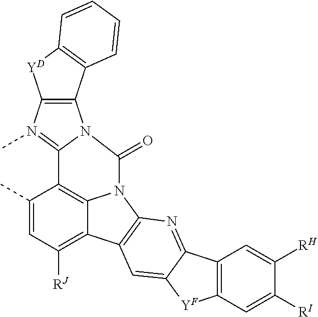 |
| L_{A156}-(R^{H})(R^{I})(R^{J})(Y^{D})(Y^{F}), wherein L_{A156}- (V1)(V1)(V1) (G1)(G1)to L_{A156}- (V263)(V263)(V263)(G31) (G31), have the structure | 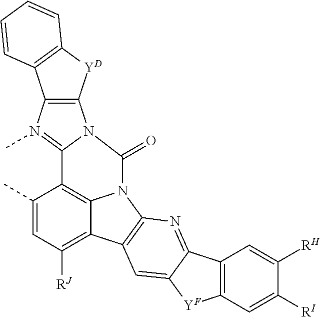 |
| L_{A157}-(R^{H})(R^{I})(R^{J})(Y^{D})(Y^{F}), wherein L_{A157}- (V1)(V1)(V1) (G1)(G1)to L_{A157}- (V263)(V263)(V263)(G31) (G31), have the structure | 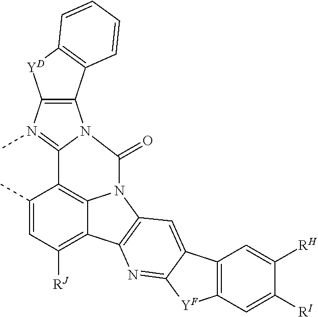 |
| L_{A158}-(R^{H})(R^{I})(R^{J})(Y^{D})(Y^{F}), wherein L_{A158}- (V1)(V1)(V1) (G1)(G1)to L_{A158}- (V263)(V263)(V263)(G31) (G31), have the structure | 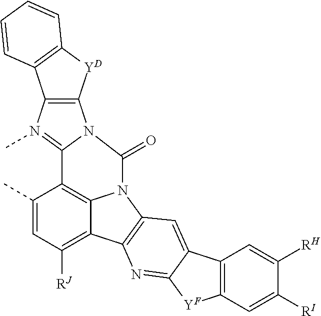 |
| L_{A159}-(R^{H})(R^{I})(R^{J})(Y^{D})(Y^{F}), wherein L_{A159}- (V1)(V1)(V1) (G1)(G1)to L_{A159}- (V263)(V263)(V263)(G31) (G31), have the structure | 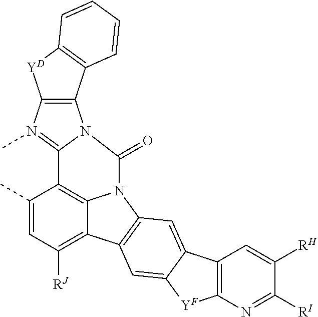 |
| L_{A160}-(R^{H})(R^{I})(R^{J})(Y^{D})(Y^{F}), wherein L_{A160}- (V1)(V1)(V1) (G1)(G1)to L_{A160}- (V263)(V263)(V263)(G31) (G31), have the structure | 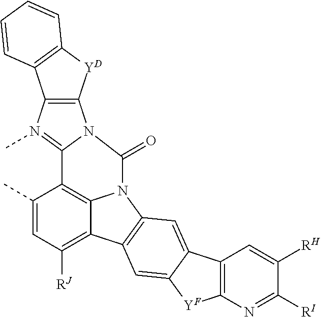 |
| L_{A161}-(R^{H})(R^{I})(R^{J})(Y^{D})(Y^{F}), wherein L_{A161}- (V1)(V1)(V1) (G1)(G1)to L_{A161}- (V263)(V263)(V263)(G31) (G31), have the structure | 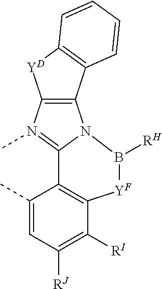 |
| L_{A162}-(R^{H})(R^{I})(R^{J})(Y^{D})(Y^{F}), wherein L_{A162}- (V1)(V1)(V1) (G1)(G1)to L_{A162}- (V263)(V263)(V263)(G31) (G31), have the structure | 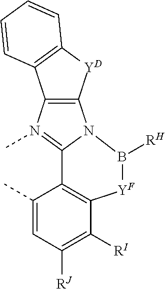 |
| L_{A163}-(R^{H})(R^{I})(R^{J})(Y^{D})(Y^{F}), wherein L_{A163}- (V1)(V1)(V1) (G1)(G1)to L_{A163}- (V263)(V263)(V263)(G31) (G31), have the structure | 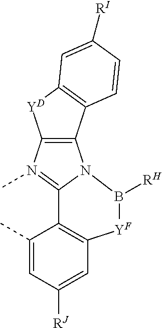 |
| L_{A164}-(R^{H})(R^{I})(R^{J})(Y^{D})(Y^{F}), wherein L_{A164}- (V1)(V1)(V1) (G1)(G1)to L_{A164}- (V263)(V263)(V263)(G31) (G31), have the structure | 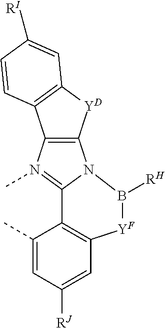 |
| L_{A165}-(R^{H})(R^{I})(R^{J})(Y^{D})(Y^{F}), wherein L_{A165}- (V1)(V1)(V1) (G1)(G1)to L_{A165}- (V263)(V263)(V263)(G3 1)(G31), have the structure | 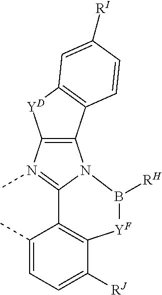 |
| L_{A166}-(R^{H})(R^{I})(R^{J})(Y^{D})(Y^{F}), wherein L_{A166}- (V1)(V1)(V1) (G1)(G1)to L_{A166}- (V263)(V263)(V263)(G31) (G31), have the structure | 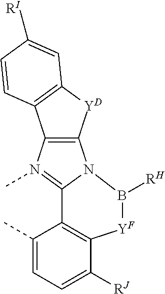 |
| L_{A167}-(R^{H})(R^{I})(R^{J})(Y^{D})(Y^{F}), wherein L_{A167}- (V1)(V1)(V1) (G1)(G1)to L_{A167}- (V263)(V263)(V263)(G31) (G31), have the structure | 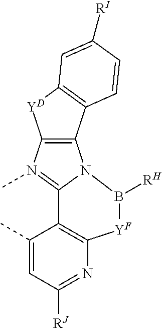 |
| L_{A168}-(R^{H})(R^{I})(R^{J})(Y^{D})(Y^{F}), wherein L_{A168}- (V1)(V1)(V1) (G1)(G1)to L_{A168}- (V263)(V263)(V263)(G31) (G31), have the structure | 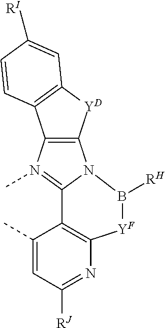 |
| L_{A169}-(R^{H})(R^{I})(R^{J})(Y^{D})(Y^{F}), wherein L_{A169}- (V1)(V1)(V1) (G1)(G1)to L_{A169}- (V263)(V263)(V263)(G31) (G31), have the structure | 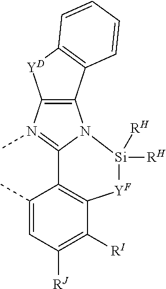 |
| L_{A170}-(R^{H})(R^{I})(R^{J})(Y^{D})(Y^{F}), wherein L_{A170}- (V1)(V1)(V1) (G1)(G1)to L_{A170}- (V263)(V263)(V263)(G31) (G31), have the structure | 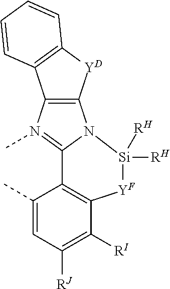 |
| L_{A171}-(R^{H})(R^{I})(R^{J})(Y^{D})(Y^{F}), wherein L_{A171}- (V1)(V1)(V1) (G1)(G1)to L_{A171}- (V263)(V263)(V263)(G31) (G31), have the structure | 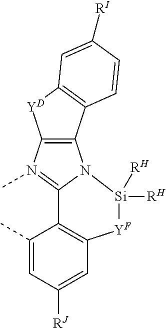 |
| L_{A172}-(R^{H})(R^{I})(R^{J})(Y^{D})(Y^{D}), wherein L_{A172}- (V1)(V1)(V1) (G1)(G1)to L_{A172}- (V263)(V263)(V263)(G31) (G31), have the structure | 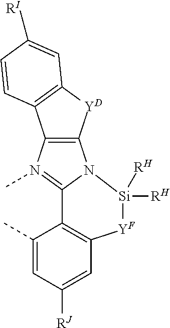 |
| L_{A173}-(R^{H})(R^{I})(R^{J})(Y^{D})(Y^{F}), wherein L_{A173}- (V1)(V1)(V1) (G1)(G1)to L_{A173}- (V263)(V263)(V263)(G31) (G31), have the structure | 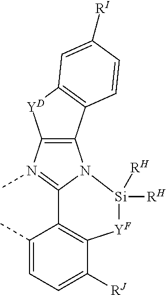 |
| L_{A174}-(R^{H})(R^{I})(R^{J})(Y^{D})(Y^{F}), wherein L_{A174}- (V1)(V1)(V1) (G1)(G1)to L_{A174}- (V263)(V263)(V263)(G31) (G31), have the structure | 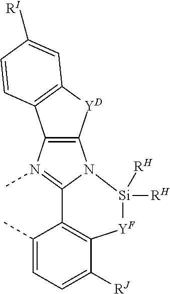 |
| L_{A175}-(R^{H})(R^{I})(R^{J})(Y^{D})(Y^{F}), wherein L_{A175}- (V1)(V1)(V1) (G1)(G1)to L_{A175}- (V263)(V263)(V263)(G31) (G31), have the structure | 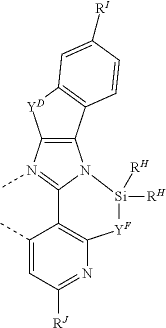 |
| L_{A176}-(R^{H})(R^{I})(R^{J})(Y^{D})(Y^{F}), wherein L_{A176}- (V1)(V1)(V1) (G1)(G1)to L_{A176}- (V263)(V263)(V263)(G31) (G31), have the structure | 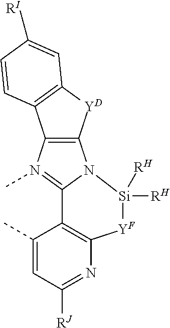 |
| L_{A177}-(R^{H})(R^{I})(R^{J})(Y^{D})(Y^{F}), wherein L_{A177}- (V1)(V1)(V1) (G1)(G1)to L_{A177}- (V263)(V263)(V263)(G31) (G31), have the structure | 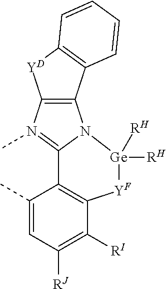 |
| L_{A178}-(R^{H})(R^{I})(R^{J})(Y^{D})(Y^{F}), wherein L_{A178}- (V1)(V1)(V1) (G1)(G1)to L_{A178}- (V263)(V263)(V263)(G31) (G31), have the structure | 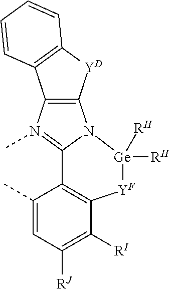 |
| L_{A179}-(R^{H})(R^{I})(R^{J})(Y^{D})(Y^{F}), wherein L_{A179}- (V1)(V1)(V1) (G1)(G1)to L_{A179}- (V263)(V263)(V263)(G31) (G31), have the structure | 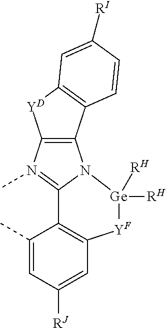 |
| L_{A180}-(R^{H})(R^{I})(R^{J})(Y^{D})(Y^{F}), wherein L_{A180}- (V1)(V1)(V1) (G1)(G1)to L_{A180}- (V263)(V263)(V263)(G31) (G31), have the structure | 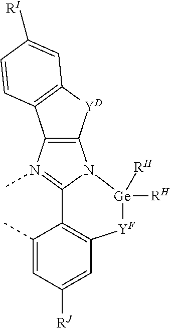 |
| L_{A181}-(R^{H})(R^{I})(R^{J})(Y^{D})(Y^{F}), wherein L_{A181}- (V1)(V1)(V1) (G1)(G1)to L_{A181}- (V263)(V263)(V263)(G31) (G31), have the structure | 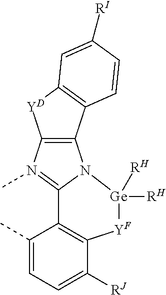 |
| L_{A182}-(R^{H})(R^{I})(R^{J})(Y^{D})(Y^{F}), wherein L_{A182}- (V1)(V1)(V1) (G1)(G1)to L_{A182}- (V263)(V263)(V263)(G31) (G31), have the structure | 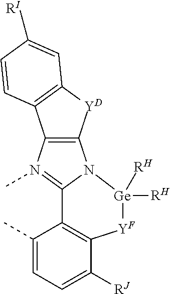 |
| L_{A183}-(R^{H})(R^{I})(R^{J})(Y^{D})(Y^{F}), wherein L_{A183}- (V1)(V1)(V1) (G1)(G1)to L_{A183}- (V263)(V263)(V263)(G31) (G31), have the structure | 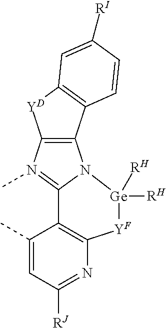 |
| L_{A184}-(R^{H})(R^{I})(R^{J})(Y^{D})(Y^{F}), wherein L_{A184}- (V1)(V1)(V1) (G1)(G1)to L_{A184}- (V263)(V263)(V263)(G31) (G31), have the structure | 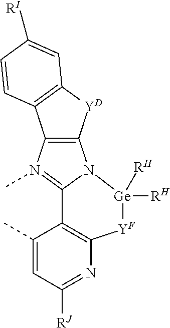 |
| L_{A185}-(R^{I})(R^{J})(Y^{D})(Y^{F}), wherein L_{A185}- (V1)(V1)(G1)(G1)to L_{A185}- (V263)(V263)(G31)(G31), have the structure | 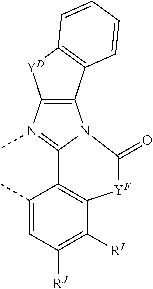 |
| L_{A186}-(R^{I})(R^{J})(Y^{D})(Y^{F}), wherein L_{A186}- (V1)(V1)(G1)(G1)to L_{A186}- (V263)(V263)(G31)(G31), have the structure | 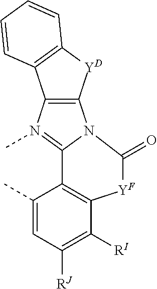 |
| L_{A187}-(R^{I})(R^{J})(Y^{D})(Y^{F}), wherein L_{A187}- (V1)(V1)(G1)(G1)to L_{A187}- (V263)(V263)(G31)(G31), have the structure | 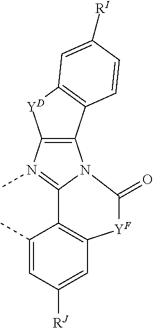 |
| L_{A188}-(R^{I})(R^{J})(Y^{D})(Y^{F}), wherein L_{A188}- (V1)(V1)(G1)(G1)to L_{A188}- (V263)(V263)(G31)(G31), have the structure | 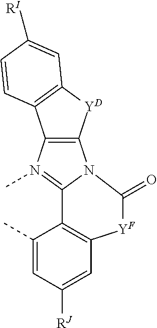 |
| L_{A189}-(R^{I})(R^{J})(Y^{D})(Y^{F}), wherein L_{A189}- (V1)(V1)(G1)(G1)to L_{A189}- (V263)(V263)(G31)(G31), have the structure | 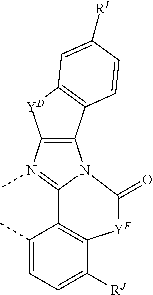 |
| L_{A190}-(R^{I})(R^{J})(Y^{D})(Y^{F}), wherein L_{A190}- (V1)(V1)(G1)(G1)to L_{A190}- (V263)(V263)(G31)(G31), have the structure | 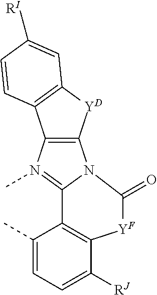 |
| L_{A191}-(R^{I})(R^{J})(Y^{D})(Y^{F}), wherein L_{A191}- (V1)(V1)(G1)(G1)to L_{A191}- (V263)(V263)(G31)(G31), have the structure | 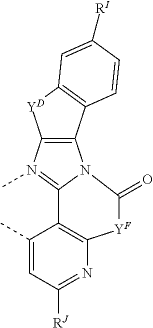 |
| L_{A192}-(R^{I})(R^{J})(Y^{D})(Y^{F}), wherein L_{A192}- (V1)(V1)(G1)(G1)to L_{A192}- (V263)(V263)(G31)(G31), have the structure | 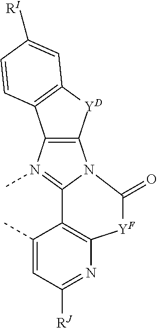 |

wherein V1 to V263 have the following structures as defined in the following LIST 14:

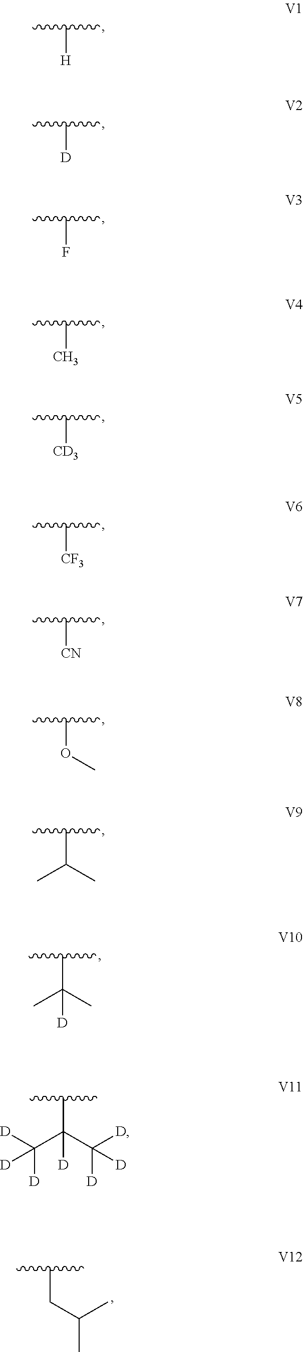

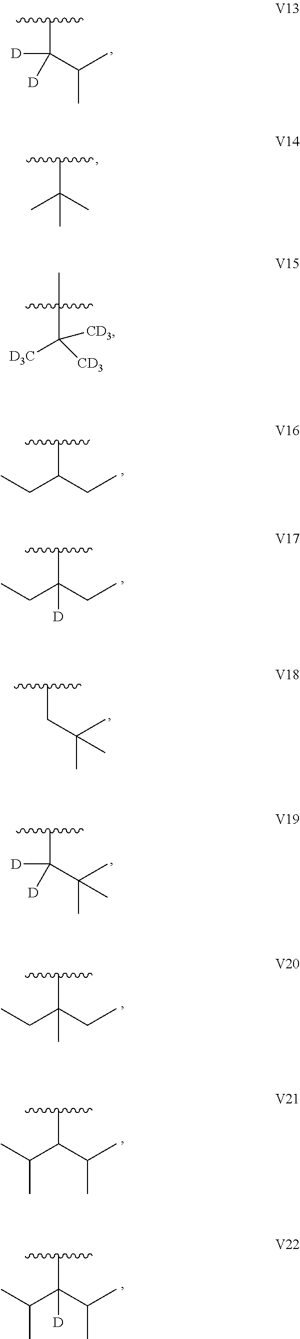

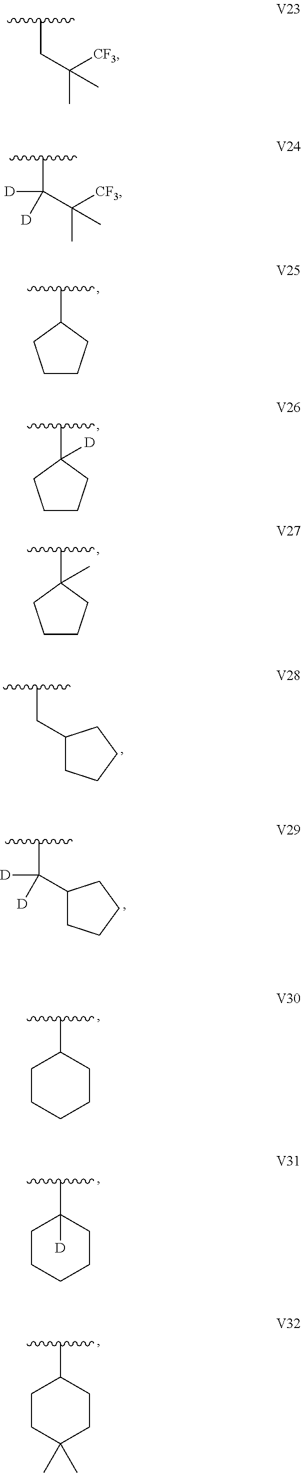

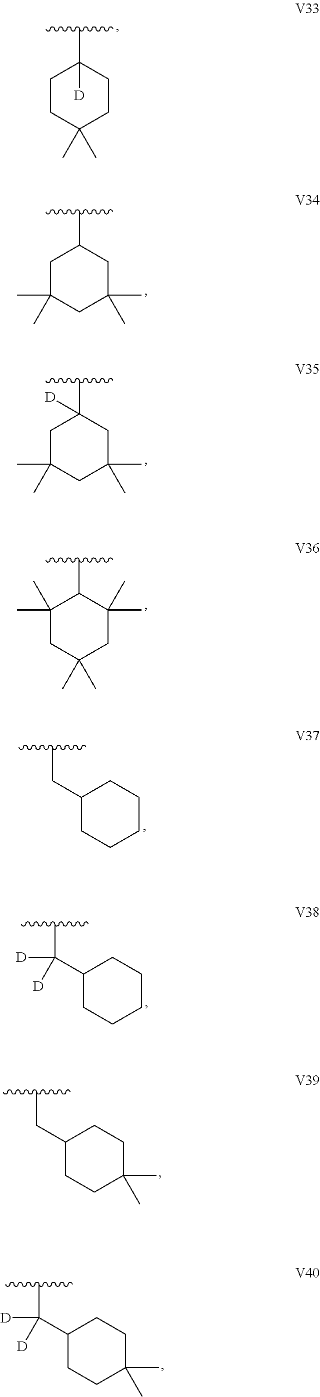

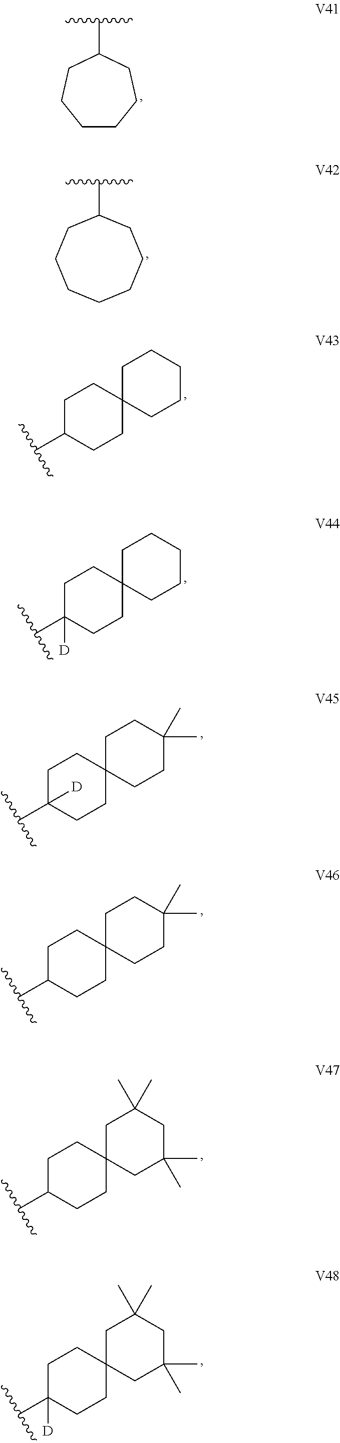

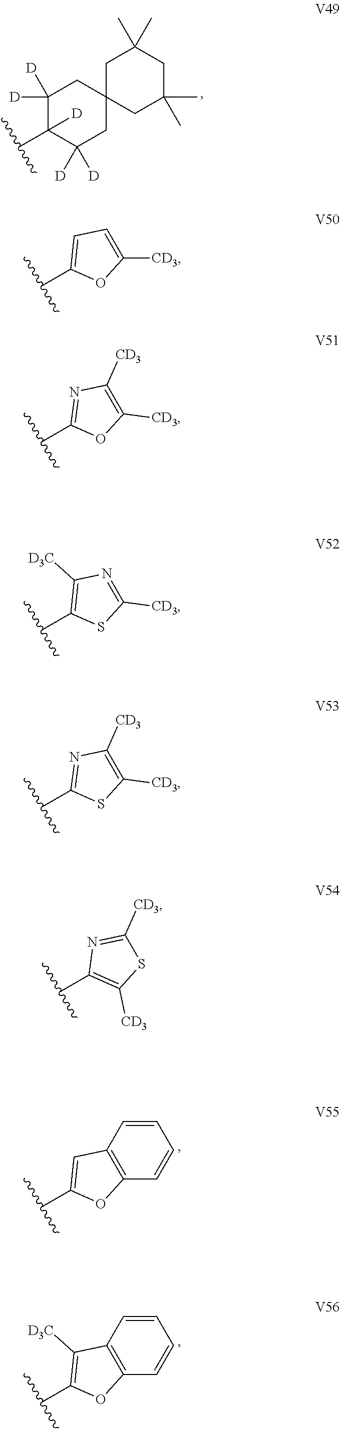

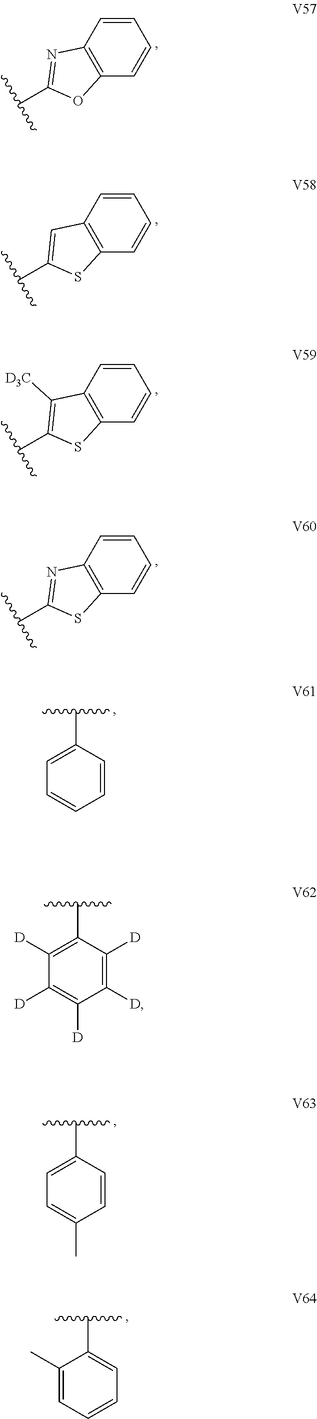

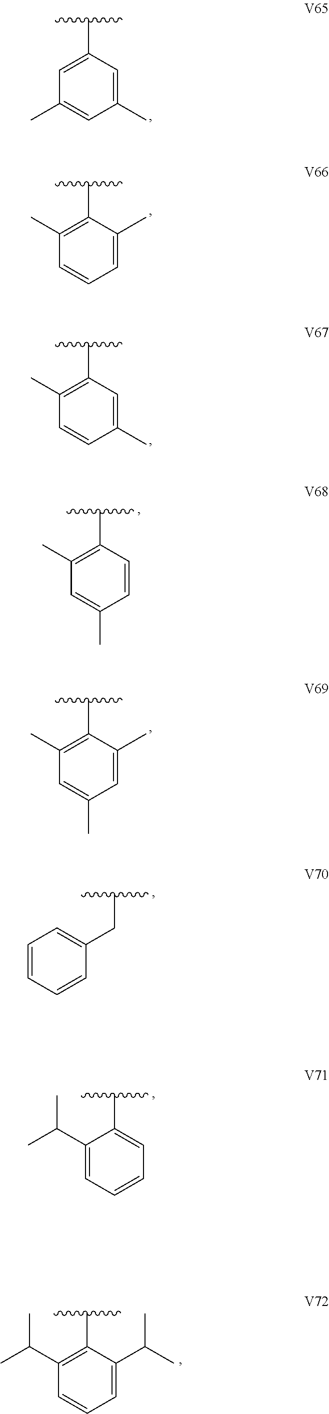

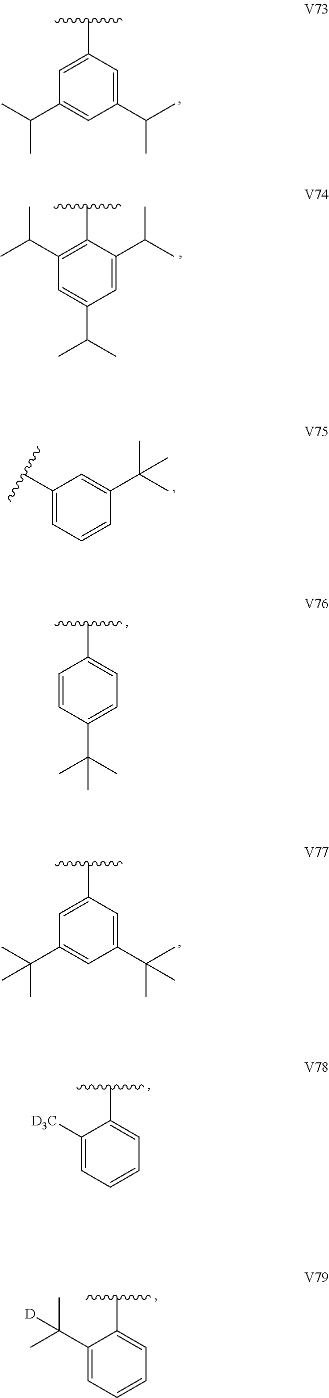

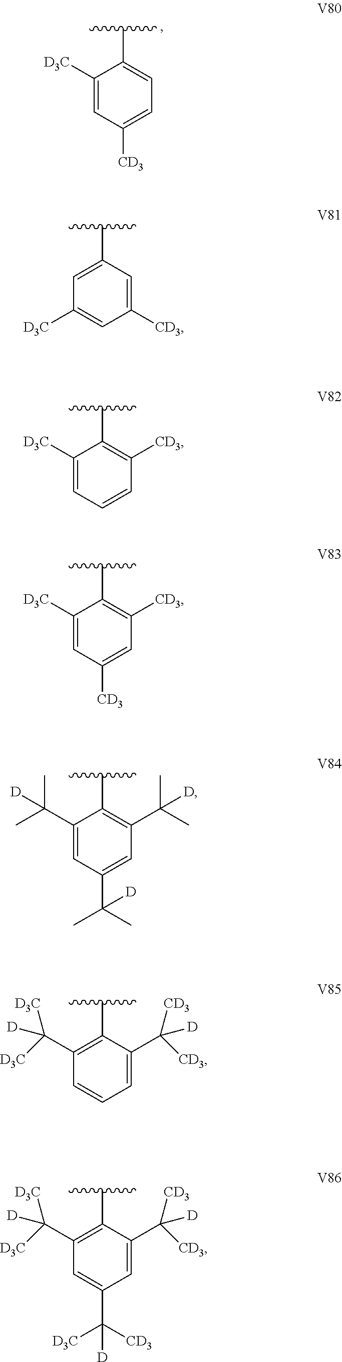

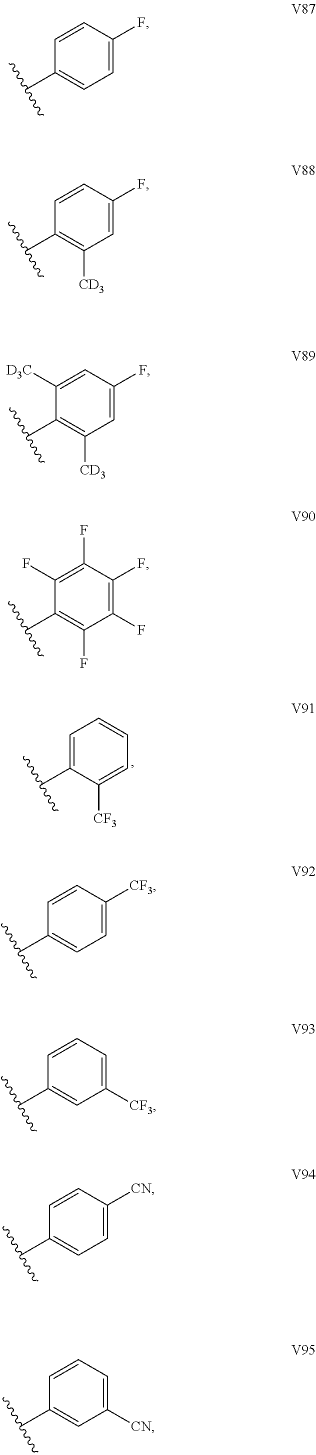

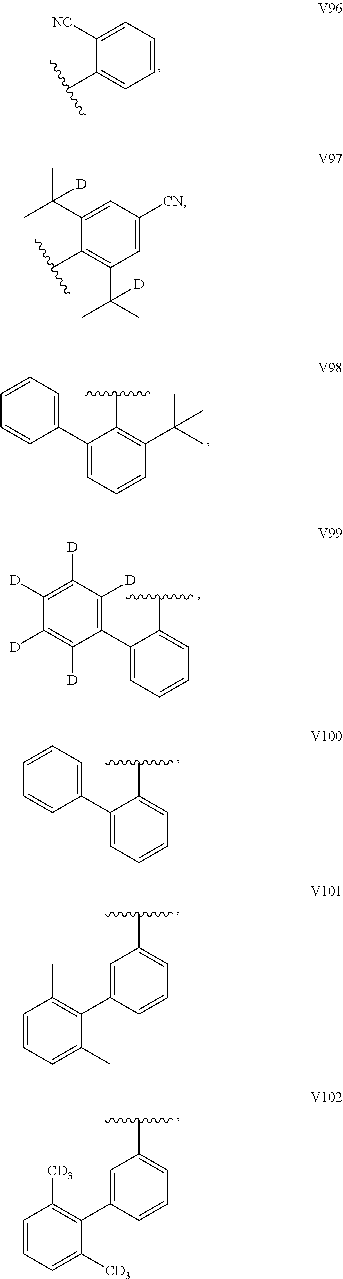

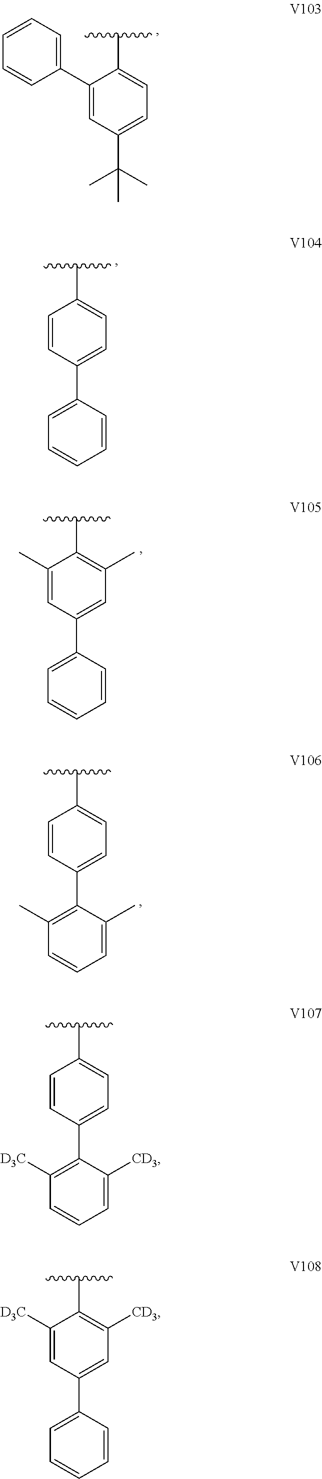

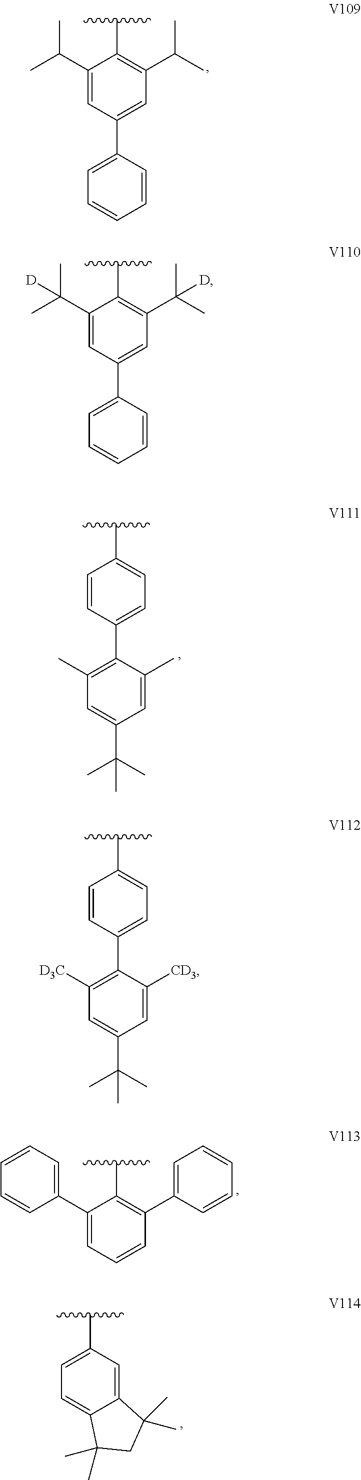

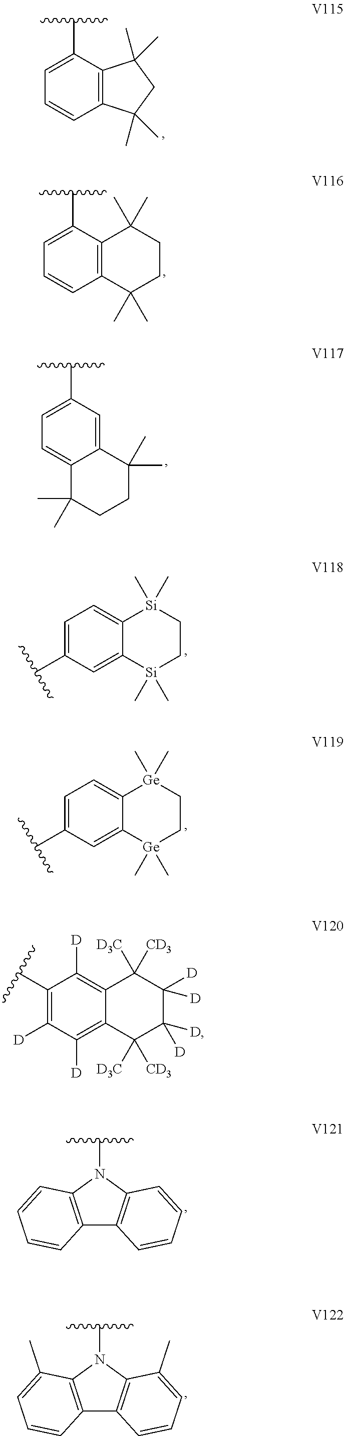

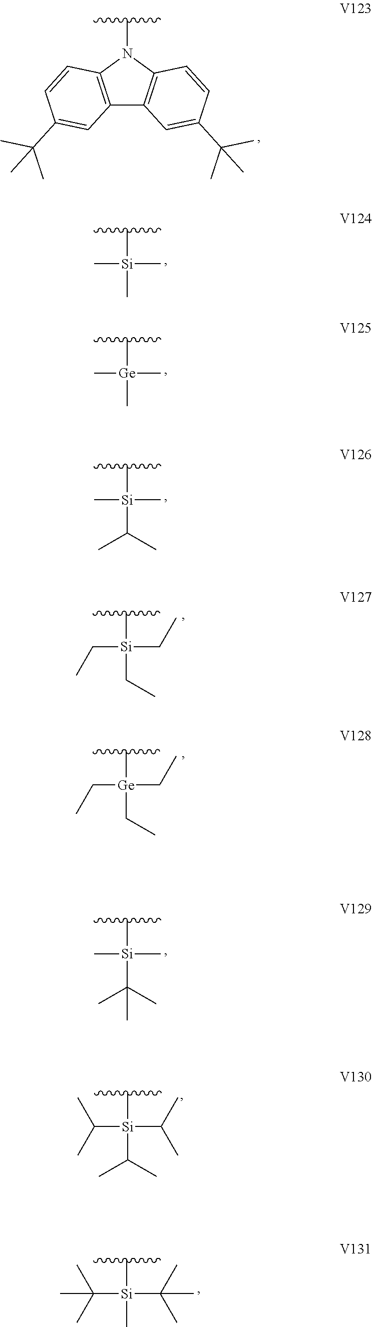

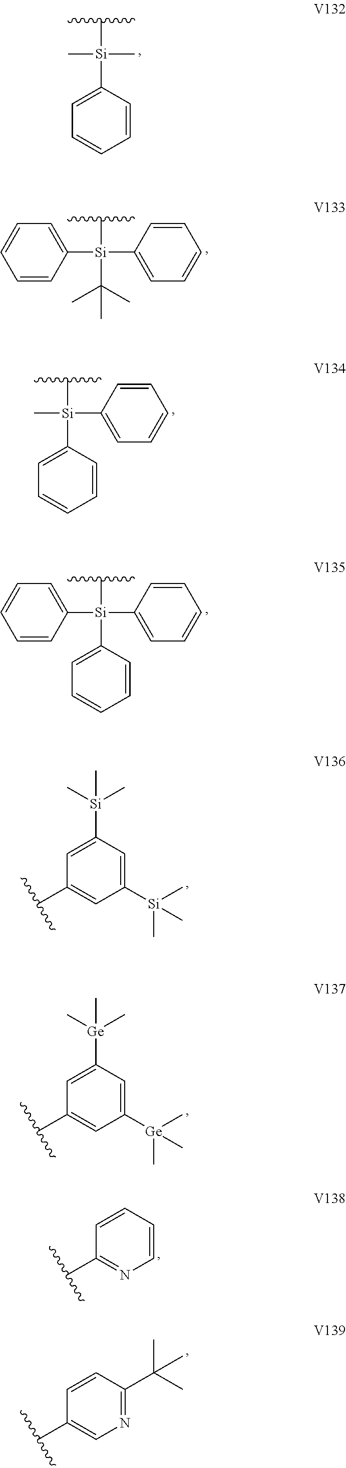

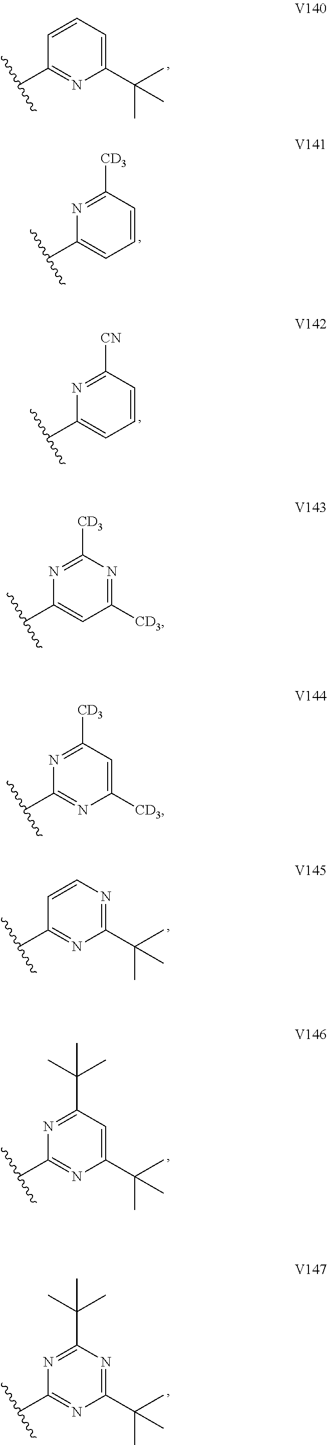

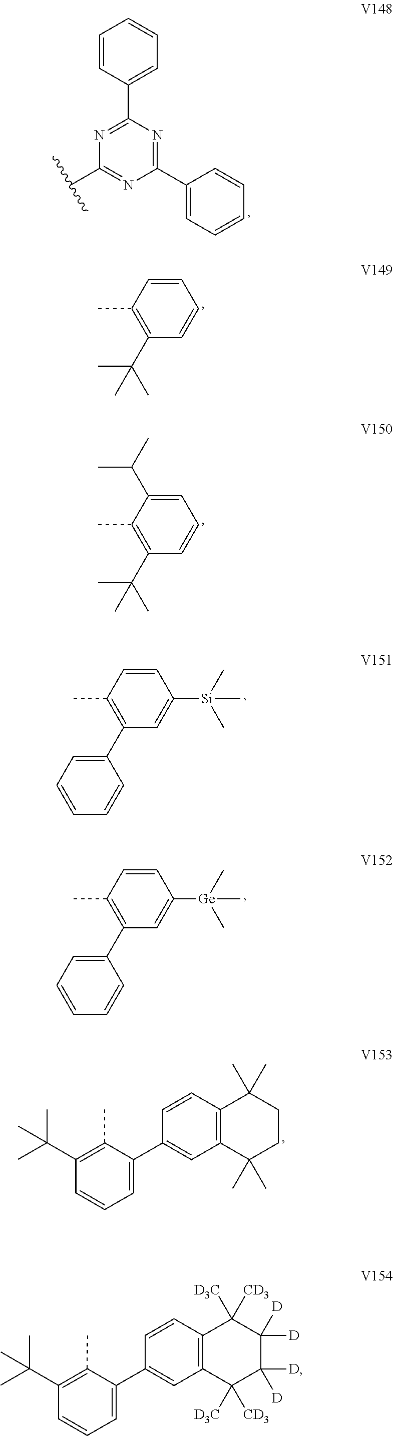

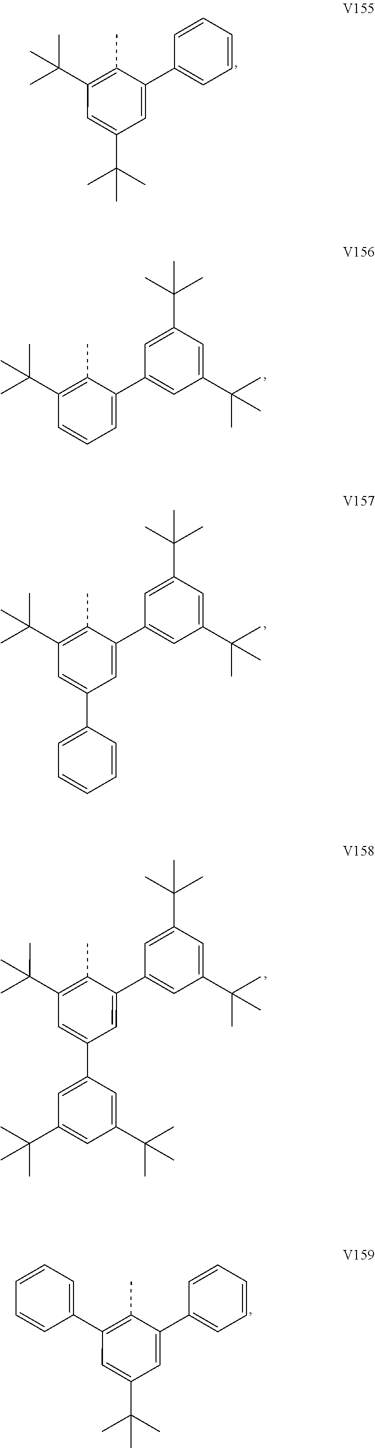

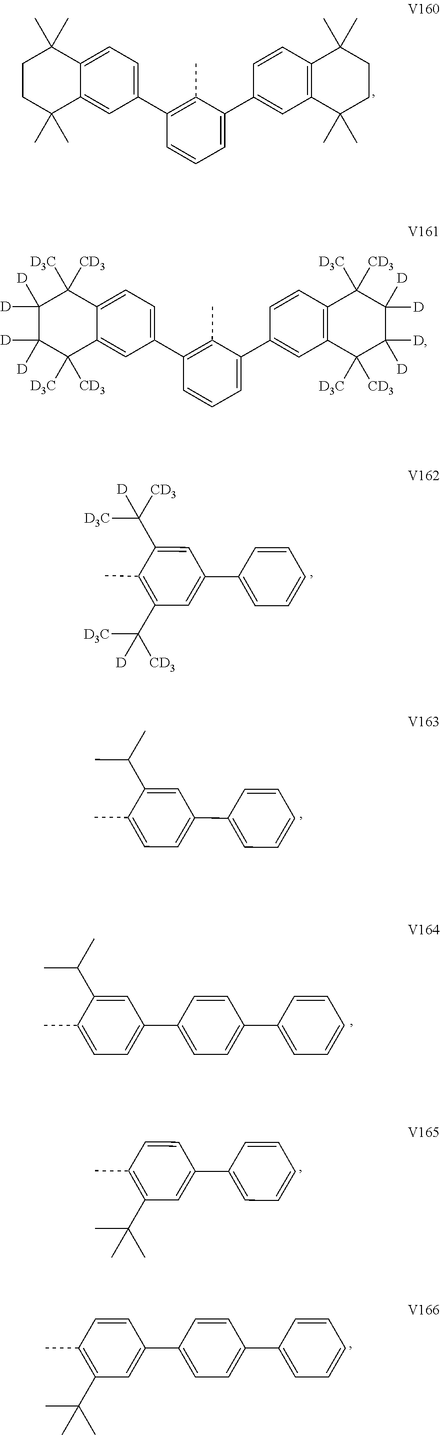

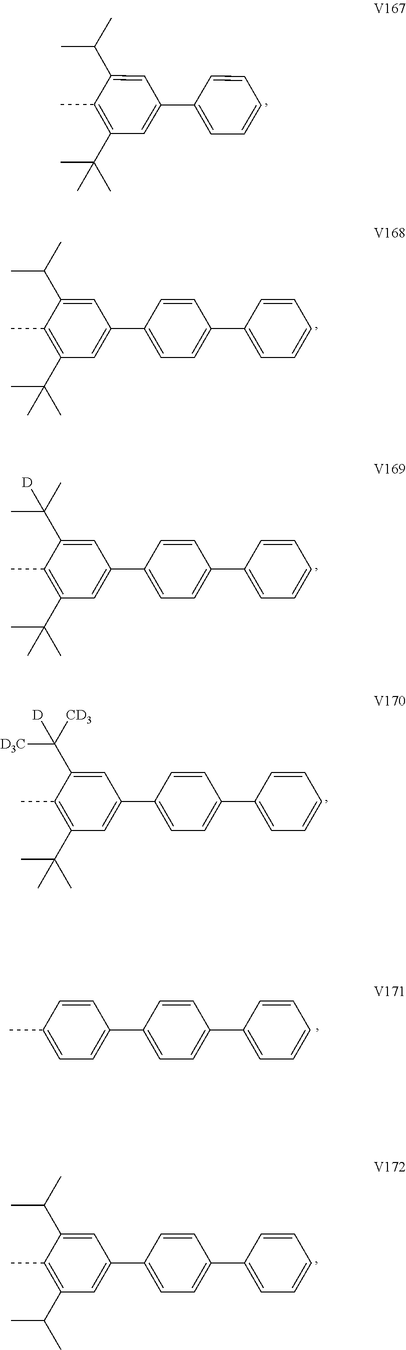

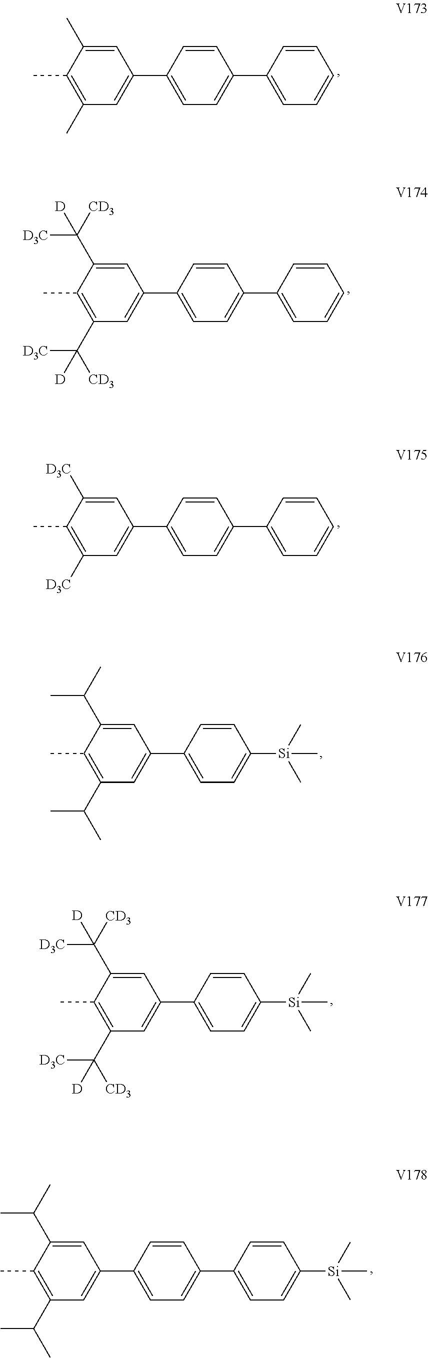

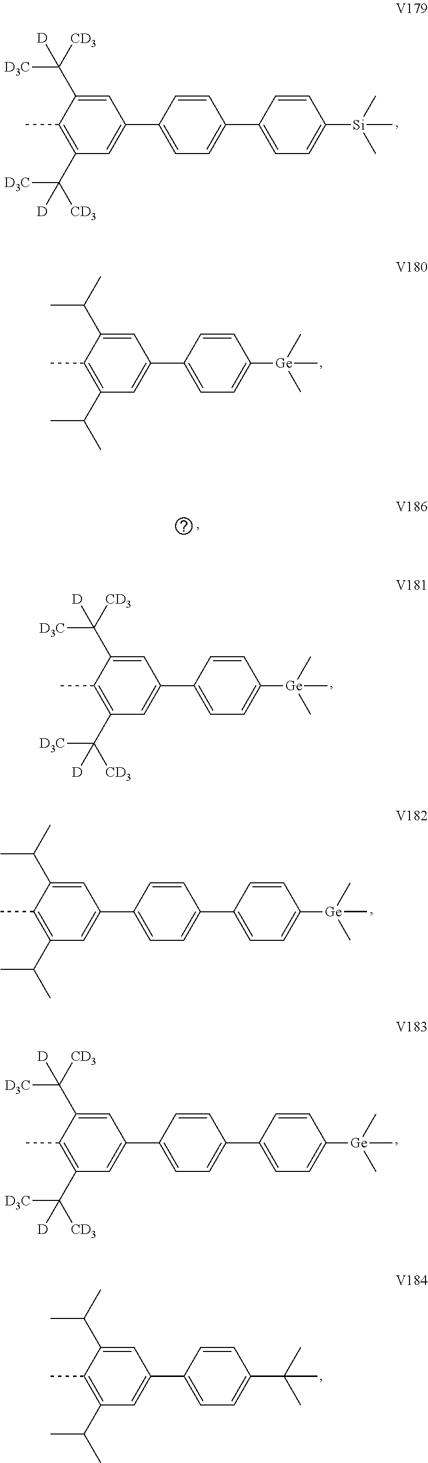

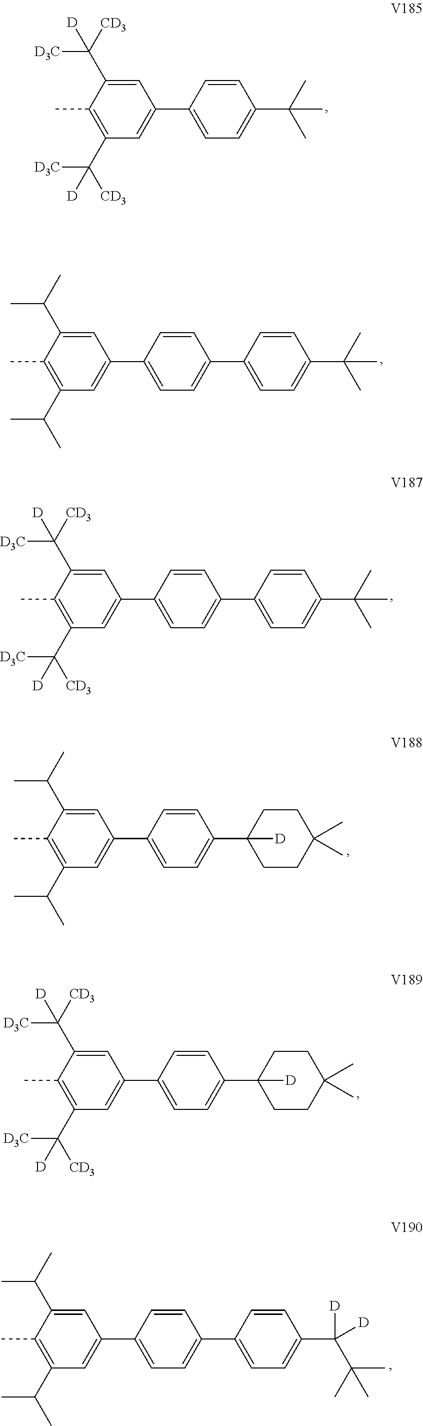

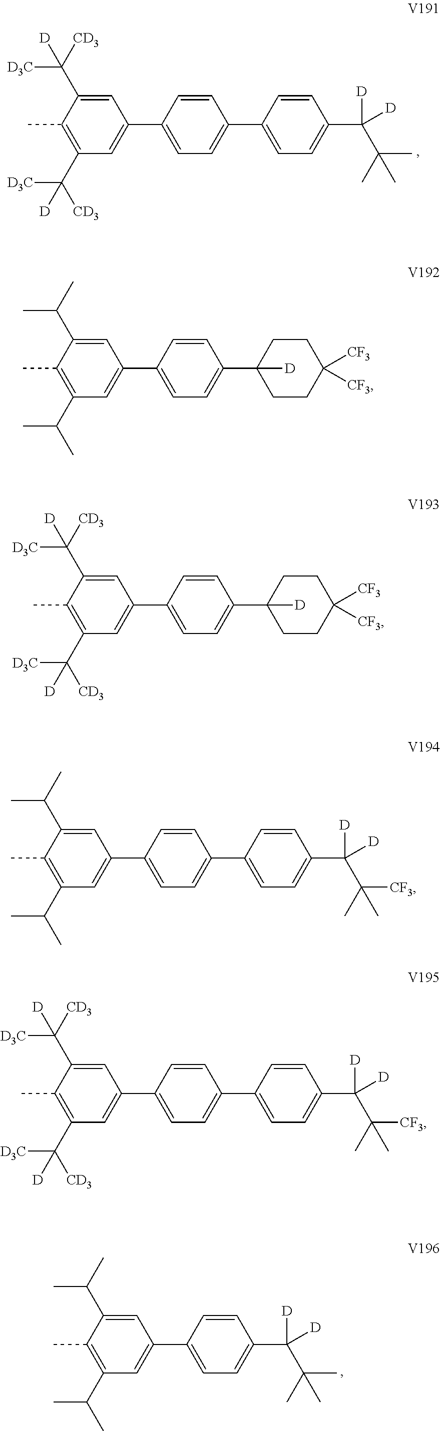

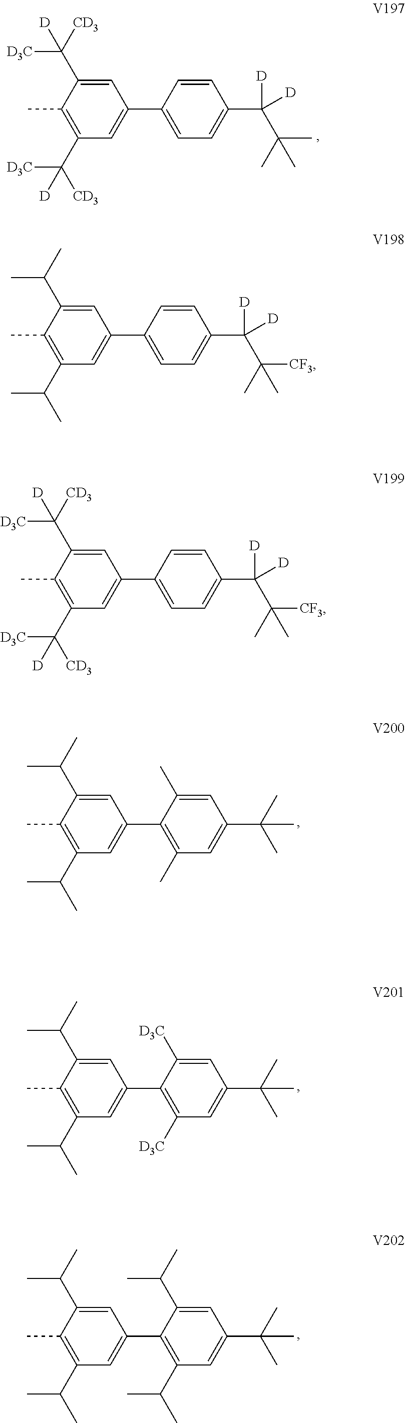

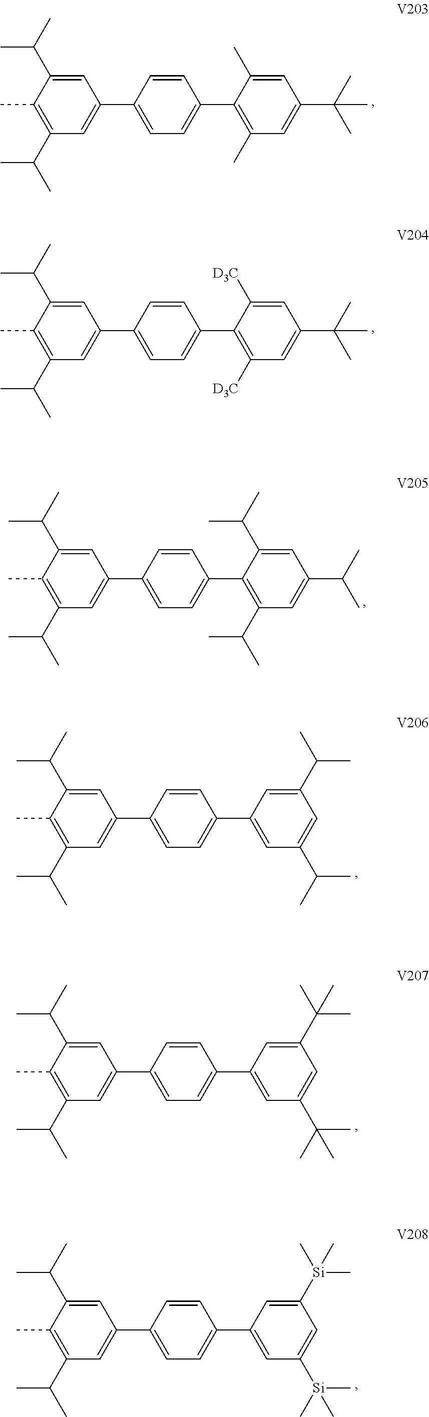

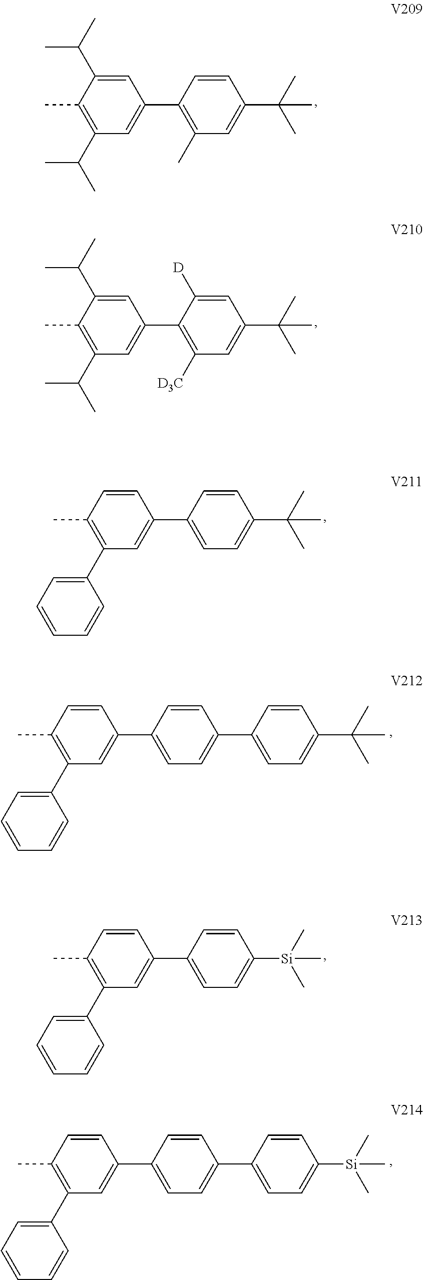

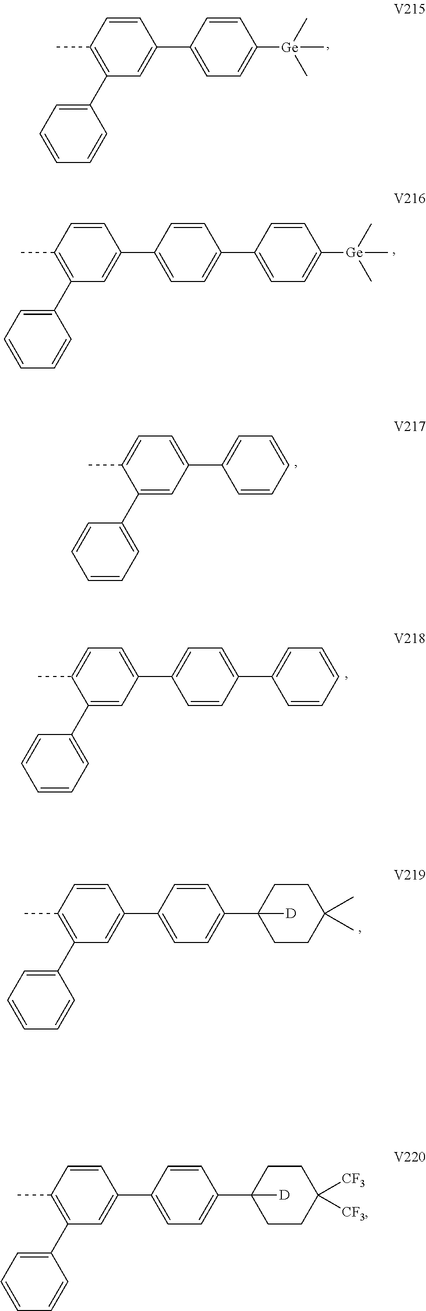

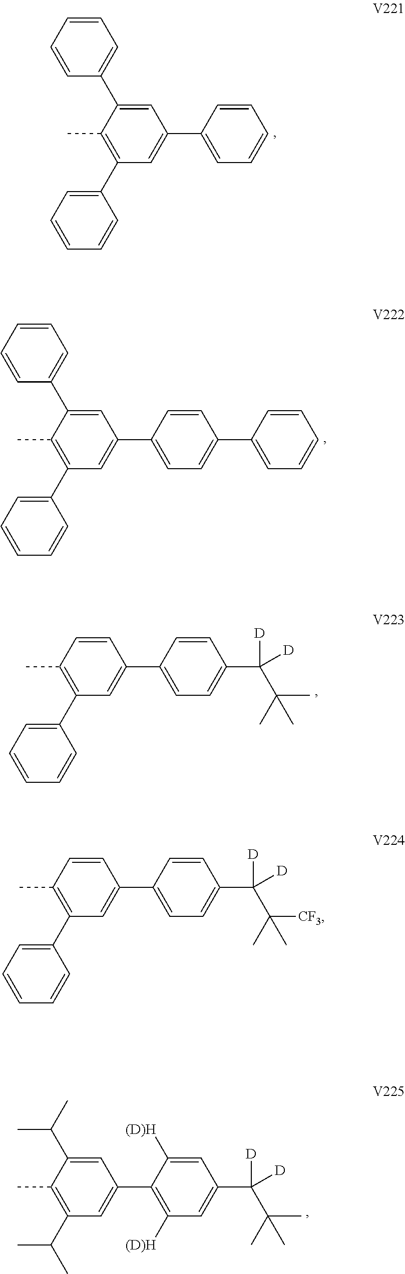

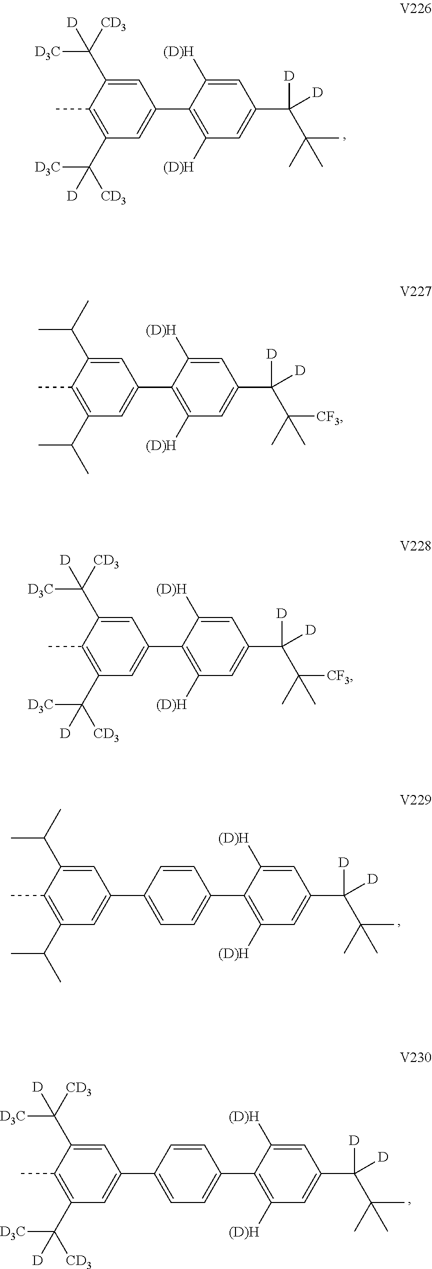

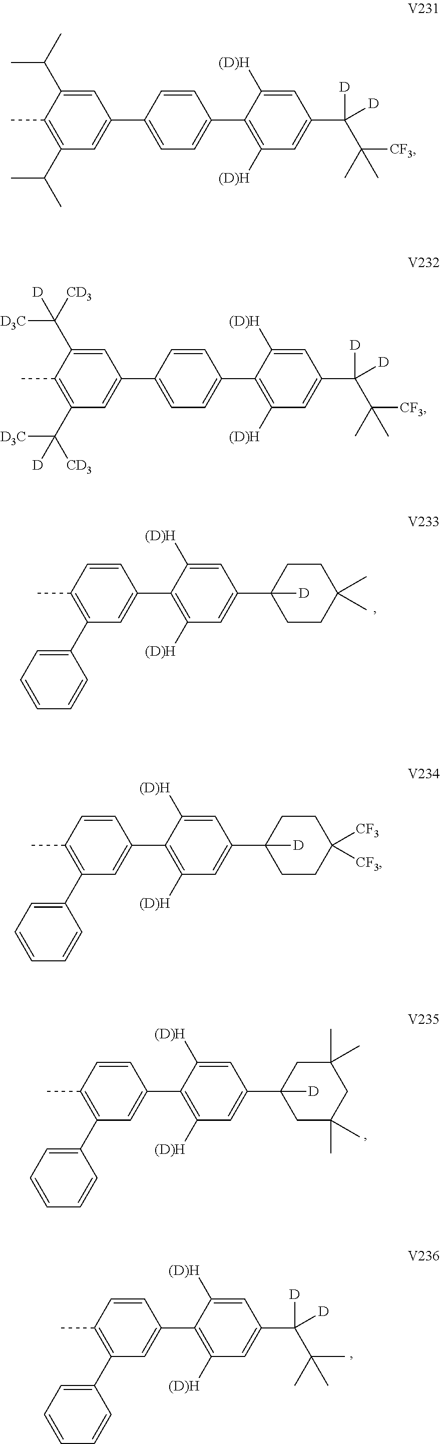

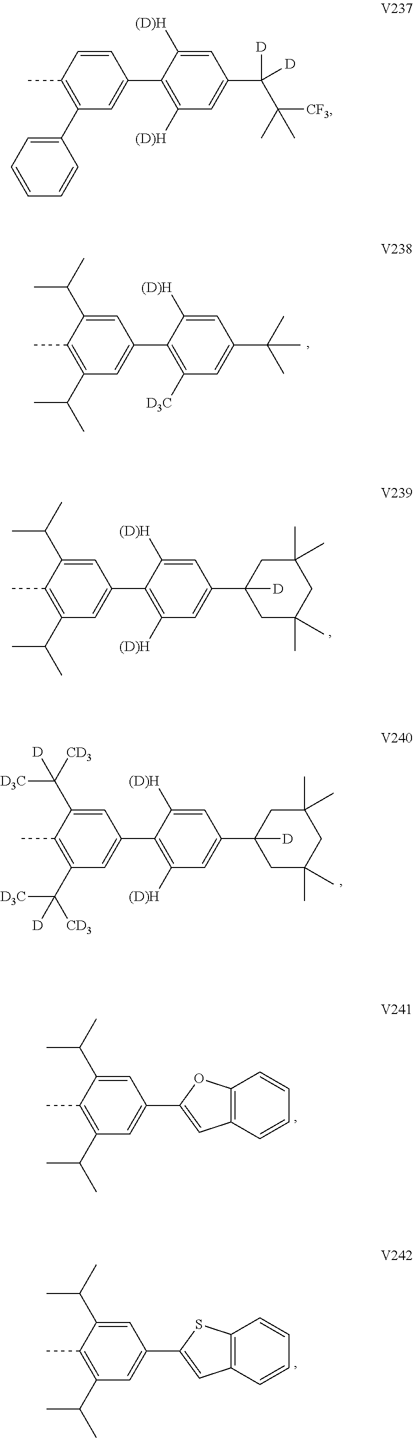

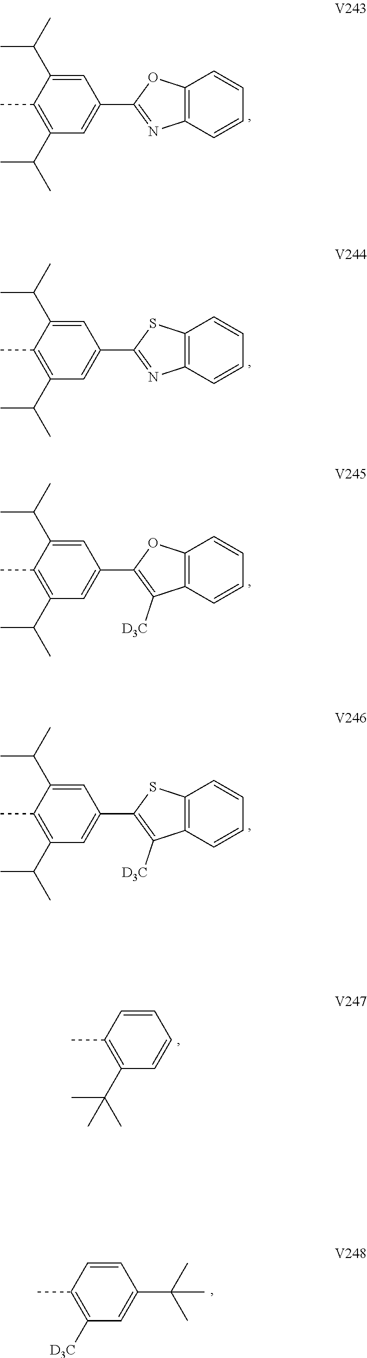

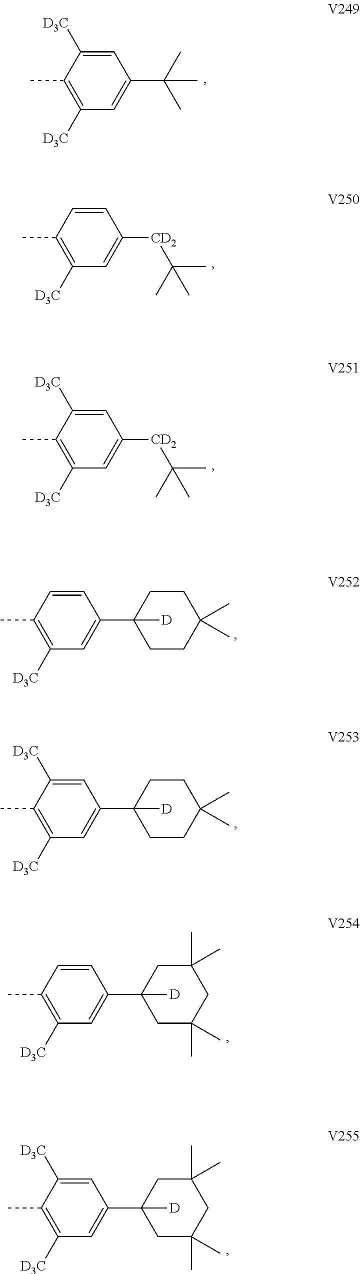

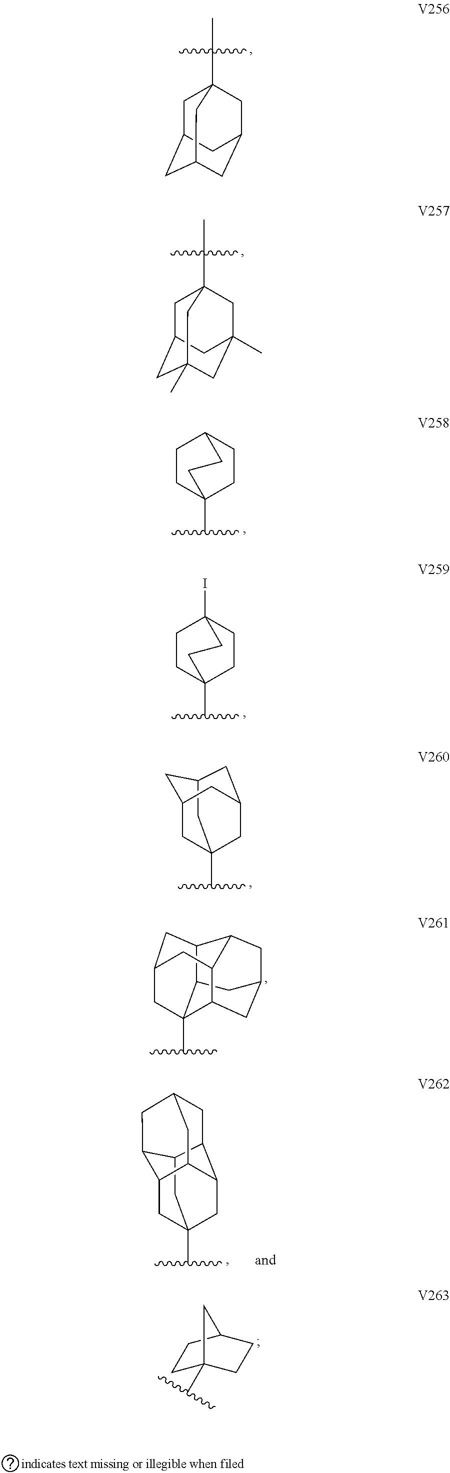

wherein G1 to G31 have the structures defined in the following:

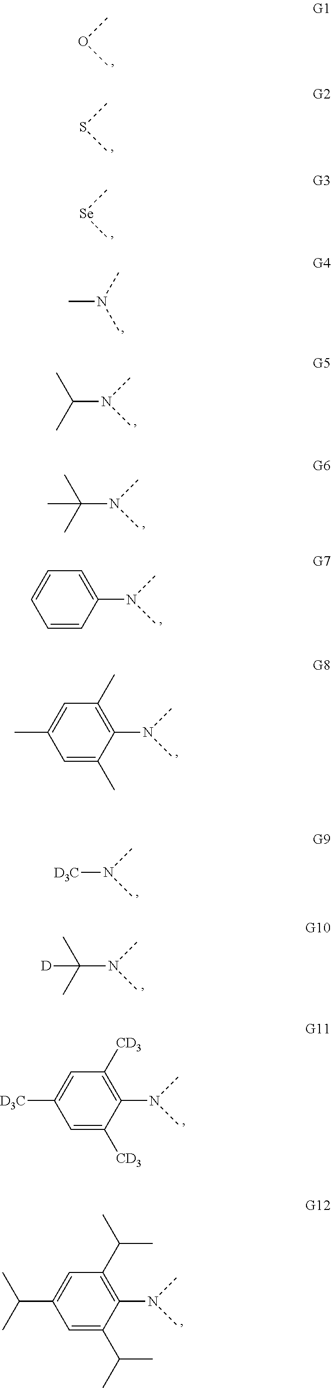

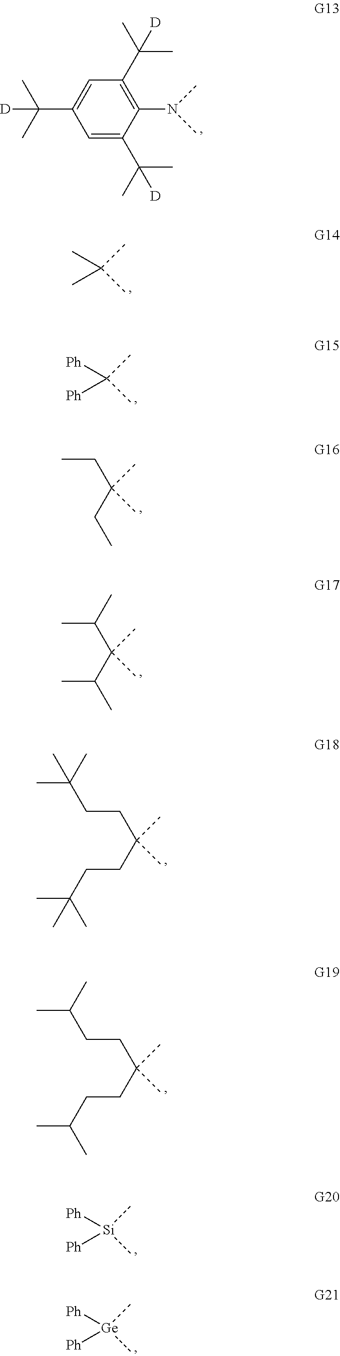

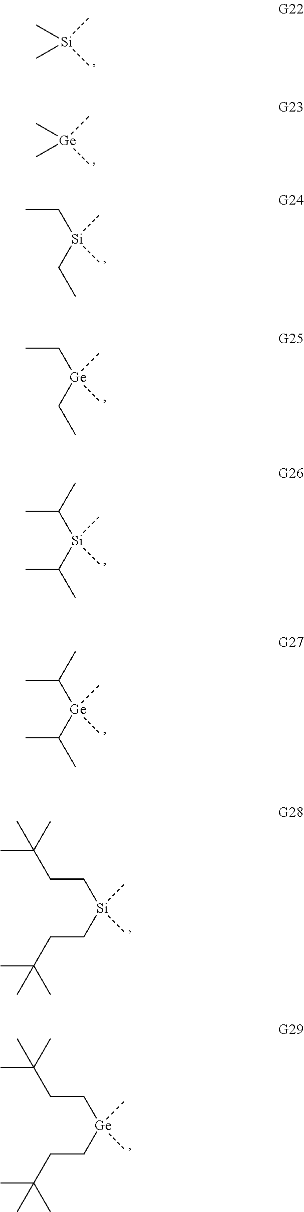

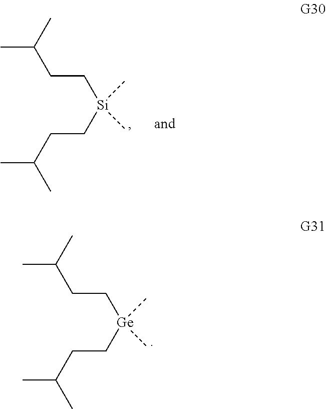

In some embodiments, Y^{E} is selected from the group consisting of G1 to G13. In some embodiments, Y^{F} is selected from the group consisting of G1 to G19.

In some embodiments, the compound has a formula of M(L_{A})ₚ(L_{B})_{q}(L_{C}), wherein L_{B} and L_{C} are each a bidentate ligand; and wherein p is 1, 2, or 3; q is 0, 1, or 2; r is 0, 1, or 2; and p+q+r is the oxidation state of the metal M.

In some embodiments, the compound has a formula selected from the group consisting of Ir(L_{A})₃, Ir(L_{A})(L_{B})₂, Ir(L_{A})₂(L_{B}), Ir(L_{A})₂(L_{C}), and Ir(L_{A})(L_{B})(L_{C}); and wherein L_{A}, L_{B}, and L_{C} are different from each other.

In some embodiments, L_{B} is a substituted or unsubstituted phenylpyridine, and L_{C} is a substituted or unsubstituted acetylacetonate.

In some embodiments, the compound has a formula of Pt(L_{A})(L_{B}); and wherein L_{A} and L_{B} can be same or different.

In some embodiments, L_{A} and L_{B} are connected to form a tetradentate ligand.

In some embodiments, L_{B} and L_{C} are each independently selected from the group consisting of the following structures (LIST 4):

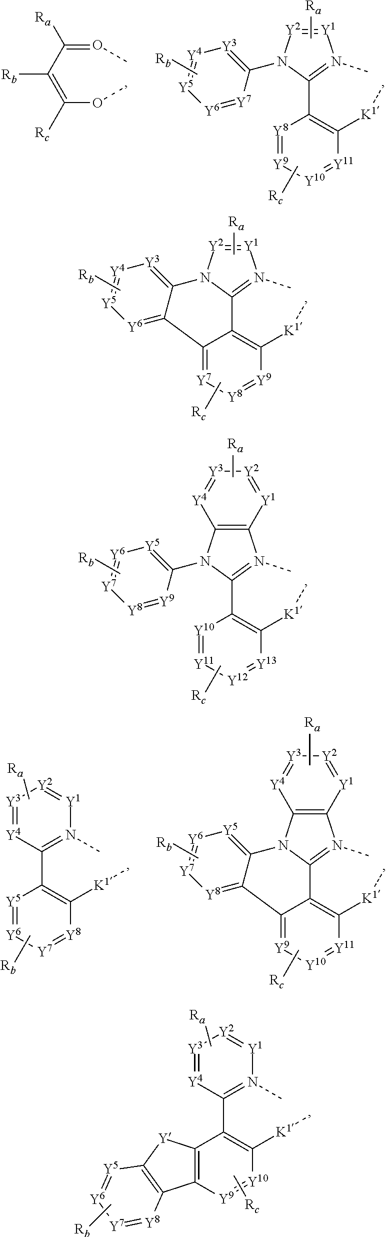

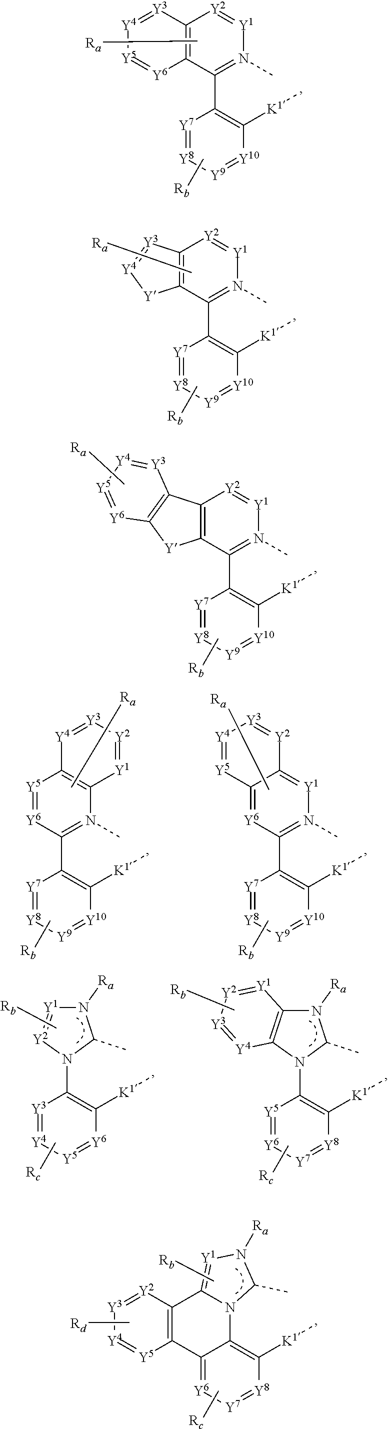

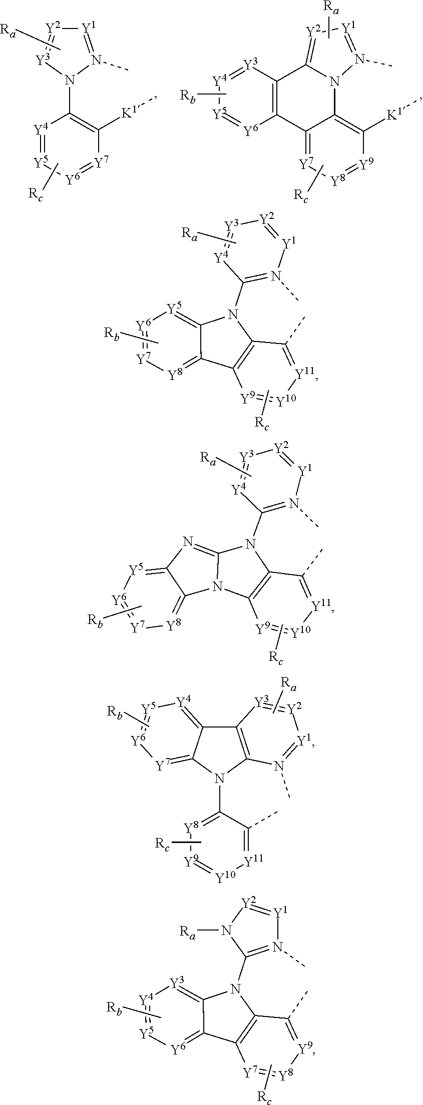

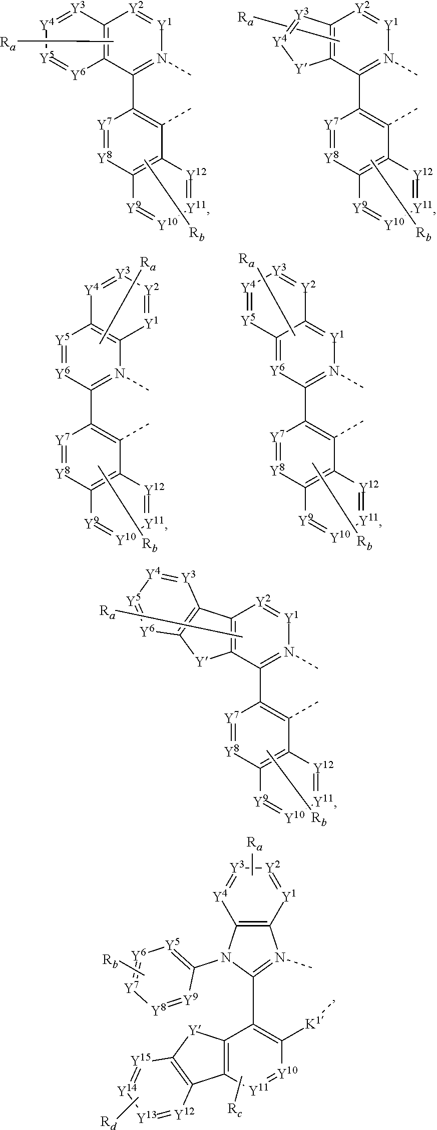

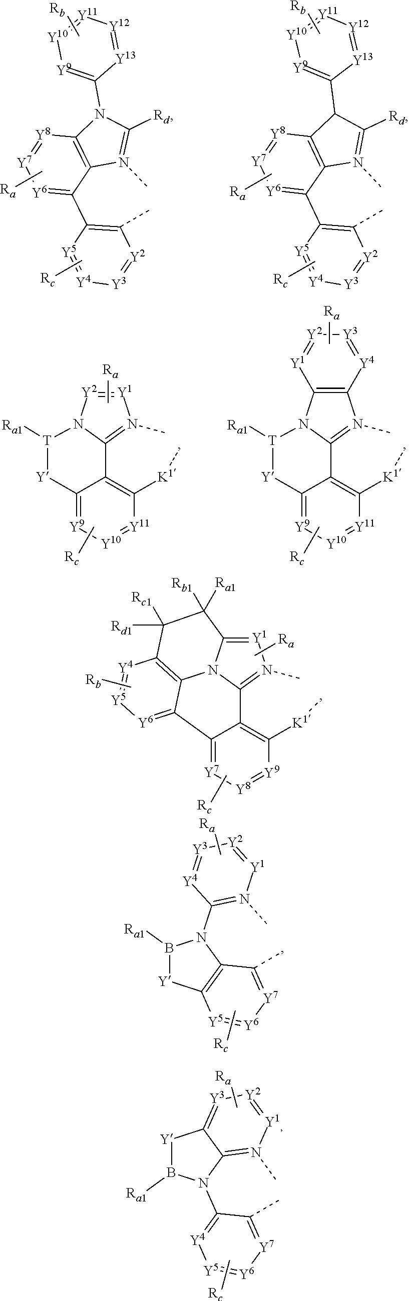

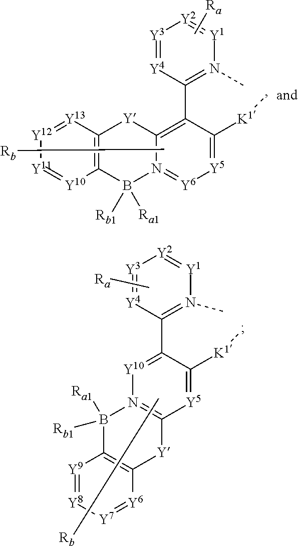

wherein:
T is selected from the group consisting of B, Al, Ga, and In;
wherein K^{1′} is a direct bond or is selected from the group consisting of NRₑ, PRₑ, O, S, and Se;
each of Y¹ to Y¹³ is independently selected from the group consisting of carbon and nitrogen;
Y′ is selected from the group consisting of BRₑ, NRₑ, PRₑ, O, S, Se, C═O, C═S, C═Se, S═O, SO₂, P(O)Rₑ, C═NRₑ, C═CRₑR_{f}, CRₑR_{f}, SiRₑR_{f}, and GeRₑR_{f};
Rₑ and R_{f} can be fused or joined to form a ring;
each Rₐ, R_{b}, R_{c}, and R_{d} independently represent zero, mono, or up to a maximum allowed number of substitutions to its associated ring;
each of Rₐ₁, R_{b1}, R_{c1}, R_{d1}, Rₐ, R_{b}, R_{c}, R_{d}, Rₑ and R_{f} is independently a hydrogen or a substituent selected from the group consisting of deuterium, halide, alkyl, cycloalkyl, heteroalkyl, arylalkyl, alkoxy, aryloxy, amino, silyl, germyl, boryl, alkenyl, cycloalkenyl, heteroalkenyl, alkynyl, aryl, heteroaryl, acyl, carbonyl, carboxylic acid, ester, nitrile, isonitrile, sulfanyl, sulfinyl, sulfonyl, phosphino, selenyl, and combinations thereof; the general substituents defined herein; and
any two adjacent Rₐ, R_{b}, R_{c}, R_{d}, Rₑ and R_{f} can be fused or joined to form a ring or form a multidentate ligand.

In some embodiments, L_{B} and L_{C} are each independently selected from the group consisting of the following structures (LIST 5):

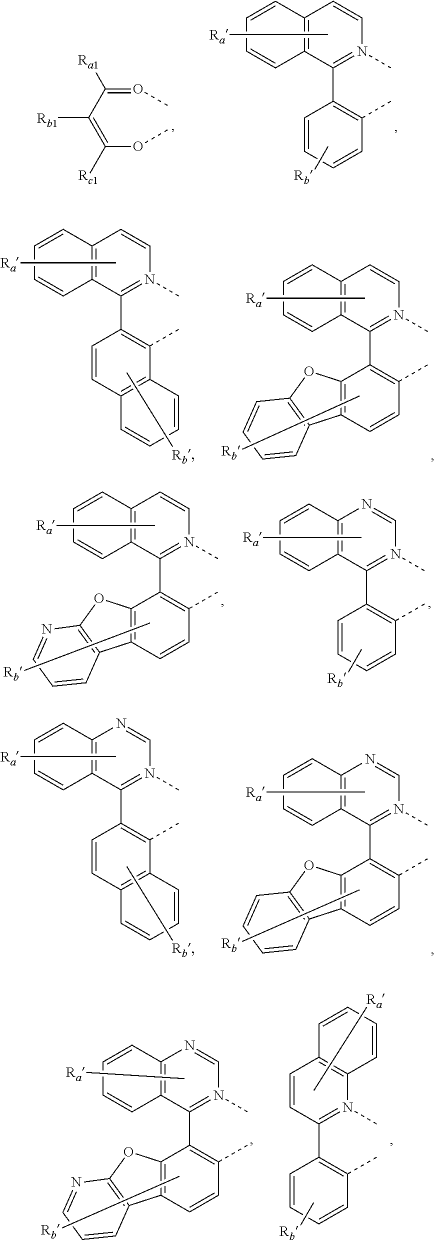

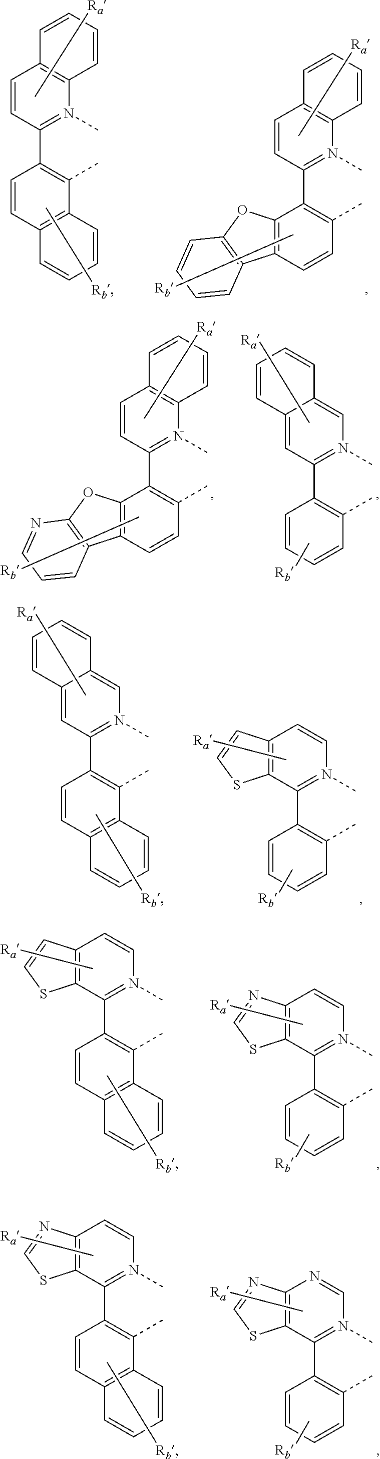

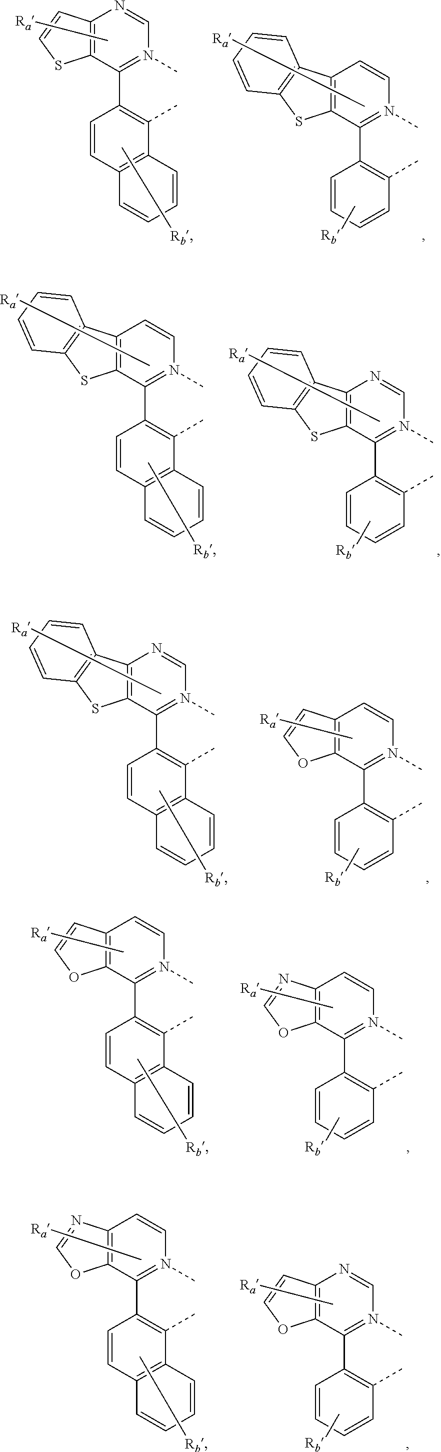

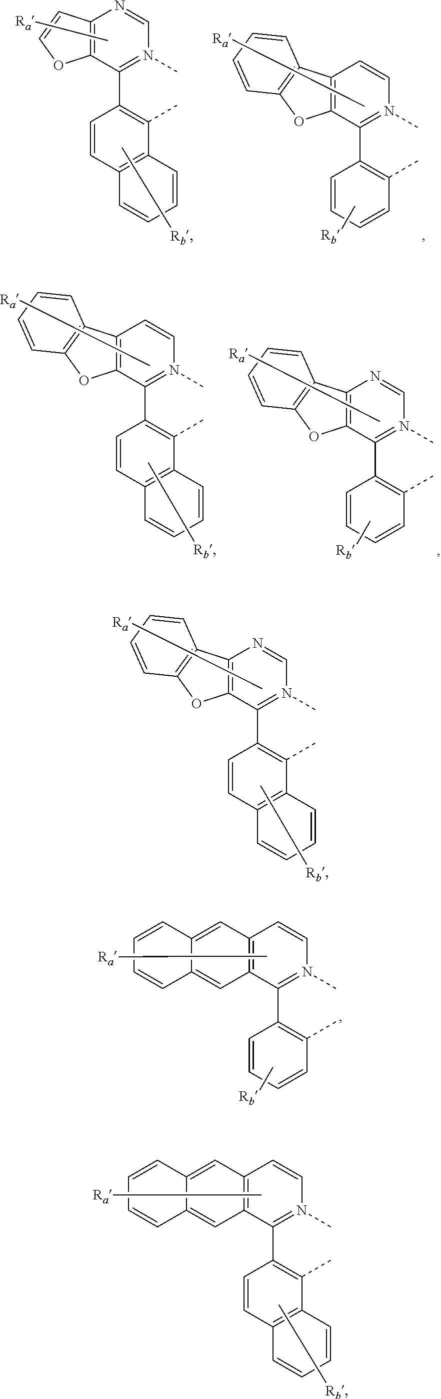

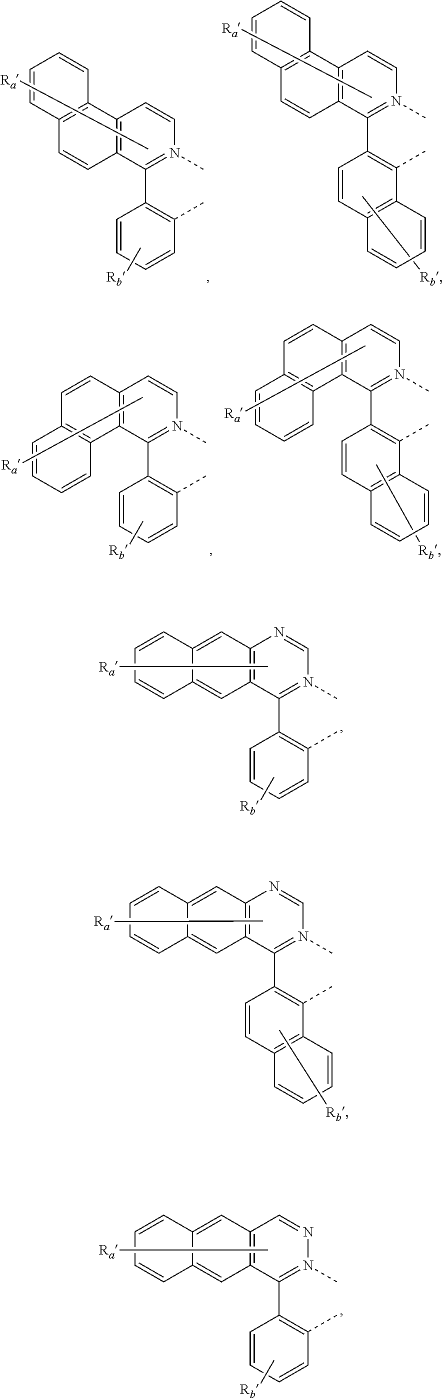

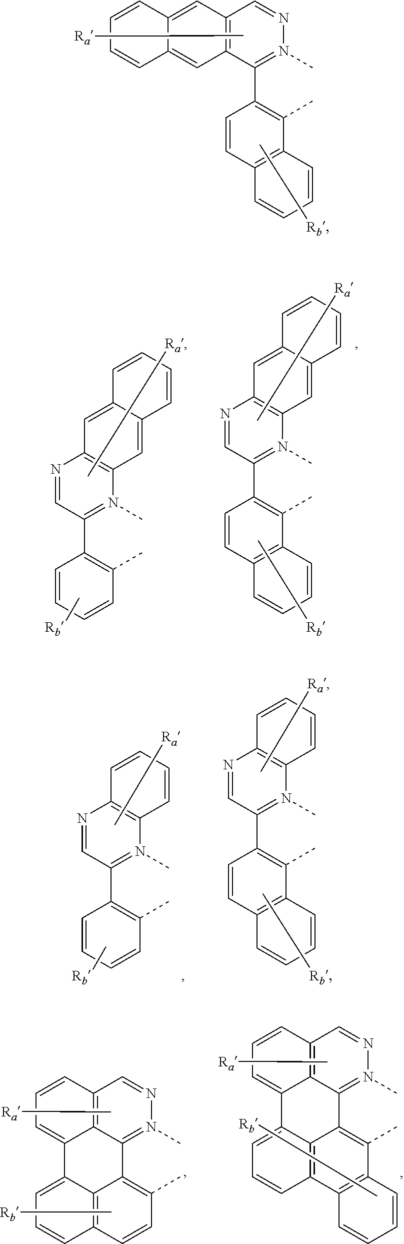

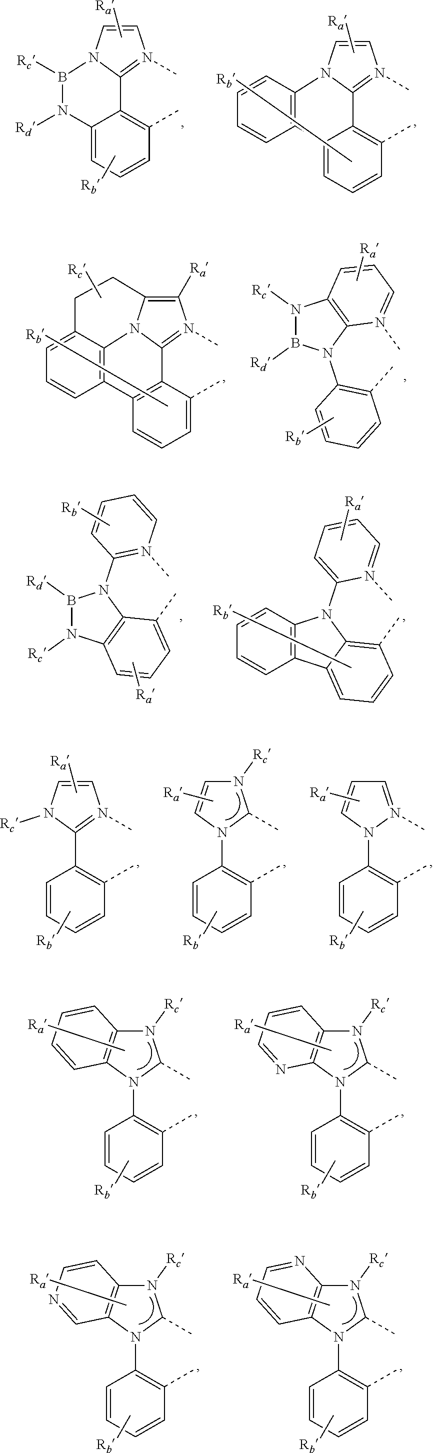

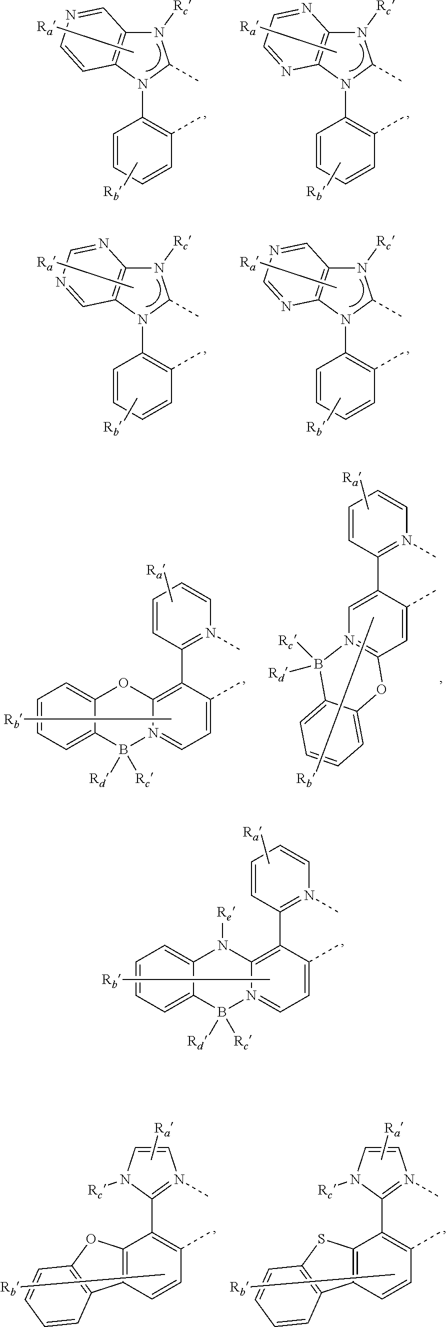

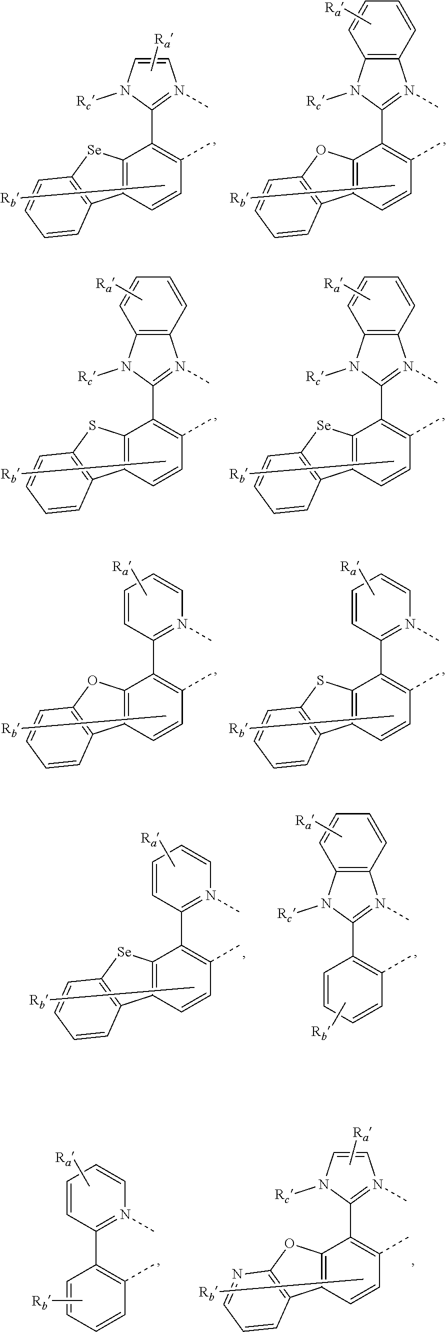

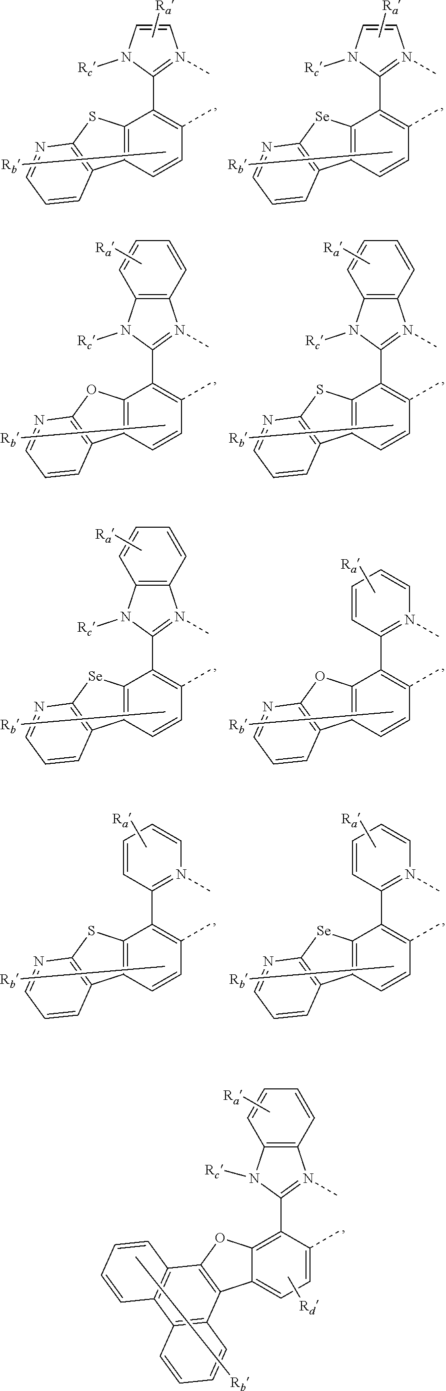

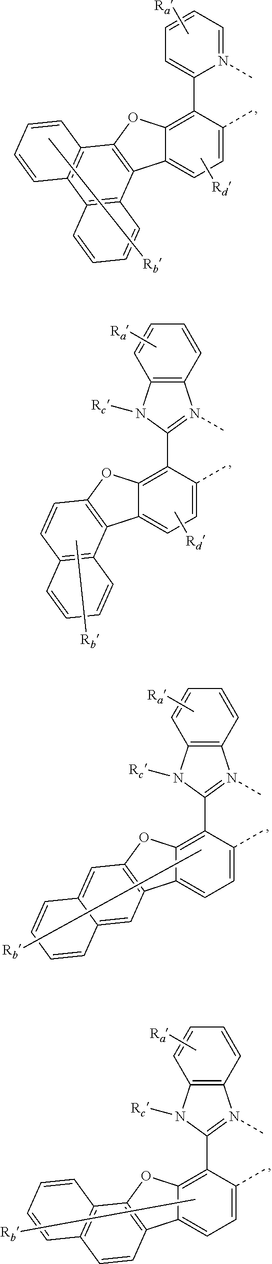

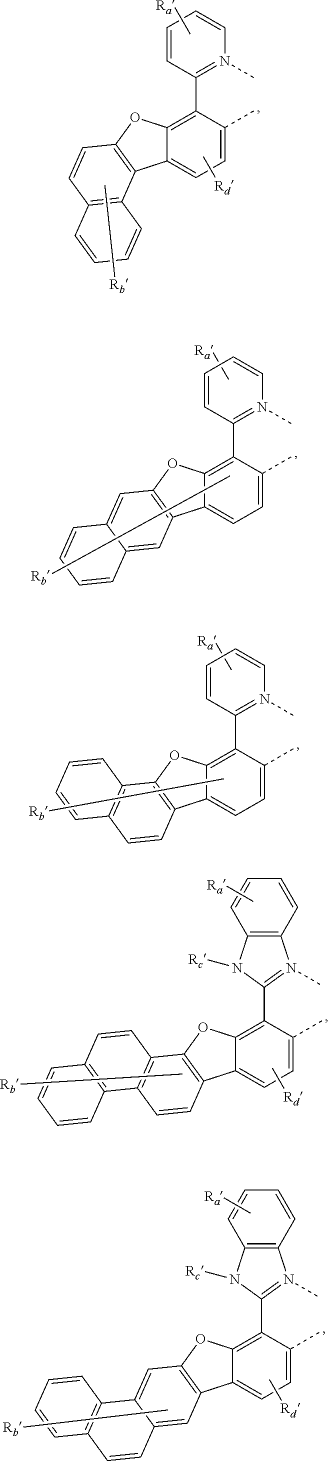

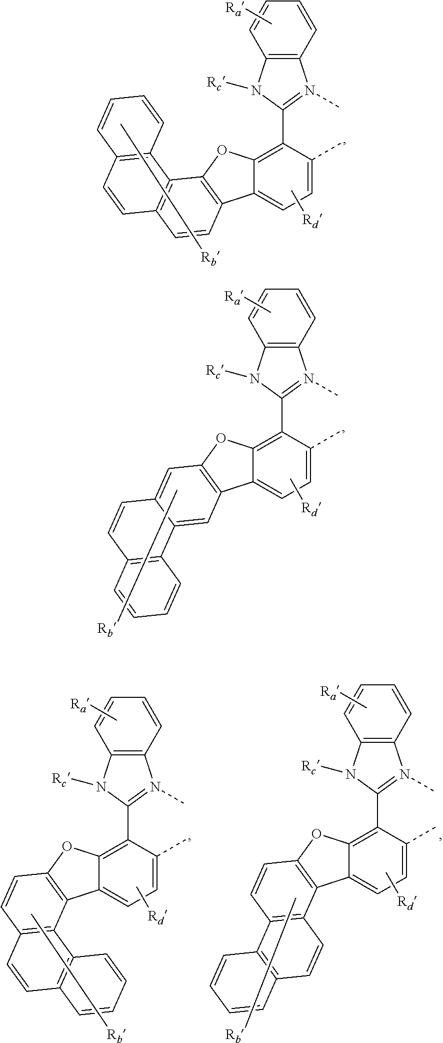

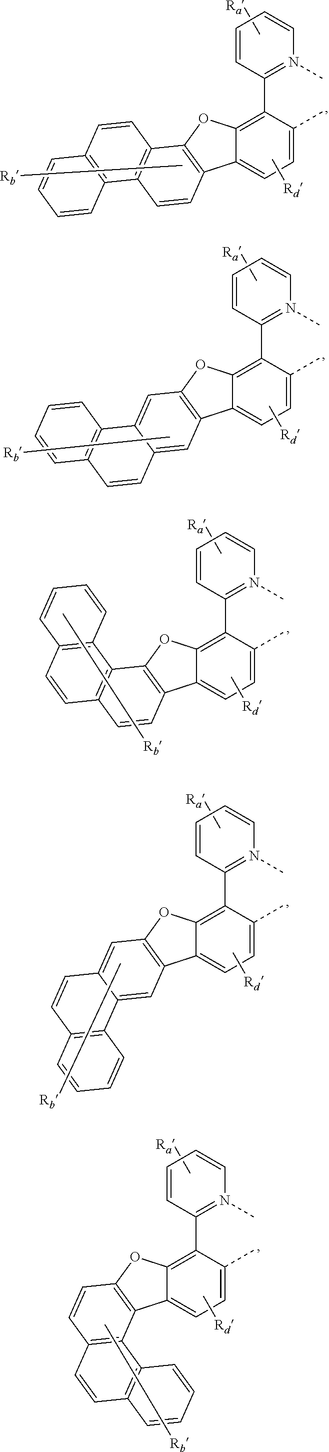

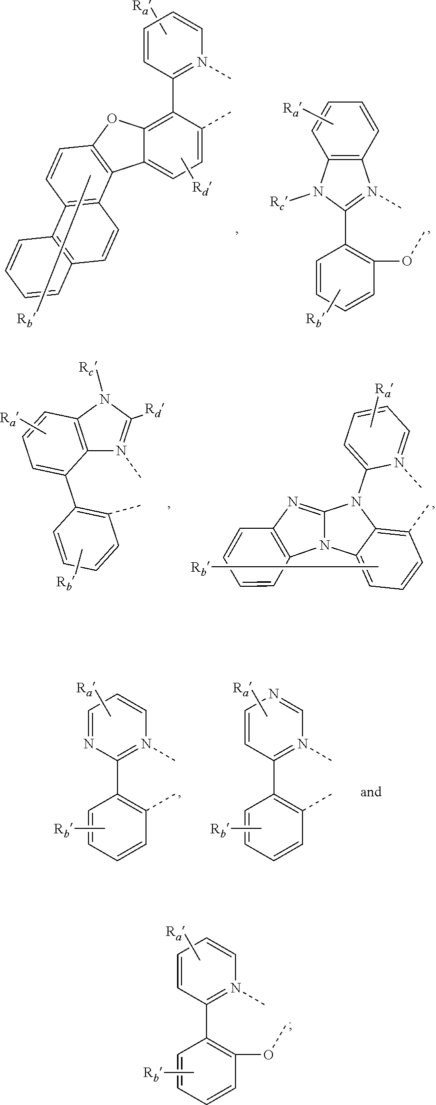

wherein Rₐ′, R_{b}′, R_{c}′, R_{d}′, and Rₑ′ each independently represent zero, mono, or up to a maximum allowed substitution to its associated ring;
wherein Rₐ′, R_{b}′, R_{c}′, R_{d}′, and Rₑ′ is each independently hydrogen or a substituent selected from the group consisting of deuterium, halide, alkyl, cycloalkyl, heteroalkyl, arylalkyl, alkoxy, aryloxy, amino, silyl, germyl, boryl, alkenyl, cycloalkenyl, heteroalkenyl, alkynyl, aryl, heteroaryl, acyl, carbonyl, carboxylic acid, ester, nitrile, isonitrile, sulfanyl, sulfinyl, sulfonyl, phosphino, selenyl, and combinations thereof; and
wherein two adjacent substituents of Rₐ′, R_{b}′, R_{c}′, R_{d}′, and Rₑ′ can be fused or joined to form a ring or form a multidentate ligand.

In some embodiments, L_{B} comprises a structure of

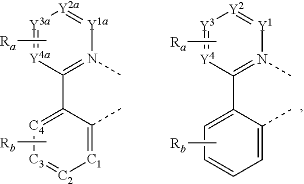

wherein the variables are the same as previously defined. In some embodiments, each of Y^{1a} to Y^{4a} is independently carbon. In some embodiments, at least one of Y^{1a} to Y^{4a} is N. In some embodiments, exactly one of Y^{1a} to Y⁴a is N. In some embodiments, Y^{1a} is N. In some embodiments, Y^{2a} is N. In some embodiments, Y^{3a} is N. In some embodiments, Y^{4a} is N.

In some embodiments, at least one of R^{a} is a tertiary alkyl, silyl or germyl. In some embodiments, at least one of R^{a} is a tertiary alkyl.

In some embodiments, Y^{1a} is carbon and attached to Rₐ₁. In some such embodiments, Rₐ₁ may be selected from the group consisting of the General Substituents defined herein. In some such embodiments, Rₐ₁ may be selected from the group consisting of the Preferred General Substituents defined herein. In some such embodiments, Rₐ₁ is a tertiary alkyl, silyl or germyl. In some such embodiments, Rₐ₁ is a tertiary alkyl. In some embodiments, Y^{2a} is carbon and attached to Rₐ₂. In some such embodiments, Rₐ₂ may be selected from the group consisting of the General Substituents defined herein. In some such embodiments, Rₐ₂ may be selected from the group consisting of the Preferred General Substituents defined herein. In some such embodiments, Raz is a tertiary alkyl, silyl or germyl. In some such embodiments, Rₐ₂ is a tertiary alkyl. In some embodiments, Y^{3a} is carbon and attached to Rₐ₃. In some such embodiments, Rₐ₃ may be selected from the group consisting of the General Substituents defined herein. In some such embodiments, Rₐ₃ may be selected from the group consisting of the Preferred General Substituents defined herein. In some such embodiments, Rₐ₃ is a tertiary alkyl, silyl or germyl. In some such embodiments, Rₐ₃ is a tertiary alkyl. In some embodiments, Y⁴a is carbon and attached to Rₐ₄. In some such embodiments, Rₐ₄ may be selected from the group consisting of the General Substituents defined herein. In some such embodiments, Rₐ₄ may be selected from the group consisting of the Preferred General Substituents defined herein. In some such embodiments, Rₐ₄ is a tertiary alkyl, silyl or germyl.

In some such embodiments, Rₐ₄ is a tertiary alkyl. In some embodiments, X^{3a} is C and the R^{C} attached thereto is a tertiary alkyl, silyl or germyl. In some embodiments, X^{2a} is C and the R^{C} attached thereto is a tertiary alkyl, silyl or germyl.

In some embodiments, at least one of R^{b} is a tertiary alkyl, silyl, or germyl. In some embodiments, at least one of R^{b} is tert-butyl. In some embodiments, at least one pair of Rₐ, one pair of R_{b}, or one Rₐ and one R_{b} are joined or fused into a ring.

In some embodiments, R_{b1} is attached to C¹ (carbon atom). In some such embodiments, R_{b1} may be selected from the group consisting of the General Substituents defined herein. In some such embodiments, R_{b1} may be selected from the group consisting of the Preferred General Substituents defined herein. In some such embodiments, R_{b1} is a tertiary alkyl, silyl or germyl. In some such embodiments, R_{b1} is a tertiary alkyl. In some embodiments, the tertiary alkyl is tert-butyl. In some embodiments, R_{b2} is attached to C² (carbon atom). In some such embodiments, R_{b2} may be selected from the group consisting of the General Substituents defined herein. In some such embodiments, R_{b2} may be selected from the group consisting of the Preferred General Substituents defined herein. In some such embodiments, R_{b2} is a tertiary alkyl, silyl or germyl. In some such embodiments, R_{b2} is a tertiary alkyl. In some embodiments, the tertiary alkyl is tert-butyl. In some embodiments, R_{b3} is attached to C3 (carbon atom). In some such embodiments, R_{b3} may be selected from the group consisting of the General Substituents defined herein. In some such embodiments, R_{b3} may be selected from the group consisting of the Preferred General Substituents defined herein. In some such embodiments, R_{b3} is a tertiary alkyl, silyl or germyl. In some such embodiments, R_{b3} is a tertiary alkyl. In some embodiments, the tertiary alkyl is tert-butyl. In some embodiments, R_{b4} is attached to C⁴ (carbon atom). In some such embodiments, R_{b4} may be selected from the group consisting of the General Substituents defined herein. In some such embodiments, R_{b4} may be selected from the group consisting of the Preferred General Substituents defined herein. In some such embodiments, R_{b4} is a tertiary alkyl, silyl or germyl. In some such embodiments, R_{b4} is a tertiary alkyl. In some embodiments, the tertiary alkyl is tert-butyl.

In some embodiments, the compound has formula Ir(L_{A})₃, formula Ir(L_{A})(L_{Bk})₂, formula Ir(L_{A})₂(L_{Bk}), formula Ir(L_{A})₂(L_{Cj-I}), or Ir(L_{A})₂(L_{Cj-II}), wherein L_{A} is as defined above;
wherein k is an integer from 1 to 541, and each L_{Bk} has the structure defined as follows in the following LIST 6:

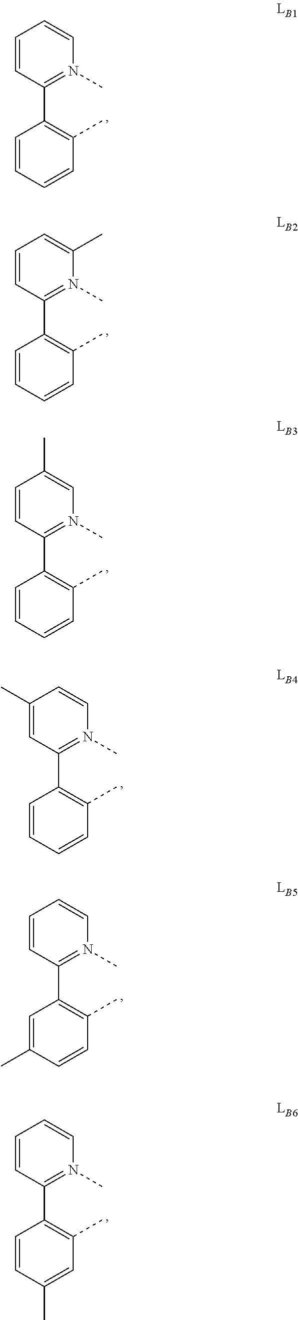

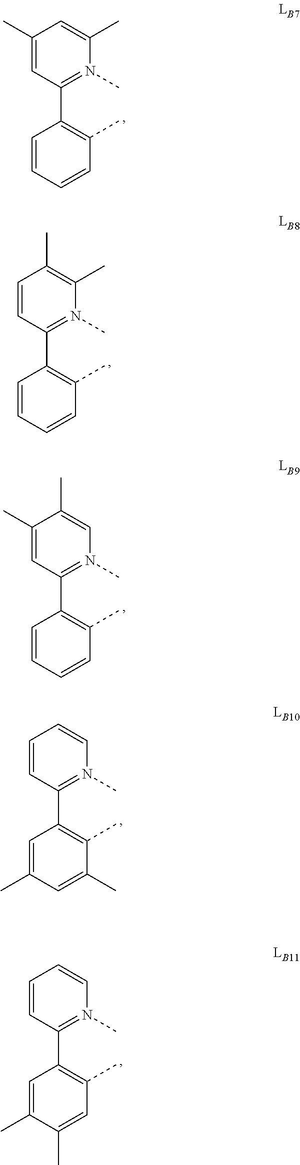

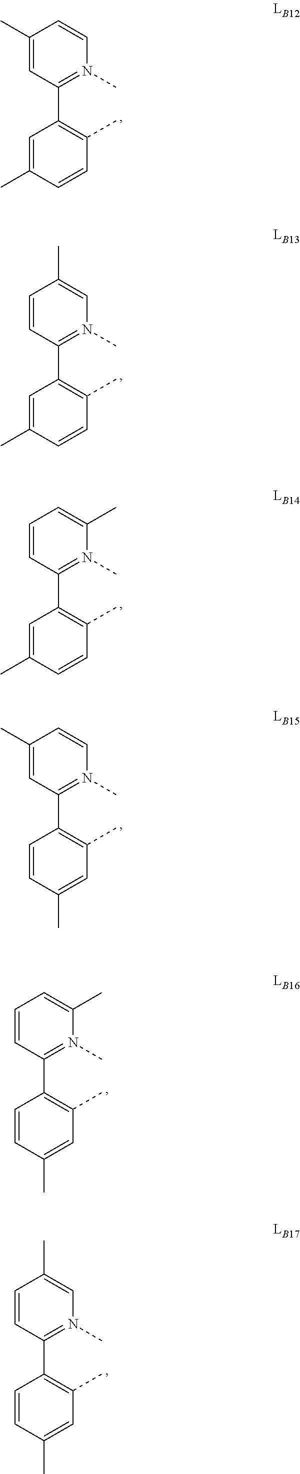

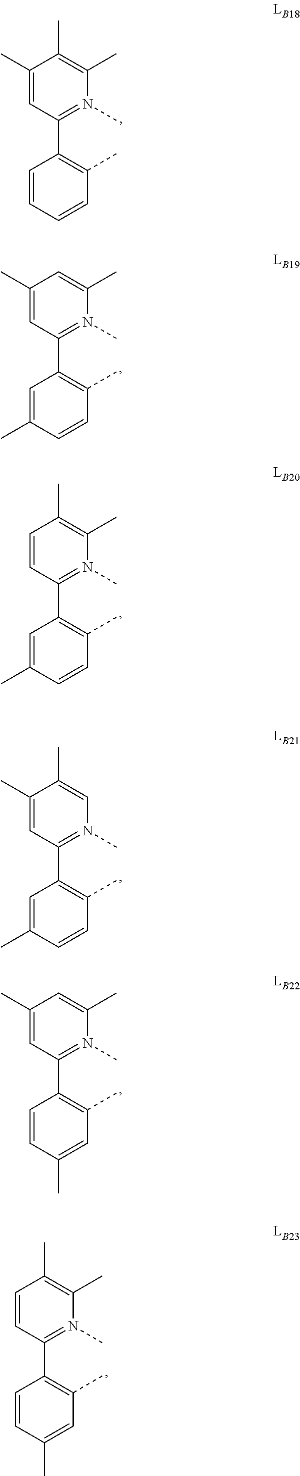

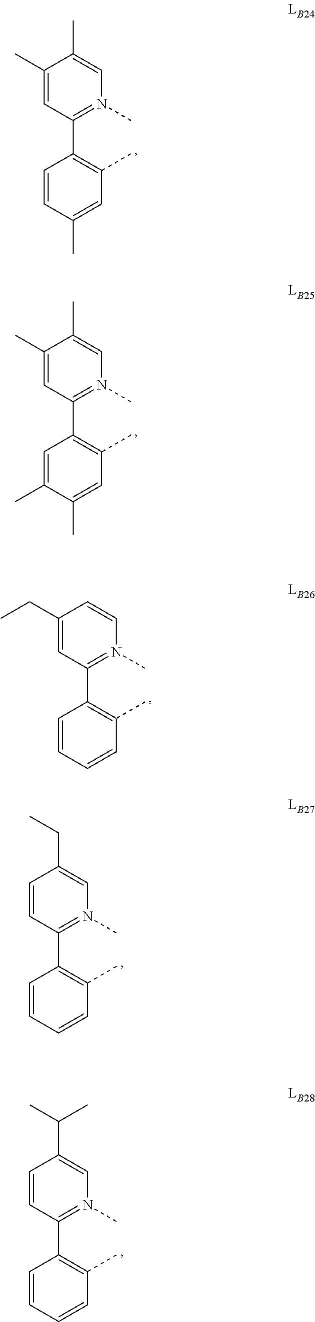

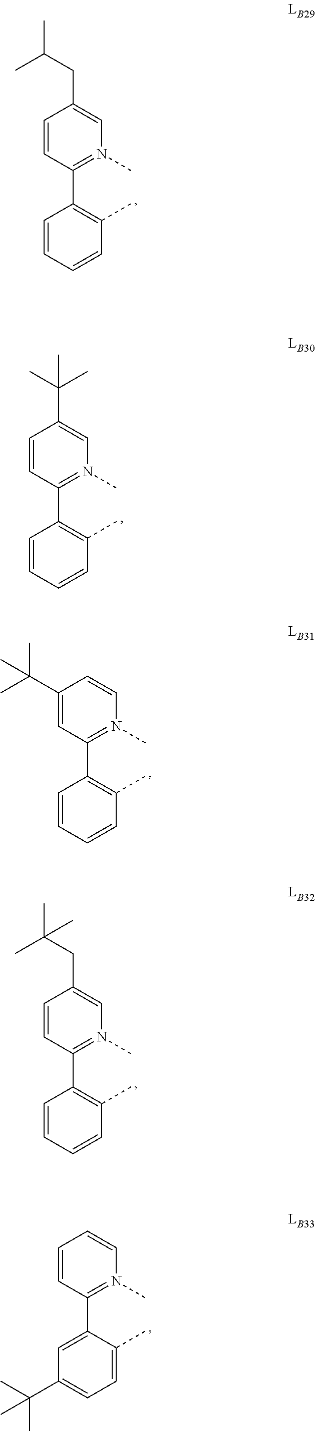

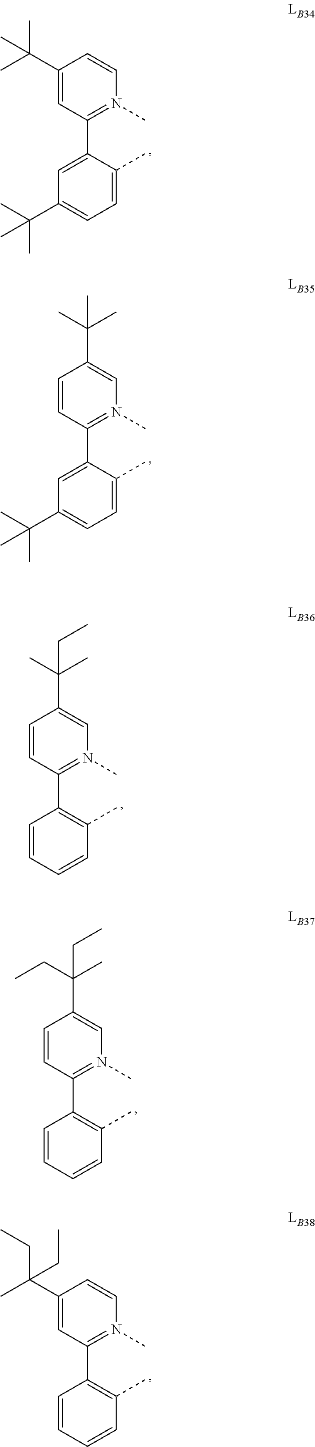

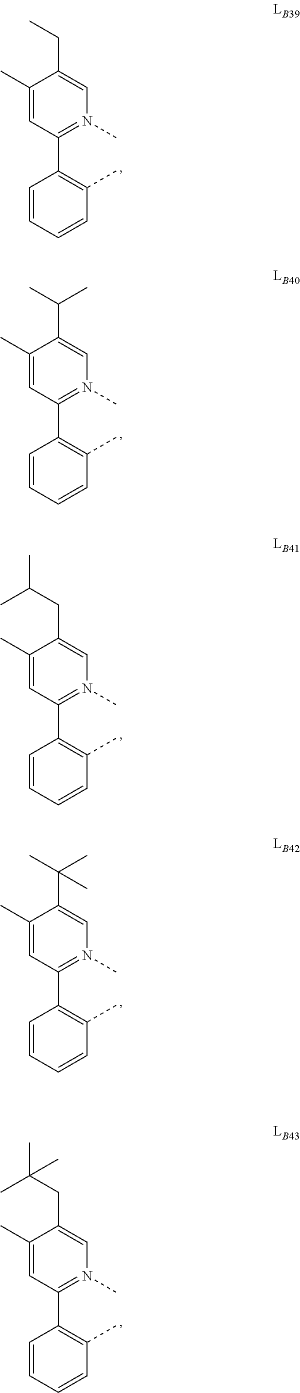

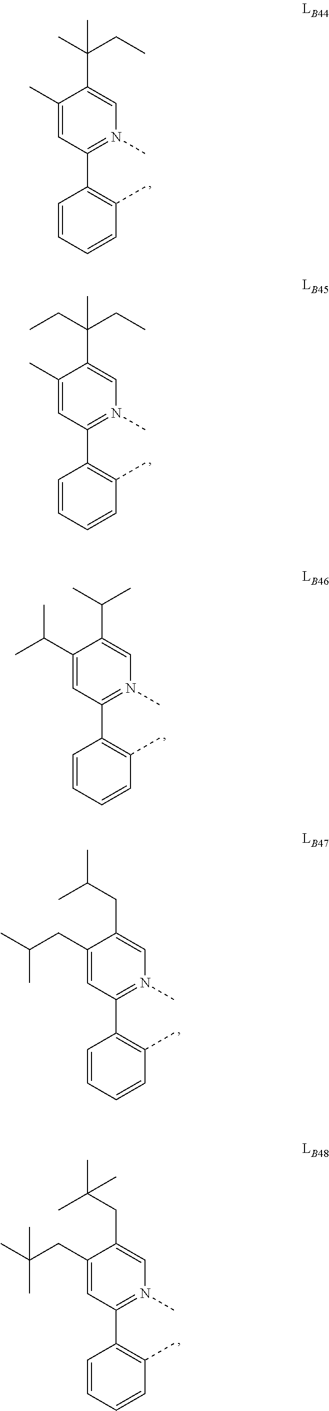

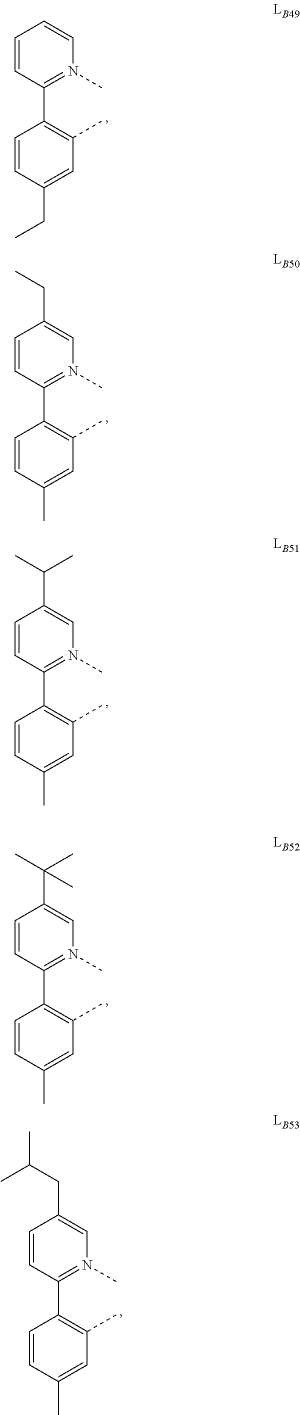

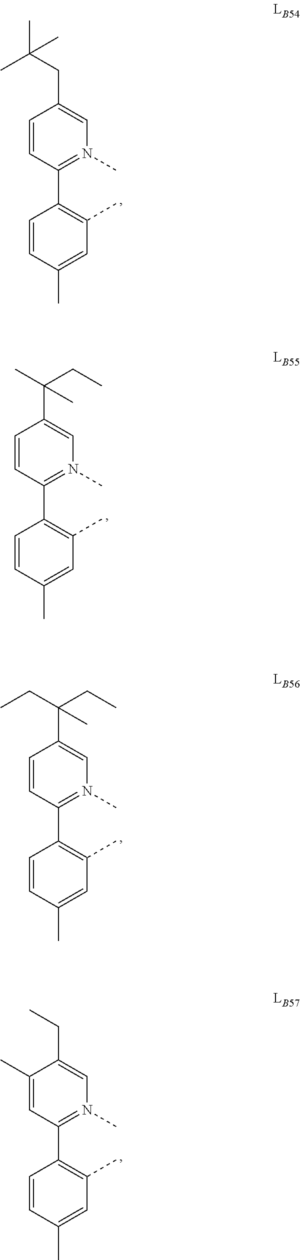

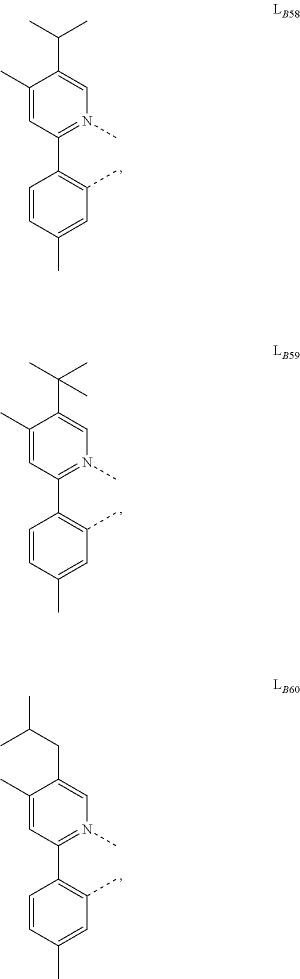

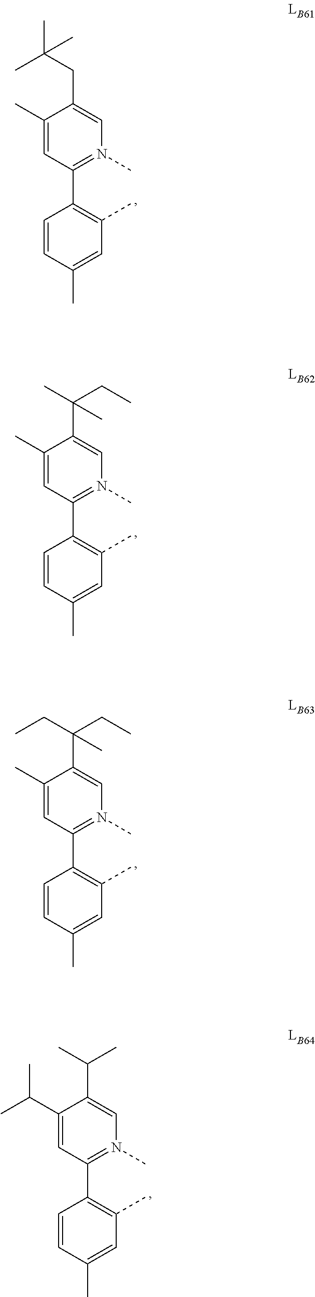

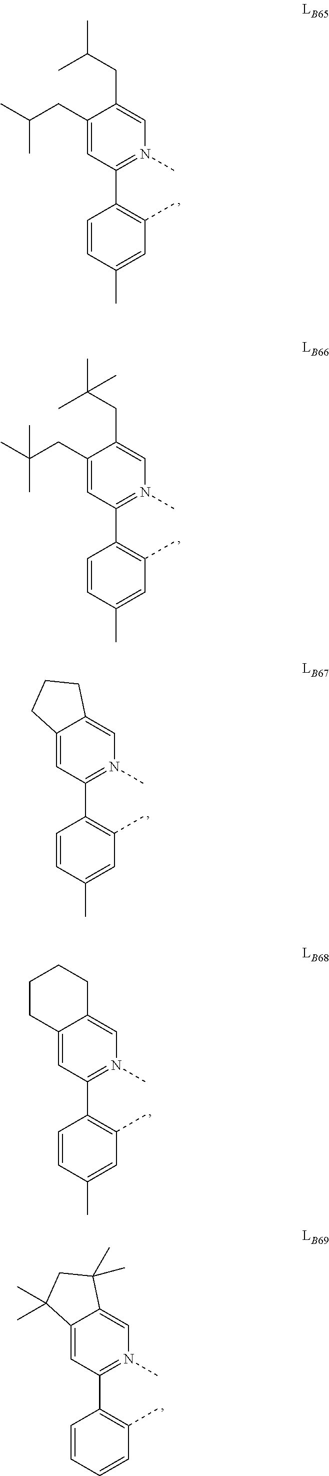

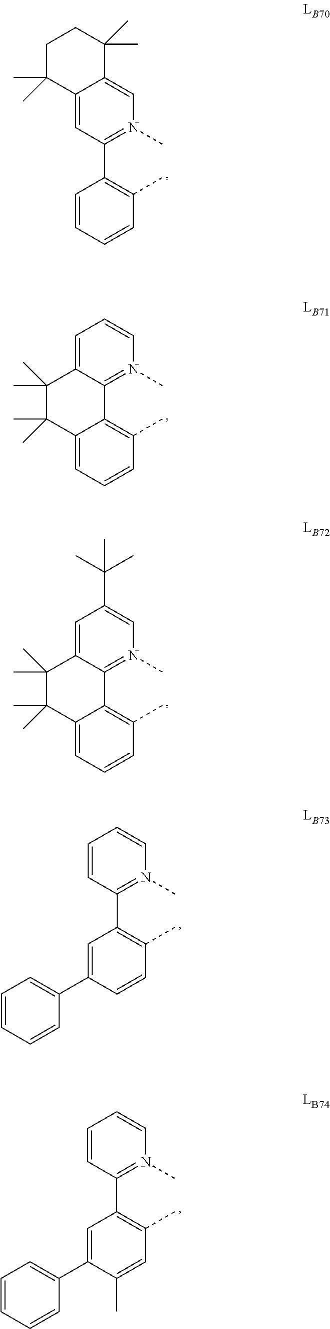

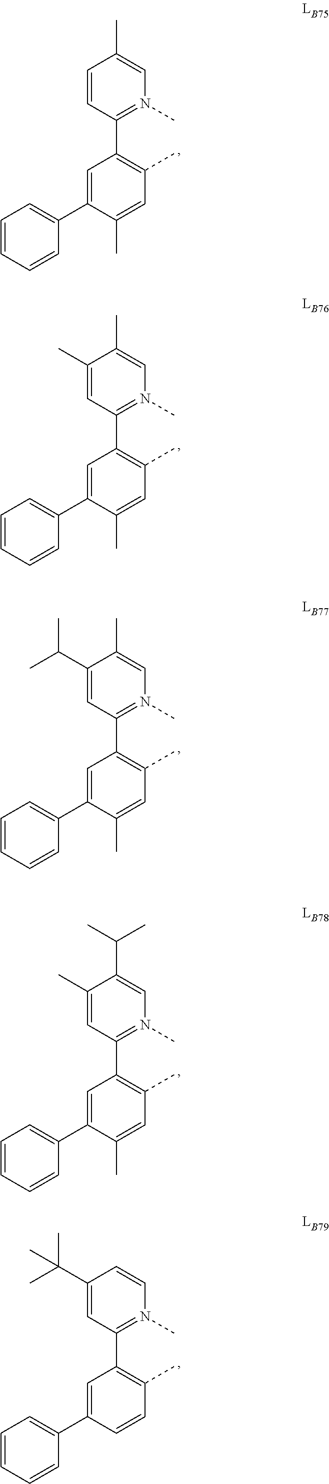

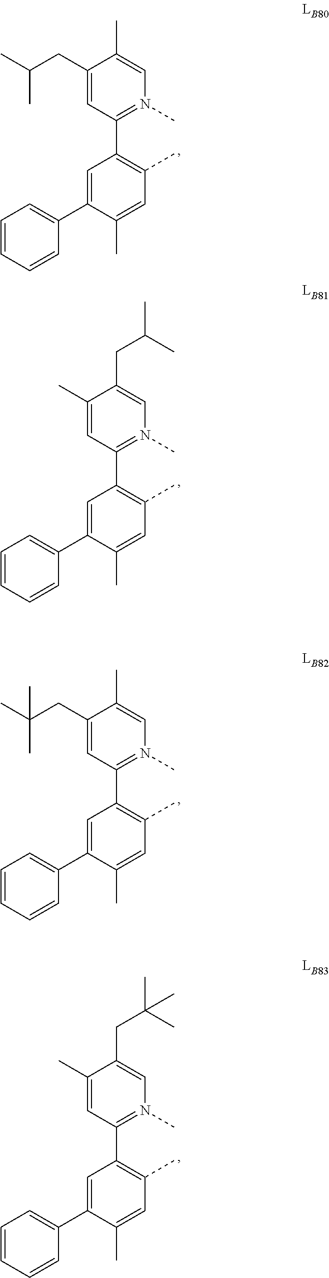

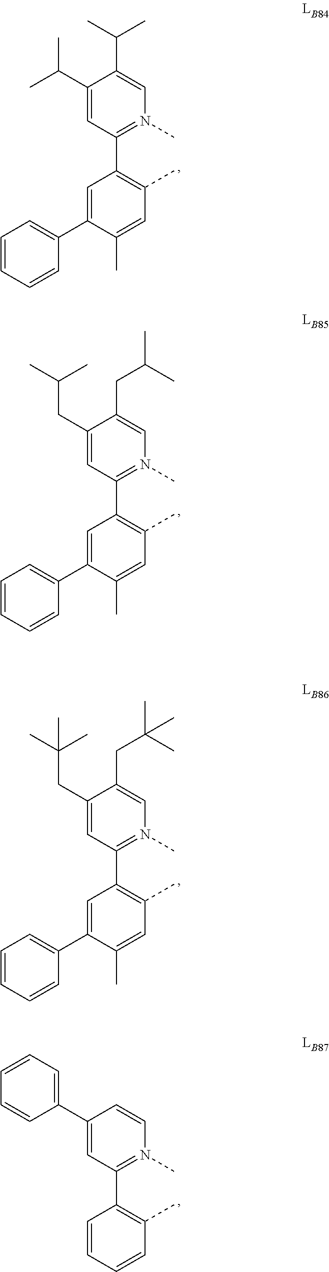

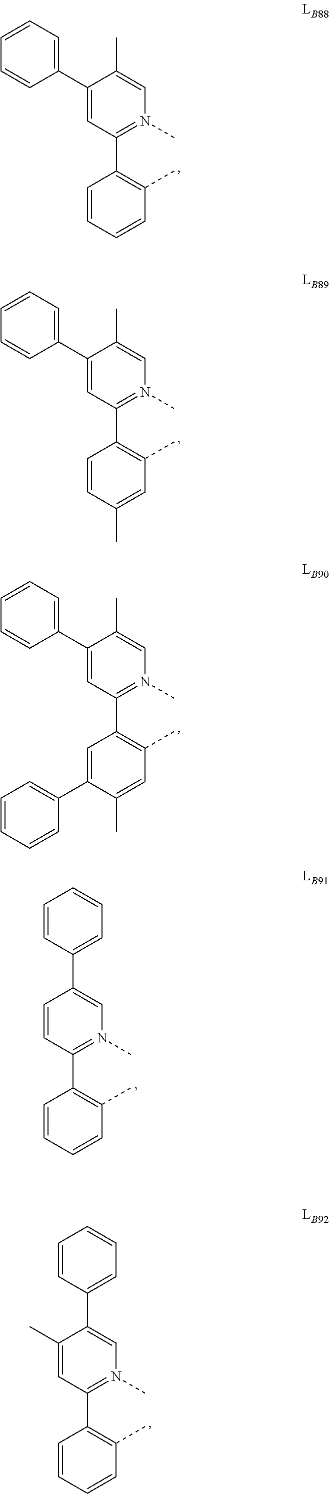

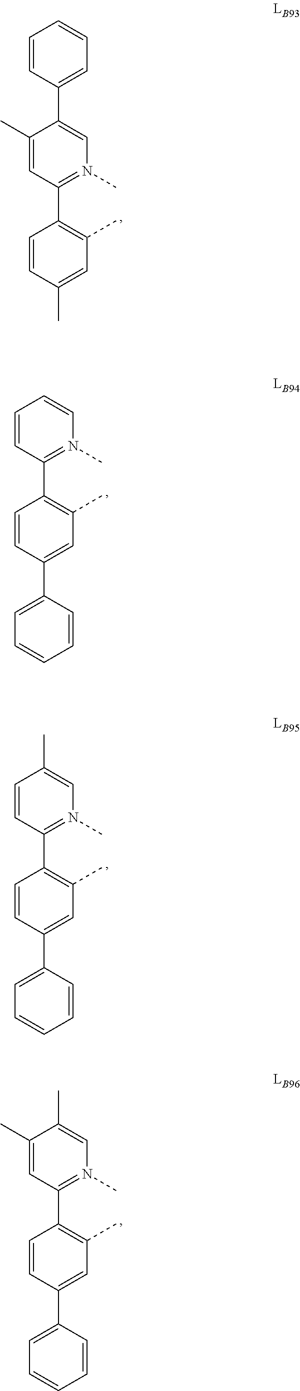

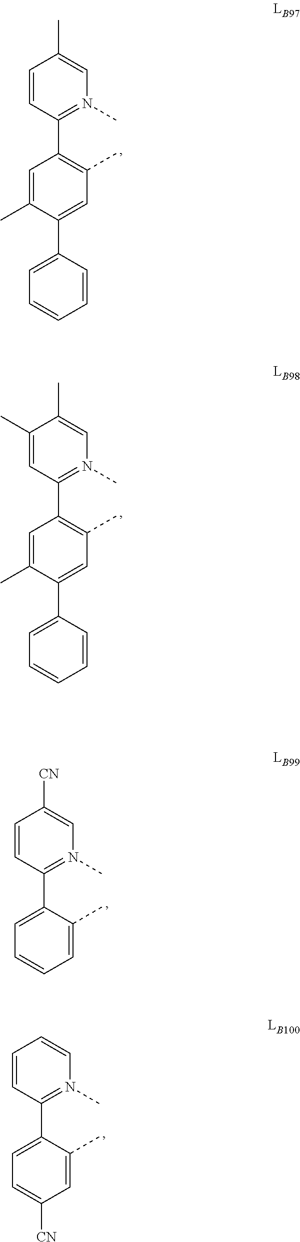

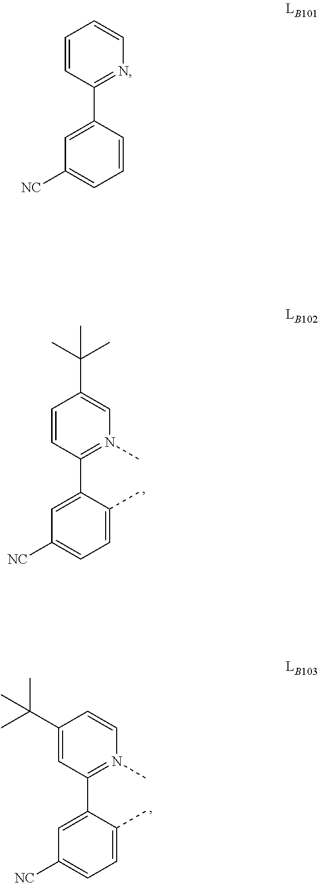

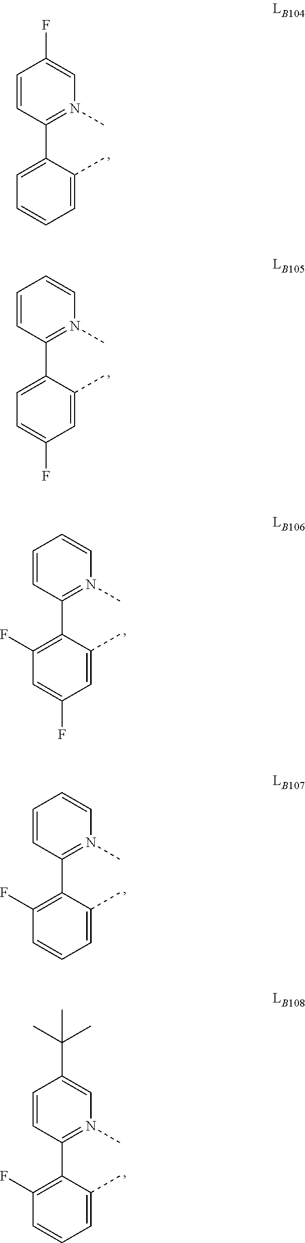

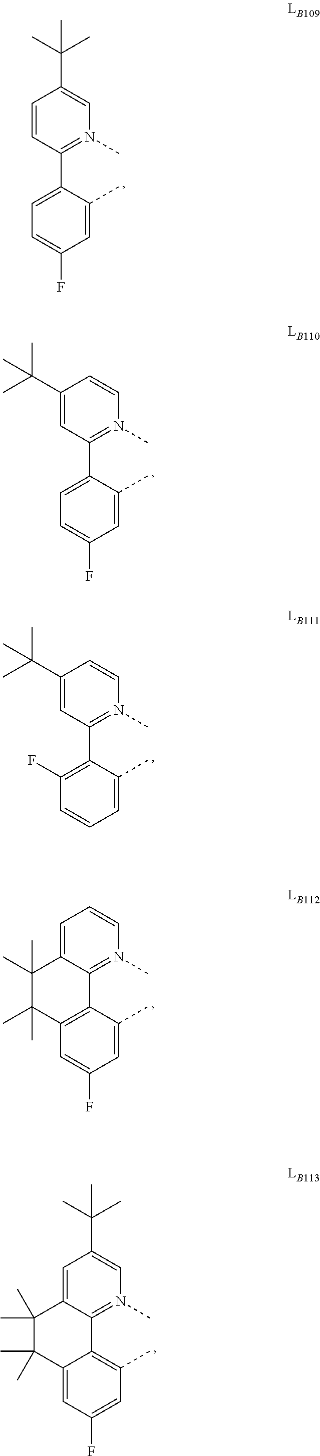

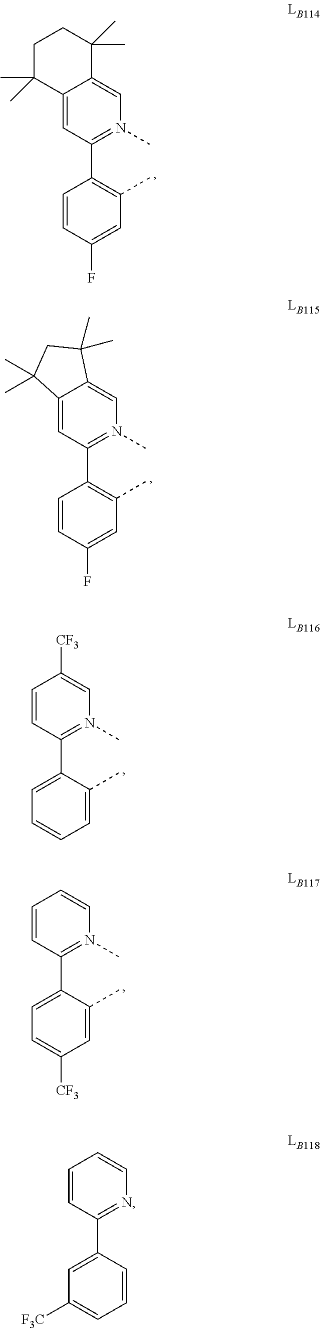

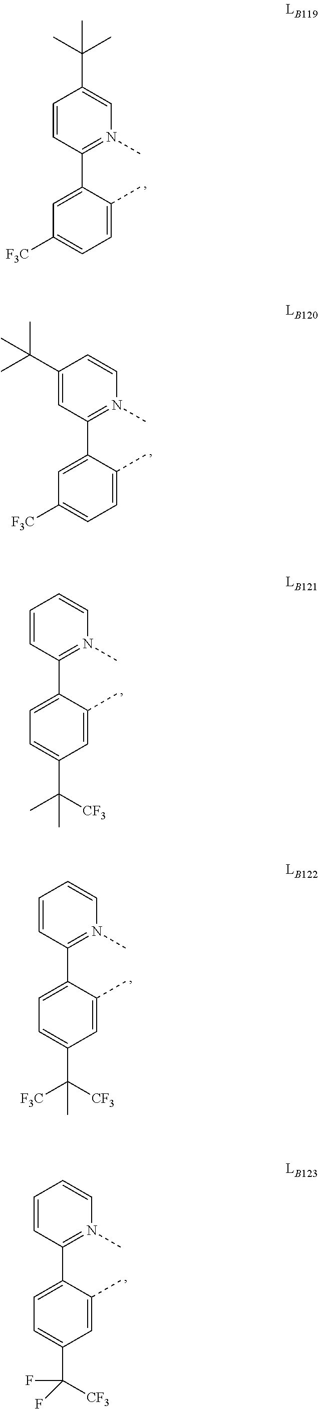

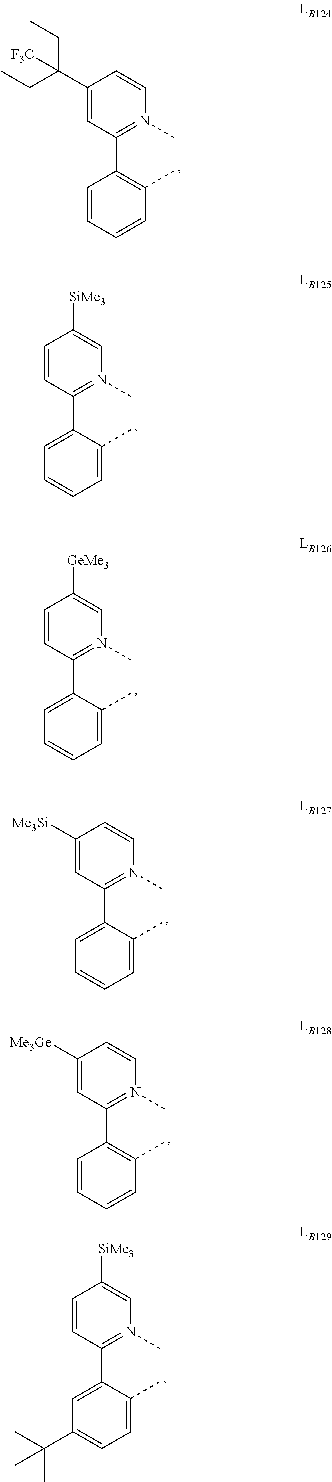

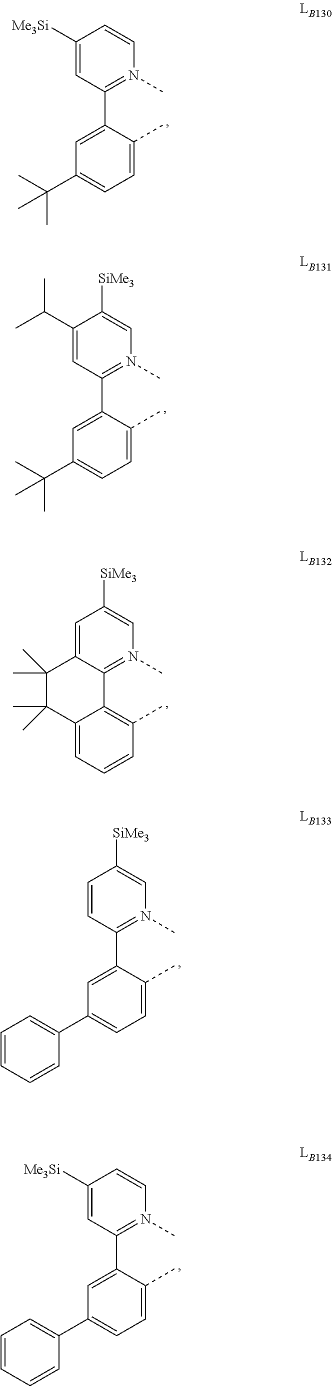

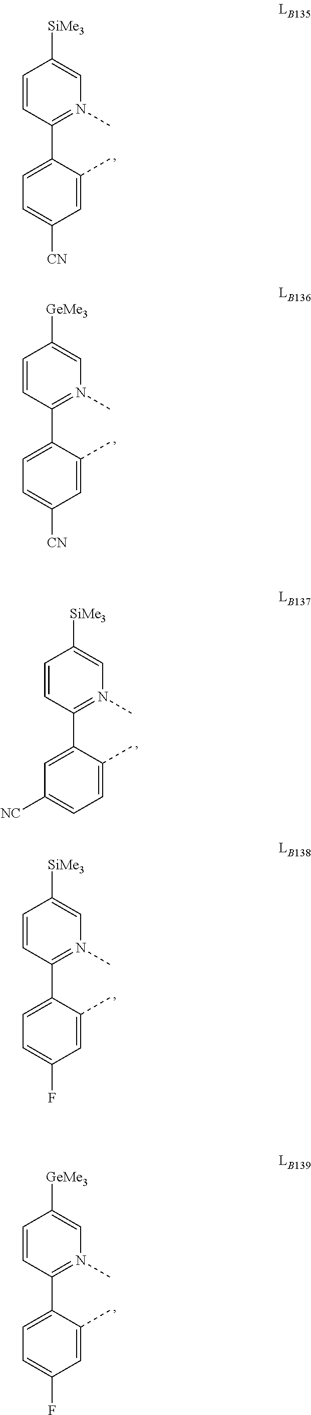

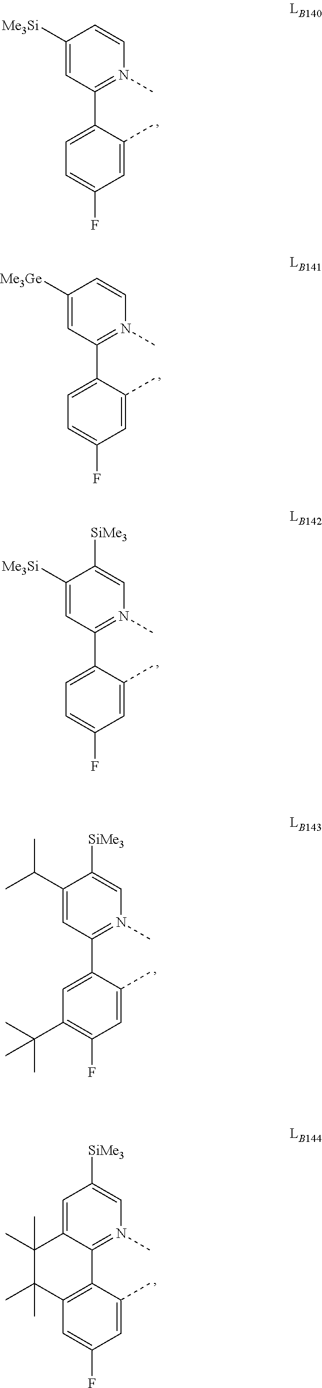

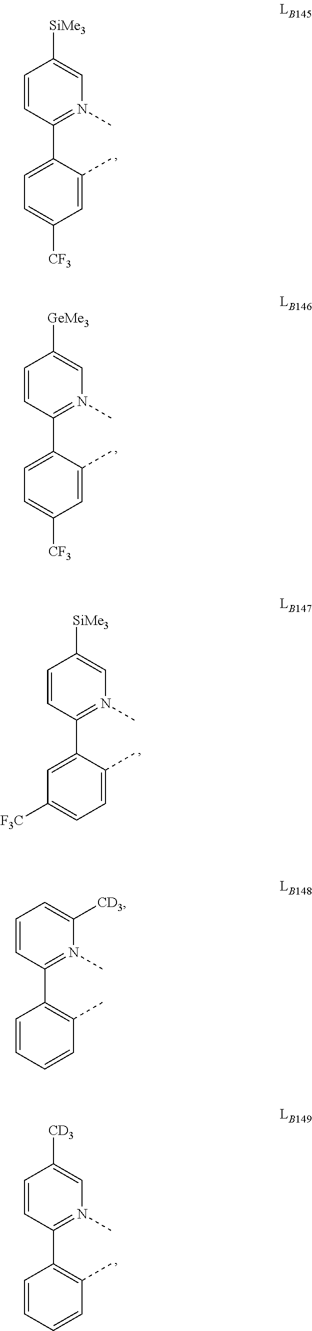

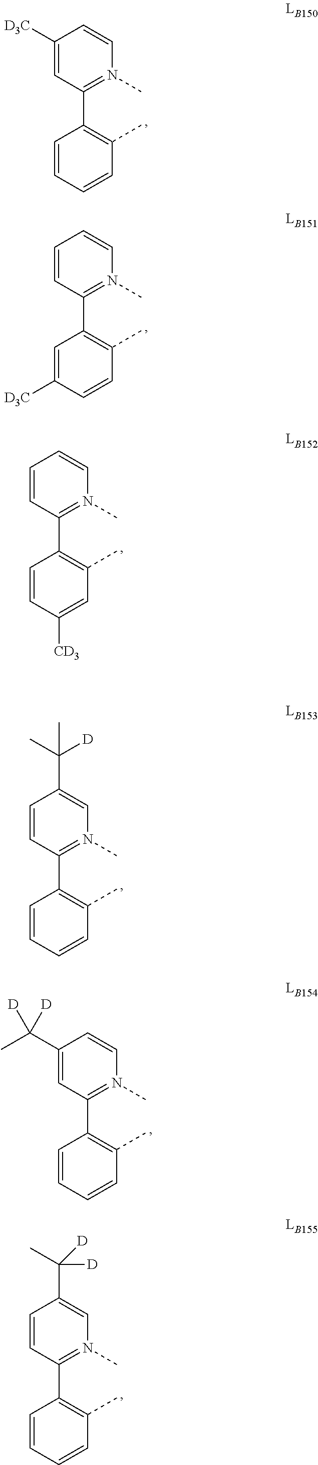

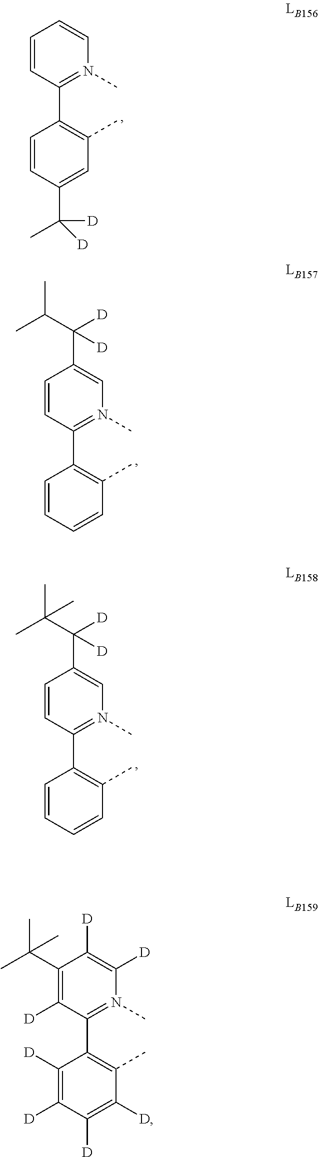

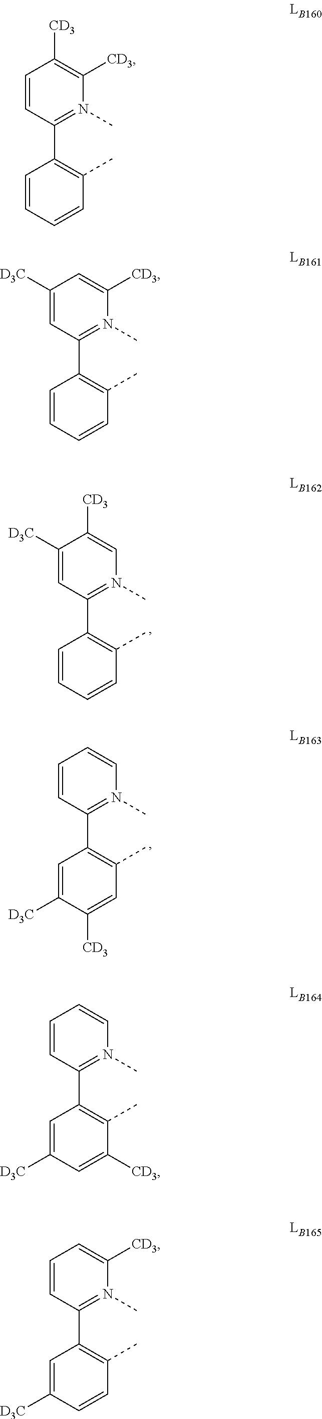

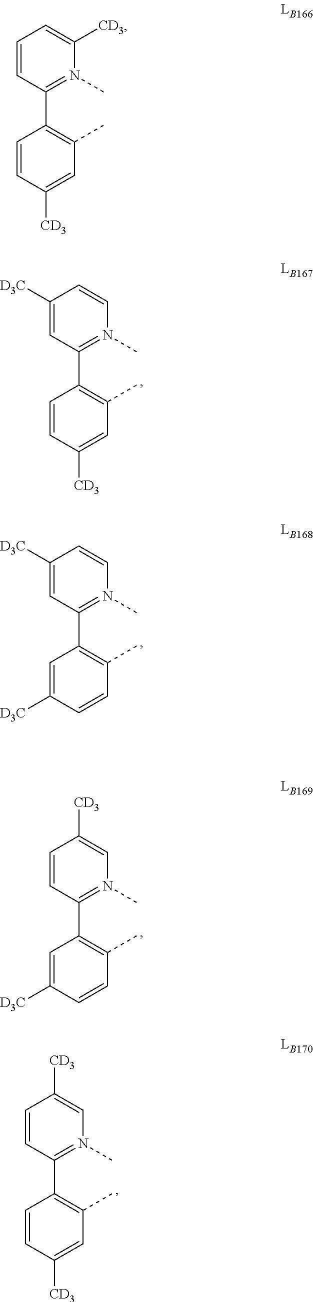

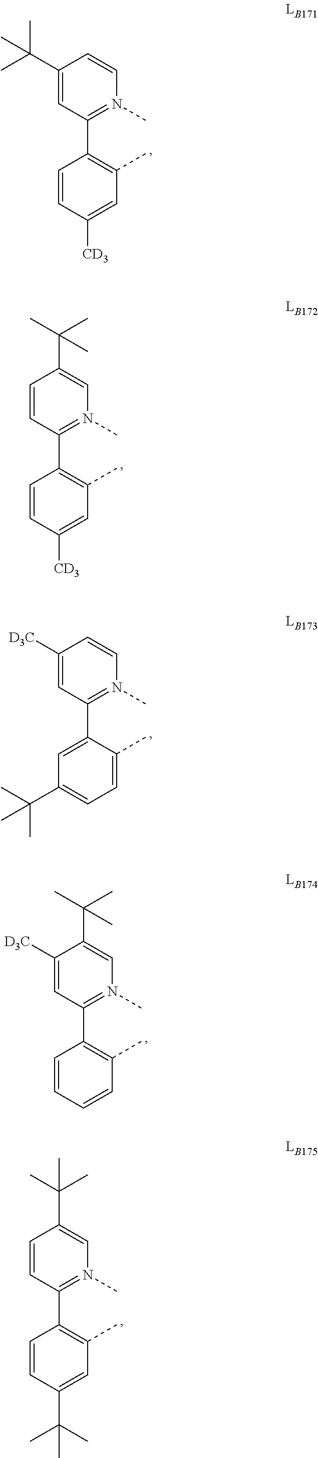

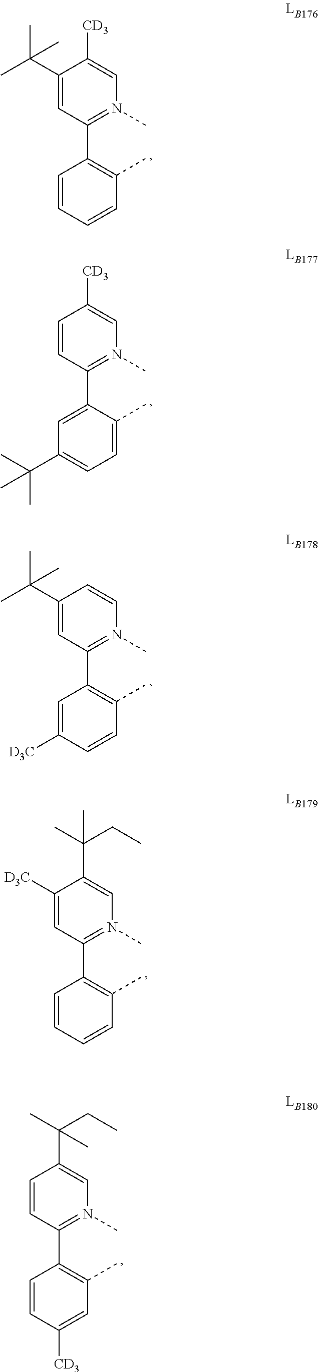

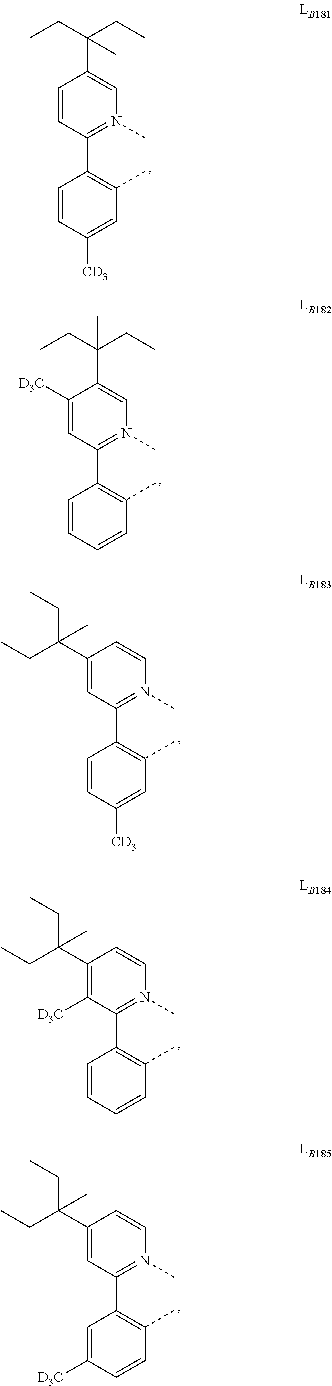

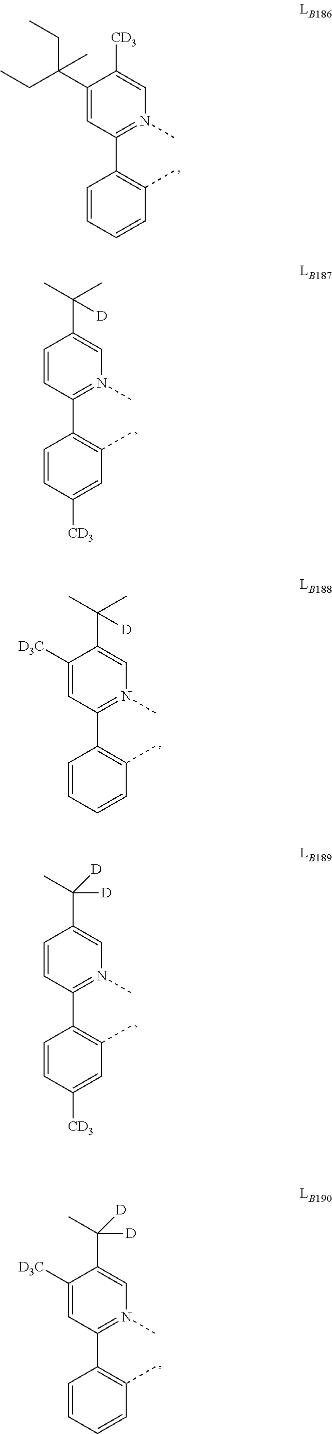

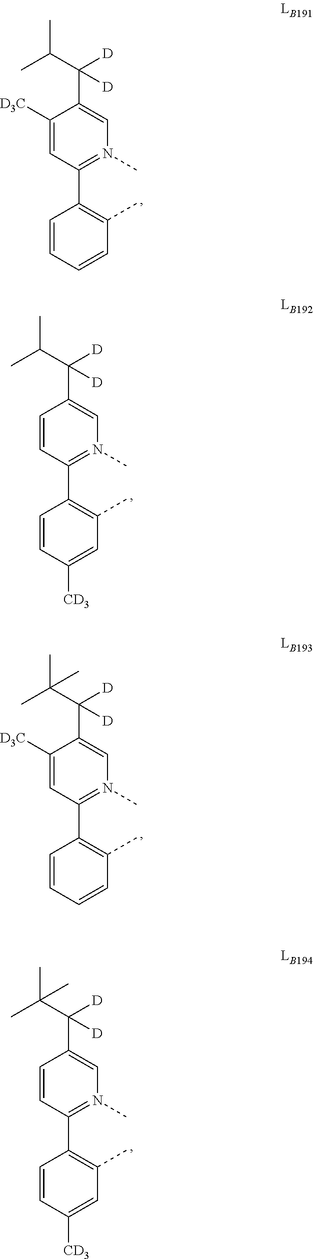

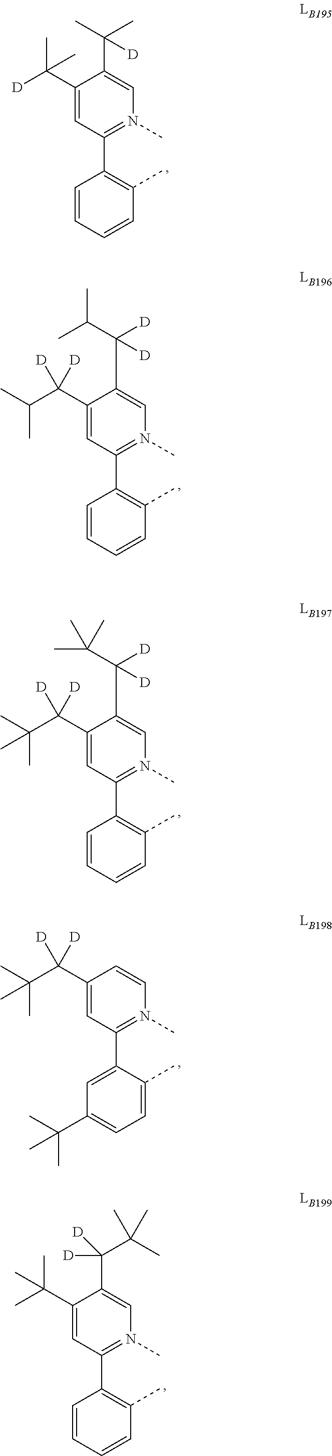

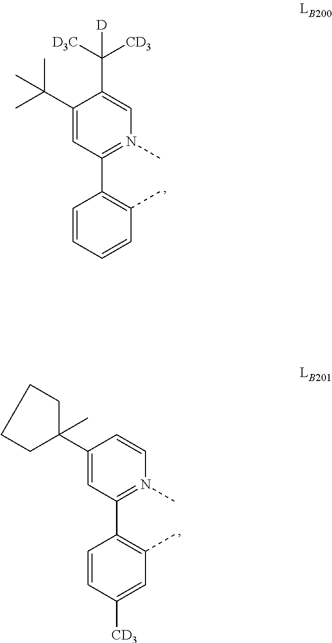

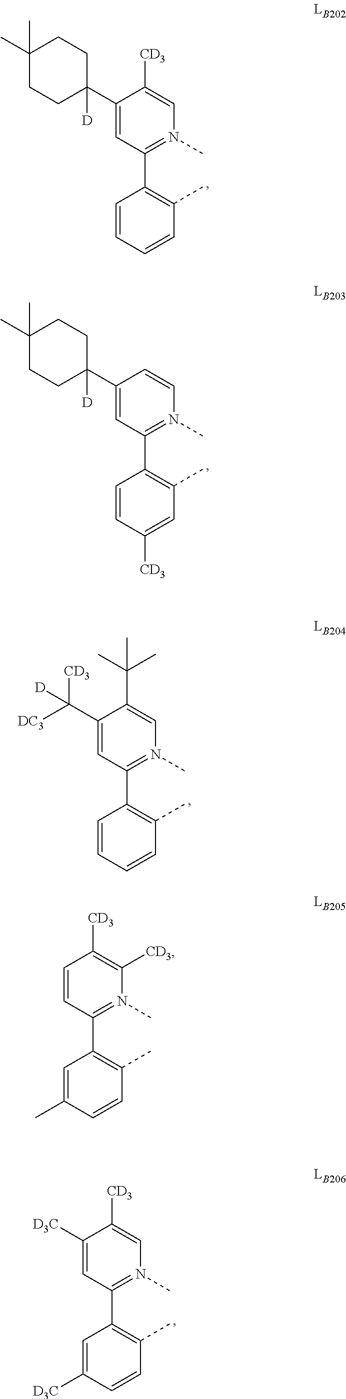

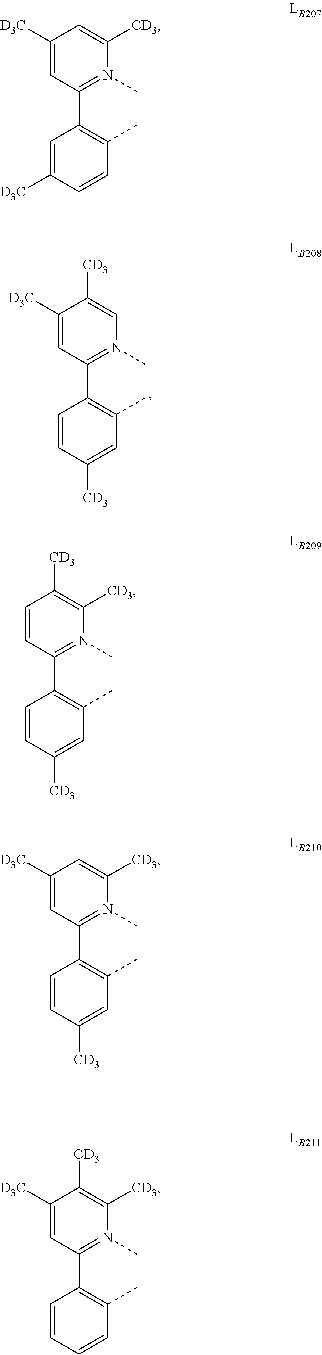

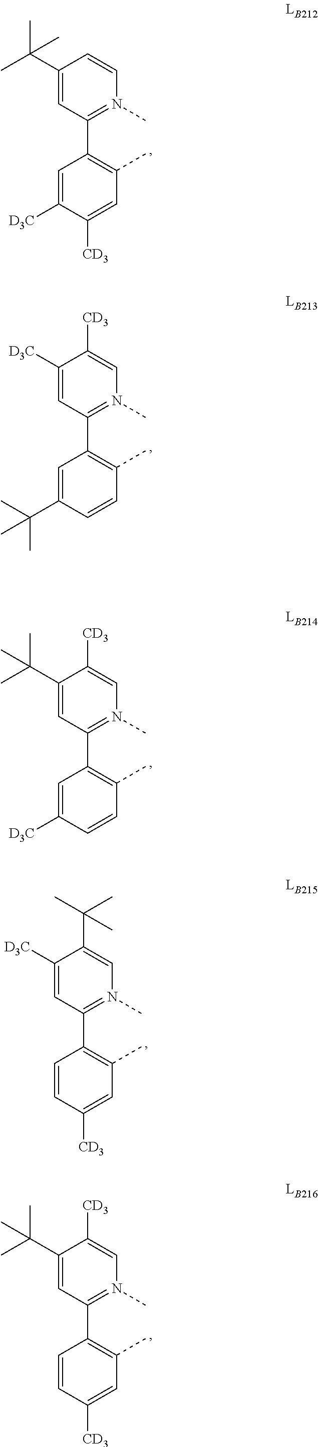

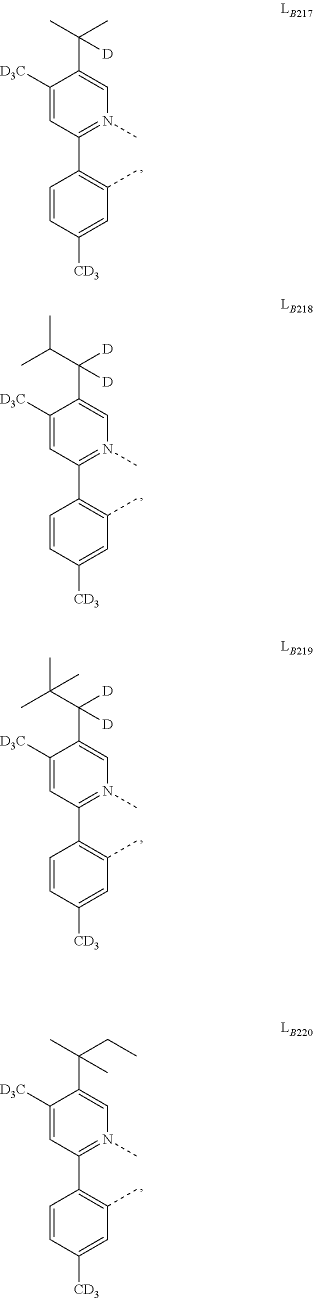

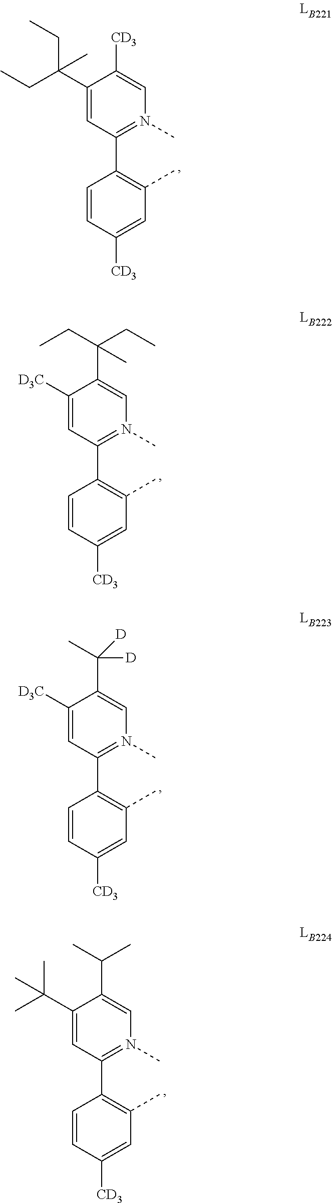

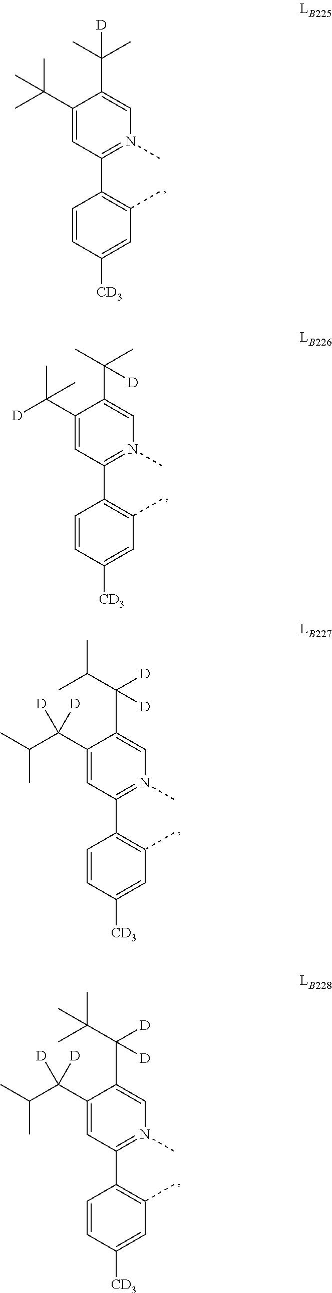

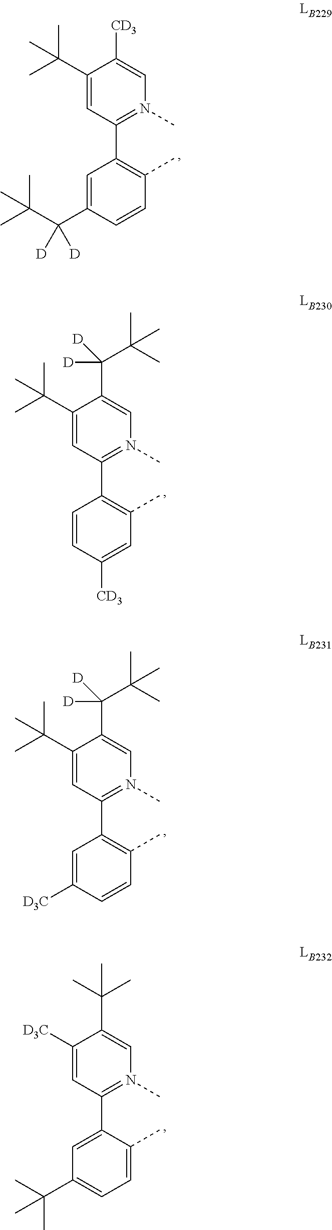

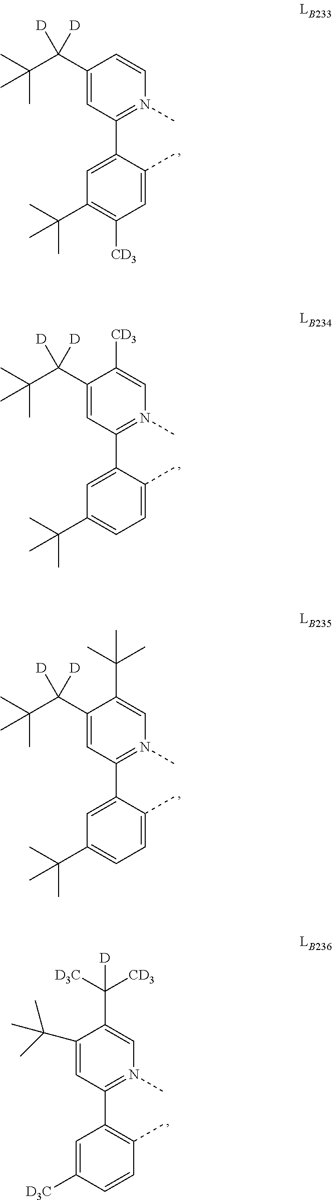

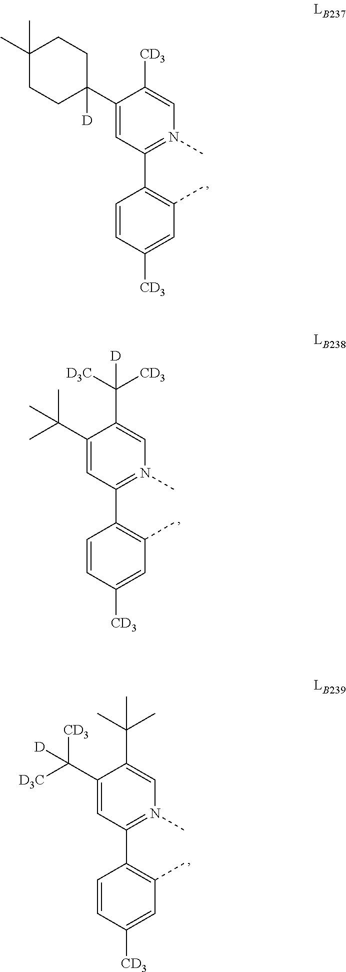

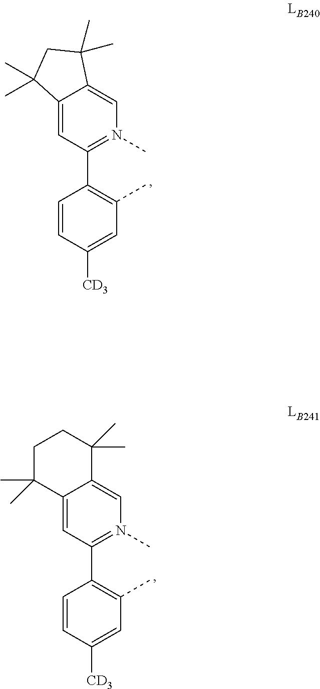

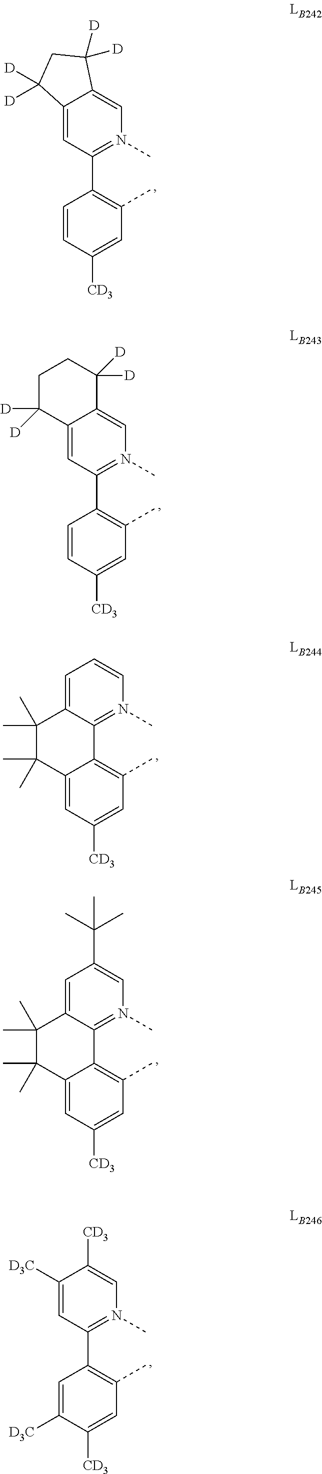

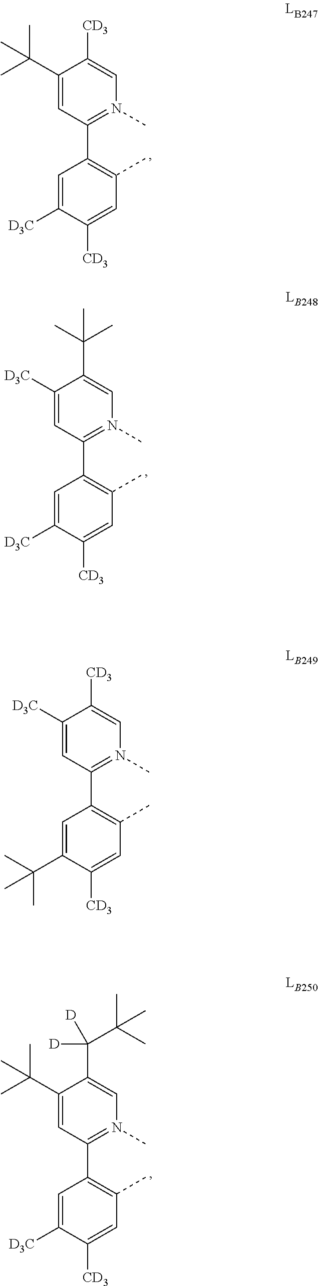

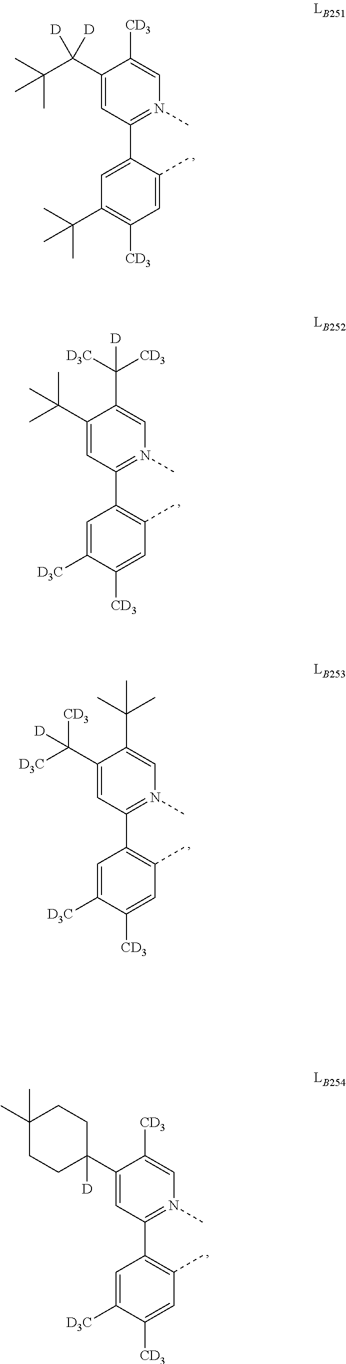

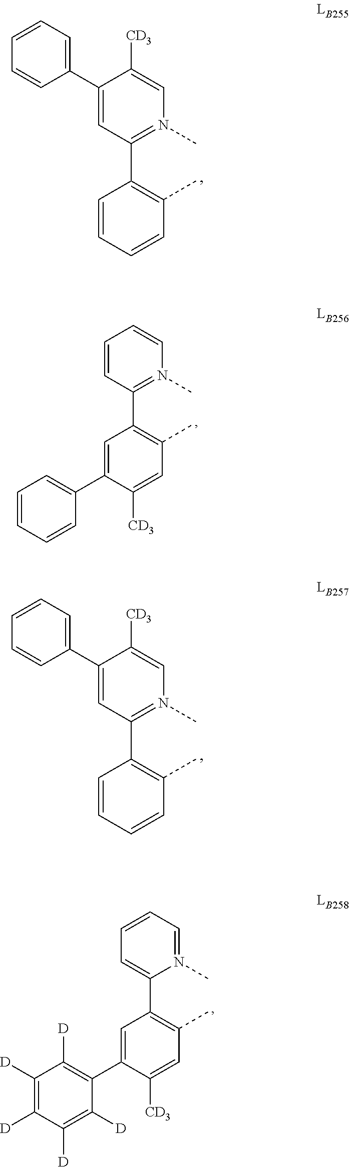

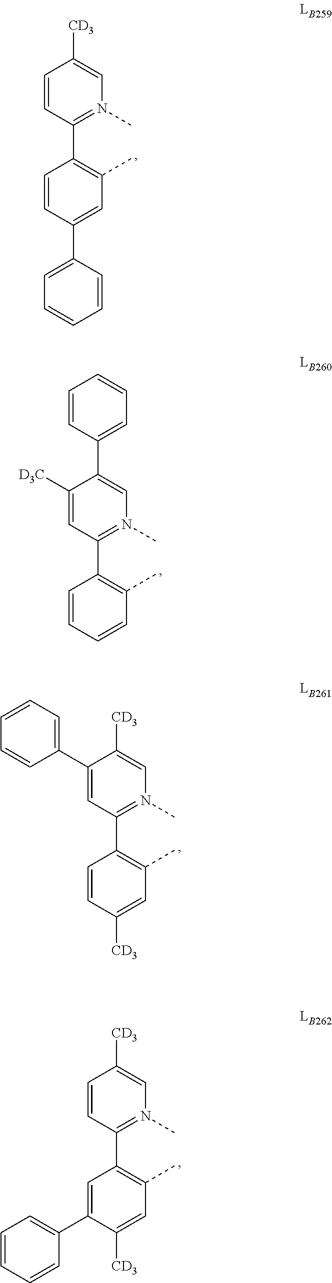

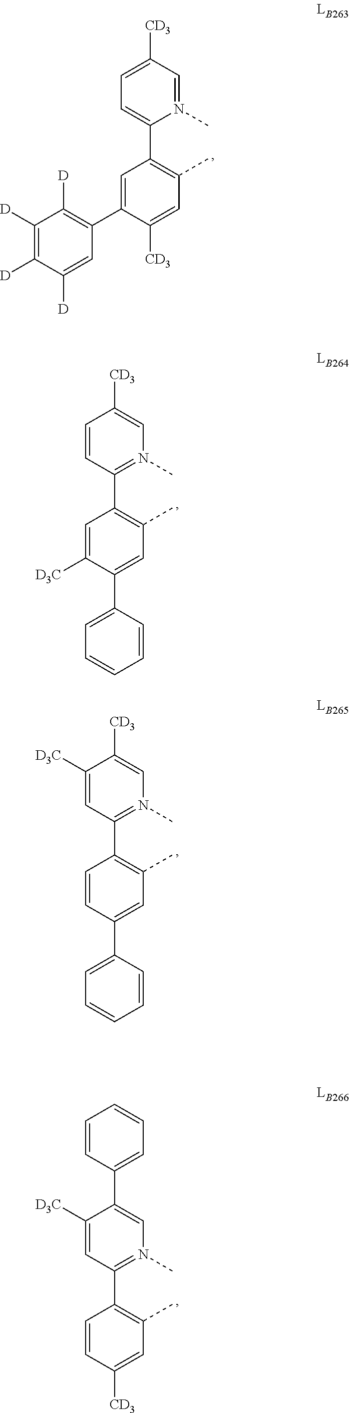

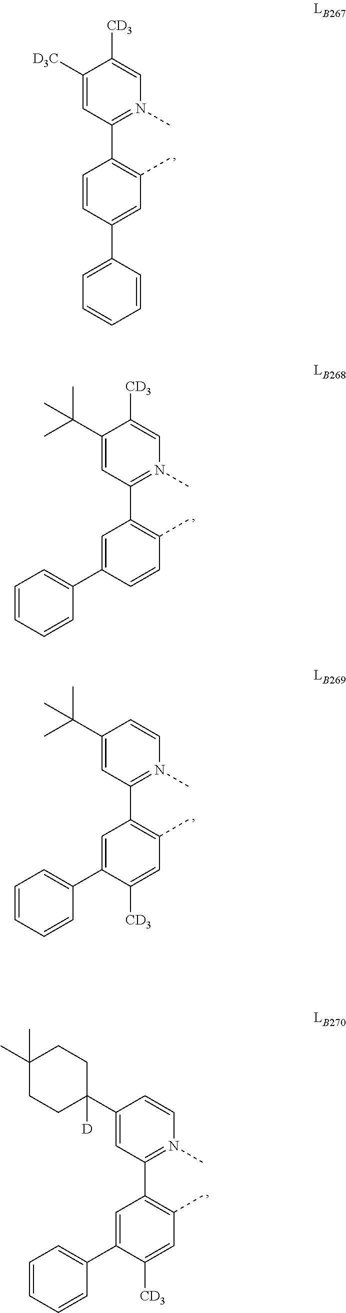

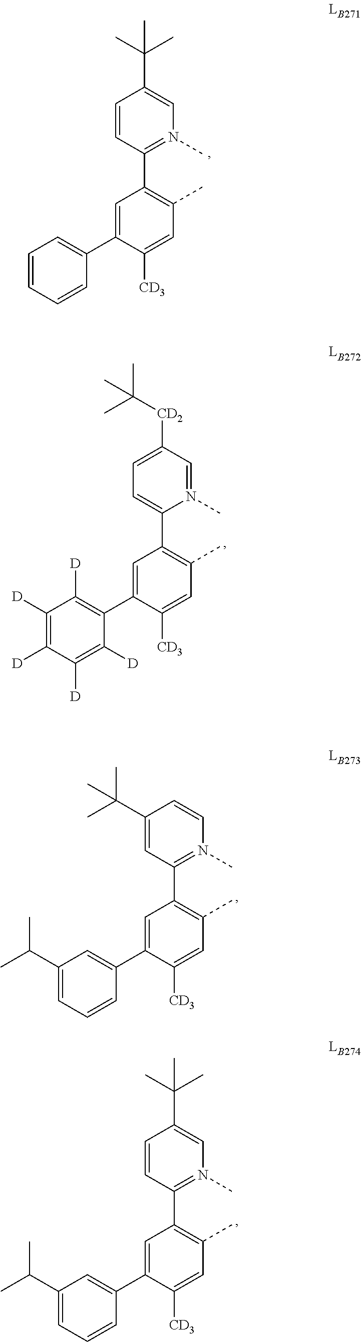

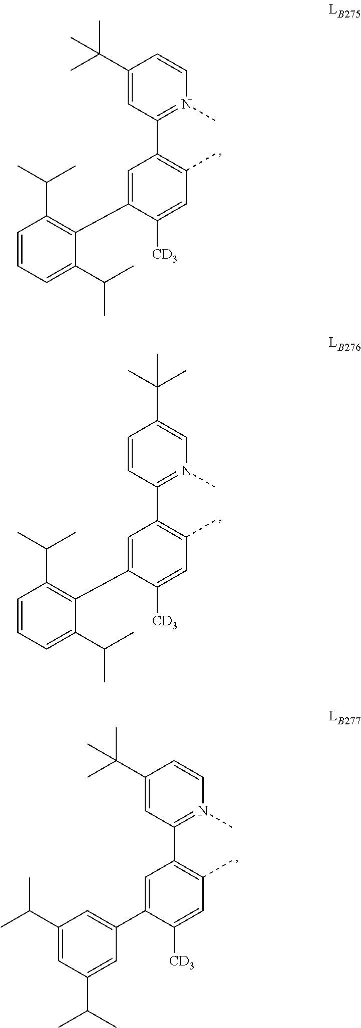

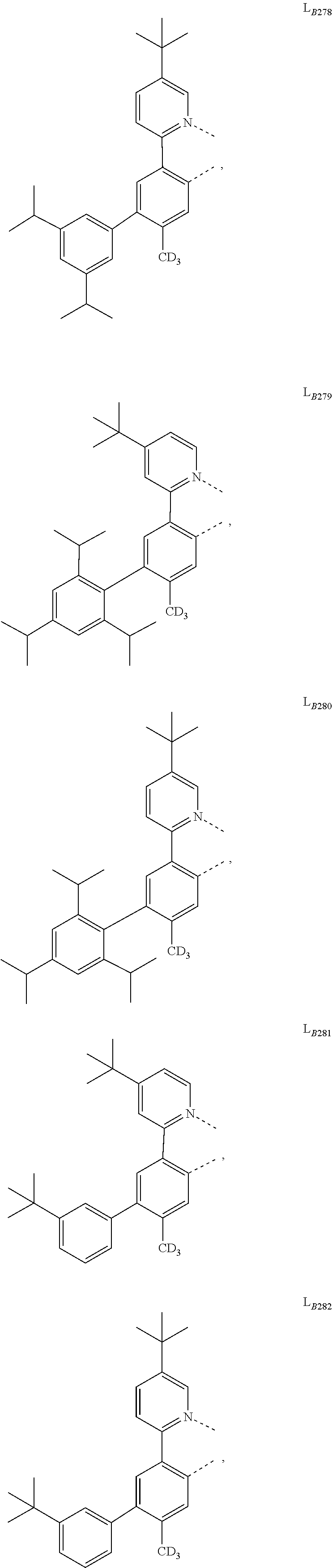

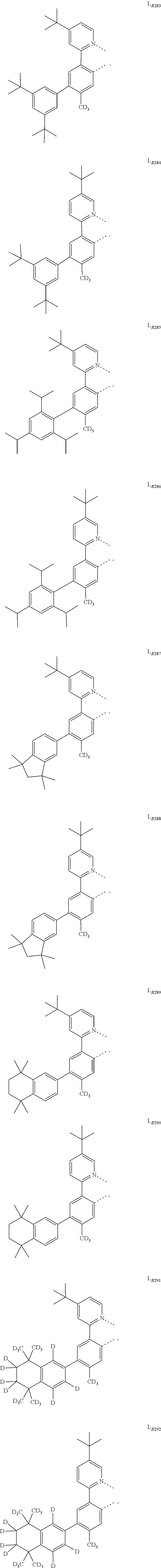

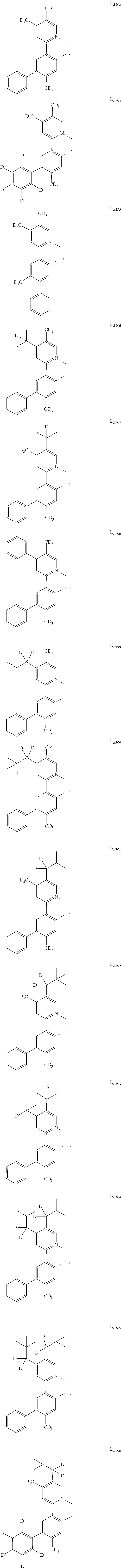

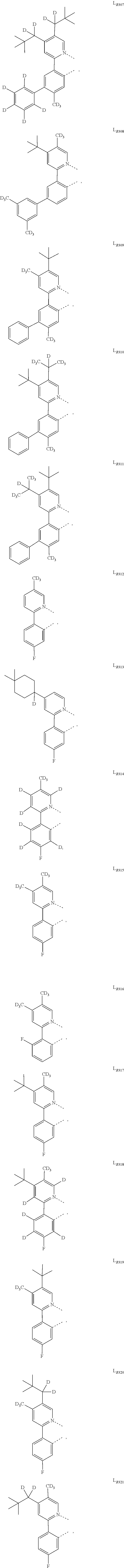

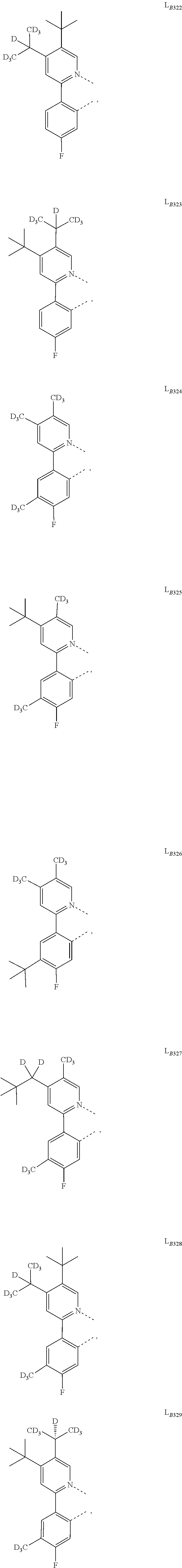

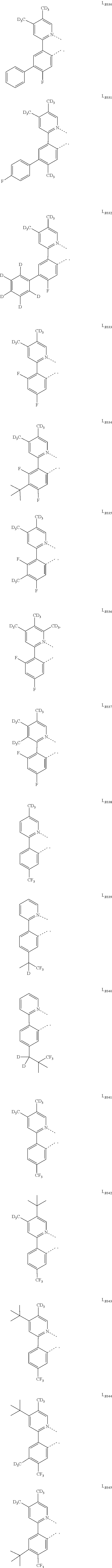

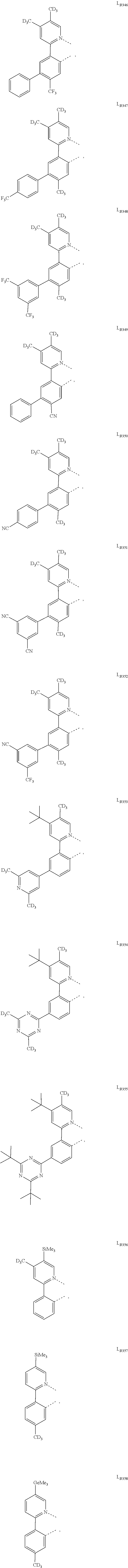

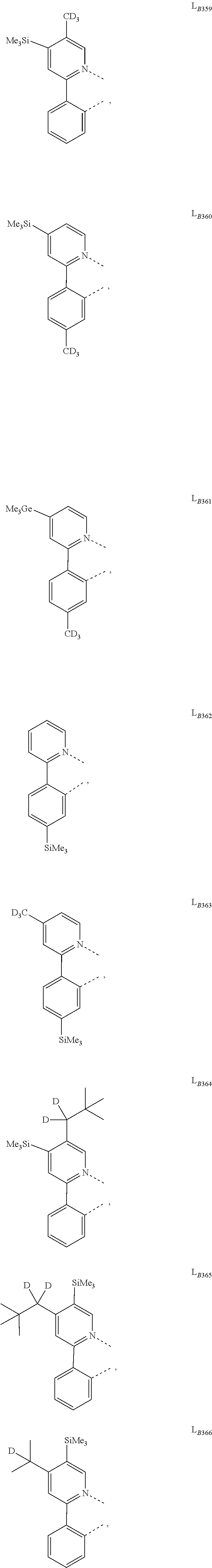

[chemical structure]

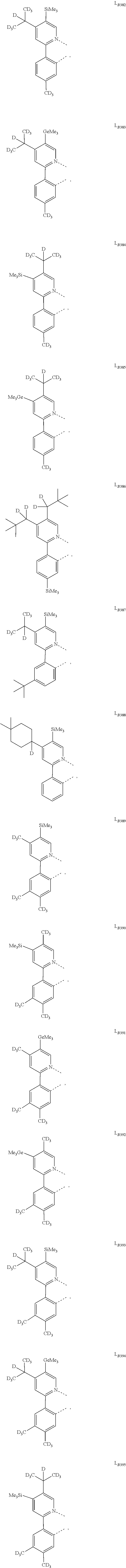

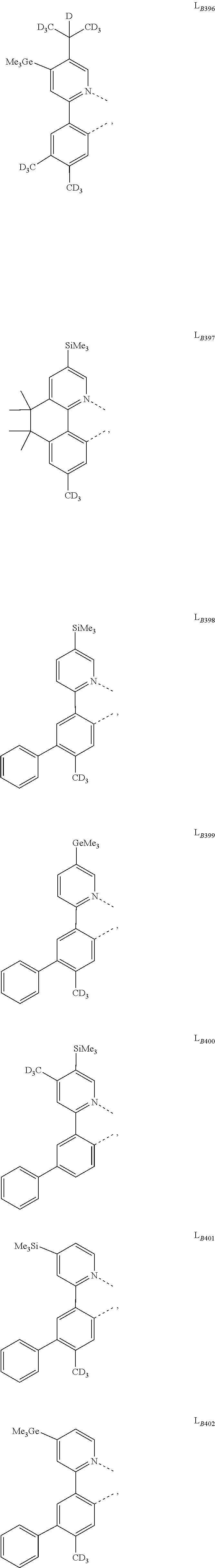

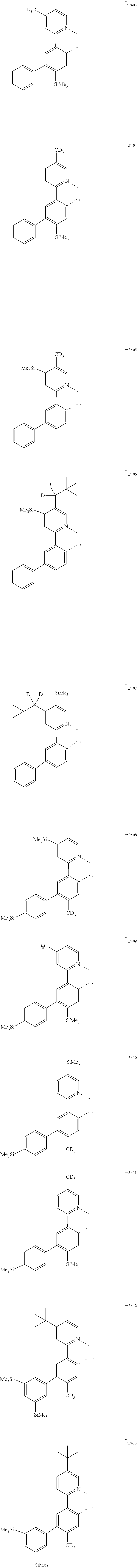

[chemical structure]

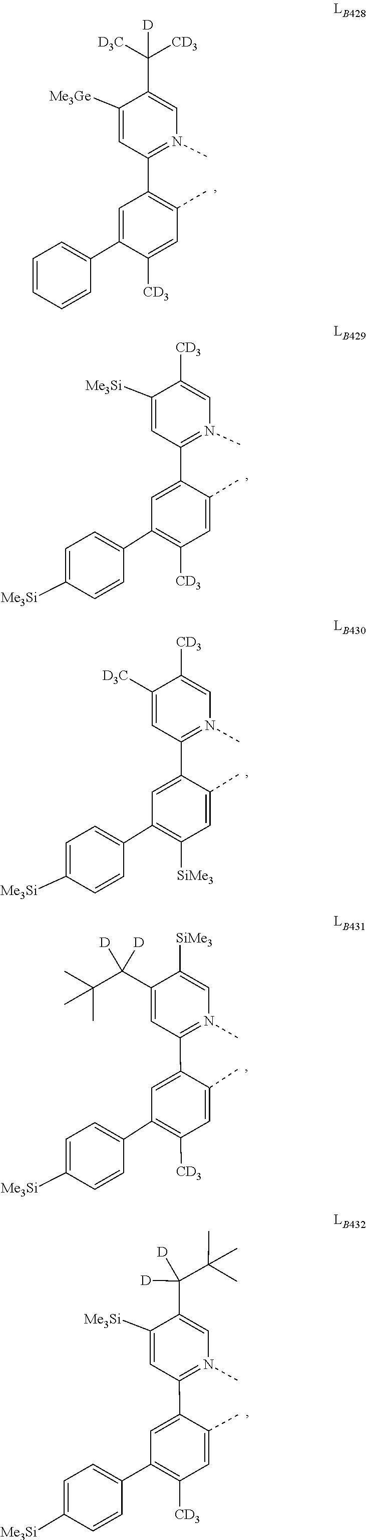

[chemical structure]

[chemical structure]

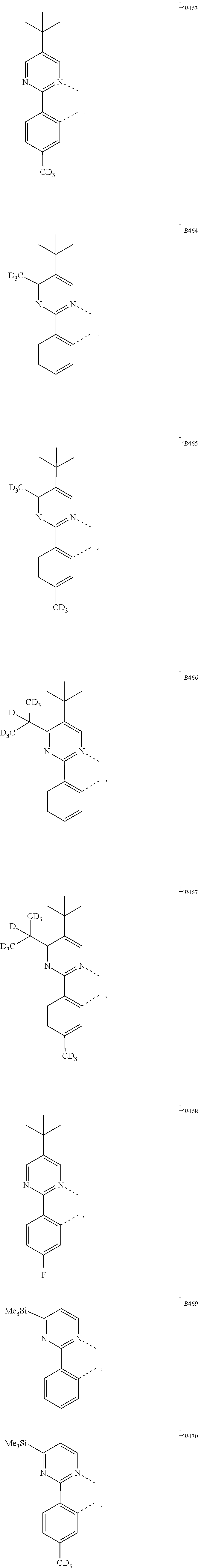

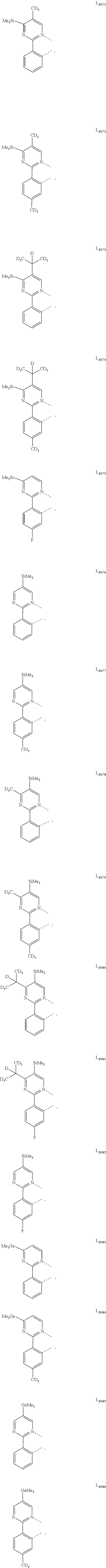

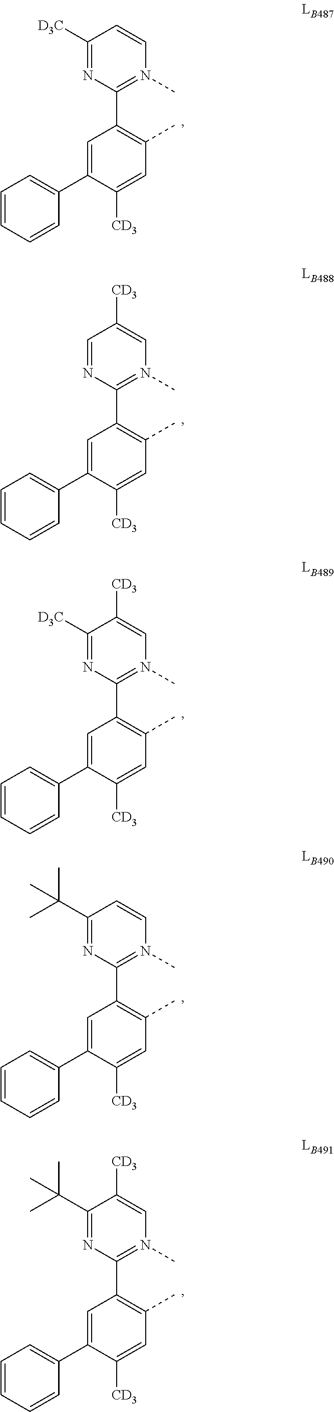

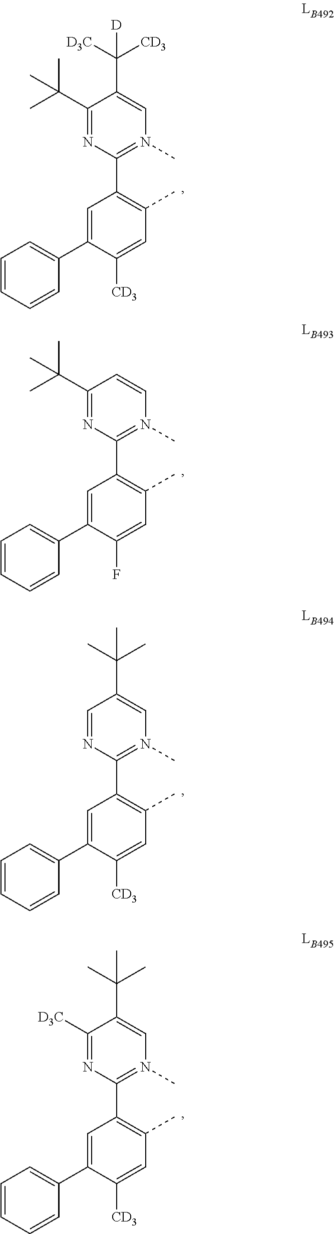

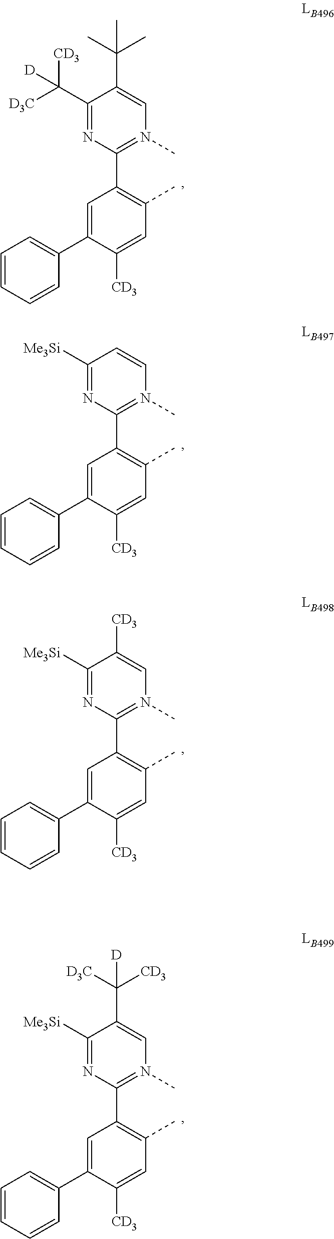

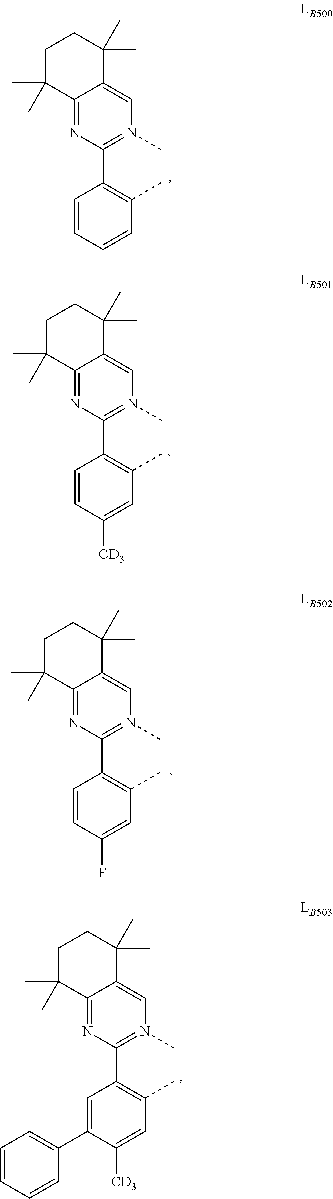

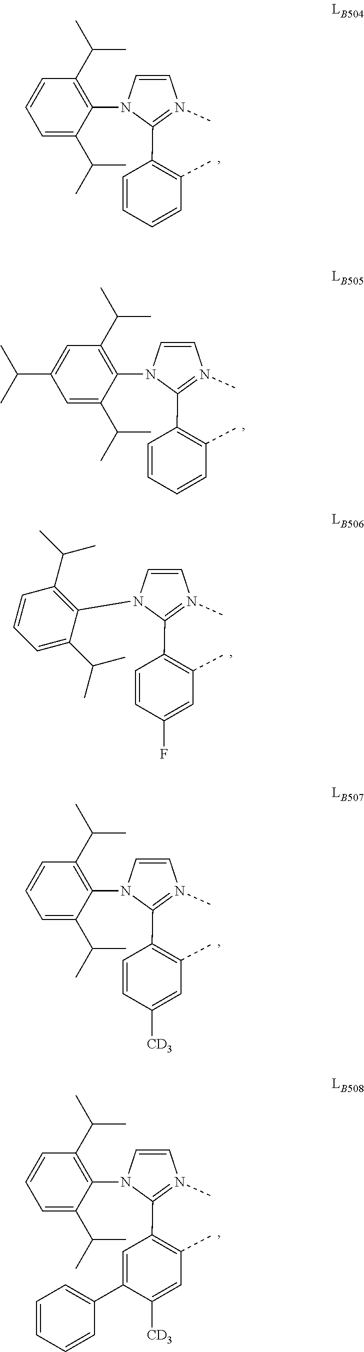

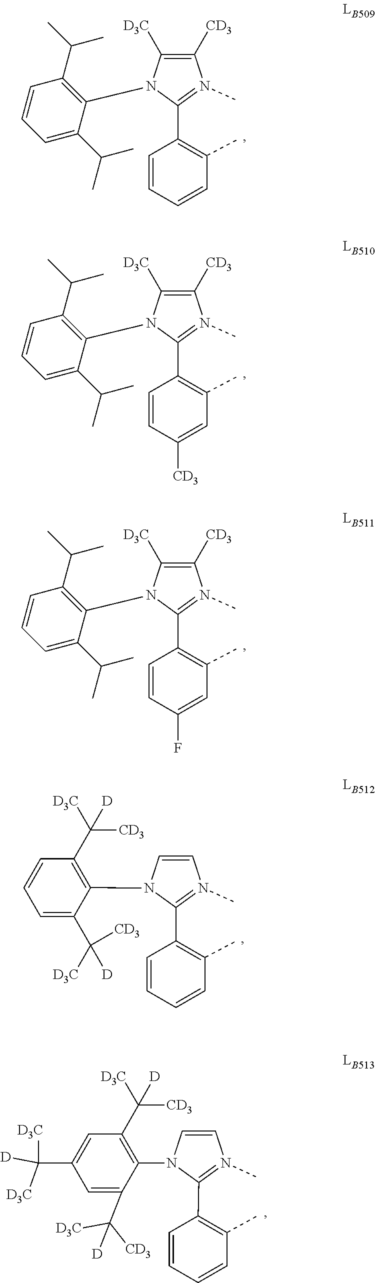

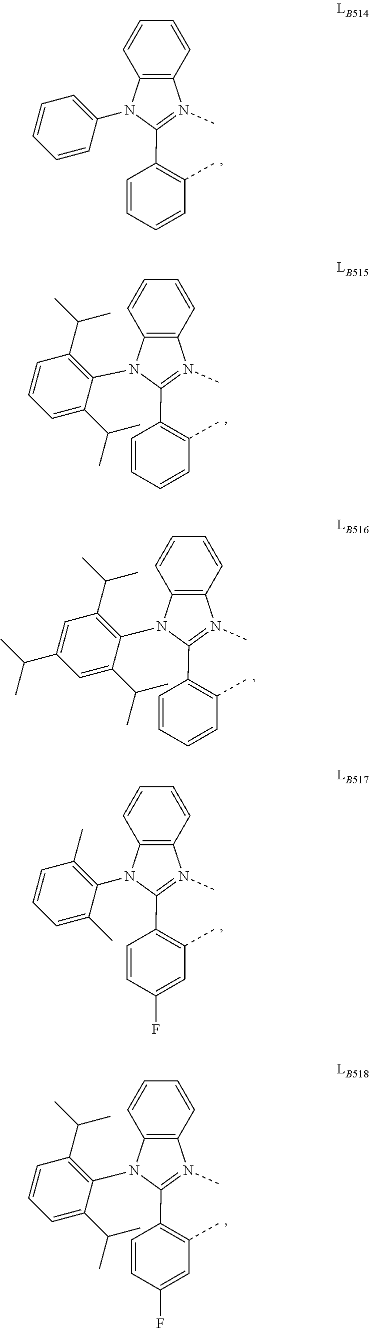

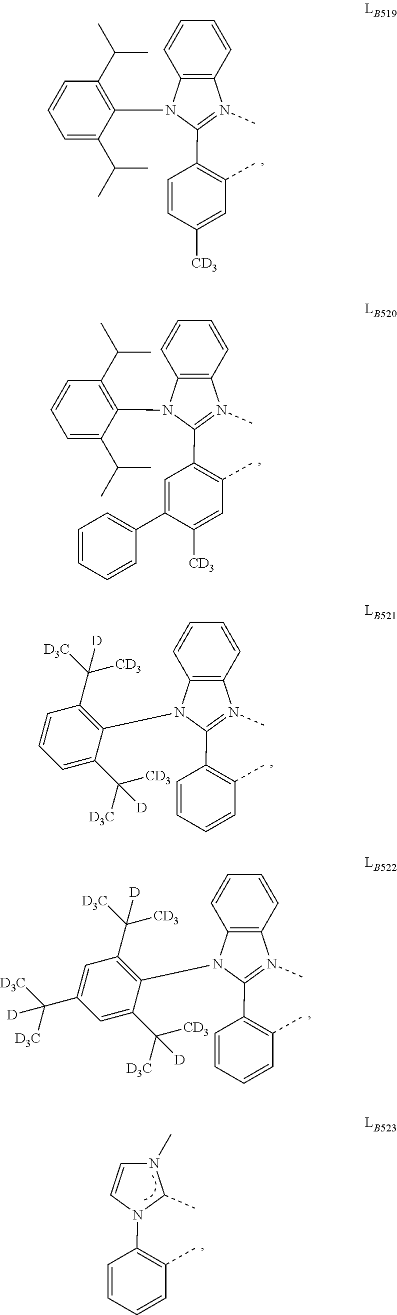

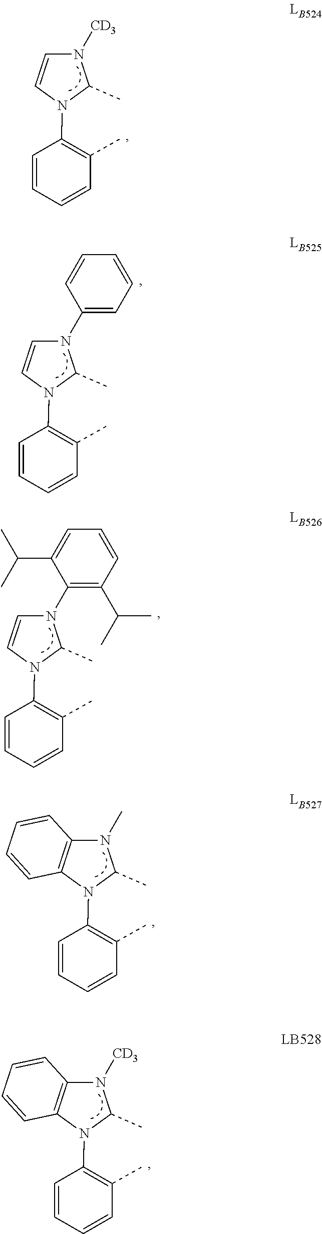

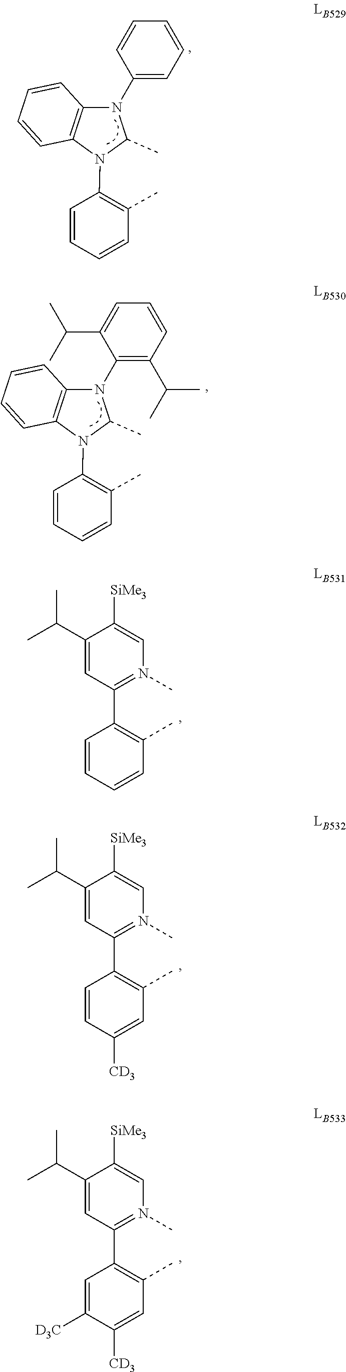

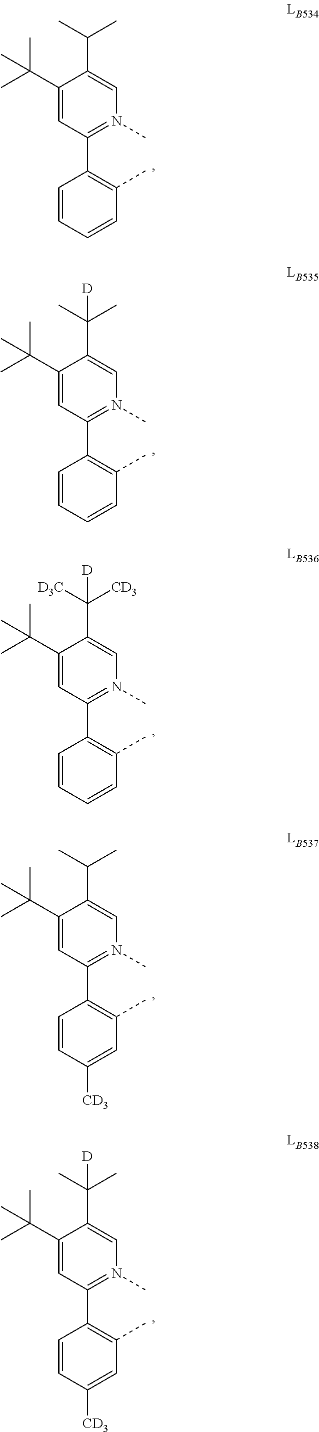

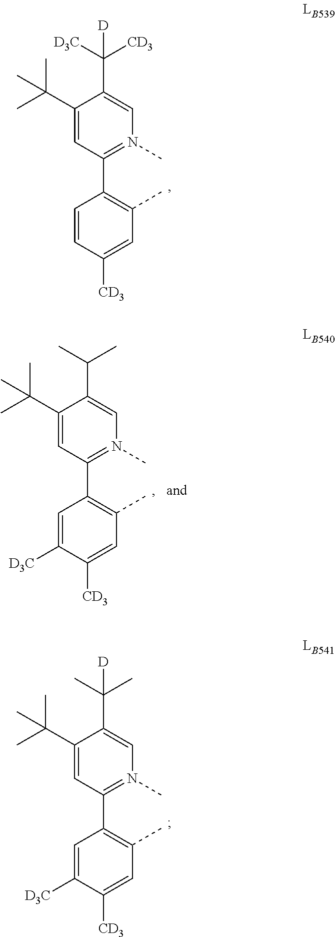

wherein each L_{Cj-I} has a structure based on formula

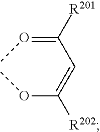

and
each L_{Cj-II} has a structure based on formula

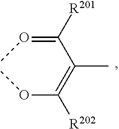

wherein for each L_{Cj} in L_{Cj-I} and L_{Cj-II}, R²⁰¹ and R²⁰² are each independently defined as follows (LIST 7):

| L_{Cj} | R²⁰¹ | R²⁰² | L_{Cj} | R²⁰¹ | R²⁰² | L_{Cj} | R²⁰¹ | R²⁰² | L_{Cj} | R²⁰¹ | R²⁰² |
|---|---|---|---|---|---|---|---|---|---|---|---|
| L_{C1} | R^{D1} | R^{D1} | L_{C193} | R^{D1} | R^{D3} | L_{C385} | R^{D17} | R^{D40} | L_{C577} | R^{D143} | R^{D120} |
| L_{C2} | R^{D2} | R^{D2} | L_{C194} | R^{D1} | R^{D4} | L_{C386} | R^{D17} | R^{D41} | L_{C578} | R^{D143} | R^{D133} |
| L_{C3} | R^{D3} | R^{D3} | L_{C195} | R^{D1} | R^{D5} | L_{C387} | R^{D17} | R^{D42} | L_{C579} | R^{D143} | R^{D134} |
| L_{C4} | R^{D4} | R^{D4} | L_{C196} | R^{D1} | R^{D9} | L_{C388} | R^{D17} | R^{D43} | L_{C580} | R^{D143} | R^{D135} |
| L_{C5} | R^{D5} | R^{D5} | L_{C197} | R^{D1} | R^{D10} | L_{C389} | R^{D17} | R^{D48} | L_{C581} | R^{D143} | R^{D136} |
| L_{C6} | R^{DE} | R^{D6} | L_{C198} | R^{D1} | R^{D17} | L_{C390} | R^{D17} | R^{D49} | L_{C582} | R^{D143} | R^{D14} |
| L_{C7} | R^{D7} | R^{D7} | L_{C199} | R^{D1} | R^{D18} | L_{C391} | R^{D17} | R^{D50} | L_{C583} | R^{D143} | R^{D145} |
| L_{C8} | R^{D8} | R^{D8} | L_{C200} | R^{D1} | R^{D20} | L_{C392} | R^{D17} | R^{D54} | L_{C584} | R^{D143} | R^{D146} |
| L_{C9} | R^{D9} | R^{D9} | L_{C201} | R^{D1} | R^{D22} | L_{C393} | R^{D17} | R^{D55} | L_{C585} | R^{D143} | R^{D147} |
| L_{C10} | R^{D10} | R^{D10} | L_{C202} | R^{D1} | R^{D37} | L_{C394} | R^{D17} | R^{D58} | L_{C586} | R^{D143} | R^{D149} |
| L_{C11} | R^{D11} | R^{D11} | L_{C203} | R^{D1} | R^{D40} | L_{C395} | R^{D17} | R^{D59} | L_{C587} | R^{D143} | R^{D151} |
| L_{C12} | R^{D12} | R^{D12} | L_{C204} | R^{D1} | R^{D41} | L_{C396} | R^{D17} | R^{D78} | L_{C588} | R^{D143} | R^{D154} |
| L_{C13} | R^{D13} | R^{D13} | L_{C205} | R^{D1} | R^{D42} | L_{C397} | R^{D17} | R^{D79} | L_{C589} | R^{D143} | R^{D155} |
| L_{C14} | R^{D14} | R^{D14} | L_{C206} | R^{D1} | R^{D43} | L_{C398} | R^{D17} | R^{D81} | L_{C590} | R^{D143} | R^{D161} |
| L_{C15} | R^{D15} | R^{D15} | L_{C207} | R^{D1} | R^{D48} | L_{C399} | R^{D17} | R^{D87} | L_{C591} | R^{D143} | R^{D175} |
| L_{C16} | R^{D16} | R^{D16} | L_{C208} | R^{D1} | R^{D49} | L_{C400} | R^{D17} | R^{D88} | L_{C592} | R^{D144} | R^{D3} |
| L_{C17} | R^{D17} | R^{D17} | L_{C209} | R^{D1} | R^{D50} | L_{C401} | R^{D17} | R^{D89} | L_{C593} | R^{D144} | R^{D5} |
| L_{C18} | R^{D18} | R^{D18} | L_{C210} | R^{D1} | R^{D54} | L_{C402} | R^{D17} | R^{D93} | L_{C594} | R^{D144} | R^{D17} |
| L_{C19} | R^{D19} | R^{D19} | L_{C211} | R^{D1} | R^{D55} | L_{C403} | R^{D17} | R^{D116} | L_{C595} | R^{D144} | R^{D18} |
| L_{C20} | R^{D20} | R^{D20} | L_{C212} | R^{D1} | R^{D58} | L_{C404} | R^{D17} | R^{D117} | L_{C596} | R^{D144} | R^{D20} |
| L_{C21} | R^{D21} | R^{D21} | L_{C213} | R^{D1} | R^{D59} | L_{C405} | R^{D17} | R^{D118} | L_{C597} | R^{D144} | R^{D22} |
| L_{C22} | R^{D22} | R^{D22} | L_{C214} | R^{D1} | R^{D78} | L_{C406} | R^{D17} | R^{D119} | L_{C598} | R^{D144} | R^{D37} |
| L_{C23} | R^{D23} | R^{D23} | L_{C215} | R^{D1} | R^{D79} | L_{C407} | R^{D17} | R^{D120} | L_{C599} | R^{D144} | R^{D40} |
| L_{C24} | R^{D24} | R^{D24} | L_{C216} | R^{D1} | R^{D81} | L_{C408} | R^{D17} | R^{D133} | L_{C600} | R^{D144} | R^{D41} |
| L_{C25} | R^{D25} | R^{D25} | L_{C217} | R^{D1} | R^{D87} | L_{C409} | R^{D17} | R^{D134} | L_{C601} | R^{D144} | R^{D42} |
| L_{C26} | R^{D26} | R^{D26} | L_{C218} | R^{D1} | R^{D88} | L_{C410} | R^{D17} | R^{D135} | L_{C602} | R^{D144} | R^{D43} |
| L_{C27} | R^{D27} | R^{D27} | L_{C219} | R^{D1} | R^{D89} | L_{C411} | R^{D17} | R^{D136} | L_{C603} | R^{D144} | R^{D48} |
| L_{C28} | R^{D28} | R^{D28} | L_{C220} | R^{D1} | R^{D93} | L_{C412} | R^{D17} | R^{D143} | L_{C604} | R^{D144} | R^{D49} |
| L_{C29} | R^{D29} | R^{D29} | L_{C221} | R^{D1} | R^{D116} | L_{C413} | R^{D17} | R^{D144} | L_{C605} | R^{D144} | R^{D54} |
| L_{C30} | R^{D30} | R^{D30} | L_{C222} | R^{D1} | R^{D117} | L_{C414} | R^{D17} | R^{D145} | L_{C606} | R^{D144} | R^{D58} |
| L_{C31} | R^{D31} | R^{D31} | L_{C223} | R^{D1} | R^{D118} | L_{C415} | R^{D17} | R^{D146} | L_{C607} | R^{D144} | R^{D59} |
| L_{C32} | R^{D32} | R^{D32} | L_{C224} | R^{D1} | R^{D119} | L_{C416} | R^{D17} | R^{D147} | L_{C608} | R^{D144} | R^{D78} |
| L_{C33} | R^{D33} | R^{D33} | L_{C225} | R^{D1} | R^{D120} | L_{C417} | R^{D17} | R^{D149} | L_{C609} | R^{D144} | R^{D79} |
| L_{C34} | R^{D34} | R^{D34} | L_{C226} | R^{D1} | R^{D133} | L_{C418} | R^{D17} | R^{D151} | L_{C610} | R^{D144} | R^{D81} |
| L_{C35} | R^{D35} | R^{D35} | L_{C227} | R^{D1} | R^{D134} | L_{C419} | R^{D17} | R^{D154} | L_{C611} | R^{D144} | R^{D87} |
| L_{C36} | R^{D36} | R^{D36} | L_{C228} | R^{D1} | R^{D135} | L_{C420} | R^{D17} | R^{D155} | L_{C612} | R^{D144} | R^{D88} |
| L_{C37} | R^{D37} | R^{D37} | L_{C229} | R^{D1} | R^{D136} | L_{C421} | R^{D17} | R^{D161} | L_{C613} | R^{D144} | R^{D89} |
| L_{C38} | R^{D38} | R^{D38} | L_{C230} | R^{D1} | R^{D143} | L_{C422} | R^{D17} | R^{D175} | L_{C614} | R^{D144} | R^{D93} |
| L_{C39} | R^{D39} | R^{D39} | L_{C231} | R^{D1} | R^{D144} | L_{C423} | R^{D50} | R^{D3} | L_{C615} | R^{D144} | R^{D116} |
| L_{C40} | R^{D40} | R^{D40} | L_{C232} | R^{D1} | R^{D145} | L_{C424} | R^{D50} | R^{D5} | L_{C616} | R^{D144} | R^{D117} |
| L_{C41} | R^{D41} | R^{D41} | L_{C233} | R^{D1} | R^{D146} | L_{C425} | R^{D50} | R^{D18} | L_{C617} | R^{D144} | R^{D118} |
| L_{C42} | R^{D42} | R^{D42} | L_{C234} | R^{D1} | R^{D147} | L_{C426} | R^{D50} | R^{D20} | L_{C618} | R^{D144} | R^{D119} |
| L_{C43} | R^{D43} | R^{D43} | L_{C235} | R^{D1} | R^{D149} | L_{C427} | R^{D50} | R^{D22} | L_{C619} | R^{D144} | R^{D120} |
| L_{C44} | R^{D44} | R^{D44} | L_{C236} | R^{D1} | R^{D151} | L_{C428} | R^{D50} | R^{D37} | L_{C620} | R^{D144} | R^{D133} |
| L_{C45} | R^{D45} | R^{D45} | L_{C237} | R^{D1} | R^{D154} | L_{C429} | R^{D50} | R^{D40} | L_{C621} | R^{D144} | R^{D134} |
| L_{C46} | R^{D46} | R^{D46} | L_{C238} | R^{D:} | R^{D155} | L_{C430} | R^{D50} | R^{D41} | L_{C622} | R^{D144} | R^{D135} |
| L_{C47} | R^{D47} | R^{D47} | L_{C239} | R^{D1} | R^{D161} | L_{C431} | R^{D50} | R^{D42} | L_{C623} | R^{D144} | R^{D136} |
| L_{C48} | R^{D48} | R^{D48} | L_{C240} | R^{D1} | R^{D175} | L_{C432} | R^{D50} | R^{D43} | L_{C624} | R^{D144} | R^{D145} |
| L_{C49} | R^{D49} | R^{D49} | L_{C241} | R^{D4} | R^{D3} | L_{C433} | R^{D50} | R^{D48} | L_{C625} | R^{D144} | R^{D146} |
| L_{C50} | R^{D50} | R^{D50} | L_{C242} | R^{D4} | R^{D5} | L_{C434} | R^{D50} | R^{D49} | L_{C626} | R^{D144} | R^{D147} |
| L_{C51} | R^{D51} | R^{D51} | L_{C243} | R^{D4} | R^{D9} | L_{C435} | R^{D50} | R^{D54} | L_{C627} | R^{D144} | R^{D149} |
| L_{C52} | R^{D52} | R^{D52} | L_{C244} | R^{D4} | R^{D10} | L_{C436} | R^{D50} | R^{D55} | L_{C628} | R^{D144} | R^{D151} |
| L_{C53} | R^{D53} | R^{D53} | L_{C245} | R^{D4} | R^{D17} | L_{C437} | R^{D50} | R^{D58} | L_{C629} | R^{D144} | R^{D154} |
| L_{C54} | R^{D54} | R^{D54} | L_{C246} | R^{D4} | R^{D18} | L_{C438} | R^{D50} | R^{D59} | L_{C630} | R^{D144} | R^{D155} |
| L_{C55} | R^{D55} | R^{D55} | L_{C247} | R^{D4} | R^{D20} | L_{C439} | R^{D50} | R^{D78} | L_{C631} | R^{D144} | R^{D161} |
| L_{C56} | R^{D56} | R^{D56} | L_{C248} | R^{D4} | R^{D22} | L_{C440} | R^{D50} | R^{D79} | L_{C632} | R^{D144} | R^{D175} |
| L_{C57} | R^{D57} | R^{D57} | L_{C249} | R^{D4} | R^{D37} | L_{C441} | R^{D50} | R^{D81} | L_{C633} | R^{D145} | R^{D3} |
| L_{C58} | R^{D58} | R^{D58} | L_{C250} | R^{D4} | R^{D40} | L_{C442} | R^{D50} | R^{D87} | L_{C634} | R^{D145} | R^{D5} |
| L_{C59} | R^{D59} | R^{D59} | L_{C251} | R^{D4} | R^{D41} | L_{C443} | R^{D50} | R^{D88} | L_{C635} | R^{D145} | R^{D17} |
| L_{C60} | R^{D60} | R^{D60} | L_{C252} | R^{D4} | R^{D42} | L_{C444} | R^{D50} | R^{D89} | L_{C636} | R^{D145} | R^{D18} |
| L_{C61} | R^{D61} | R^{D61} | L_{C253} | R^{D4} | R^{D43} | L_{C445} | R^{D50} | R^{D93} | L_{C637} | R^{D145} | R^{D20} |
| L_{C62} | R^{D62} | R^{D62} | L_{C254} | R^{D4} | R^{D48} | L_{C446} | R^{D50} | R^{D116} | L_{C638} | R^{D145} | R^{D22} |
| L_{C63} | R^{D63} | R^{D63} | L_{C255} | R^{D4} | R^{D49} | L_{C447} | R^{D50} | R^{D117} | L_{C639} | R^{D145} | R^{D37} |
| L_{C64} | R^{D64} | R^{D64} | L_{C256} | R^{D4} | R^{D50} | L_{C448} | R^{D50} | R^{D118} | L_{C640} | R^{D145} | R^{D40} |
| L_{C65} | R^{D65} | R^{D65} | L_{C257} | R^{D4} | R^{D54} | L_{C449} | R^{D50} | R^{D119} | L_{C641} | R^{D145} | R^{D41} |
| L_{C66} | R^{D66} | R^{D66} | L_{C258} | R^{D4} | R^{D55} | L_{C450} | R^{D50} | R^{D120} | L_{C642} | R^{D145} | R^{D42} |
| L_{C67} | R^{D67} | R^{D67} | L_{C259} | R^{D4} | R^{D58} | L_{C451} | R^{D50} | R^{D133} | L_{C643} | R^{D145} | R^{D43} |
| L_{C68} | R^{D68} | R^{D68} | L_{C260} | R^{D4} | R^{D59} | L_{C452} | R^{D50} | R^{D134} | L_{C644} | R^{D145} | R^{D48} |
| L_{C69} | R^{D69} | R^{D69} | L_{C261} | R^{D4} | R^{D78} | L_{C453} | R^{D50} | R^{D135} | L_{C645} | R^{D145} | R^{D49} |
| L_{C70} | R^{D70} | R^{D70} | L_{C262} | R^{D4} | R^{D79} | L_{C454} | R^{D50} | R^{D136} | L_{C646} | R^{D145} | R^{D54} |
| L_{C71} | R^{D71} | R^{D71} | L_{C263} | R^{D4} | R^{D81} | L_{C455} | R^{D50} | R^{D143} | L_{C647} | R^{D145} | R^{D58} |
| L_{C72} | R^{D72} | R^{D72} | L_{C264} | R^{D4} | R^{D87} | L_{C456} | R^{D50} | R^{D144} | L_{C648} | R^{D145} | R^{D59} |
| L_{C73} | R^{D73} | R^{D73} | L_{C265} | R^{D4} | R^{D88} | L_{C457} | R^{D50} | R^{D145} | L_{C649} | R^{D145} | R^{D78} |
| L_{C74} | R^{D74} | R^{D74} | L_{C266} | R^{D4} | R^{D89} | L_{C458} | R^{D50} | R^{D146} | L_{C650} | R^{D145} | R^{D79} |
| L_{C75} | R^{D75} | R^{D75} | L_{C267} | R^{D4} | R^{D93} | L_{C459} | R^{D50} | R^{D147} | L_{C651} | R^{D145} | R^{D81} |
| L_{C76} | R^{D76} | R^{D76} | L_{C268} | R^{D4} | R^{D116} | L_{C460} | R^{D50} | R^{D149} | L_{C652} | R^{D145} | R^{D87} |
| L_{C77} | R^{D77} | R^{D77} | L_{C269} | R^{D4} | R^{D117} | L_{C461} | R^{D50} | R^{D151} | L_{C653} | R^{D145} | R^{D88} |
| L_{C78} | R^{D78} | R^{D78} | L_{C270} | R^{D4} | R^{D118} | L_{C462} | R^{D50} | R^{D154} | L_{C654} | R^{D145} | R^{D89} |
| L_{C79} | R^{D79} | R^{D79} | L_{C271} | R^{D4} | R^{D119} | L_{C463} | R^{D50} | R^{D155} | L_{C655} | R^{D145} | R^{D93} |
| L_{C80} | R^{D80} | R^{D80} | L_{C272} | R^{D4} | R^{D120} | L_{C464} | R^{D50} | R^{D161} | L_{C656} | R^{D145} | R^{D116} |
| L_{C81} | R^{D81} | R^{D81} | L_{C273} | R^{D4} | R^{D133} | L_{C465} | R^{D50} | R^{D175} | L_{C657} | R^{D145} | R^{D117} |
| L_{C82} | R^{D82} | R^{D82} | L_{C274} | R^{D4} | R^{D134} | L_{C466} | R^{D55} | R^{D3} | L_{C658} | R^{D145} | R^{D118} |
| L_{C83} | R^{D83} | R^{D83} | L_{C275} | R^{D4} | R^{D135} | L_{C467} | R^{D55} | R^{D5} | L_{C659} | R^{D145} | R^{D119} |
| L_{C84} | R^{D84} | R^{D84} | L_{C276} | R^{D4} | R^{D136} | L_{C468} | R^{D55} | R^{D18} | L_{C660} | R^{D145} | R^{D120} |
| L_{C85} | R^{D85} | R^{D85} | L_{C277} | R^{D4} | R^{D143} | L_{C469} | R^{D55} | R^{D20} | L_{C661} | R^{D145} | R^{D133} |
| L_{C86} | R^{D86} | R^{D86} | L_{C278} | R^{D4} | R^{D144} | L_{C470} | R^{D55} | R^{D22} | L_{C662} | R^{D145} | R^{D134} |
| L_{C87} | R^{D87} | R^{D87} | L_{C279} | R^{D4} | R^{D145} | L_{C471} | R^{D55} | R^{D37} | L_{C663} | R^{D145} | R^{D135} |
| L_{C88} | R^{D88} | R^{D88} | L_{C280} | R^{D4} | R^{D146} | L_{C472} | R^{D55} | R^{D40} | L_{C664} | R^{D145} | R^{D136} |
| L_{C89} | R^{D89} | R^{D89} | L_{C281} | R^{D4} | R^{D147} | L_{C473} | R^{D55} | R^{D41} | L_{C665} | R^{D145} | R^{D146} |
| L_{C90} | R^{D90} | R^{D90} | L_{C282} | R^{D4} | R^{D149} | L_{C474} | R^{D55} | R^{D42} | L_{C666} | R^{D145} | R^{D147} |
| L_{C91} | R^{D91} | R^{D91} | L_{C283} | R^{D4} | R^{D151} | L_{C475} | R^{D55} | R^{D43} | L_{C667} | R^{D145} | R^{D149} |
| L_{C92} | R^{D92} | R^{D92} | L_{C284} | R^{D4} | R^{D154} | L_{C476} | R^{D55} | R^{D48} | L_{C668} | R^{D145} | R^{D151} |
| L_{C93} | R^{D93} | R^{D93} | L_{C285} | R^{D4} | R^{D155} | L_{C477} | R^{D55} | R^{D49} | L_{C669} | R^{D145} | R^{D154} |
| L_{C94} | R^{D94} | R^{D94} | L_{C286} | R^{D4} | R^{D161} | L_{C478} | R^{D55} | R^{D54} | L_{C670} | R^{D145} | R^{D155} |
| L_{C95} | R^{D95} | R^{D95} | L_{C287} | R^{D4} | R^{D175} | L_{C479} | R^{D55} | R^{D58} | L_{C671} | R^{D145} | R^{D161} |
| L_{C96} | R^{D96} | R^{D96} | L_{C288} | R^{D9} | R^{D3} | L_{C480} | R^{D55} | R^{D59} | L_{C672} | R^{D145} | R^{D175} |
| L_{C97} | R^{D97} | R^{D97} | L_{C289} | R^{D9} | R^{D5} | L_{C481} | R^{D55} | R^{D78} | L_{C673} | R^{D146} | R^{D3} |
| L_{C98} | R^{D98} | R^{D98} | L_{C290} | R^{D9} | R^{D10} | L_{C482} | R^{D55} | R^{D79} | L_{C674} | R^{D146} | R^{D5} |
| L_{C99} | R^{D99} | R^{D99} | L_{C291} | R^{D9} | R^{D17} | L_{C483} | R^{D55} | R^{D81} | L_{C675} | R^{D146} | R^{D17} |
| L_{C100} | R^{D100} | R^{D100} | L_{C292} | R^{D9} | R^{D18} | L_{C484} | R^{D55} | R^{D87} | L_{C676} | R^{D146} | R^{D18} |
| L_{C101} | R^{D101} | R^{D101} | L_{C293} | R^{D9} | R^{D20} | L_{C485} | R^{D55} | R^{D88} | L_{C677} | R^{D146} | R^{D20} |
| L_{C102} | R^{D102} | R^{D102} | L_{C294} | R^{D9} | R^{D22} | L_{C486} | R^{D55} | R^{D89} | L_{C678} | R^{D146} | R^{D22} |
| L_{C103} | R^{D103} | R^{D103} | L_{C295} | R^{D9} | R^{D37} | L_{C487} | R^{D55} | R^{D93} | L_{C679} | R^{D146} | R^{D37} |
| L_{C104} | R^{D104} | R^{D104} | L_{C296} | R^{D9} | R^{D40} | L_{C488} | R^{D55} | R^{D116} | L_{C680} | R^{D146} | R^{D40} |
| L_{C105} | R^{D105} | R^{D105} | L_{C297} | R^{D9} | R^{D41} | L_{C489} | R^{D55} | R^{D117} | L_{C681} | R^{D146} | R^{D41} |
| L_{C106} | R^{D106} | R^{D106} | L_{C298} | R^{D9} | R^{D42} | L_{C490} | R^{D55} | R^{D118} | L_{C682} | R^{D146} | R^{D42} |
| L_{C107} | R^{D107} | R^{D107} | L_{C299} | R^{D9} | R^{D43} | L_{C491} | R^{D55} | R^{D119} | L_{C683} | R^{D146} | R^{D43} |
| L_{C108} | R^{D108} | R^{D108} | L_{C300} | R^{DS} | R^{D48} | L_{C492} | R^{D55} | R^{D120} | L_{C684} | R^{D146} | R^{D48} |
| L_{C109} | R^{D109} | R^{D109} | L_{C301} | R^{D9} | R^{D49} | L_{C493} | R^{D55} | R^{D133} | L_{C685} | R^{D146} | R^{D49} |
| L_{C110} | R^{D110} | R^{D110} | L_{C302} | R^{D9} | R^{D50} | L_{C494} | R^{D55} | R^{D134} | L_{C686} | R^{D146} | R^{D54} |
| L_{C111} | R^{D111} | R^{D111} | L_{C303} | R^{D9} | R^{D54} | L_{C495} | R^{D55} | R^{D135} | L_{C687} | R^{D146} | R^{D58} |
| L_{C112} | R^{D112} | R^{D112} | L_{C304} | R^{D9} | R^{D55} | L_{C496} | R^{D55} | R^{D136} | L_{C688} | R^{D146} | R^{D59} |
| L_{C113} | R^{D113} | R^{D113} | L_{C305} | R^{D9} | R^{D58} | L_{C497} | R^{D55} | R^{D143} | L_{C689} | R^{D146} | R^{D78} |
| L_{C114} | R^{D114} | R^{D114} | L_{C306} | R^{D9} | R^{D59} | L_{C498} | R^{D55} | R^{D144} | L_{C690} | R^{D146} | R^{D79} |
| L_{C115} | R^{D115} | R^{D115} | L_{C307} | R^{D9} | R^{D78} | L_{C499} | R^{D55} | R^{D145} | L_{C691} | R^{D146} | R^{D81} |
| L_{C116} | R^{D116} | R^{D116} | L_{C308} | R^{D9} | R^{D79} | L_{C500} | R^{D55} | R^{D146} | L_{C692} | R^{D146} | R^{D87} |
| L_{C117} | R^{D117} | R^{D117} | L_{C309} | R^{D9} | R^{D81} | L_{C501} | R^{D55} | R^{D147} | L_{C693} | R^{D146} | R^{D88} |
| L_{C118} | R^{D118} | R^{D118} | L_{C310} | R^{D9} | R^{D87} | L_{C502} | R^{D55} | R^{D149} | L_{C694} | R^{D146} | R^{D89} |
| L_{C119} | R^{D119} | R^{D119} | L_{C311} | R^{D9} | R^{D88} | L_{C503} | R^{D55} | R^{D151} | L_{C695} | R^{D146} | R^{D93} |
| L_{C120} | R^{D120} | R^{D120} | L_{C312} | R^{D9} | R^{D89} | L_{C504} | R^{D55} | R^{D154} | L_{C696} | R^{D146} | R^{D117} |
| L_{C121} | R^{D121} | R^{D121} | L_{C313} | R^{D9} | R^{D93} | L_{C505} | R^{D55} | R^{D155} | L_{C697} | R^{D146} | R^{D118} |
| L_{C122} | R^{D122} | R^{D122} | L_{C314} | R^{D9} | R^{D116} | L_{C506} | R^{D55} | R^{D161} | L_{C698} | R^{D146} | R^{D119} |
| L_{C123} | R^{D123} | R^{D123} | L_{C315} | R^{D9} | R^{D117} | L_{C507} | R^{D55} | R^{D175} | L_{C699} | R^{D146} | R^{D120} |
| L_{C124} | R^{D124} | R^{D124} | L_{C316} | R^{D9} | R^{D118} | L_{C508} | R^{D116} | R^{D3} | L_{C700} | R^{D146} | R^{D133} |
| L_{C125} | R^{D125} | R^{D125} | L_{C317} | R^{D9} | R^{D119} | L_{C509} | R^{D116} | R^{D5} | L_{C701} | R^{D146} | R^{D134} |
| L_{C126} | R^{D126} | R^{D126} | L_{C318} | R^{D9} | R^{D120} | L_{C510} | R^{D116} | R^{D17} | L_{C702} | R^{D146} | R^{D135} |
| L_{C127} | R^{D127} | R^{D127} | L_{C3 19} | R^{D9} | R^{D133} | L_{C511} | R^{D116} | R^{D18} | L_{C703} | R^{D146} | R^{D136} |
| L_{C128} | R^{D128} | R^{D128} | L_{C320} | R^{D9} | R^{D134} | L_{C512} | R^{D116} | R^{D20} | L_{C704} | R^{D146} | R^{D146} |
| L_{C129} | R^{D129} | R^{D129} | L_{C321} | R^{D9} | R^{D135} | L_{C513} | R^{D116} | R^{D22} | L_{C705} | R^{D146} | R^{D147} |
| L_{C130} | R^{D130} | R^{D130} | L_{C322} | R^{D9} | R^{D136} | L_{C514} | R^{D116} | R^{D37} | L_{C706} | R^{D146} | R^{D149} |
| L_{C131} | R^{D131} | R^{D131} | L_{C323} | R^{D9} | R^{D143} | L_{C515} | R^{D116} | R^{D40} | L_{C707} | R^{D146} | R^{D151} |
| L_{C132} | R^{D132} | R^{D132} | L_{C324} | R^{D9} | R^{D144} | L_{C516} | R^{D116} | R^{D41} | L_{C708} | R^{D146} | R^{D154} |
| L_{C133} | R^{D133} | R^{D133} | L_{C325} | R^{D9} | R^{D145} | L_{C517} | R^{D116} | R^{D42} | L_{C709} | R^{D146} | R^{D155} |
| L_{C134} | R^{D134} | R^{D134} | L_{C326} | R^{D9} | R^{D146} | L_{C518} | R^{D116} | R^{D43} | L_{C710} | R^{D146} | R^{D161} |
| L_{C135} | R^{D135} | R^{D135} | L_{C327} | R^{D9} | R^{D147} | L_{C519} | R^{D116} | R^{D48} | L_{C711} | R^{D146} | R^{D175} |
| L_{C136} | R^{D136} | R^{D136} | L_{C328} | R^{D9} | R^{D149} | L_{C520} | R^{D116} | R^{D49} | L_{C712} | R^{D133} | R^{D3} |
| L_{C137} | R^{D137} | R^{D137} | L_{C329} | R^{D9} | R^{D151} | L_{C521} | R^{D116} | R^{D54} | L_{C713} | R^{D133} | R^{D5} |
| L_{C138} | R^{D138} | R^{D138} | L_{C330} | R^{D9} | R^{D154} | L_{C522} | R^{D116} | R^{D58} | L_{C714} | R^{D133} | R^{D3} |
| L_{C139} | R^{D139} | R^{D139} | L_{C331} | R^{D} | R^{D155} | L_{C523} | R^{D116} | R^{D59} | L_{C715} | R^{D133} | R^{D18} |
| L_{C140} | R^{D140} | R^{D140} | L_{C332} | R^{D9} | R^{D161} | L_{C524} | R^{D116} | R^{D78} | L_{C716} | R^{D133} | R^{D20} |
| L_{C141} | R^{D141} | R^{D141} | L_{C333} | R^{D9} | R^{D175} | L_{C525} | R^{D116} | R^{D79} | L_{C717} | R^{D133} | R^{D22} |
| L_{C142} | R^{D142} | R^{D142} | L_{C34} | R^{D10} | R^{D3} | L_{C526} | R^{D116} | R^{D81} | L_{C718} | R^{D133} | R^{D37} |
| L_{C143} | R^{D143} | R^{D143} | L_{C335} | R^{D10} | R^{D5} | L_{C527} | R^{D116} | R^{D87} | L_{C719} | R^{D133} | R^{D40} |
| L_{C144} | R^{D144} | R^{D144} | L_{C336} | R^{D10} | R^{D17} | L_{C528} | R^{D116} | R^{D88} | L_{C720} | R^{D133} | R^{D41} |
| L_{C145} | R^{D145} | R^{D145} | L_{C337} | R^{D10} | R^{D18} | L_{C529} | R^{D116} | R^{D89} | L_{C721} | R^{D133} | R^{D42} |
| L_{C146} | R^{D146} | R^{D146} | L_{C338} | R^{D10} | R^{D20} | L_{C530} | R^{D116} | R^{D93} | L_{C722} | R^{D133} | R^{D43} |
| L_{C147} | R^{D147} | R^{D147} | L_{C339} | R^{D10} | R^{D22} | L_{C531} | R^{D116} | R^{D117} | L_{C723} | R^{D133} | R^{D48} |
| L_{C148} | R^{D148} | R^{D148} | L_{C340} | R^{D10} | R^{D37} | L_{C532} | R^{D116} | R^{D118} | L_{C724} | R^{D133} | R^{D49} |
| L_{C149} | R^{D149} | R^{D149} | L_{C341} | R^{D10} | R^{D40} | L_{C533} | R^{D116} | R^{D119} | L_{C725} | R^{D133} | R^{D54} |
| L_{C150} | R^{D150} | R^{D150} | L_{C342} | R^{D10} | R^{D41} | L_{C534} | R^{D116} | R^{D120} | L_{C726} | R^{D133} | R^{D58} |
| L_{C151} | R^{D151} | R^{D151} | L_{C343} | R^{D10} | R^{D42} | L_{C535} | R^{D116} | R^{D133} | L_{C727} | R^{D133} | R^{D59} |
| L_{C152} | R^{D152} | R^{D152} | L_{C34} | R^{D10} | R^{D43} | L_{C536} | R^{D116} | R^{D134} | L_{C728} | R^{D133} | R^{D78} |
| L_{C153} | R^{D153} | R^{D153} | L_{C345} | R^{D10} | R^{D48} | L_{C537} | R^{D116} | R^{D135} | L_{C729} | R^{D133} | R^{D79} |
| L_{C154} | R^{D154} | R^{D154} | L_{C346} | R^{D10} | R^{D49} | L_{C538} | R^{D116} | R^{D136} | L_{C730} | R^{D133} | R^{D81} |
| L_{C155} | R^{D155} | R^{D155} | L_{C347} | R^{D10} | R^{D50} | L_{C539} | R^{D116} | R^{D143} | L_{C731} | R^{D133} | R^{D87} |
| L_{C156} | R^{D156} | R^{D156} | L_{C348} | R^{D10} | R^{D54} | L_{C540} | R^{D116} | R^{D144} | L_{C732} | R^{D133} | R^{D 8} |
| L_{C157} | R^{D157} | R^{D157} | L_{C349} | R^{D10} | R^{D55} | L_{C541} | R^{D116} | R^{D145} | L_{C733} | R^{D133} | R^{D89} |
| L_{C158} | R^{D158} | R^{D158} | L_{C350} | R^{D10} | R^{D58} | L_{C542} | R^{D116} | R^{D146} | L_{C734} | R^{D133} | R^{D93} |
| L_{C159} | R^{D159} | R^{D159} | L_{C351} | R^{D10} | R^{D59} | L_{C543} | R^{D116} | R^{D147} | L_{C735} | R^{D133} | R^{D117} |
| L_{C160} | R^{D160} | R^{D160} | L_{C352} | R^{D10} | R^{D78} | L_{C544} | R^{D116} | R^{D149} | L_{C736} | R^{D133} | R^{D118} |
| L_{C161} | R^{D161} | R^{D161} | L_{C353} | R^{D10} | R^{D79} | L_{C545} | R^{D116} | R^{D151} | L_{C737} | R^{D133} | R^{D119} |
| L_{C162} | R^{D162} | R^{D162} | L_{C354} | R^{D10} | R^{D81} | L_{C546} | R^{D116} | R^{D154} | L_{C738} | R^{D133} | R^{D120} |
| L_{C163} | R^{D163} | R^{D163} | L_{C355} | R^{D10} | R^{D87} | L_{C547} | R^{D116} | R^{D155} | L_{C739} | R^{D133} | R^{D133} |
| L_{C164} | R^{D164} | R^{D164} | L_{C356} | R^{D10} | R^{D88} | L_{C548} | R^{D116} | R^{D161} | L_{C740} | R^{D133} | R^{D134} |
| L_{C165} | R^{D165} | R^{D165} | L_{C357} | R^{D10} | R^{D89} | L_{C549} | R^{D116} | R^{D175} | L_{C741} | R^{D133} | R^{D135} |
| L_{C166} | R^{D166} | R^{D166} | L_{C358} | R^{D10} | R^{D93} | L_{C550} | R^{D143} | R^{D3} | L_{C742} | R^{D133} | R^{D136} |
| L_{C167} | R^{D167} | R^{D167} | L_{C359} | R^{D10} | R^{D116} | L_{C551} | R^{D143} | R^{D5} | L_{C743} | R^{D133} | R^{D146} |
| L_{C168} | R^{D168} | R^{D168} | L_{C360} | R^{D10} | R^{D117} | L_{C552} | R^{D143} | R^{D17} | L_{C744} | R^{D133} | R^{D147} |
| L_{C169} | R^{D169} | R^{D169} | L_{C361} | R^{D10} | R^{D118} | L_{C553} | R^{D143} | R^{D18} | L_{C745} | R^{D133} | R^{D149} |
| L_{C170} | R^{D170} | R^{D170} | L_{C362} | R^{D10} | R^{D119} | L_{C554} | R^{D143} | R^{D20} | L_{C746} | R^{D133} | R^{D151} |
| L_{C171} | R^{D171} | R^{D171} | L_{C363} | R^{D10} | R^{D120} | L_{C555} | R^{D143} | R^{D22} | L_{C747} | R^{D133} | R^{D154} |
| L_{C172} | R^{D172} | R^{D172} | L_{C364} | R^{D10} | R^{D133} | L_{C556} | R^{D143} | R^{D37} | L_{C748} | R^{D133} | R^{D155} |
| L_{C173} | R^{D173} | R^{D173} | L_{C365} | R^{D10} | R^{D134} | L_{C557} | R^{D143} | R^{D40} | L_{C749} | R^{D133} | R^{D161} |
| L_{C174} | R^{D174} | R^{D174} | L_{C366} | R^{D10} | R^{D135} | L_{C558} | R^{D143} | R^{D41} | L_{C750} | R^{D133} | R^{D175} |
| L_{C175} | R^{D175} | R^{D175} | L_{C367} | R^{D10} | R^{D136} | L_{C559} | R^{D143} | R^{D42} | L_{C751} | R^{D175} | R^{D3} |
| L_{C176} | R^{D176} | R^{D176} | L_{C368} | R^{D10} | R^{D143} | L_{C560} | R^{D143} | R^{D43} | L_{C752} | R^{D175} | R^{D5} |
| L_{C177} | R^{D177} | R^{D177} | L_{C369} | R^{D10} | R^{D144} | L_{C561} | R^{D143} | R^{D48} | L_{C753} | R^{D175} | R^{D18} |
| L_{C178} | R^{D178} | R^{D178} | L_{C370} | R^{D10} | R^{D145} | L_{C562} | R^{D143} | R^{D49} | L_{C754} | R^{D175} | R^{D20} |
| L_{C179} | R^{D179} | R^{D179} | L_{C371} | R^{D10} | R^{D146} | L_{C563} | R^{D143} | R^{D54} | L_{C755} | R^{D175} | R^{D22} |
| L_{C180} | R^{D180} | R^{D180} | L_{C372} | R^{D10} | R^{D147} | L_{C564} | R^{D143} | R^{D58} | L_{C756} | R^{D175} | R^{D37} |
| L_{C181} | R^{D181} | R^{D181} | L_{C373} | R^{D10} | R^{D149} | L_{C565} | R^{D143} | R^{D59} | L_{C757} | R^{D175} | R^{D40} |
| L_{C182} | R^{D182} | R^{D182} | L_{C374} | R^{D10} | R^{D151} | L_{C566} | R^{D143} | R^{D78} | L_{C758} | R^{D175} | R^{D41} |
| L_{C183} | R^{D183} | R^{D183} | L_{C375} | R^{D10} | R^{D154} | L_{C567} | R^{D143} | R^{D79} | L_{C759} | R^{D175} | R^{D42} |
| L_{C184} | R^{D184} | R^{D184} | L_{C376} | R^{D10} | R^{D155} | L_{C568} | R^{D143} | R^{D81} | L_{C760} | R^{D175} | R^{D43} |
| L_{C185} | R^{D185} | R^{D185} | L_{C377} | R^{D10} | R^{D161} | L_{C569} | R^{D143} | R^{D87} | L_{C761} | R^{D175} | R^{D48} |
| L_{C186} | R^{D186} | R^{D186} | L_{C378} | R^{D10} | R^{D175} | L_{C570} | R^{D143} | R^{D88} | L_{C762} | R^{D175} | R^{D49} |
| L_{C187} | R^{D187} | R^{D187} | L_{C379} | R^{D17} | R^{D3} | L_{C571} | R^{D143} | R^{D89} | L_{C763} | R^{D175} | R^{D54} |
| L_{C188} | R^{D188} | R^{D188} | L_{C380} | R^{D17} | R^{D5} | L_{C572} | R^{D143} | R^{D93} | L_{C764} | R^{D175} | R^{D58} |
| L_{C189} | R^{D189} | R^{D189} | L_{C381} | R^{D17} | R^{D18} | L_{C573} | R^{D143} | R^{D116} | L_{C765} | R^{D175} | R^{D59} |
| L_{C190} | R^{D190} | R^{D190} | L_{C382} | R^{D17} | R^{D20} | L_{C574} | R^{D143} | R^{D117} | L_{C766} | R^{D175} | R^{D78} |
| L_{C191} | R^{D191} | R^{D191} | L_{C383} | R^{D17} | R^{D22} | L_{C575} | R^{D143} | R^{D118} | L_{C767} | R^{D175} | R^{D79} |
| L_{C192} | R^{D192} | R^{D192} | L_{C384} | R^{D17} | R^{D37} | L_{C576} | R^{D143} | R^{D119} | L_{C768} | R^{D175} | R^{D81} |
| L_{C769} | R^{D193} | R^{D193} | L_{C877} | R^{D1} | R^{D193} | L_{C985} | R^{D4} | R^{D193} | L_{C1093} | R^{D9} | R^{D193} |
| L_{C770} | R^{D194} | R^{D194} | L_{C878} | R^{D1} | R^{D194} | L_{C986} | R^{D4} | R^{D194} | L_{C1094} | R^{D9} | R^{D194} |
| L_{C771} | R^{D195} | R^{D195} | L_{C879} | R^{D1} | R^{D195} | L_{C987} | R^{D4} | R^{D195} | L_{C1095} | R^{D9} | R^{D195} |
| L_{C772} | R^{D196} | R^{D196} | L_{C880} | R^{D1} | R^{D196} | L_{C988} | R^{D4} | R^{D196} | L_{C1096} | R^{D9} | R^{D196} |
| L_{C773} | R^{D197} | R^{D197} | L_{C881} | R^{D1} | R^{D197} | L_{C989} | R^{D4} | R^{D197} | L_{C1097} | R^{D9} | R^{D197} |
| L_{C774} | R^{D198} | R^{D198} | L_{C882} | R^{D1} | R^{D198} | L_{C990} | R^{D4} | R^{D198} | L_{C1098} | R^{D9} | R^{D198} |
| L_{C775} | R^{D199} | R^{D199} | L_{C883} | R^{D1} | R^{D199} | L_{C991} | R^{D4} | R^{D199} | L_{C1099} | R^{D9} | R^{D199} |
| L_{C776} | R^{D200} | R^{D200} | L_{C884} | R^{D1} | R^{D200} | L_{C992} | R^{D4} | R^{D200} | L_{C1100} | R^{D9} | R^{D200} |
| L_{C777} | R^{D201} | R^{D201} | L_{C885} | R^{D1} | R^{D201} | L_{C993} | R^{D4} | R^{D201} | L_{C1101} | R^{D9} | R^{D201} |
| L_{C778} | R^{D202} | R^{D202} | L_{C886} | R^{D1} | R^{D202} | L_{C994} | R^{D4} | R^{D202} | L_{C1102} | R^{D9} | R^{D202} |
| L_{C779} | R^{D203} | R^{D203} | L_{C887} | R^{D1} | R^{D203} | L_{C995} | R^{D4} | R^{D203} | L_{C1103} | R^{D9} | R^{D203} |
| L_{C780} | R^{D204} | R^{D204} | L_{C888} | R^{D1} | R^{D204} | L_{C996} | R^{D4} | R^{D204} | L_{C1104} | R^{D9} | R^{D204} |
| L_{C781} | R^{D205} | R^{D205} | L_{C889} | R^{D1} | R^{D205} | L_{C997} | R^{D4} | R^{D205} | L_{C1105} | R^{D9} | R^{D205} |
| L_{C782} | R^{D206} | R^{D206} | L_{C890} | R^{D1} | R^{D206} | L_{C998} | R^{D4} | R^{D206} | L_{C1106} | R^{D9} | R^{D206} |
| L_{C783} | R^{D207} | R^{D207} | L_{C891} | R^{D1} | R^{D207} | L_{C999} | R^{D4} | R^{D207} | L_{C1107} | R^{D9} | R^{D207} |
| L_{C784} | R^{D208} | R^{D208} | L_{C892} | R^{D1} | R^{D208} | L_{C1000} | R^{D4} | R^{D208} | L_{C1108} | R^{D9} | R^{D208} |
| L_{C785} | R^{D209} | R^{D209} | L_{C893} | R^{D1} | R^{D209} | L_{C1001} | R^{D4} | R^{D209} | L_{C1109} | R^{D9} | R^{D209} |
| L_{C786} | R^{D210} | R^{D210} | L_{C894} | R^{D1} | R^{D210} | L_{C1002} | R^{D4} | R^{D210} | L_{C1110} | R^{D9} | R^{D210} |
| L_{C787} | R^{D211} | R^{D211} | L_{C895} | R^{D1} | R^{D211} | L_{C1003} | R^{D4} | R^{D211} | L_{C1111} | R^{D9} | R^{D211} |
| L_{C788} | R^{D212} | R^{D212} | L_{C896} | R^{D1} | R^{D212} | L_{C1004} | R^{D4} | R^{D212} | L_{C1112} | R^{D9} | R^{D212} |
| L_{C789} | R^{D213} | R^{D213} | L_{C897} | R^{D1} | R^{D213} | L_{C1005} | R^{D4} | R^{D213} | L_{C1113} | R^{DS} | R^{D213} |
| L_{C790} | R^{D214} | R^{D214} | L_{C898} | R^{D1} | R^{D214} | L_{C1006} | R^{D4} | R^{D214} | L_{C1114} | R^{D9} | R^{D214} |
| L_{C791} | R^{D215} | R^{D215} | L_{C899} | R^{D1} | R^{D215} | L_{C1007} | R^{D4} | R^{D215} | L_{C1115} | R^{D9} | R^{D215} |
| L_{C792} | R^{D216} | R^{D216} | L_{C900} | R^{D1} | R^{D216} | L_{C1008} | R^{D4} | R^{D216} | L_{C1116} | R^{D9} | R^{D216} |
| L_{C793} | R^{D217} | R^{D217} | L_{C901} | R^{D1} | R^{D217} | L_{C1009} | R^{D4} | R^{D217} | L_{C1117} | R^{D9} | R^{D217} |
| L_{C794} | R^{D218} | R^{D218} | L_{C902} | R^{D1} | R^{D218} | L_{C1010} | R^{D4} | R^{D218} | L_{C1118} | R^{D9} | R^{D218} |
| L_{C795} | R^{D219} | R^{D219} | L_{C903} | R^{D1} | R^{D219} | L_{C1011} | R^{D4} | R^{D219} | L_{C1119} | R^{D9} | R^{D219} |
| L_{C796} | R^{D220} | R^{D220} | L_{C904} | R^{D1} | R^{D220} | L_{C1012} | R^{D4} | R^{D220} | L_{C1120} | R^{D9} | R^{D220} |
| L_{C797} | R^{D221} | R^{D221} | L_{C905} | R^{D1} | R^{D221} | L_{C1013} | R^{D4} | R^{D221} | L_{C1121} | R^{D9} | R^{D221} |
| L_{C798} | R^{D222} | R^{D222} | L_{C906} | R^{D1} | R^{D222} | L_{C1014} | R^{D4} | R^{D222} | L_{C1122} | R^{D9} | R^{D222} |
| L_{C799} | R^{D223} | R^{D223} | L_{C907} | R^{D1} | R^{D223} | L_{C1015} | R^{D4} | R^{D223} | L_{C1123} | R^{D9} | R^{D223} |
| L_{C800} | R^{D224} | R^{D224} | L_{C908} | R^{D1} | R^{D224} | L_{C1016} | R^{D4} | R^{D224} | L_{C1124} | R^{D9} | R^{D224} |
| L_{C801} | R^{D225} | R^{D225} | L_{C909} | R^{D1} | R^{D225} | L_{C1017} | R^{D4} | R^{D225} | L_{C1125} | R^{D9} | R^{D225} |
| L_{C802} | R^{D226} | R^{D226} | L_{C910} | R^{D1} | R^{D226} | L_{C1018} | R^{D4} | R^{D226} | L_{C1126} | R^{DS} | R^{D226} |
| L_{C803} | R^{D227} | R^{D227} | L_{C911} | R^{D1} | R^{D227} | L_{C1019} | R^{D4} | R^{D227} | L_{C1127} | R^{D9} | R^{D227} |
| L_{C804} | R^{D228} | R^{D228} | L_{C912} | R^{D1} | R^{D228} | L_{C1020} | R^{D4} | R^{D228} | L_{C1128} | R^{D9} | R^{D228} |
| L_{C805} | R^{D229} | R^{D229} | L_{C913} | R^{D1} | R^{D229} | L_{C1021} | R^{D4} | R^{D229} | L_{C1129} | R^{D9} | R^{D229} |
| L_{C806} | R^{D230} | R^{D230} | L_{C914} | R^{D1} | R^{D230} | L_{C1022} | R^{D4} | R^{D230} | L_{C1130} | R^{D9} | R^{D230} |
| L_{C807} | R^{D231} | R^{D231} | L_{C915} | R^{D1} | R^{D231} | L_{C1023} | R^{D4} | R^{D231} | L_{C1131} | R^{D9} | R^{D231} |
| L_{C808} | R^{D232} | R^{D232} | L_{C916} | R^{D1} | R^{D232} | L_{C1024} | R^{D4} | R^{D232} | L_{C1132} | R^{D9} | R^{D232} |
| L_{C809} | R^{D233} | R^{D233} | L_{C917} | R^{D1} | R^{D233} | L_{C1025} | R^{D4} | R^{D233} | L_{C1133} | R^{D9} | R^{D233} |
| L_{C810} | R^{D234} | R^{D234} | L_{C918} | R^{D1} | R^{D234} | L_{C1026} | R^{D4} | R^{D234} | L_{C1134} | R^{D9} | R^{D234} |
| L_{C811} | R^{D235} | R^{D235} | L_{C919} | R^{D1} | R^{D235} | L_{C1027} | R^{D4} | R^{D235} | L_{C1135} | R^{D9} | R^{D235} |
| L_{C812} | R^{D236} | R^{D236} | L_{C920} | R^{D1} | R^{D236} | L_{C1028} | R^{D4} | R^{D236} | L_{C1136} | R^{D9} | R^{D236} |
| L_{C813} | R^{D237} | R^{D237} | L_{C921} | R^{D1} | R^{D237} | L_{C1029} | R^{D4} | R^{D237} | L_{C1137} | R^{D9} | R^{D237} |
| L_{C814} | R^{D238} | R^{D238} | L_{C922} | R^{D1} | R^{D238} | L_{C1030} | R^{D4} | R^{D238} | L_{C1138} | R^{D9} | R^{D238} |
| L_{C815} | R^{D239} | R^{D239} | L_{C923} | R^{D1} | R^{D239} | L_{C1031} | R^{D4} | R^{D239} | L_{C1139} | R^{D9} | R^{D239} |
| L_{C816} | R^{D240} | R^{D240} | L_{C924} | R^{D1} | R^{D240} | L_{C1032} | R^{D4} | R^{D240} | L_{C1140} | R^{D9} | R^{D240} |
| L_{C817} | R^{D241} | R^{D241} | L_{C925} | R^{D1} | R^{D241} | L_{C1033} | R^{D4} | R^{D241} | L_{C1141} | R^{D9} | R^{D241} |
| L_{C818} | R^{D242} | R^{D242} | L_{C926} | R^{D1} | R^{D242} | L_{C1034} | R^{D4} | R^{D242} | L_{C1142} | R^{D9} | R^{D242} |
| L_{C819} | R^{D243} | R^{D243} | L_{C927} | R^{D1} | R^{D243} | L_{C1035} | R^{D4} | R^{D243} | L_{C1143} | R^{D9} | R^{D243} |
| L_{C820} | R^{D244} | R^{D244} | L_{C928} | R^{D1} | R^{D244} | L_{C1036} | R^{D4} | R^{D244} | L_{C1144} | R^{D9} | R^{D244} |
| L_{C821} | R^{D245} | R^{D245} | L_{C929} | R^{D} | R^{D245} | L_{C1037} | R^{D4} | R^{D245} | L_{C1145} | R^{D9} | R^{D245} |
| L_{C822} | R^{D246} | R^{D246} | L_{C930} | R^{D1} | R^{D246} | L_{C1038} | R^{D4} | R^{D246} | L_{C1146} | R^{D9} | R^{D246} |
| L_{C823} | R^{D17} | R^{D19} | L_{C931} | R^{D50} | R^{D193} | L_{C1039} | R^{D145} | R^{D193} | L_{C1147} | R^{D168} | R^{D193} |
| L_{C824} | R^{D17} | R^{D194} | L_{C932} | R^{D50} | R^{D194} | L_{C1040} | R^{D145} | R^{D194} | L_{C1148} | R^{D168} | R^{D194} |
| L_{C825} | R^{D17} | R^{D195} | L_{C933} | R^{D50} | R^{D195} | L_{C1041} | R^{D145} | R^{D195} | L_{C1149} | R^{D168} | R^{D195} |
| L_{C826} | R^{D17} | R^{D196} | L_{C934} | R^{D50} | R^{D196} | L_{C1042} | R^{D145} | R^{D196} | L_{C1150} | R^{D168} | R^{D196} |
| L_{C827} | R^{D17} | R^{D197} | L_{C93.5} | R^{D50} | R^{D197} | L_{C1043} | R^{D145} | R^{D197} | L_{C1151} | R^{D168} | R^{D197} |
| L_{C828} | R^{D17} | R^{D198} | L_{C936} | R^{D50} | R^{D198} | L_{C1044} | R^{D145} | R^{D198} | L_{C1152} | R^{D168} | R^{D198} |
| L_{C829} | R^{D17} | R^{D199} | L_{C937} | R^{D50} | R^{D199} | L_{C1045} | R^{D145} | R^{D199} | L_{C1153} | R^{D168} | R^{D199} |
| L_{C830} | R^{D17} | R^{D200} | L_{C938} | R^{D50} | R^{D200} | L_{C1046} | R^{D145} | R^{D200} | L_{C1154} | R^{D168} | R^{D200} |
| L_{C831} | R^{D17} | R^{D201} | L_{C939} | R^{D50} | R^{D201} | L_{C1047} | R^{D145} | R^{D201} | L_{C1155} | R^{D168} | R^{D201} |
| L_{C832} | R^{D17} | R^{D202} | L_{C940} | R^{D50} | R^{D202} | L_{C1048} | R^{D145} | R^{D202} | L_{C1156} | R^{D168} | R^{D202} |
| L_{C833} | R^{D17} | R^{D203} | L_{C941} | R^{D50} | R^{D203} | L_{C1049} | R^{D145} | R^{D203} | L_{C1157} | R^{D168} | R^{D203} |
| L_{C834} | R^{D17} | R^{D204} | L_{C942} | R^{D50} | R^{D204} | L_{C1050} | R^{D145} | R^{D204} | L_{C1158} | R^{D168} | R^{D204} |
| L_{C835} | R^{D17} | R^{D205} | L_{C943} | R^{D50} | R^{D205} | L_{C1051} | R^{D145} | R^{D205} | L_{C1159} | R^{D168} | R^{D205} |
| L_{C836} | R^{D17} | R^{D206} | L_{C944} | R^{D50} | R^{D206} | L_{C1052} | R^{D145} | R^{D206} | L_{C1160} | R^{D168} | R^{D206} |
| L_{C837} | R^{D17} | R^{D207} | L_{C945} | R^{D50} | R^{D207} | L_{C1053} | R^{D145} | R^{D207} | L_{C1161} | R^{D168} | R^{D207} |
| L_{C838} | R^{D17} | R^{D208} | L_{C946} | R^{D50} | R^{D208} | L_{C1054} | R^{D145} | R^{D208} | L_{C1162} | R^{D168} | R^{D208} |
| L_{C839} | R^{D17} | R^{D209} | L_{C947} | R^{D50} | R^{D209} | L_{C1055} | R^{D145} | R^{D209} | L_{C1163} | R^{D168} | R^{D209} |
| L_{C840} | R^{D17} | R^{D210} | L_{C948} | R^{D50} | R^{D210} | L_{C1056} | R^{D145} | R^{D210} | L_{C1164} | R^{D168} | R^{D210} |
| L_{C841} | R^{D17} | R^{D211} | L_{C949} | R^{D50} | R^{D211} | L_{C1057} | R^{D145} | R^{D211} | L_{C1165} | R^{D168} | R^{D211} |
| L_{C842} | R^{D17} | R^{D212} | L_{C950} | R^{D50} | R^{D212} | L_{C1058} | R^{D145} | R^{D212} | L_{C1166} | R^{D168} | R^{D212} |
| L_{C843} | R^{D17} | R^{D213} | L_{C951} | R^{D50} | R^{D213} | L_{C1059} | R^{D145} | R^{D213} | L_{C1167} | R^{D168} | R^{D213} |
| L_{C844} | R^{D17} | R^{D214} | L_{C952} | R^{D50} | R^{D214} | L_{C1060} | R^{D145} | R^{D214} | L_{C1168} | R^{D168} | R^{D214} |
| L_{C845} | R^{D17} | R^{D215} | L_{C953} | R^{D50} | R^{D215} | L_{C1061} | R^{D145} | R^{D215} | L_{C1169} | R^{D168} | R^{D215} |
| L_{C846} | R^{D17} | R^{D216} | L_{C954} | R^{D50} | R^{D216} | L_{C1062} | R^{D145} | R^{D216} | L_{C1170} | R^{D168} | R^{D216} |
| L_{C847} | R^{D17} | R^{D217} | L_{C955} | R^{D50} | R^{D217} | L_{C1063} | R^{D145} | R^{D217} | L_{C1171} | R^{D168} | R^{D217} |
| L_{C848} | R^{D17} | R^{D218} | L_{C956} | R^{D50} | R^{D218} | L_{C1064} | R^{D145} | R^{D218} | L_{C1172} | R^{D168} | R^{D218} |
| L_{C849} | R^{D17} | R^{D219} | L_{C957} | R^{D50} | R^{D219} | L_{C1065} | R^{D145} | R^{D219} | L_{C1173} | R^{D168} | R^{D219} |
| L_{C850} | R^{D17} | R^{D220} | L_{C958} | R^{D50} | R^{D220} | L_{C1066} | R^{D145} | R^{D220} | L_{C1174} | R^{D168} | R^{D220} |
| L_{C851} | R^{D17} | R^{D221} | L_{C959} | R^{D50} | R^{D221} | L_{C1067} | R^{D145} | R^{D221} | L_{C1175} | R^{D168} | R^{D221} |
| L_{C852} | R^{D17} | R^{D222} | L_{C960} | R^{D50} | R^{D222} | L_{C1068} | R^{D145} | R^{D222} | L_{C1176} | R^{D168} | R^{D222} |
| L_{C853} | R^{D17} | R^{D223} | L_{C961} | R^{D50} | R^{D223} | L_{C1069} | R^{D145} | R^{D223} | L_{C1177} | R^{D168} | R^{D223} |
| L_{C854} | R^{D17} | R^{D224} | L_{C962} | R^{D50} | R^{D224} | L_{C1070} | R^{D145} | R^{D224} | L_{C1178} | R^{D168} | R^{D224} |
| L_{C855} | R^{D17} | R^{D225} | L_{C963} | R^{D50} | R^{D225} | L_{C1071} | R^{D145} | R^{D225} | L_{C1179} | R^{D168} | R^{D225} |
| L_{C856} | R^{D17} | R^{D226} | L_{C964} | R^{D50} | R^{D226} | L_{C1072} | R^{D145} | R^{D226} | L_{C1180} | R^{D168} | R^{D226} |
| L_{C857} | R^{D17} | R^{D227} | L_{C965} | R^{D50} | R^{D227} | L_{C1073} | R^{D145} | R^{D227} | L_{C1181} | R^{D168} | R^{D227} |
| L_{C858} | R^{D17} | R^{D228} | L_{C966} | R^{D50} | R^{D228} | L_{C1074} | R^{D145} | R^{D228} | L_{C1182} | R^{D168} | R^{D228} |
| L_{C859} | R^{D17} | R^{D229} | L_{C967} | R^{D50} | R^{D229} | L_{C1075} | R^{D145} | R^{D229} | L_{C1183} | R^{D168} | R^{D229} |
| L_{C860} | R^{D17} | R^{D230} | L_{C968} | R^{D50} | R^{D230} | L_{C1076} | R^{D145} | R^{D230} | L_{C1184} | R^{D168} | R^{D230} |
| L_{C861} | R^{D17} | R^{D231} | L_{C969} | R^{D50} | R^{D231} | L_{C1077} | R^{D145} | R^{D231} | L_{C1185} | R^{D168} | R^{D231} |
| L_{C862} | R^{D17} | R^{D232} | L_{C970} | R^{D50} | R^{D232} | L_{C1078} | R^{D145} | R^{D232} | L_{C1186} | R^{D168} | R^{D232} |
| L_{C863} | R^{D17} | R^{D233} | L_{C971} | R^{D50} | R^{D233} | L_{C1079} | R^{D145} | R^{D233} | L_{C1187} | R^{D168} | R^{D233} |
| L_{C864} | R^{D17} | R^{D234} | L_{C972} | R^{D50} | R^{D234} | L_{C1080} | R^{D145} | R^{D234} | L_{C1188} | R^{D168} | R^{D234} |
| L_{C865} | R^{D17} | R^{D235} | L_{C973} | R^{D50} | R^{D235} | L_{C1081} | R^{D145} | R^{D235} | L_{C1189} | R^{D168} | R^{D235} |
| L_{C866} | R^{D17} | R^{D236} | L_{C974} | R^{D50} | R^{D236} | L_{C1082} | R^{D145} | R^{D236} | L_{C1190} | R^{D168} | R^{D236} |
| L_{C867} | R^{D17} | R^{D237} | L_{C975} | R^{D50} | R^{D237} | L_{C1083} | R^{D145} | R^{D237} | L_{C1191} | R^{D168} | R^{D237} |
| L_{C868} | R^{D17} | R^{D238} | L_{C976} | R^{D50} | R^{D238} | L_{C1084} | R^{D145} | R^{D238} | L_{C1192} | R^{D168} | R^{D238} |
| L_{C869} | R^{D17} | R^{D239} | L_{C977} | R^{D50} | R^{D239} | L_{C1085} | R^{D145} | R^{D239} | L_{C1193} | R^{D168} | R^{D239} |
| L_{C870} | R^{D17} | R^{D240} | L_{C978} | R^{D50} | R^{D240} | L_{C1086} | R^{D145} | R^{D240} | L_{C1194} | R^{D168} | R^{D240} |
| L_{C871} | R^{D17} | R^{D241} | L_{C979} | R^{D50} | R^{D241} | L_{C1087} | R^{D145} | R^{D241} | L_{C1195} | R^{D168} | R^{D241} |
| L_{C872} | R^{D17} | R^{D242} | L_{C980} | R^{D50} | R^{D242} | L_{C1088} | R^{D145} | R^{D242} | L_{C1196} | R^{D168} | R^{D242} |
| L_{C873} | R^{D17} | R^{D243} | L_{C981} | R^{D50} | R^{D243} | L_{C1089} | R^{D145} | R^{D243} | L_{C1197} | R^{D168} | R^{D243} |
| L_{C874} | R^{D17} | R^{D244} | L_{C982} | R^{D50} | R^{D244} | L_{C1090} | R^{D145} | R^{D244} | L_{C1198} | R^{D168} | R^{D244} |
| L_{C875} | R^{D17} | R^{D245} | L_{C983} | R^{D50} | R^{D245} | L_{C1091} | R^{D145} | R^{D245} | L_{C1199} | R^{D168} | R^{D245} |
| L_{C876} | R^{D17} | R^{D246} | L_{C984} | R^{D50} | R^{D246} | L_{C1092} | R^{D145} | R^{D246} | L_{C1200} | R^{D168} | R^{D246} |
| L_{C1201} | R^{D10} | R^{D193} | L_{C1255} | R^{D55} | R^{D193} | L_{C1309} | R^{D37} | R^{D193} | L_{C1363} | R^{D143} | R^{D193} |
| L_{C1202} | R^{D10} | R^{D194} | L_{C1256} | R^{D55} | R^{D194} | L_{C1310} | R^{D37} | R^{D194} | L_{C1364} | R^{D143} | R^{D194} |
| L_{C1203} | R^{D10} | R^{D195} | L_{C1257} | R^{D55} | R^{D195} | L_{C1311} | R^{D37} | R^{D195} | L_{C1365} | R^{D143} | R^{D195} |
| L_{C1204} | R^{D10} | R^{D196} | L_{C1258} | R^{D55} | R^{D196} | L_{C1312} | R^{D37} | R^{D196} | L_{C1366} | R^{D143} | R^{D196} |
| L_{C1205} | R^{D10} | R^{D197} | L_{C1259} | R^{D55} | R^{D197} | L_{C1313} | R^{D37} | R^{D197} | L_{C1367} | R^{D143} | R^{D197} |
| L_{C1206} | R^{D10} | R^{D198} | L_{C1260} | R^{D55} | R^{D198} | L_{C1314} | R^{D37} | R^{D198} | L_{C1368} | R^{D143} | R^{D198} |
| L_{C1207} | R^{D10} | R^{D199} | L_{C1261} | R^{D55} | R^{D199} | L_{C1315} | R^{D37} | R^{D199} | L_{C1369} | R^{D143} | R^{D199} |
| L_{C1208} | R^{D10} | R^{D200} | L_{C1262} | R^{D55} | R^{D200} | L_{C1316} | R^{D37} | R^{D200} | L_{C1370} | R^{D143} | R^{D200} |
| L_{C1209} | R^{D10} | R^{D201} | L_{C1263} | R^{D55} | R^{D201} | L_{C1317} | R^{D37} | R^{D201} | L_{C1371} | R^{D143} | R^{D201} |
| L_{C1210} | R^{D10} | R^{D202} | L_{C1264} | R^{D55} | R^{D202} | L_{C1318} | R^{D37} | R^{D202} | L_{C1372} | R^{D143} | R^{D202} |
| L_{C1211} | R^{D10} | R^{D203} | L_{C1265} | R^{D55} | R^{D203} | L_{C1319} | R^{D37} | R^{D203} | L_{C1373} | R^{D143} | R^{D203} |
| L_{C1212} | R^{D10} | R^{D204} | L_{C1266} | R^{D55} | R^{D204} | L_{C1320} | R^{D37} | R^{D204} | L_{C1374} | R^{D143} | R^{D204} |
| L_{C1213} | R^{D10} | R^{D205} | L_{C1267} | R^{D55} | R^{D205} | L_{C1321} | R^{D37} | R^{D205} | L_{C1375} | R^{D143} | R^{D205} |
| L_{C1214} | R^{D10} | R^{D206} | L_{C1268} | R^{D55} | R^{D206} | L_{C1322} | R^{D37} | R^{D206} | L_{C1376} | R^{D143} | R^{D206} |
| L_{C1215} | R^{D10} | R^{D207} | L_{C1269} | R^{D55} | R^{D207} | L_{C1323} | R^{D37} | R^{D207} | L_{C1377} | R^{D143} | R^{D207} |
| L_{C1216} | R^{D10} | R^{D208} | L_{C1270} | R^{D55} | R^{D208} | L_{C1324} | R^{D37} | R^{D208} | L_{C1378} | R^{D143} | R^{D208} |
| L_{C1217} | R^{D10} | R^{D209} | L_{C1271} | R^{D55} | R^{D209} | L_{C1325} | R^{D37} | R^{D209} | L_{C1379} | R^{D143} | R^{D209} |
| L_{C1218} | R^{D10} | R^{D210} | L_{C1272} | R^{D55} | R^{D210} | L_{C1326} | R^{D37} | R^{D210} | L_{C1380} | R^{D143} | R^{D210} |
| L_{C1219} | R^{D10} | R^{D211} | L_{C1273} | R^{D55} | R^{D211} | L_{C1327} | R^{D37} | R^{D211} | L_{C1381} | R^{D143} | R^{D211} |
| L_{C1220} | R^{D10} | R^{D212} | L_{C1274} | R^{D55} | R^{D212} | L_{C1328} | R^{D37} | R^{D212} | L_{C1382} | R^{D143} | R^{D212} |
| L_{C1221} | R^{D10} | R^{D213} | L_{C1275} | R^{D55} | R^{D213} | L_{C1329} | R^{D37} | R^{D213} | L_{C1383} | R^{D143} | R^{D213} |
| L_{C1222} | R^{D10} | R^{D214} | L_{C1276} | R^{D55} | R^{D214} | L_{C1330} | R^{D37} | R^{D214} | L_{C1384} | R^{D143} | R^{D214} |
| L_{C1223} | R^{D10} | R^{D215} | L_{C1277} | R^{D55} | R^{D215} | L_{C1331} | R^{D37} | R^{D215} | L_{C1385} | R^{D143} | R^{D215} |
| L_{C1224} | R^{D10} | R^{D216} | L_{C1278} | R^{D55} | R^{D216} | L_{C1332} | R^{D37} | R^{D216} | L_{C1386} | R^{D143} | R^{D216} |
| L_{C1225} | R^{D10} | R^{D217} | L_{C1279} | R^{D55} | R^{D217} | L_{C1333} | R^{D37} | R^{D217} | L_{C1387} | R^{D143} | R^{D217} |
| L_{C1226} | R^{D10} | R^{D218} | L_{C1280} | R^{D55} | R^{D218} | L_{C1334} | R^{D37} | R^{D218} | L_{C1388} | R^{D143} | R^{D218} |
| L_{C1227} | R^{D10} | R^{D219} | L_{C1281} | R^{D55} | R^{D219} | L_{C1335} | R^{D37} | R^{D219} | L_{C1389} | R^{D143} | R^{D219} |
| L_{C1228} | R^{D10} | R^{D220} | L_{C1282} | R^{D55} | R^{D220} | L_{C1336} | R^{D37} | R^{D220} | L_{C1390} | R^{D143} | R^{D220} |
| L_{C1229} | R^{D10} | R^{D221} | L_{C1283} | R^{D55} | R^{D221} | L_{C1337} | R^{D37} | R^{D221} | L_{C1391} | R^{D143} | R^{D221} |
| L_{C1230} | R^{D10} | R^{D222} | L_{C1284} | R^{D55} | R^{D222} | L_{C1338} | R^{D37} | R^{D222} | L_{C1392} | R^{D143} | R^{D222} |
| L_{C1231} | R^{D10} | R^{D223} | L_{C1285} | R^{D55} | R^{D223} | L_{C1339} | R^{D37} | R^{D223} | L_{C1393} | R^{D143} | R^{D223} |
| L_{C1232} | R^{D10} | R^{D224} | L_{C1286} | R^{D55} | R^{D224} | L_{C1340} | R^{D37} | R^{D224} | L_{C1394} | R^{D143} | R^{D224} |
| L_{C1233} | R^{D10} | R^{D225} | L_{C1287} | R^{D55} | R^{D225} | L_{C1341} | R^{D37} | R^{D225} | L_{C1395} | R^{D143} | R^{D225} |
| L_{C1234} | R^{D10} | R^{D226} | L_{C1288} | R^{D55} | R^{D226} | L_{C1342} | R^{D37} | R^{D226} | L_{C1396} | R^{D143} | R^{D226} |
| L_{C1235} | R^{D10} | R^{D227} | L_{C1289} | R^{D55} | R^{D227} | L_{C1343} | R^{D37} | R^{D227} | L_{C1397} | R^{D143} | R^{D227} |
| L_{C1236} | R^{D10} | R^{D228} | L_{C1290} | R^{D55} | R^{D228} | L_{C1344} | R^{D37} | R^{D228} | L_{C1398} | R^{D143} | R^{D228} |
| L_{C1237} | R^{D10} | R^{D229} | L_{C1291} | R^{D55} | R^{D229} | L_{C1345} | R^{D37} | R^{D229} | L_{C1399} | R^{D143} | R^{D229} |
| L_{C1238} | R^{D10} | R^{D230} | L_{C1292} | R^{D55} | R^{D230} | L_{C1346} | R^{D37} | R^{D230} | L_{C1400} | R^{D143} | R^{D230} |
| L_{C1239} | R^{D10} | R^{D231} | L_{C1293} | R^{D55} | R^{D231} | L_{C1347} | R^{D37} | R^{D231} | L_{C1401} | R^{D143} | R^{D231} |
| L_{C1240} | R^{D10} | R^{D232} | L_{C1294} | R^{D55} | R^{D232} | L_{C1348} | R^{D37} | R^{D232} | L_{C1402} | R^{D143} | R^{D232} |
| L_{C1241} | R^{D10} | R^{D233} | L_{C1295} | R^{D55} | R^{D233} | L_{C1349} | R^{D37} | R^{D233} | L_{C1403} | R^{D143} | R^{D233} |
| L_{C1242} | R^{D10} | R^{D234} | L_{C1296} | R^{D55} | R^{D234} | L_{C1350} | R^{D37} | R^{D234} | L_{C1404} | R^{D143} | R^{D234} |
| L_{C1243} | R^{D10} | R^{D235} | L_{C1297} | R^{D55} | R^{D235} | L_{C1351} | R^{D37} | R^{D235} | L_{C1405} | R^{D143} | R^{D235} |
| L_{C1244} | R^{D10} | R^{D236} | L_{C1298} | R^{D55} | R^{D236} | L_{C1352} | R^{D37} | R^{D236} | L_{C1406} | R^{D143} | R^{D236} |
| L_{C1245} | R^{D10} | R^{D237} | L_{C1299} | R^{D55} | R^{D237} | L_{C1353} | R^{D37} | R^{D237} | L_{C1407} | R^{D143} | R^{D237} |
| L_{C1246} | R^{D10} | R^{D238} | L_{C1300} | R^{D55} | R^{D238} | L_{C1354} | R^{D37} | R^{D238} | L_{C1408} | R^{D143} | R^{D238} |
| L_{C1247} | R^{D10} | R^{D239} | L_{C1301} | R^{D55} | R^{D239} | L_{C1355} | R^{D37} | R^{D239} | L_{C1409} | R^{D143} | R^{D239} |
| L_{C1248} | R^{D10} | R^{D240} | L_{C1302} | R^{D55} | R^{D240} | L_{C1356} | R^{D37} | R^{D240} | L_{C1410} | R^{D143} | R^{D240} |
| L_{C1249} | R^{D10} | R^{D241} | L_{C1303} | R^{D55} | R^{D241} | L_{C1357} | R^{D37} | R^{D241} | L_{C1411} | R^{D143} | R^{D241} |
| L_{C1250} | ^{rD10} | R^{D242} | L_{C1304} | R^{D55} | R^{D242} | L_{C1358} | R^{D37} | R^{D242} | L_{C1412} | R^{D143} | R^{D242} |
| L_{C1251} | R^{D10} | R^{D243} | L_{C1305} | R^{D55} | R^{D243} | L_{C1359} | R^{D37} | R^{D243} | L_{C1413} | R^{D143} | R^{D243} |
| L_{C1252} | R^{D10} | R^{D244} | L_{C1306} | R^{D55} | R^{D244} | L_{C1360} | R^{D37} | R^{D244} | L_{C1414} | R^{D143} | R^{D244} |
| L_{C1253} | R^{D10} | R^{D245} | L_{C1307} | R^{D55} | R^{D245} | L_{C1361} | R^{D37} | R^{D245} | L_{C1415} | R^{D143} | R^{D245} |
| L_{C1254} | R^{D10} | R^{D246} | L_{C1308} | R^{D55} | R^{D246} | L_{C1362} | R^{D37} | R^{D246} | L_{C1416} | R^{D143} | R^{D246} |

wherein R^{D1} to R^{D246} have the following structures as defined in the following LIST 15:

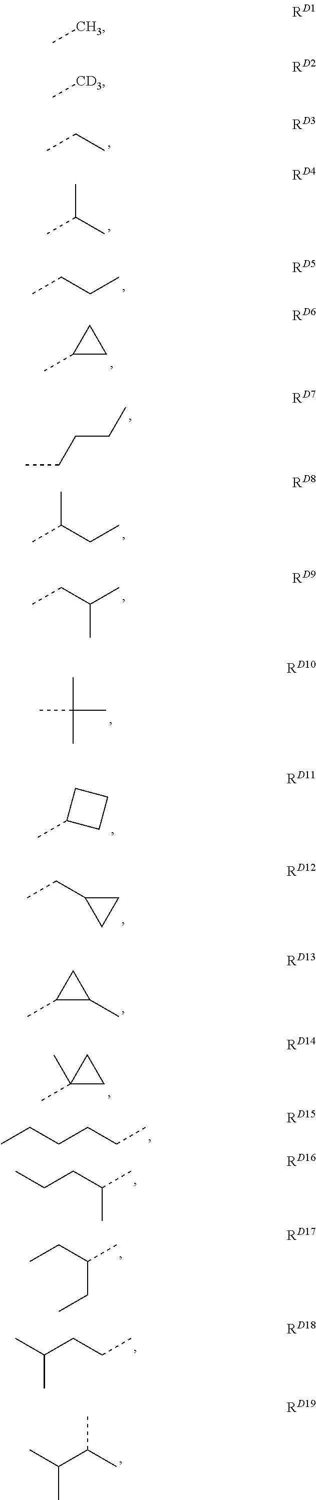

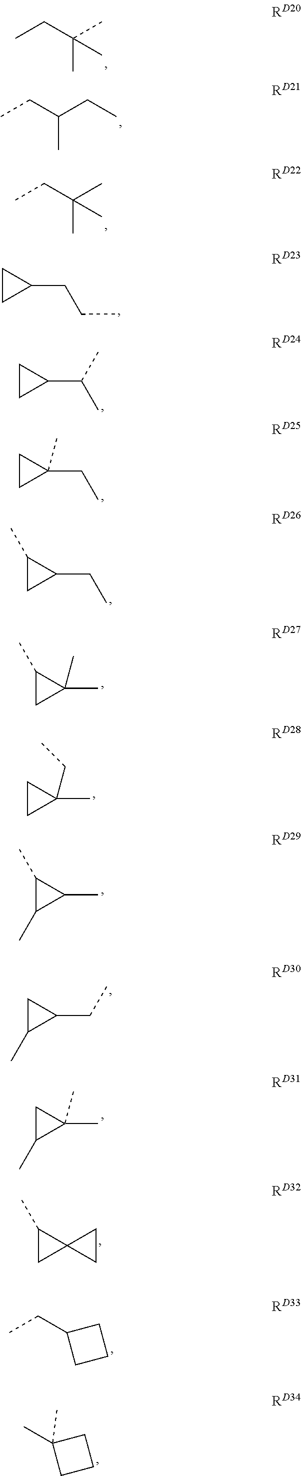

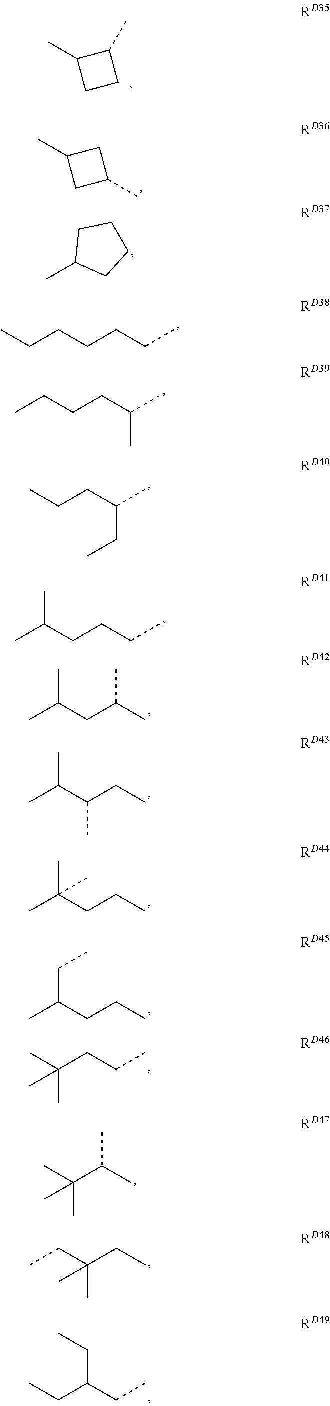

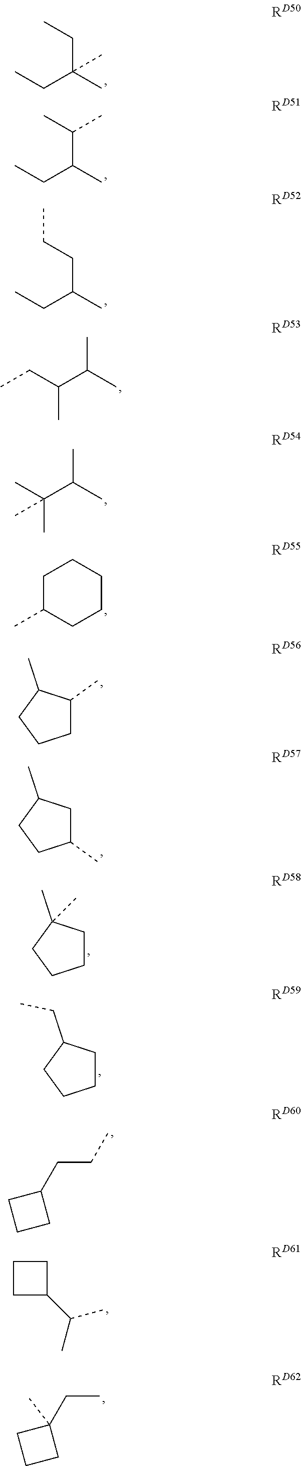

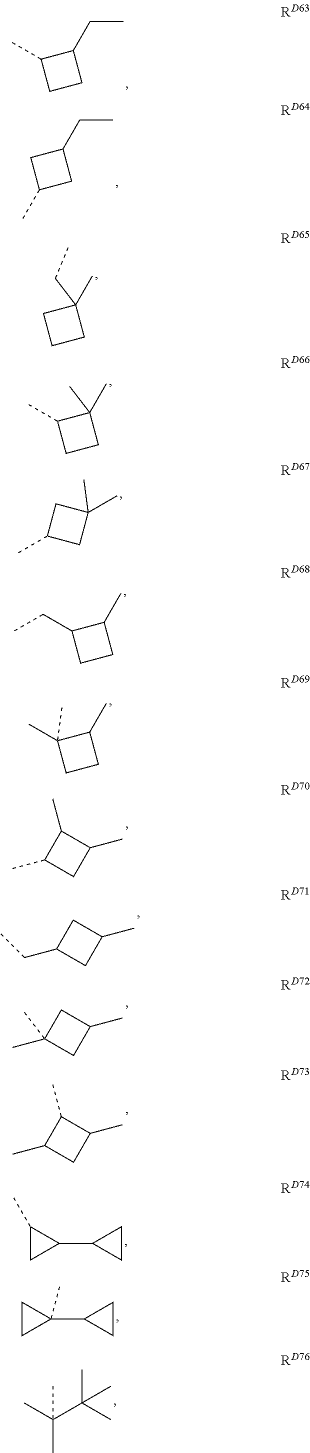

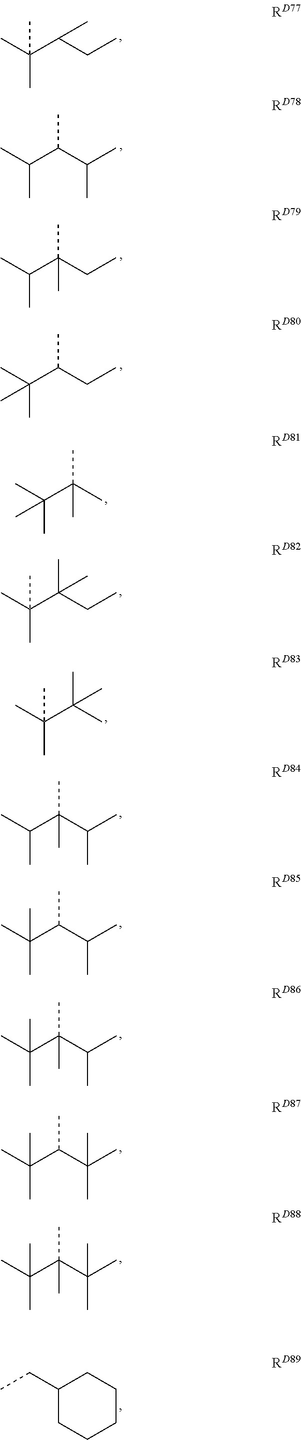

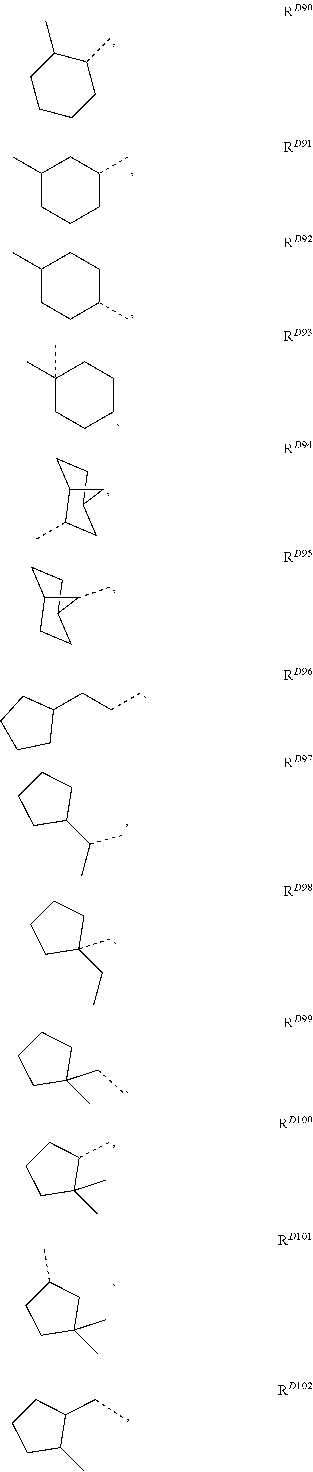

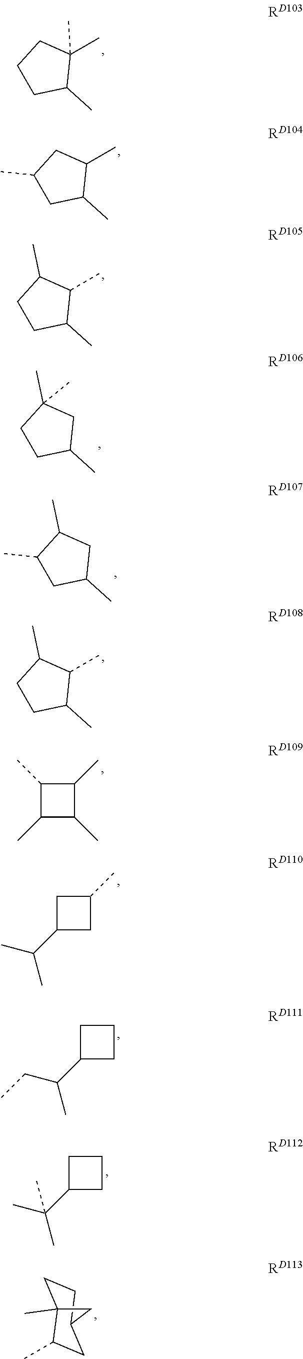

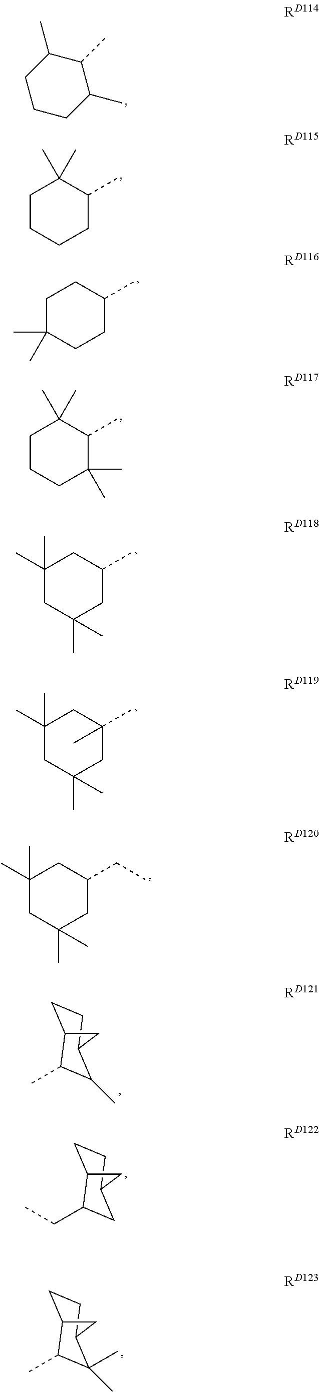

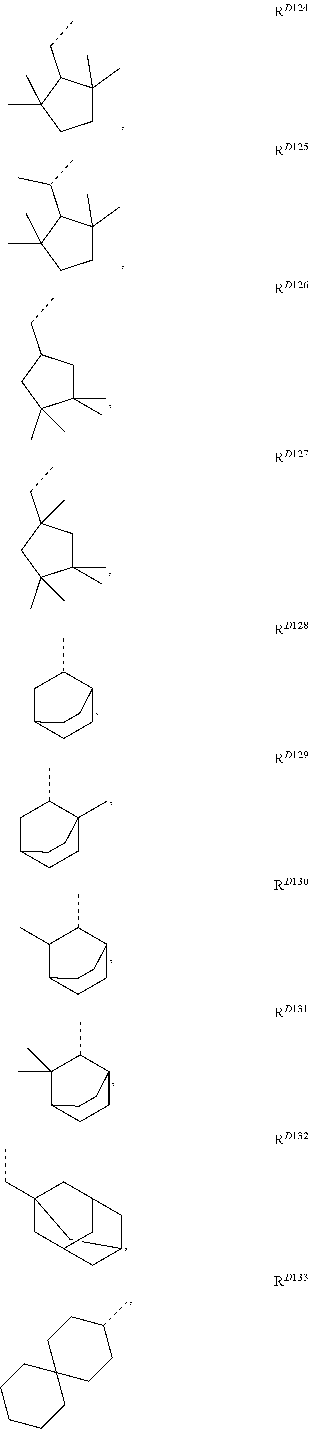

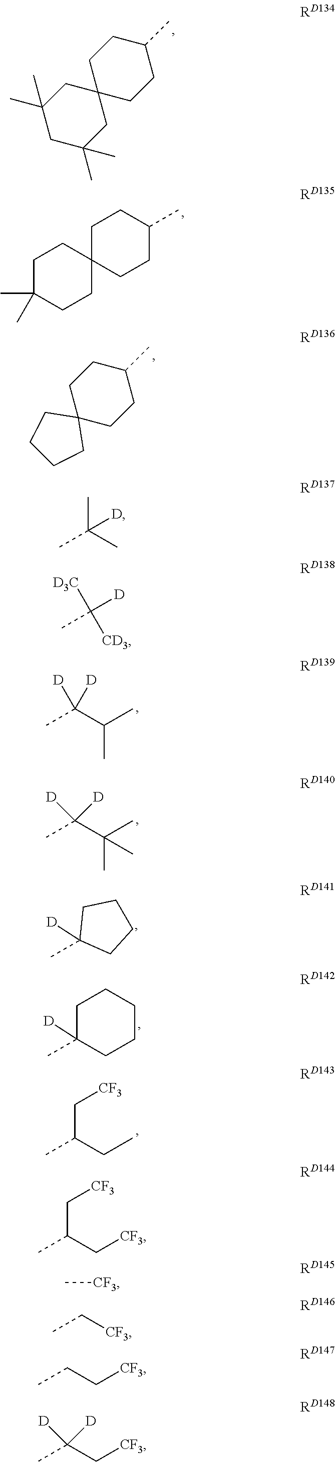

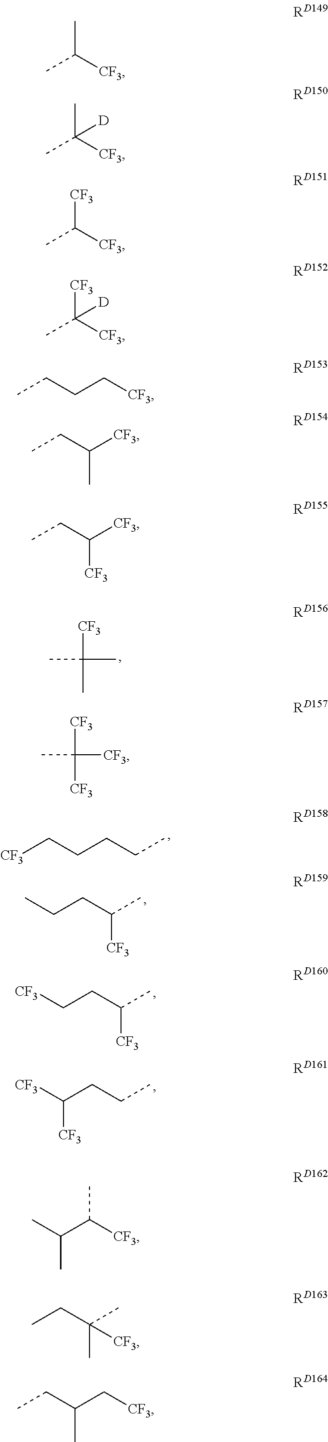

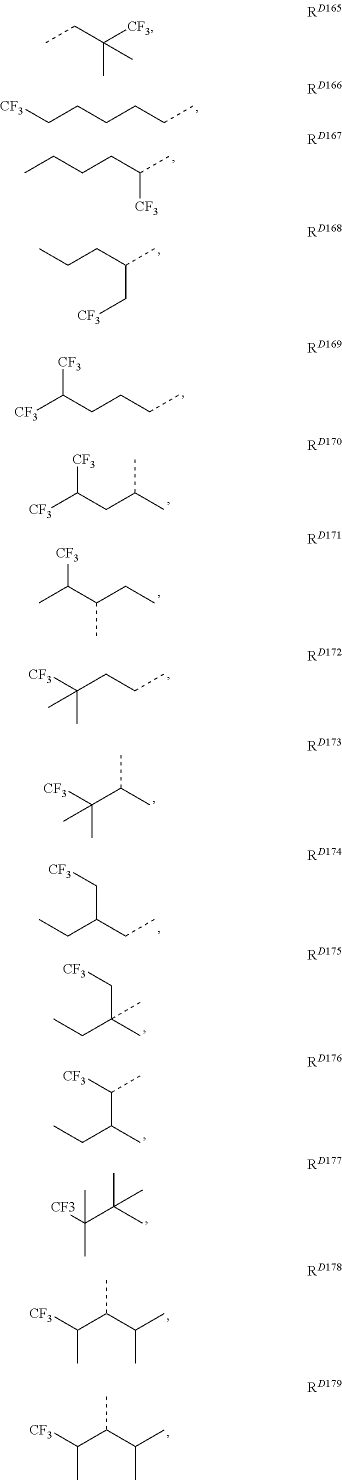

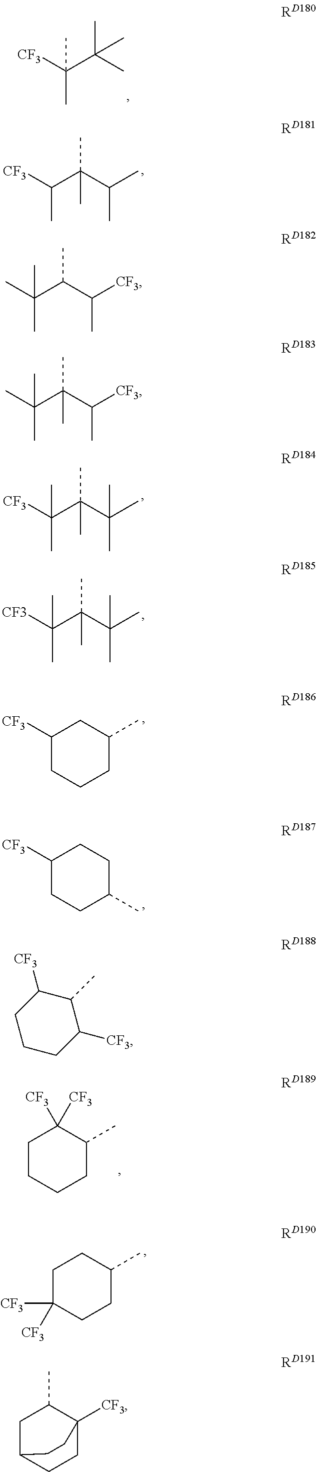

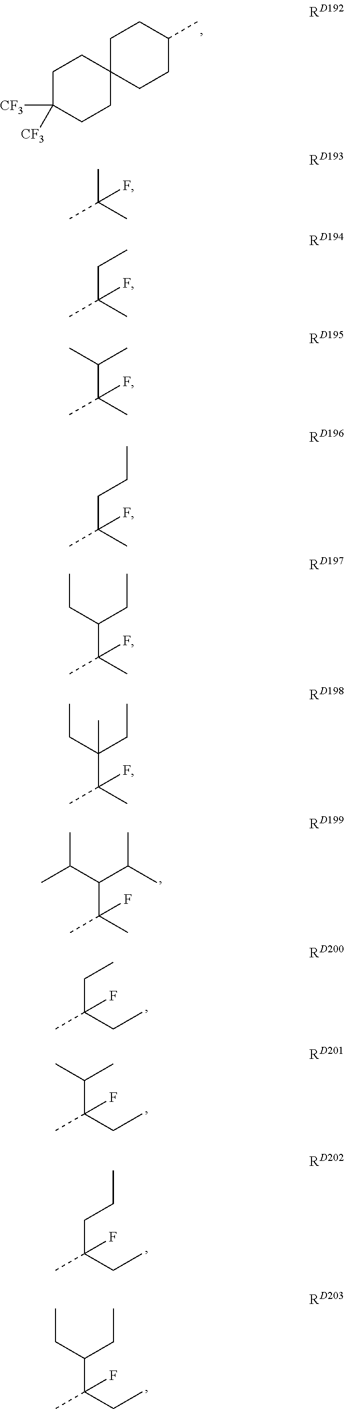

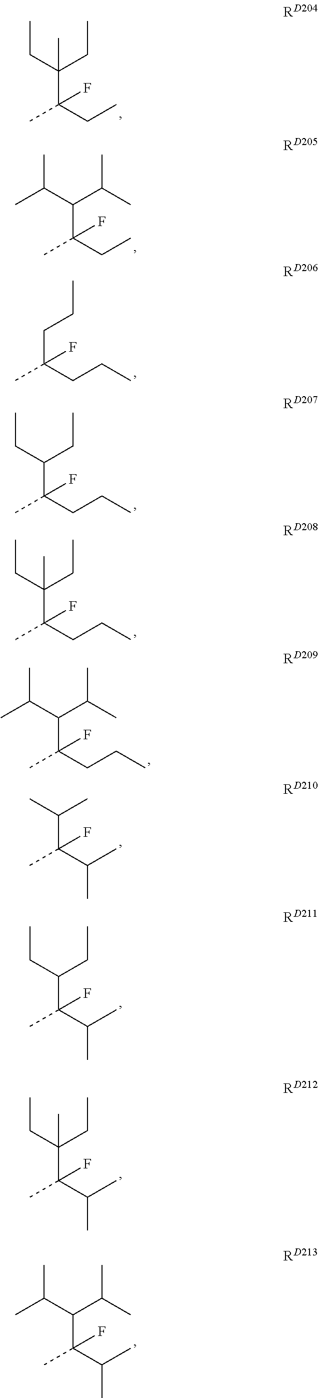

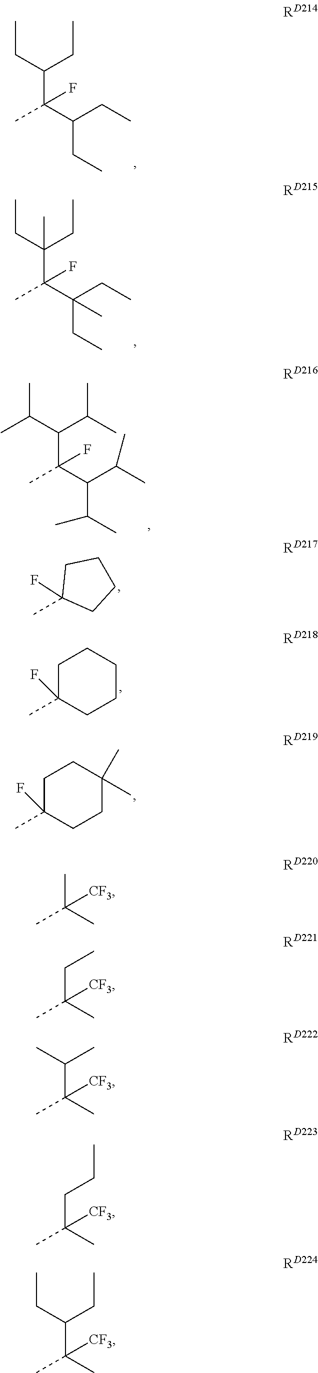

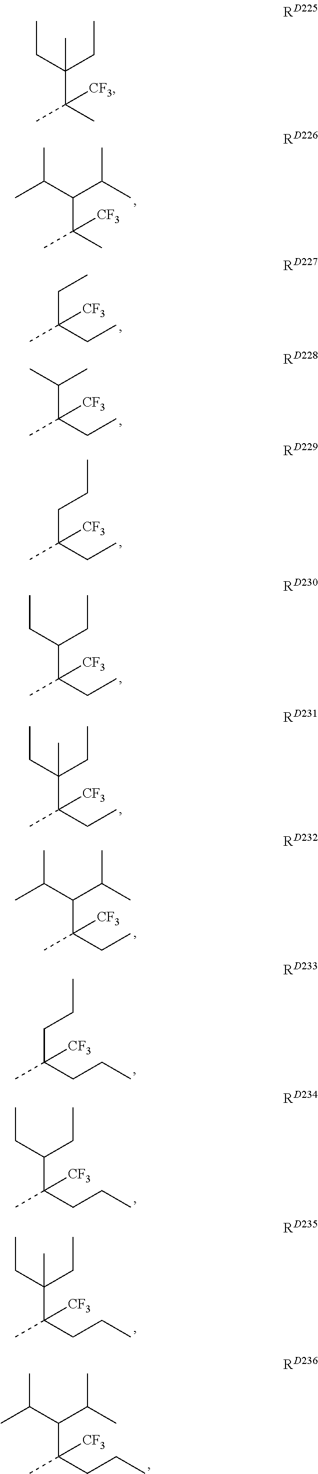

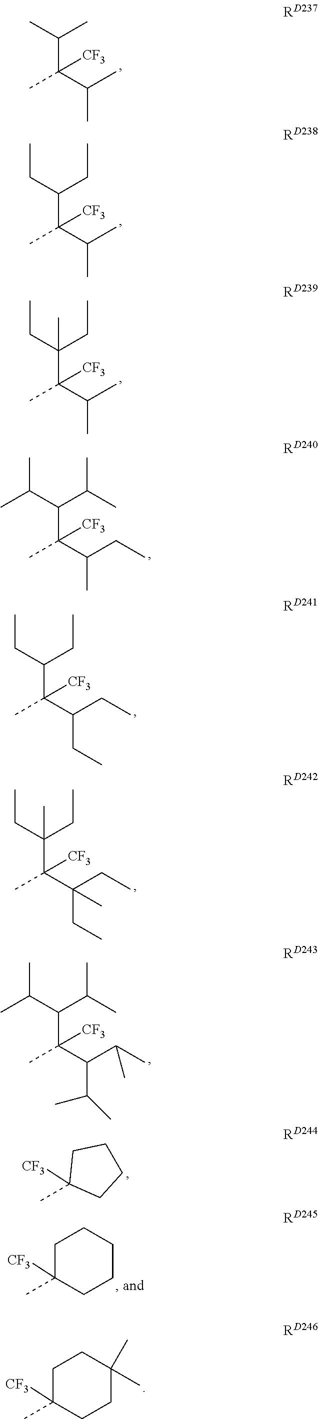

In some embodiments, the compound is selected from the group consisting of only those compounds whose L_{Bk} corresponds to one of the following: L_{B1}, L_{B30}, L_{B31}, L_{B109}, L_{B110}, L_{B112}, L_{B113}, L_{B114}, L_{B125}, L_{B127}, L_{B138}, L_{B140}, L_{B149}, L_{B150}, L_{B170}, L_{B171}, L_{B172}, L_{B174}, L_{B208}, L_{B241}, L_{B312}, L_{B315}, L_{B356}, L_{B367}, L_{B371}, L_{B382}, L_{B439}, L_{B440}, L_{B455}, L_{B456}, L_{B457}, L_{B458}, L_{B461}, L_{B462}, L_{B463}, L_{B469}, and L_{B476}.

In some embodiments, the compound is selected from the group consisting of only those compounds whose L_{Bk} corresponds to one of the following: L_{B1}, L_{B30}, L_{B31}, L_{B125}, L_{B138}, L_{B171}, L_{B172}, L_{B356}, L_{B357}, L_{B367}, L_{B371}, L_{B382}, L_{B455}, and L_{B456}.

In some embodiments, the compound is selected from the group consisting of only those compounds having L_{Cj-I} or L_{Cj-II} ligand whose corresponding R²⁰¹ and R²⁰² are defined to be one of the following structures: R^{D1}, R^{D3}, R^{D4}, R^{D5}, R^{D9}, R^{D10}, R^{D17}, R^{D18}, R^{D20}, R^{D22}, R^{D37}, R^{D40}, R^{D41}, R^{D42}, R^{D43}, R^{D48}, R^{D49}, R^{D50}, R^{D54}, R^{D55}, R^{D58}, R^{D59}, R^{D78}, R^{D79}, R^{D81}, R^{D87}, R^{D88}, R^{D89}, R^{D93}, R^{D116}, R^{D117}, R^{D118}, R^{D119}, R^{D120}, R^{D133}, R^{D134}, R^{D135}, R^{D136}, R^{D143}, R^{D144}, R^{D145}, R^{D146}, R^{D147}, R^{D149}, R^{D151}, R^{D154}, R^{D155}, R^{D161}, R^{D175}, R^{D190}, R^{D193}, R^{D200}, R^{D201}, R^{D206}, R^{D210}, R^{D214}, R^{D215}, R^{D216}, R^{D218}, R^{D219}, R^{D220}, R^{D227}, R^{D237}, R^{D241}, R^{D242}, R^{D245}, and R^{D246}.

In some embodiments, the compound is selected from the group consisting of only those compounds having L_{Cj-I} or L_{Cj-II} ligand whose corresponding R²⁰¹ and R²⁰² are defined to be one of selected from the following structures R^{D1}, R^{D3}, R^{D4}, R^{D5}, R^{D9}, R^{D10}, R^{D17}, R^{D2}, R^{D43}, R^{D50}, R^{D78}, R^{D16}, R^{D118}, R^{D13}, R^{D134}, R^{D135}, R^{D136}, R^{D143}, R^{D144}, R^{D145}, R^{D146}, R^{D149}, R^{D151}, R^{D154}, R^{D155}, R^{D190}, R^{D193}, R^{D200}, R^{D201}, R^{D206}, R^{D210}, R^{D214}, R^{D215}, R^{D216}, R^{D218}, R^{D219}, R^{D220}, R^{D227}, R^{D237}, R^{D241}, R^{D242}, R^{D245}, and R^{D246}.

In some embodiments, the compound is selected from the group consisting of only those compounds having one of the following structures for the L_{Cj-I} ligand:

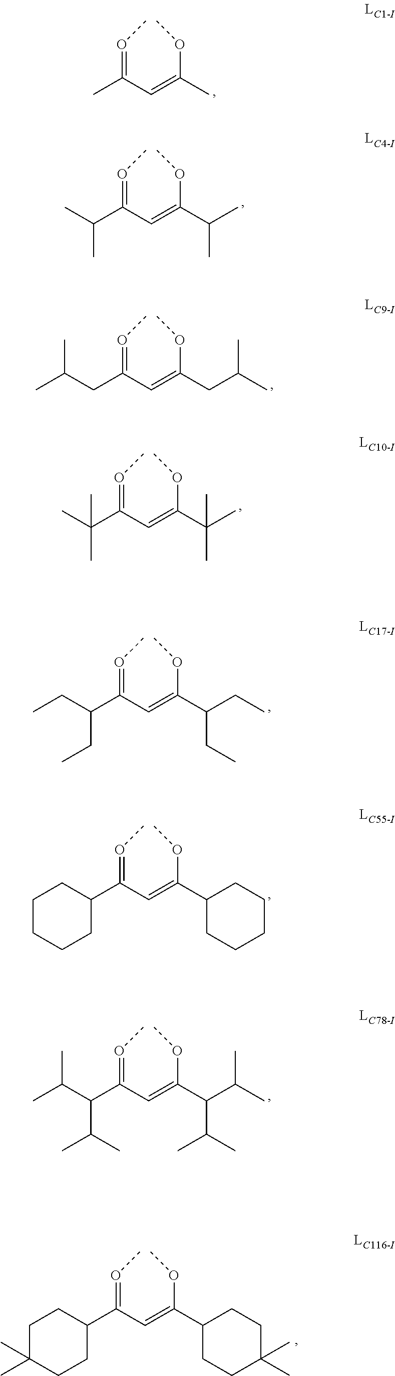

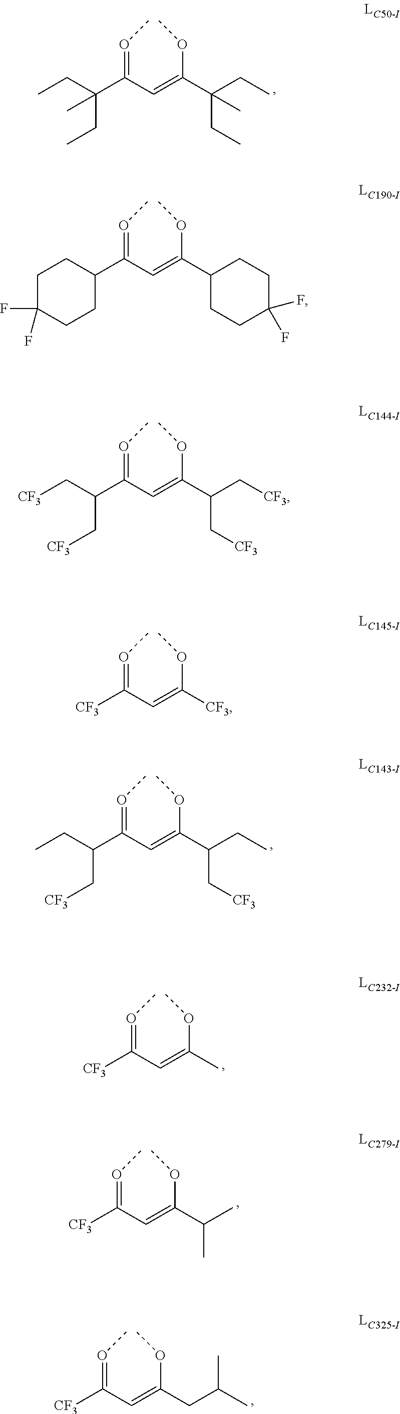

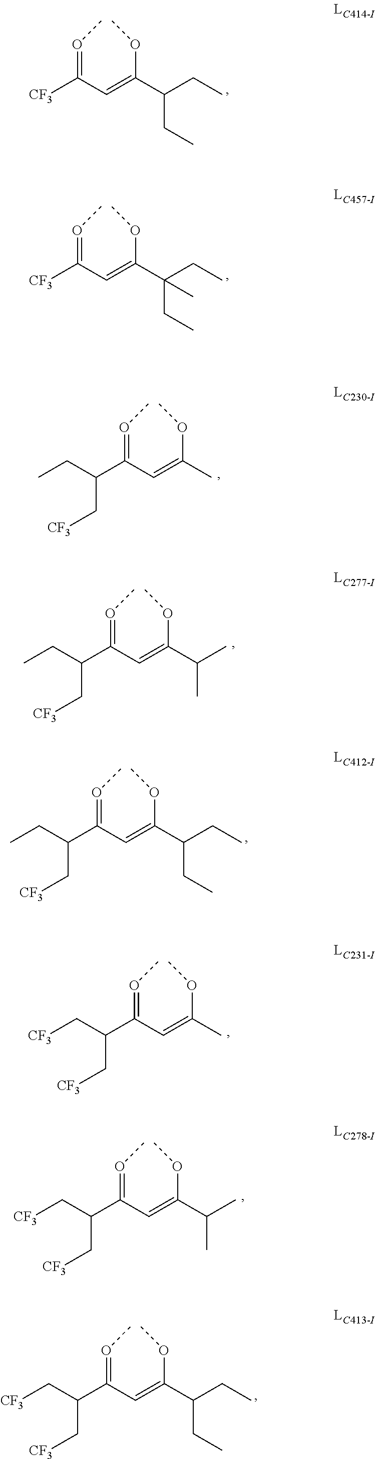

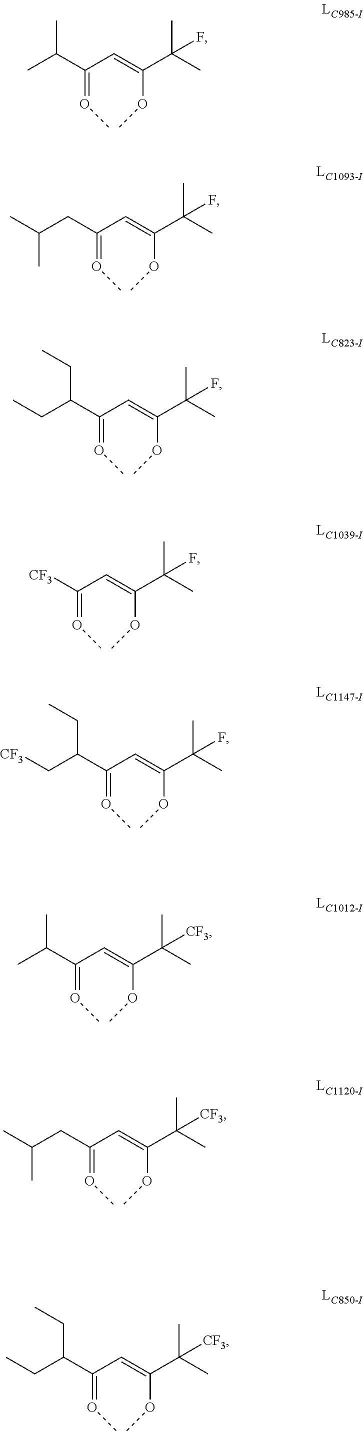

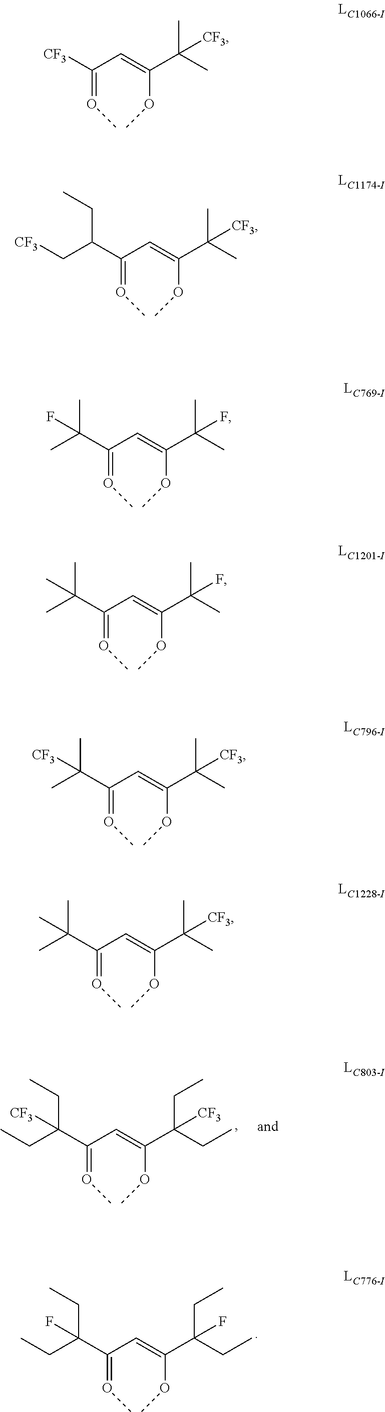

In some embodiments, the compound has a formula selected from the group consisting of Ir(L_{A})₃, Ir(L_{A})₂(L_{B}), Ir(L_{A})(L_{B})₂, Ir(L_{A})₂(L_{C}), and Ir(L_{A})(L_{B})(L_{C}). In some embodiments, L_{A} is selected from the group consisting of the structures of LIST 1, LIST 2, and LIST 3, L_{B} is selected from the group consisting of the structures of LIST 4, LIST 5, and LIST 6 (L_{Bk}), and L_{C} is selected from the group consisting of the structures of L_{Cj-I} and L_{Cj-II} as defined in LIST 7.

In some embodiments, L_{A} is selected from the group consisting of the structures of LIST 1 and L_{B} is selected from the group consisting of the structures of L_{Bk}. In some embodiments, L_{A} is selected from the group consisting of the structures of LIST 2 and L_{B} is selected from the group consisting of the structures of L_{Bk}. In some embodiments, L_{A} is selected from LIST 3 defined herein, and L_{B} is selected from the group consisting of the structures of L_{Bk} wherein k is an integer from 1 to 541. In some embodiments, L_{A} is selected from LIST 1 defined herein, and L_{C} is selected from the group consisting of the structures of L_{Cj-I} and L_{Cj-II} wherein j is an integer from 1 to 1416. In some embodiments, L_{A} is selected from LIST 2 defined herein, and L_{C} is selected from the group consisting of the structures of L_{Cj-I} and L_{Cj-II} wherein j is an integer from 1 to 1416. In some embodiments, L_{A} is selected from LIST 3 defined herein, and L_{C} is selected from the group consisting of the structures of L_{Cj-I} and L_{Cj-II} wherein j is an integer from 1 to 1416.

In some embodiments, the compound can have the formula Ir(L_{Ai1} (R^{H})(R^{I})(R^{J})(Y^{D})(Y^{E}))₃ consisting of the compounds of Ir(L_{A1}(V1)(V1)(V1)(G1)(G1))₃ to Ir(L_{A56}(V263)(V263)(V263)(G31)(G31))₃, the formula Ir(L_{Ai1}(R^{H})(R^{I})(R^{J})(Y^{D})(Y^{E})(L_{Bk})₂ consisting of the compounds of Ir(L_{A1}(V1)(V1)(V1)(G1)(G1)(L_{B1})₂ to Ir(L_{A56}(V263)(V263)(V263)(G31)(G31)(L_{B541})₂, the formula Ir(Lₐᵢ₁(R^{H})(R^{I})(R^{J})(Y^{D})(Y^{E}))₂(L_{Bk}) consisting of the compounds of Ir(L_{A1}(V1)(V1)(V1)(G1)(G1))₂(L_{B1}) to Ir(L_{A56}(V263)(V263)(V263)(G31)(G31))₂(L_{B541}), the formula Ir(L_{Ai1}(R_{H})(R^{I})(R^{J})(Y^{D})(Y^{E}))₂(L_{C1-I}) consisting of the compounds of Ir(L_{A1}(V1)(V1)(V1)(G1)(G1))₂(L_{C1-I}) to Ir(L_{A56}(V263)(V263)(V263)(G31)(G31))₂(L_{C1416-I}), the formula Ir(L_{Ai1}(R^{H})(R^{I})(R^{J})(Y^{D})(Y^{E}))₂(L_{Cj-II}) consisting of the compounds of Ir(L_{A1}(V1)(V1)(V1)(G1)(G1))₂(L_{C1-II}) to Ir(L_{A56}(V263)(V263)(V263)(G31)(G31))₂(L_{C1416-II}), the formula Ir(L_{Ai1}(R^{H})(R^{I})(R^{J})(Y^{D})(Y^{E}))(L_{Bk})(L_{Cj-I}) consisting of the compounds of Ir(L_{A1}(V1)(V1)(V1)(G1)(G1)(L_{B1})(L_{C1-I}) to Ir(L_{A56}(V263)(V263)(V263)(G31)(G31)(L_{B541})(L_{C1416-I}), or the formula Ir(L_{Ai2}(R^{H})(R^{I})(R^{J})(Y^{D})(Y^{E})(L_{Bk})(L_{Cj-II}) consisting of the compounds of Ir(L_{A1}(V1)(V1)(V1)(G1)(G1)(L_{B1})(L_{C1-II}) to Ir(L_{A56}(V263)(V263)(V263)(G31)(G31))(L_{B541})(L_{C1416-II}), wherein L_{Ai1}(R^{H})(R^{I})(R^{J})(Y^{D})(Y^{E}), L_{Bk}, and L_{Cj-I} and L_{Cj-II} are all defined herein.

In some embodiments, the compound can have the formula Ir(L_{Ai2}(R^{H})(R^{I})(R^{J})(Y^{D})(Y^{F}))₃ consisting of the compounds of Ir(L_{A57}(V1)(V1)(V1)(G1)(G1))₃ to Ir(L_{A90}(V263)(V263)(V263)(G31)(G31))₃, the formula Ir(L_{Ai2} (R^{H})(R^{I})(R^{J})(Y^{D})(Y^{F}))(L_{Bk})₂ consisting of the compounds of Ir(L_{A57}(V1)(V1)(V1)(G1)(G1))(L_{B1})₂ to Ir(L_{A90}(V263)(V263)(V263)(G31)(G31))(L_{B541})₂, the formula Ir(L_{A2}(R^{H})(R^{I})(R^{J})(Y^{D})(Y^{F}))₂(L_{Bk}) consisting of the compounds of Ir(L_{A57}(V1)(V1)(V1)(G1)(G1))₂(L_{B1}) to Ir(L_{A90}(V263)(V263)(V263)(G31)(G31))₂(L_{B541}), the formula Ir(L_{Ai2}(R^{H})(R^{I})(R^{J})(Y^{D})(Y^{F}))₂(L_{Cj-I}) consisting of the compounds of Ir(L_{A57}(V1)(V1)(V1)(G1)(G1))₂(L_{C1-I}) to Ir(L_{A90}(V263)(V263)(V263)(G31)(G31))₂(L_{C1416-I}), the formula Ir(L_{Ai2}(R^{H})(R^{I})(R^{J})(Y^{D})(Y^{F}))₂(L_{Cj-II}) consisting of the compounds of Ir(L_{A57}(V1)(V1)(V1)(G1)(G1))₂(L_{C1-II}) to Ir(L_{A90}(V263)(V263)(V263)(G31)(G31))₂(L_{C1416-II}), the formula Ir(L_{Ai2} (R^{H})(R^{I})(R^{J})(Y^{D})(Y^{F}))(L_{Bk})(L_{Cj-I}) consisting of the compounds of Ir(L_{A57}(V1)(V1)(V1)(G1)(G1))(L_{B1})(L_{C1-I}) to Ir(L_{A90}(V263)(V263)(V263)(G31)(G31))(L_{B541})(L_{C1416-I}), or the formula Ir(L_{Ai2}(R^{H})(R^{I})(R^{J})(Y^{D})(Y^{F}))(L_{Bk}) (L_{Cj-II}) consisting of the compounds of Ir(L_{A57}(V1)(V1)(V1)(G1)(G1))(L_{B1})(L_{C1-II}) to Ir(L_{A90}(V263)(V263)(V263)(G31)(G31))(L_{B541})(L_{C1416-II}), wherein L_{Ai1}(R^{H})(R^{I})(R^{J})(Y^{D})(Y^{E}), L_{Bk}, and L_{Cj-I} and L_{Cj-II} are all defined herein.

In some embodiments, the compound is selected from the group consisting of the following structures (LIST 8):

What is claimed is:

1. A compound having a first ligand L_{A} comprising a structure of Formula I: 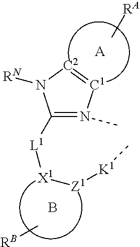
wherein C¹ and C² are carbon atoms;
wherein X¹ is C or N;
wherein Z¹ is C or N;
wherein K¹ is selected from the group consisting of a direct bond, O, S, N(R^{α}), P(R^{α}), B(R^{α}), C(R^{α})(R^{β}), and Si(R^{α})(R^{β});
wherein if K¹ is selected from the group consisting of O, S, N(R^{α}), P(R^{α}), B(R^{α}), C(R^{α})(R^{β}), and Si(R^{α})(R^{β}), then Z¹ is C;
wherein L¹ is selected from the group consisting of a direct bond, O, S, Se, NR, BR, BRR′, PR, CR, C═O, C═NR, C═CRR′, C═S, CRR′, SO, SO₂, P(O)R, SiRR′, GeRR′, alkylene, cycloalkyl, aryl, cycloalkylene, arylene, and heteroarylene;
wherein L_{A} is coordinated to a metal M;
wherein M is selected from the group consisting of Ir, Rh, Re, Ru, Os, Pt, Pd, Ag, Au, and Cu;
wherein moiety A is a fused ring system comprised of exactly one 5-membered ring and one 6-membered ring, and the 5-membered ring comprises C¹ and C²;
wherein moiety B is a monocyclic ring or a polycyclic fused ring system, wherein the monocyclic ring or each ring of the polycyclic fused ring system is independently a 5-membered to 10-membered carbocyclic or heterocyclic ring with the proviso that when M is Ir, moiety B is a polycyclic fused ring system;
wherein R^{A} and R^{B} each independently represent mono to the maximum allowable substitution, or no substitution;
wherein each of R^{N}, R, R′, R^{α}, R^{β}, R^{A}, and R^{B} is independently hydrogen or a substituent selected from the group consisting of deuterium, halogen, alkyl, cycloalkyl, heteroalkyl, heterocycloalkyl, arylalkyl, alkoxy, aryloxy, amino, silyl, germyl, boryl, alkenyl, cycloalkenyl, heteroalkenyl, alkynyl, aryl, heteroaryl, acyl, carboxylic acid, ether, ester, nitrile, isonitrile, sulfanyl, sulfinyl, sulfonyl, phosphino, and combinations thereof;
wherein L_{A} may be joined with other ligands to comprise a tridentate, tetradentate, pentadentate, or hexadentate ligand; and
wherein any two of R^{N}, R, R′, R^{α}, R^{β}, R^{A}, and R^{B} may be joined or fused to form a ring, with the proviso that when M is Ir, two R^{A} substituents do not join to form a ring.

2. The compound of claim 1, wherein each of R^{N}, R, R′, R^{α}, R^{β}, R^{A}, and R^{B} is independently a hydrogen or a substituent selected from the group consisting of deuterium, fluorine, alkyl, cycloalkyl, heteroalkyl, alkoxy, aryloxy, amino, silyl, germyl, boryl, alkenyl, cycloalkenyl, heteroalkenyl, aryl, heteroaryl, nitrile, isonitrile, sulfanyl, and combinations thereof.

3. The compound of claim 1, wherein M is Ir.

4. The compound of claim 1, wherein X¹ is C; and/or wherein Z¹ is C.

5. The compound of claim 1, wherein K¹ is a direct bond; and/or wherein L¹ is a direct bond.

6. The compound of claim 1, wherein RN comprises at least one aryl group; and/or wherein R^{N} comprises at least one alkyl group.

7. The compound of claim 1, wherein moiety A is selected from the group consisting of benzofuran, aza-benzofuran, benzothiophene, aza-benzothiophene, benzothiazole, aza-benzothiazole, indene, aza-indene, indole, and aza-indole.

8. The compound of claim 1, wherein moiety B comprises at least five 5-membered to 10-membered carbocyclic or heterocyclic rings which are fused together.

9. The compound of claim 1, wherein the ligand L_{A} is selected from the group consisting of the structures of LIST 1 as defined herein;
wherein X² to X¹⁷ is C or N;
wherein R^{AA}, R^{BB}, and R^{CC} is independently hydrogen or a substituent selected from the group consisting of deuterium, halogen, alkyl, cycloalkyl, heteroalkyl, heterocycloalkyl, arylalkyl, alkoxy, aryloxy, amino, silyl, germyl, boryl, alkenyl, cycloalkenyl, heteroalkenyl, alkynyl, aryl, heteroaryl, acyl, carboxylic acid, ether, ester, nitrile, isonitrile, sulfanyl, sulfinyl, sulfonyl, phosphino, and combinations thereof;
wherein Y¹, Y², and Y³ are each independently selected from the group consisting of O, S, NR, CRR′, and SiRR′ and;
wherein Y⁴ is selected from the group consisting of C═O, C═S, C═Se, BR, GaR, SiRR′, and GeRR′.

10. The compound of claim 1, wherein the ligand L_{A} is selected from the group consisting of the following structures of LIST 2 as defined herein;
wherein X¹⁸ is Cor N;
wherein R^{N1}, R^{A1}, R^{B1}, R^{B2}, and R^{B3} is each independently hydrogen or a substituent selected from the group consisting of deuterium, halogen, alkyl, cycloalkyl, heteroalkyl, heterocycloalkyl, arylalkyl, alkoxy, aryloxy, amino, silyl, germyl, boryl, alkenyl, cycloalkenyl, heteroalkenyl, alkynyl, aryl, heteroaryl, acyl, carboxylic acid, ether, ester, nitrile, isonitrile, sulfanyl, sulfinyl, sulfonyl, phosphino, and combinations thereof;
wherein Y^{A}, Y^{B}, and Y^{C} are each independently selected from the group consisting of O, S, NR, CRR′, and SiRR′; and
wherein Y^{S} is selected from the group consisting of C═O, C═S, C═Se, BR, GaR, SiRR′, and GeRR′.

11. The compound of claim 1, wherein the ligand L_{A} is selected from L_{Ai1}(R^{H})(R^{I})(R^{J})(Y^{D})(Y^{E}), L_{Ai2}(R^{H})(R^{I})(R^{J})(Y^{D})(Y^{F}), L_{Ai3}(R^{H})(R^{I})(R^{J})(Y^{D}), and L_{Ai4}(R^{I})(R^{J})(Y^{D})(Y^{F}), wherein i1 is an integer of from 1 to 56, i2 is an integer of from 57 to 90, and 135 to 184, i3 is an integer of from 91 to 134, i4 is an integer of from 185 to 192, H, I and J are each independent an integer of from 1 to 263, each of D, E and F is an integer of from 1 to 31, each of R^{H}, R^{I}, and R^{J} are independently selected from V1 to V263, each of Y^{D}, Y^{E} and Y^{F} is independently selected from G1 to G31, wherein L_{A1}(V1)(V1)(V1)(G1)(G1) to L_{A56}(V263)(V263)(V263)(G31)(G31), L_{A57}(V1)(V1)(V1)(G1)(G1) to L_{A90}(V263)(V263)(V263)(G31)(G31), L_{A91}-(V1)(V1)(V1)(G1) to L_{A134}-(V263)(V263)(V263)(G31), L_{A135}(V1)(V1)(V1)(G1)(G1) to L_{A184}(V263)(V263)(V263)(G31)(G31), L_{A185}-(V1)(V1)(G1)(G1) to L_{A192}-(V263)(V263)(G31)(G31) are defined in the table of LIST 3 as defined herein;
wherein V1 to V263 have the following structures as defined in LIST 14 as defined herein;
wherein G1 to G31 have the structures defined in the following:

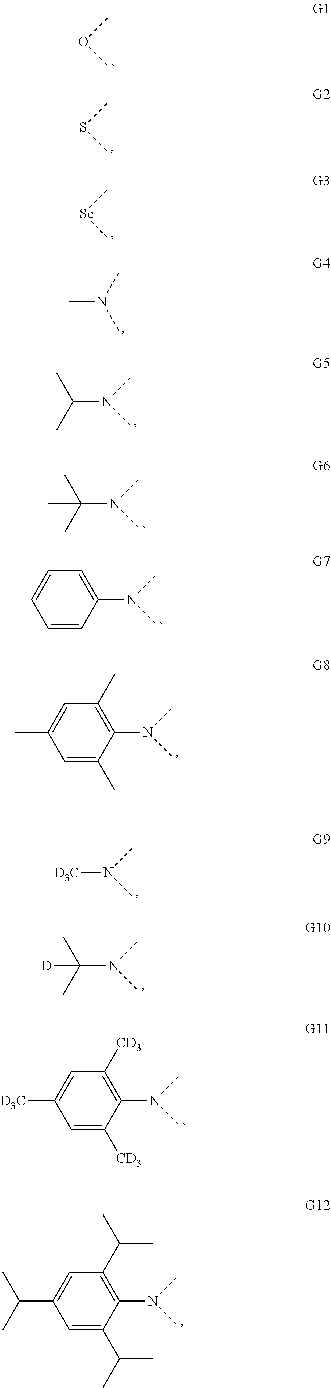

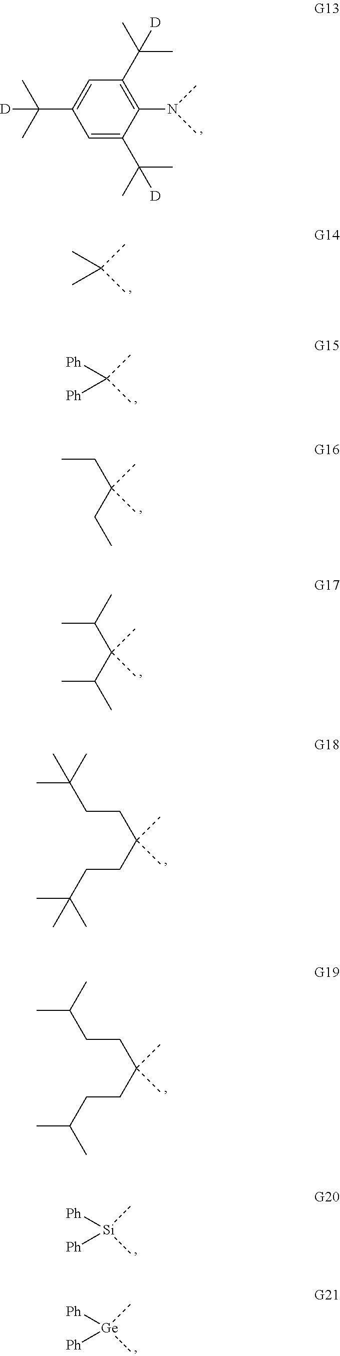

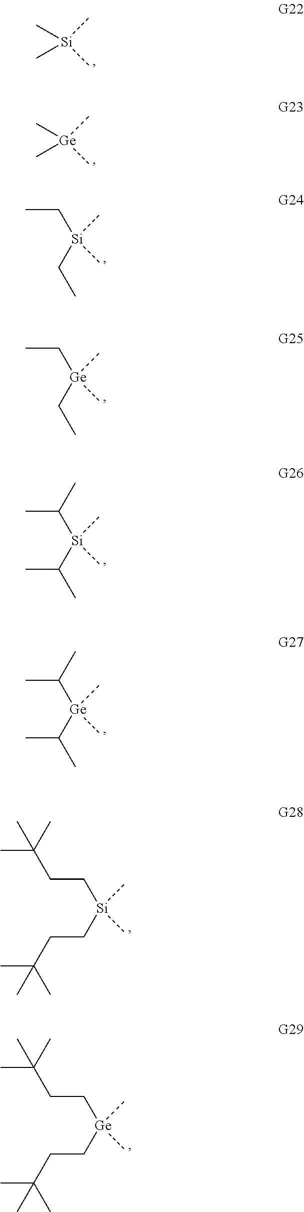

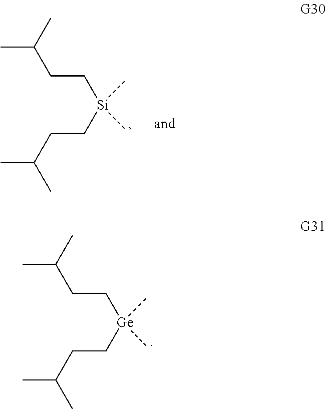

12. The compound of claim 1, wherein the compound has a formula of M(L_{A})ₚ(L_{B})_{q}(L_{C}), wherein L_{B} and L_{C} are each a bidentate ligand; and wherein p is 1, 2, or 3; q is 0, 1, or 2; r is 0, 1, or 2; and p+q+r is the oxidation state of the metal M.

13. The compound of claim 12, wherein L_{B} and L_{C} are each independently selected from the group consisting of the structures of LIST 4 as defined herein;
wherein:
T is selected from the group consisting of B, Al, Ga, and In;
wherein K^{1′} is a direct bond or is selected from the group consisting of NRₑ, PRₑ, O, S, and Se;
each of Y¹ to Y¹³ is independently selected from the group consisting of carbon and nitrogen;
Y′ is selected from the group consisting of BRₑ, NRₑ, PRₑ, O, S, Se, C═O, C═S, C═Se, S═O, SO₂, P(O)Rₑ, C═NRₑ, C═CRₑR_{f}, CRₑR_{f}, SiRₑR_{f}, and GeRₑR_{f};
Rₑ and R_{f} can be fused or joined to form a ring;
each Rₐ, R_{b}, R_{c}, and R_{d} independently represent zero, mono, or up to a maximum allowed number of substitutions to its associated ring;
each of Rₐ₁, R_{b1}, R_{c1}, R_{d1}, Rₐ, R_{b}, R_{c}, R_{d}, Rₑ and R_{f} is independently a hydrogen or a substituent selected from the group consisting of deuterium, halide, alkyl, cycloalkyl, heteroalkyl, arylalkyl, alkoxy, aryloxy, amino, silyl, germyl, boryl, alkenyl, cycloalkenyl, heteroalkenyl, alkynyl, aryl, heteroaryl, acyl, carbonyl, carboxylic acid, ester, nitrile, isonitrile, sulfanyl, sulfinyl, sulfonyl, phosphino, selenyl, and combinations thereof; the general substituents defined herein; and
any two adjacent Rₐ, R_{b}, R_{c}, R_{d}, Rₑ and R_{f} can be fused or joined to form a ring or form a multidentate ligand.

14. The compound of claim 12, wherein the compound comprises a structure of Formula III: 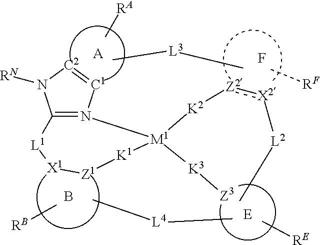
wherein:
M¹ is Pd or Pt;
X^{2′} is selected from the group consisting of BR^{δ}, BR^{δ}R^{η}, NR^{δ}, NR^{δ}R^{η}, PR^{δ}, PR^{δ}R^{η}, P(O)R^{δ}, O, S, Se, C═O, C═S, C═S^{δ}, C═NR^{δ}, C═CR^{δ}R^{η}, S═O, SO₂, CR^{δ}, CR^{δ}R^{η}, SiR^{δ}R^{η}, and GeR^{δ}R^{η};
Z^{2′} is selected from the group consisting of CR^{Z}, NR^{Z}, O, S, Se, P, and As;
Z³ is Cor N;
K² and K³ are each independently selected from the group consisting of a direct bond, O, S, N(R^{α}), P(R^{α}), B(R^{α}), C(R^{α})(R^{β}), and Si(R^{α})(R^{β}), wherein at least two of them are direct bonds;
L², L³, and L⁴ are each independently selected from the group consisting of a single bond, absent a bond, O, S, CRR′, SiRR′, BR, and NR, wherein at least one of L³ and L⁴ is present;
R^{δ} or R^{η} of X^{2′} and R^{Z} of Z^{2′} are optionally joined or fused to form moiety F;
wherein moiety F (if present) is optionally substituted by R^{F} representing mono to the maximum allowable substitution, or no substitution;
R^{E} represents mono to the maximum allowable substitution, or no substitution;
moieties E and F (if present) are each independently a monocyclic ring or a polycyclic fused ring system, wherein the monocyclic ring or each ring of the polycyclic fused ring system is independently a 5-membered to 10-membered carbocyclic or heterocyclic ring;
each of R^{δ}, R^{η}, R^{Z}, R^{E}, and R^{F} (if present) is independently a hydrogen or a substituent selected from the group consisting of deuterium, fluorine, alkyl, cycloalkyl, heteroalkyl, alkoxy, aryloxy, amino, silyl, germyl, boryl, alkenyl, cycloalkenyl, heteroalkenyl, aryl, heteroaryl, nitrile, isonitrile, sulfanyl, and combinations thereof;
two adjacent R^{A}, R^{B}, R^{E}, R^{N}, and R^{F} (if present) can be joined or fused together to form a ring where chemically feasible; and
X¹, Z¹, R^{A}, R^{B}, R^{N}, R^{α}, R^{β}, R, R′, moiety A, and moiety B are all defined the same as above, with the proviso that two R^{A} substituents do not join to form a ring.

15. The compound of claim 14, wherein the compound is selected from the group consisting of compounds having the formula of Pt(L_{A′})(Ly): 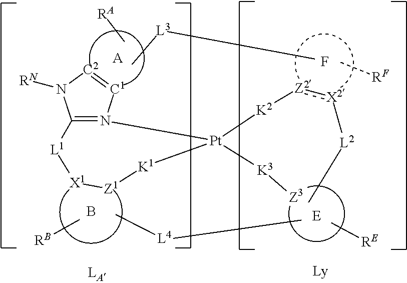
wherein L_{A′} is selected from the group consisting of the structures shown in LIST 9 as defined herein;
wherein L_{y} is selected from the group consisting of the structures shown in LIST 10 as defined herein; R^{X} and R^{Y} is independently hydrogen or a substituent selected from the group consisting of deuterium, halogen, alkyl, cycloalkyl, heteroalkyl, heterocycloalkyl, arylalkyl, alkoxy, aryloxy, amino, silyl, germyl, boryl, alkenyl, cycloalkenyl, heteroalkenyl, alkynyl, aryl, heteroaryl, acyl, carboxylic acid, ether, ester, nitrile, isonitrile, sulfanyl, sulfinyl, sulfonyl, phosphino, and combinations thereof.

16. The compound of claim 14, wherein the compound is selected from the group consisting of the compounds having the formula of Pt(L_{A′})(Ly): 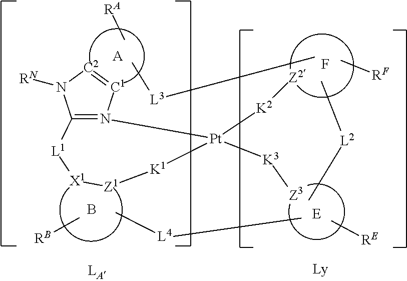
wherein L_{A′} is selected from L_{A′p1}(R^{H})(R^{I})(R^{J})(Y^{D})(Y^{E}), L_{A′p2}(R^{H})(R^{I})(R^{J})(Y^{D})(Y^{F}), and L_{A′p3}(R^{H})(R^{I})(R^{J})(Y^{D}), wherein p1 is an integer of from 1 to 56, p2 is an integer of from 57 to 90, p3 is an integer of from 91 to 94, H, I and J are each independent an integer of from 1 to 246, each of D, E and F is an integer of from 1 to 31, each of R^{H}, R^{I}, and R^{J} are independently selected from V1 to V263, each of Y^{D}, Y^{E} and Y^{F} is independently selected from G1 to G31, wherein L_{A′1}(V1)(V1)(V1)(G1)(G1) to L_{A′56}(V263)(V263)(V263)(G31)(G31), L_{A′57}(V1)(V1)(V1)(G1)(G1) to L_{A′90}(V263)(V263)(V263)(G31)(G31), and L_{A′91}(V1)(V1)(V1)(G1) to L_{A′94}(V263)(V263)(V263)(G31) are defined in the table of LIST 11 as defined herein;
wherein L_{y} is selected from LyQ-(Rs)(Rt)(Ru), wherein Q is an integer of from 1 to 50, s, t, u are each an integer of from 1 to 246, Rs, Rt, and Ru are each independently selected from the group consisting of V1 to V263, each of Ly1-(V1)(V1)(V1) to Ly50-(V263)(V263)(V263) are defined in the table of LIST 12 as defined herein.

17. The compound of claim 14, wherein the compound is selected from the group consisting of the structures of LIST 13 as defined herein.

18. An organic light emitting device (OLED) comprising:
an anode;
a cathode; and
an organic layer disposed between the anode and the cathode,
wherein the organic layer comprises a compound having a first ligand L_{A} comprising a structure of Formula I: 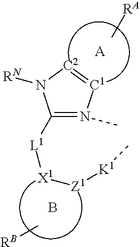
wherein C¹ and C² are carbon atoms;
wherein X¹ is C or N;
wherein Z¹ is Cor N;
wherein K¹ is selected from the group consisting of a direct bond, O, S, N(R^{α}), P(R^{α}), B(R^{α}), C(R^{α})(R^{β}), and Si(R^{α})(R^{β});
wherein if K¹ is selected from the group consisting of O, S, N(R^{α}), P(R^{α}), B(R^{α}), C(R^{α})(R^{β}), and Si(R^{α})(R^{β}), then Z¹ is C;
wherein L¹ is selected from the group consisting of a direct bond, O, S, Se, NR, BR, BRR′, PR, CR, C═O, C═NR, C═CRR′, C═S, CRR′, SO, SO₂, P(O)R, SiRR′, GeRR′, alkylene, cycloalkyl, aryl, cycloalkylene, arylene, and heteroarylene;
wherein L_{A} is coordinated to a metal M;
wherein M is selected from the group consisting of Ir, Rh, Re, Ru, Os, Pt, Pd, Ag, Au, and Cu;
wherein moiety A is a fused ring system comprised of exactly one 5-membered ring and one 6-membered ring, and the 5-membered ring comprises C¹ and C²;
wherein moiety B is a monocyclic ring or a polycyclic fused ring system, wherein the monocyclic ring or each ring of the polycyclic fused ring system is independently a 5-membered to 10-membered carbocyclic or heterocyclic ring with the proviso that when M is Ir, moiety B is a polycyclic fused ring system;
wherein R^{A} and R^{B} each independently represent mono to the maximum allowable substitution, or no substitution;
wherein each of R^{N}, R, R′, R^{α}, R^{β}, R^{A}, and R^{B} is independently hydrogen or a substituent selected from the group consisting of deuterium, halogen, alkyl, cycloalkyl, heteroalkyl, heterocycloalkyl, arylalkyl, alkoxy, aryloxy, amino, silyl, germyl, boryl, alkenyl, cycloalkenyl, heteroalkenyl, alkynyl, aryl, heteroaryl, acyl, carboxylic acid, ether, ester, nitrile, isonitrile, sulfanyl, sulfinyl, sulfonyl, phosphino, and combinations thereof;
wherein L_{A} may be joined with other ligands to comprise a tridentate, tetradentate, pentadentate, or hexadentate ligand; and
wherein any two of R^{N}, R, R′, R^{α}, R^{β}, R^{A}, and R^{B} may be joined or fused to form a ring, with the proviso that when M is Ir, two R^{A} substituents do not join to form a ring.

19. A consumer product comprising an organic light-emitting device (OLED) comprising:
an anode;
a cathode; and
an organic layer disposed between the anode and the cathode,
wherein the organic layer comprises a compound according to claim 1.

20. A compound, or a neutral molecular form thereof, or a monovalent or polyvalent form thereof, or a monomeric or polymeric form thereof, or a macromolecular or supramolecular form thereof;
wherein the compound has a first ligand L_{A} comprising a structure of Formula I: 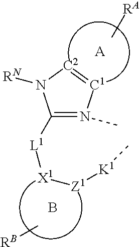
wherein C¹ and C² are carbon atoms;
wherein X¹ is C or N;
wherein Z¹ is C or N;
wherein K¹ is selected from the group consisting of a direct bond, O, S, N(R^{α}), P(R^{α}), B(R^{α}), C(R^{α})(R^{β}), and Si(R^{α})(R^{β});
wherein if K¹ is selected from the group consisting of O, S, N(R^{α}), P(R^{α}), B(R^{α}), C(R^{α})(R^{β}), and Si(R^{α})(R^{β}), then Z¹ is C;
wherein L¹ is selected from the group consisting of a direct bond, O, S, Se, NR, BR, BRR′, PR, CR, C═O, C═NR, C═CRR′, C═S, CRR′, SO, SO₂, P(O)R, SiRR′, GeRR′, alkylene, cycloalkyl, aryl, cycloalkylene, arylene, and heteroarylene;
wherein L_{A} is coordinated to a metal M;
wherein M is selected from the group consisting of Ir, Rh, Re, Ru, Os, Pt, Pd, Ag, Au, and Cu;
wherein moiety A is a fused ring system comprised of exactly one 5-membered ring and one 6-membered ring, and the 5-membered ring comprises C¹ and C²;
wherein moiety B is a monocyclic ring or a polycyclic fused ring system, wherein the monocyclic ring or each ring of the polycyclic fused ring system is independently a 5-membered to 10-membered carbocyclic or heterocyclic ring with the proviso that when M is Ir, moiety B is a polycyclic fused ring system;
wherein R^{A} and R^{B} each independently represent mono to the maximum allowable substitution, or no substitution;
wherein each of R^{N}, R, R′, R^{α}, R^{β}, R^{A}, and R^{B} is independently hydrogen or a substituent selected from the group consisting of deuterium, halogen, alkyl, cycloalkyl, heteroalkyl, heterocycloalkyl, arylalkyl, alkoxy, aryloxy, amino, silyl, germyl, boryl, alkenyl, cycloalkenyl, heteroalkenyl, alkynyl, aryl, heteroaryl, acyl, carboxylic acid, ether, ester, nitrile, isonitrile, sulfanyl, sulfinyl, sulfonyl, phosphino, and combinations thereof;
wherein L_{A} may be joined with other ligands to comprise a tridentate, tetradentate, pentadentate, or hexadentate ligand; and
wherein any two of R^{N}, R, R′, R^{α}, R^{β}, R^{A}, and R^{B} may be joined or fused to form a ring, with the proviso that when M is Ir, two R^{A} substituents do not join to form a ring.
